(19) United States
(12) Patent Application Publication
(10) Pub. No.: US 2006/0011946 A1
(43) Pub. Date: Jan. 19, 2006

(54) Nitride semiconductor laser element

(76) Inventors: Tadao Toda, Souraku-gun (JP); Tsutomu Yamaguchi, Nara-shi (JP); Masayuki Hata, Osaka (JP); Yasuhiko Nomura, Osaka (JP); Masayuki Shouno, Osaka (JP); Yuuji Hishida, Osaka (JP); Keiichi Yodoshi, Osaka (JP); Daijiro Inoue, Kyoto-shi (JP); Takashi Kano, Osaka (JP); Nobuhiko Hayashi, Osaka (JP)

Correspondence Address: MCDERMOTT WILL & EMERY LLP, 600 13TH STREET, N.W., WASHINGTON, DC, 20005-3096, US

(21) Appl. No.: 10/506,100

(22) PCT Filed: Feb. 28, 2003
(86) PCT No.: PCT/JP03/02287

§ 371 Date: Jul. 11, 2005

(30) Foreign Application Priority Data
Mar. 1, 2002 (JP) 2002-56364
Dec. 3, 2002 (JP) 2002-350693

(51) Int. Cl. H01L 27/10

(52) U.S. Cl. 257/202

(57) ABSTRACT

A nitride semiconductor laser element capable of controlling the lateral confinement of light with a good reproducibility, the nitride semiconductor element comprising an n-type cladding layer (3), an MQW light emitting layer (4) formed on the cladding layer (3), a p-type cladding layer (5) and a p-type contact layer (6) formed on the light emitting layer (4), and an ion implantation light absorbing layer (7) formed, by introducing carbon, in regions other than a current passing region (8) in the cladding layer (5) and the contact layer (6).

### TECHNICAL FIELD

The present invention relates to a nitride semiconductor laser element, and more particularly, it relates to a nitride semiconductor laser element having a light absorption layer.

### BACKGROUND TECHNIQUE

A nitride semiconductor laser element has recently been expected for utilization as the light source for an advanced large capacity optical disk, and is increasingly subjected to development.

FIG. 173 is a sectional view showing the structure of a conventional nitride semiconductor laser element. The structure of the conventional semiconductor laser element is described with reference to FIG. 173. In this conventional nitride semiconductor laser element, an n-type contact layer 1002 of n-type GaN, an n-type cladding layer 1003 of n-type AlGaN, an MQW (Multiple Quantum Well: multiple quantum well) active layer 1004 of InGaN and a p-type cladding layer 1005 having a projecting portion and consisting of p-type AlGaN are formed on a sapphire substrate 1001. The projecting portion of the p-type cladding layer 1005 and the p-type contact layer 1006 form a ridge portion 1020 serving as a current passing region (current path).

A current blocking layer 1007 consisting of a dielectric such as SiO₂ is formed to have an opening on an exposed upper surface portion of the n-type contact layer 1002 and to cover the overall surface excluding the upper surface of the p-type contact layer 1006. A p-side ohmic electrode 1008 is formed on the p-type contact layer 1006. A p-side pad electrode 1009 is formed to be in contact with the upper surface of this p-side ohmic electrode 1008. An n-side ohmic electrode 1010 is formed to be in contact with the upper surface portion of the n-type contact layer 1002 exposed in the opening of the current blocking layer 1007. An n-side pad electrode 1011 is formed on this n-side ohmic electrode 1010.

The conventional nitride semiconductor laser element limits the current passing region and transversely confines light with the ridge portion 1020 and the current blocking layer 1007. In other words, the p-type cladding layer 1005 having the projecting portion is different in thickness between the portion of the p-type cladding layer 1005 constituting the ridge portion 1020 forming the current passing region and the remaining portions. Thus, transverse refractive index difference can be so provided that transverse optical confinement can be performed. Further, the current passing region can be limited with the current blocking layer 1007. The width of the current passing region and the transverse refractive index difference, strongly influencing the characteristics of the laser element, must be strictly controlled. In the conventional structure shown in FIG. 173, the width of the current passing region is controlled through the ridge portion 1020. Further, the transverse refractive index difference is controlled through the width of the ridge portion 1020 and the thickness of the p-type cladding layer 1005 on the portions other than the ridge portion 1020. In this case, the thickness of the p-type cladding layer 1005 on the portions other than the ridge portion 1020 is controlled through the etching depth of the p-type cladding layer 1005 in formation of the ridge portion 1020. In the conventional nitride semiconductor laser element, it has been necessary to precisely control the etching depth of the p-type cladding layer 1005 on the order of 0.01 μm, in order to obtain excellent element characteristics.

A method of forming a high resistance region in an element by ion implantation is also known as a technique of controlling the width of a current passing region. Such methods are disclosed in Japanese Patent Laying Open No. 9-45962 and Japanese Patent Laying-Open No. 11-214800.

In the conventional structure shown in FIG. 173, however, there has been such a disadvantage that it is so difficult to strictly control the etching depth that it is difficult to control transverse optical confinement with excellent reproducibility. Consequently, the fabrication yield of the nitride semiconductor laser element has disadvantageously been reduced.

In the technique of controlling the width of a current passing region disclosed in the aforementioned Japanese Patent Laying Open No. 9-45962 or Japanese Patent Laying-Open No. 11-214800, transverse optical confinement is not particularly taken into consideration. A laser structure performing only current narrowing controlling the width of such a current passing region is generally referred to as a gain waveguide structure. In this gain waveguide structure, there has been such a problem that transverse optical confinement is unstabilized.

### DISCLOSURE OF THE INVENTION

An object of the present invention is to provide a nitride semiconductor laser element capable of controlling transverse optical confinement with excellent reproducibility.

Another object of the present invention is to improve the yield of the element in the aforementioned nitride semiconductor laser element.

In order to attain the aforementioned objects, a nitride semiconductor laser element according to an aspect of the present invention comprises a first nitride semiconductor layer, an emission layer formed on the first nitride semiconductor layer, a second nitride semiconductor layer formed on the emission layer and a light absorption layer formed by introducing a first impurity element into at least parts of regions of the first nitride semiconductor layer and the second nitride semiconductor layer other than a current passing region.

In the nitride semiconductor laser element according to this aspect, as hereinabove described, the light absorption layer is formed by introducing the first impurity element into at least the parts of the regions of the first nitride semiconductor layer and the second nitride semiconductor layer other than the current passing region so that the light absorption layer can be formed with excellent reproducibility when the light absorption layer is formed by introducing the first impurity element by ion implantation, for example, since ion implantation is excellent in reproducibility. Thus, transverse optical confinement can be controlled with excellent reproducibility. Consequently, the yield can be improved as compared with a conventional nitride semiconductor laser element having a ridge portion. Further, no unevenness or high-concentration crystal defects are present on the interface between the light absorption layer formed by introducing the first impurity element and the current passing region dissimilarly to the conventional structure having the ridge portion, whereby generation of a leakage current can be remarkably suppressed. In addition, the light absorption layer is so formed by introducing the first impurity element that no conventional projecting ridge portion is present, whereby no such disadvantage is caused that the element characteristics are deteriorated due to stress applied to a projecting ridge portion and heat radiation characteristics are deteriorated due to reduction of a contact area with a heat radiation base resulting from the projecting ridge portion when the laser element is mounted on the heat radiation base from the surface side of the element closer to the emission layer in a junction-down system.

In the aforementioned nitride semiconductor laser element, the upper surface of the light absorption layer and the upper surface of the current passing region are preferably formed substantially on the same plane. According to this structure, unevenness on the element surface can be easily reduced. Thus, stress applied to a projecting portion can be reduced as compared with a conventional ridge structure when the laser element is mounted on the heat radiation base from the surface side of the element closer to the emission layer in the junction-down system, whereby the element characteristics can be inhibited from deterioration resulting from the stress. Further, the contact area with the heat radiation base can be increased by reducing the unevenness on the element surface, whereby excellent heat radiation characteristics can be obtained.

In the aforementioned nitride semiconductor laser element, the second nitride semiconductor layer preferably has a projecting ridge portion including the current passing region. According to this structure, the light absorption layer can be formed on the region of the second nitride semiconductor layer other than the ridge portion with excellent reproducibility when forming the light absorption layer by introducing the first impurity element into the region of the second nitride semiconductor layer other than the ridge portion by ion implantation, for example, since ion implantation is excellent in reproducibility. Thus, transverse optical confinement can be controlled with excellent reproducibility. Consequently, the transverse mode can be stabilized with excellent reproducibility while performing current narrowing through the ridge portion. Further, the transverse mode can be so stabilized that outbreak of kinks (bending of current-light output characteristics) resulting from higher mode oscillation can be suppressed. Thus, a high-maximum light output can be obtained while a beam shape can be stabilized.

In the aforementioned nitride semiconductor laser element, the side ends of the light absorption layer are preferably substantially located immediately under the side ends of the ridge portion. According to this structure, the width of current narrowing and the width of optical confinement can be substantially equalized with each other, whereby the laser element can excellently perform current narrowing and light absorption through the light absorption layer.

In the aforementioned nitride semiconductor laser element, the side ends of the light absorption layer are preferably provided on positions separated at prescribed intervals from the side ends of the ridge portion. According to this structure, the interval between light absorption layers (width of optical confinement) can be rendered larger than the width of the ridge portion (width of current narrowing), whereby a portion, located immediately under the ridge portion, having high light intensity can be inhibited from excess light absorption while current narrowing can be strengthened. Thus, increase of a threshold current can be further suppressed.

In the aforementioned nitride semiconductor laser element, the light absorption layer is preferably provided on each side surface of the ridge portion. According to this structure, not only current narrowing but also transverse optical confinement can be performed through the ridge portion due to the light absorption layers provided on both side surfaces of the ridge portion.

In the aforementioned nitride semiconductor laser element, the ridge portion may be preferably formed before introducing the first impurity element. According to this structure, the implantation depth may not be increased when forming the light absorption layer by introducing the first impurity element into the region of the second nitride semiconductor layer other than the ridge portion by ion implantation, for example, whereby implantation energy can be reduced. Thus, the spreading width of an impurity profile can be so reduced that the implantation depth can be precisely controlled. Consequently, the impurity element can be prevented from reaching the emission layer, whereby the emission layer can be prevented from damage by the impurity element.

In the aforementioned nitride semiconductor laser element, the ridge portion may be preferably formed after introducing the first impurity element. According to this structure, it is necessary to form a light absorption layer having an implantation depth exceeding the height of the ridge portion by increasing implantation energy when forming the light absorption layer by introducing the first impurity element into the region of the second nitride semiconductor layer other than a ridge portion forming region by ion implantation, for example. In this case, the implantation energy is so increased that the spreading width of the impurity profile is increased. Thus, a profile in the vicinity of a peak depth of impurity concentration can be so flattened that the light absorption function of the light absorption layer can be flattened (uniformized). Consequently, transverse optical confinement can be stabilized.

In the aforementioned nitride semiconductor laser element, the light absorption layer preferably has a larger number of crystal defects than the current passing region. According to this structure, the laser element light absorption can be performed through the crystal defects largely contained in the light absorption layer.

In the aforementioned nitride semiconductor laser element, the light absorption layer preferably has a current blocking function. According to this structure, transverse optical confinement and current narrowing can be simultaneously performed.

The aforementioned nitride semiconductor laser element preferably further comprises a current blocking layer formed by introducing a second impurity element into at least parts of the regions of the first nitride semiconductor layer and the second nitride semiconductor layer other than the current passing region. When forming the current blocking layer independently of the light absorption layer in this manner, the width of optical confinement and the width of the current passing region can be rendered different from each other.

In the aforementioned nitride semiconductor laser element, the light absorption layer is preferably formed by ion-implanting the first impurity element into the regions of the first nitride semiconductor layer and the second nitride semiconductor layer other than the current passing region. When forming the light absorption layer by ion implantation in this manner, the light absorption layer can be easily formed with excellent reproducibility.

In the aforementioned nitride semiconductor laser element, the light absorption layer has either high resistance or a reverse conductivity to the current passing region. According to this structure, the light absorption layer can be easily provided with a current blocking function.

In the nitride semiconductor laser element according to the aforementioned aspect, the first impurity element may be an impurity element other than group 3 and group 5 elements.

In the nitride semiconductor laser element according to the aforementioned aspect, the first impurity element may be an impurity element having a larger mass number than carbon. According to this structure, channeling of ions can be so prevented that impurity ions can be inhibited from deep implantation. Consequently, controllability for an implantation profile in the depth direction can be improved.

In the nitride semiconductor laser element according to the aforementioned aspect, the maximum value of the impurity concentration of the first impurity element may be at least 5.0×10¹⁹ cm⁻³. According to this structure, crystal defects can be generated in the light absorption layer with sufficient density, whereby the absorption coefficient of the light absorption layer can be sufficiently increased. Thus, transverse optical confinement can be sufficiently performed.

In the nitride semiconductor laser element according to the aforementioned aspect, the maximum value of crystal defect density of at least either the first nitride semiconductor layer or the second nitride semiconductor layer containing the first impurity element may be at least 5×10¹⁸ cm⁻³. According to this structure, the light absorption coefficient is so sufficiently increased that transverse optical confinement can be sufficiently performed.

In the nitride semiconductor laser element according to the aforementioned aspect, the maximum value of the absorption coefficient of the light absorption layer may be at least 1×10⁴ cm⁻¹. According to this structure, transverse optical confinement can be sufficiently performed.

The nitride semiconductor laser element according to the aforementioned aspect is heat-treated after introduction of the first impurity element. According to this structure, the absorption coefficient can be easily controlled. In this case, the absorption coefficient may be reduced by the heat treatment.

In the nitride semiconductor laser element according to the aforementioned aspect, the light absorption layer is formed by ion implantation from a direction inclined from the [0001] direction of a nitride semiconductor. According to this structure, channeling of ions can be so prevented that impurity ions can be inhibited from deep implantation. Consequently, controllability for an implantation profile in the depth direction can be improved. In this case, the surface of the nitride semiconductor is the (0001) plane, the light absorption layer is formed excluding a striped width, and ion implantation is performed from a direction inclined from the [0001] direction of the nitride semiconductor in a plane including a stripe direction not formed with light absorption layer and a direction perpendicular to the surface of the nitride semiconductor. Thus, channeling of ions can be prevented while preventing the ions from asymmetrical implantation into a lower portion of a mask for forming the light absorption layer excluding the striped width.

In the nitride semiconductor laser element according to the aforementioned aspect, the current blocking layer may consist of a nitride semiconductor having high resistance. According to this structure, a high-resistance layer can be easily formed by introducing hydrogen into a region containing a p-type dopant, for example, whereby the current blocking layer can be easily formed.

In the nitride semiconductor laser element according to the aforementioned aspect, the current passing region may have a p type, and the current blocking layer may contain hydrogen in higher density than the current passing region. According to this structure, the current blocking layer can be easily formed by introducing hydrogen into the region containing the p-type dopant. In this case, the current blocking layer containing hydrogen in higher density than the current passing region may be formed by performing heat treatment in an atmosphere containing hydrogen. According to this structure, the current blocking layer can be easily formed by diffusion of hydrogen. In this case, crystal defects are more hardly introduced through diffusion than through ion implantation, whereby reliability of the element can be improved. In particular, the light absorption layer may be formed excluding a first width, a current narrowing layer may be formed excluding a second width, a region of the second width may be formed in a region of the first width and the first width may be rendered larger than the second width. Further, the current narrowing layer may be formed separately from the emission layer by a second distance in the depth direction, the light absorption layer may be formed separately from the emission layer by a first distance in the depth direction, and the first distance may be formed to be larger than the second distance. According to this structure, crystal defects of a region close to the emission layer can be reduced, whereby the aforementioned effect of improving the reliability of the element by hydrogen diffusion is large.

In the nitride semiconductor laser element according to the aforementioned aspect, the current blocking layer has a reverse conductivity type to the current passing region. According to this structure, a nitride semiconductor of the reverse conductivity type can be easily formed by introducing a dopant of the reverse conductivity type to the current passing region into the current blocking layer, for example, whereby the current blocking layer can be easily formed.

In the nitride semiconductor laser element according to the aforementioned aspect, the second impurity element may be an impurity element other than group 3 and 5 elements. In this case, the second impurity element may be an element different from the first impurity element. According to this structure, the introduced impurity elements are so different from each other that concentration profiles of the first impurity element and the second impurity element can be easily rendered different from each other. Therefore, the shape of the light absorption layer and the shape of the current blocking layer can be easily controlled. Further, the conductivity type of the current blocking layer can be easily controlled. In formation of the current blocking layer, further, crystal defects can be prevented from excess formation by ion-implanting a relatively light element. In formation of the light absorption layer, on the other hand, crystal defects can be introduced with a low dose by ion-implanting a relatively heavy element, whereby the introduced element can be prevented from diffusing into the emission layer and exerting bad influence on the characteristics of the element dissimilarly to a case of a high dose (high concentration).

In the nitride semiconductor laser element according to the aforementioned aspect, the current blocking layer is formed by ion-implanting the second impurity element. According to this structure, the impurity element can be introduced from the surface up to a deep position by ion implantation. While a limited element such as a dopant element must be employed in diffusion, ion implantation advantageously provides a wide range of selection for implanted elements.

In the nitride semiconductor laser element according to the aforementioned aspect, the current blocking layer is formed by ion-implanting the second impurity element into the lower portion of a mask layer obliquely from above. According to this structure, the light absorption layer is formed excluding the first width while the current narrowing layer is formed excluding the second width, the first width is larger than the second width, and a region of the second width is formed in a region of the first width. Thus, the width of a current passing region can be reduced beyond the width of optical confinement. Consequently, light absorption by the light absorption layer can be reduced while simultaneously strengthening current narrowing, whereby reduction of the threshold current and improvement of slope efficiency can be attained.

In the nitride semiconductor laser element according to the aforementioned aspect, the current blocking layer is formed by diffusing the second impurity element. In this case, crystal defects are more hardly introduced through diffusion than through ion implantation, whereby reliability of the element can be improved. In particular, the current narrowing layer may be formed excluding a second width, the light absorption layer may be formed excluding a first width, a region of the second width may be formed in a region of the first width and the first width may be rendered larger than the second width. Further, the current narrowing layer may be formed separately from the emission layer by a second distance in the depth direction, the light absorption layer may be formed separately from the emission layer by a first distance in the depth direction, and the first distance may be formed to be larger than the second distance. According to this structure, crystal defects of a region close to the emission layer can be reduced, whereby the aforementioned effect of improving the reliability of the element by diffusion is large.

In the nitride semiconductor laser element according to the aforementioned aspect, the light absorption layer may be formed excluding a first width while the current narrowing layer may be formed excluding a second width, the first width may be larger than the second width, and a region of the second width may be formed in a region of the first width. Thus, light absorption by the light absorption layer can be reduced while simultaneously strengthening current narrowing, whereby reduction of the threshold current and improvement of the slope efficiency can be attained.

In the nitride semiconductor laser element according to the aforementioned aspect, the light absorption layer may be formed separately from the emission layer by a first distance in the depth direction while the current blocking layer may be formed separately from the emission layer by a second distance in the depth direction, and the first distance may be rendered larger than the second distance. According to this structure, the width of the current passing region can be inhibited from exceeding the width of optical confinement. Thus, light absorption by the light absorption layer can be reduced while simultaneously strengthening current narrowing, whereby reduction of the threshold current and improvement of the slope efficiency can be attained. In this case, the second distance may be zero, and the current blocking layer may be formed in the emission layer.

In the nitride semiconductor laser element according to the aforementioned aspect, the concentration of the second impurity element in the current blocking layer may be lower than the concentration of the first impurity element in the light absorption layer. According to this structure, the density of crystal defects in the current blocking layer can be reduced beyond the density of crystal defects in the light absorption layer when implanting the second impurity element into the current blocking layer by ion implantation, whereby light absorption in the current blocking layer can be sufficiently reduced. Thus, unnecessary light absorption in the current blocking layer can be suppressed.

In the nitride semiconductor laser element according to the aforementioned aspect, the density of crystal defects in the current blocking layer may be lower than the density of crystal defects in the light absorption layer. According to this structure, light absorption in the current blocking layer can be so sufficiently reduced that unnecessary light absorption in the current blocking layer can be suppressed.

In the nitride semiconductor laser element according to the aforementioned aspect, the impurity concentration of the first impurity element in a portion of the emission layer corresponding to an upper or lower region of the light absorption layer may be not more than 5.0×10¹⁸ cm⁻³. According to this structure, crystal defects in the portion of the emission layer corresponding to the upper or lower region of the light absorption layer can be so reduced that the life of the element can be improved.

In the nitride semiconductor laser element according to the aforementioned aspect, the density of crystal defects in a portion of the emission layer located on an upper or lower region of the light absorption layer may be not more than 5.0×10¹⁷ cm⁻³. According to this structure, the number of crystal defects in the portion of the emission layer located on the upper or lower region of the light absorption layer is so small that the life of the element can be improved.

In the nitride semiconductor laser element according to the aforementioned aspect, the first nitride semiconductor layer and the second nitride semiconductor layer include a cladding layer, and the concentration of the first impurity element is maximized in the cladding layer. According to this structure, crystal defects can be formed in the cladding layer with sufficient concentration, whereby a light absorption layer having a sufficient light absorption effect can be formed in the cladding layer. Light exudes into the cladding layer to some extent, whereby the light can be effectively absorbed by providing the light absorption layer in the cladding layer. Therefore, the element has a sufficient transverse optical confinement effect while the number of crystal defects is small in the portion of the emission layer corresponding to the upper or lower region of the light absorption layer, whereby the life of the element can be improved.

In the nitride semiconductor laser element according to the aforementioned aspect, the light absorption layer may be so formed that the light absorption layer is not formed in the emission layer. More preferably, the light absorption layer may be formed separately from the emission layer by a finite first distance larger than zero in the depth direction. According to this structure, the number of crystal defects is so small in the portion of the emission layer corresponding to the upper or lower region of the light absorption layer that the life of the element can be improved.

In the nitride semiconductor laser element according to the aforementioned aspect, the first nitride semiconductor layer and the second nitride semiconductor layer include a cladding layer, and the density of crystal defects in the light absorption layer is maximized in the cladding layer. According to this structure, a light absorption having a sufficient light absorption effect can be formed in the cladding layer. According to this structure, the number of crystal defects is so small in the portion of the emission layer corresponding to the upper or lower region of the light absorption layer, that the life of the element can be improved.

In the nitride semiconductor laser element according to the aforementioned aspect, the first nitride semiconductor layer and the second nitride semiconductor layer include a cladding layer, and the light absorption coefficient of the light absorption layer is maximized in the cladding layer. According to this structure, the element has a sufficient transverse optical confinement effect while the number of crystal defects is so small in the portion of the emission layer corresponding to the upper or lower region of the light absorption layer that the life of the element can be improved.

In the nitride semiconductor laser element according to the aforementioned aspect, the emission layer is formed on the first nitride semiconductor layer after the first impurity element is introduced into the first nitride semiconductor layer. According to this structure, transverse optical confinement can be performed on the first-nitride-semiconductor-layer side. Further, no ion implantation is performed on the emission layer so that the number of defects in the emission layer can be reduced, whereby the life of the element can be improved as a result. In a structure not implanting ions into a contact layer on the second-nitride-semiconductor-layer side, the contact layer on the second-nitride-semiconductor-layer side having low defect concentration can be formed with a wide area. Therefore, the carrier concentration of the contact layer on the second-nitride-semiconductor-layer side can be so improved that a contact area between the contact layer on the second-nitride-semiconductor-layer side and an electrode can be widened. Consequently, contact resistance on the second-nitride-semiconductor-layer-side can be reduced.

In the nitride semiconductor laser element according to the aforementioned aspect, the impurity concentration of the first impurity element may be maximized in the emission layer. According to this structure, strong complex refractive index difference can be formed in the in-plane direction of the emission layer, whereby the dose of the first impurity element can be reduced.

In the nitride semiconductor laser element according to the aforementioned aspect, the density of crystal defects may be maximized in the emission layer. According to this structure, strong complex refractive index difference can be formed in the in-plane direction of the emission layer, whereby the dose of the first impurity element can be reduced.

In the nitride semiconductor laser element according to the aforementioned aspect, the light absorption coefficient of the light absorption layer may be maximized in the emission layer. According to this structure, strong complex refractive index difference can be formed in the in-plane direction of the emission layer, whereby the dose of the first impurity element may be small.

In the nitride semiconductor laser element according to the aforementioned aspect, a contact layer is formed on the second nitride semiconductor layer after the light absorption layer is formed by introducing the first impurity element into the second nitride semiconductor layer on the emission layer. According to this structure, no ion implantation is performed on the contact layer located upward beyond the emission layer, whereby the contact layer having a small number of crystal defects can be formed with a wide area. Thus, the carrier concentration of the contact layer located upward beyond the emission layer can be so improved that contact resistance between the contact layer located upward beyond the emission layer and an electrode layer can be reduced.

In the nitride semiconductor laser element according to the aforementioned aspect, the first impurity element is ion-implanted through a through film. According to this structure, channeling of ions can be so prevented that impurity ions can be inhibited from deep implantation.

In the nitride semiconductor laser element according to the aforementioned aspect, the through film may be an insulator film. According to this structure, the insulator film employed for the through film can be utilized as an insulator film on the light absorption layer or the current blocking layer, whereby current blocking can be more reliably performed.

In the nitride semiconductor laser element according to the aforementioned aspect, the first impurity element is ion-implanted through a through film having a first ion permeation region having first stopping power and a second ion permeation region having second stopping power more hardly permeating ions than the first ion permeation region. According to this structure, regions having different implantation depths can be simultaneously formed through single ion implantation. Thus, a structure having a width of optical confinement and a width of the current passing region different from each other can be formed through single ion implantation. Therefore, an optical confinement region and a current blocking region may not be formed through different steps respectively, whereby steps can be simplified.

The nitride semiconductor laser element according to the aforementioned aspect employs a first film including a first region having first stopping power and a second region having third stopping power hardly permeating ions as a through film while employing the said second region as a mask for ion-implanting the said first impurity element. According to this structure, a non-implanted region of a prescribed width can be easily formed.

The nitride semiconductor laser element according to the aforementioned aspect further comprises an electrode layer formed on the second nitride semiconductor layer, while the first impurity element is ion-implanted into the second nitride semiconductor layer through a through film with the electrode layer serving as a mask. According to this structure, the electrode layer serving as a mask layer can be utilized as a contact electrode, whereby a fabrication process can be simplified.

In the nitride semiconductor laser element according to the aforementioned aspect, an insulator film may be formed on the light absorption layer. According to this structure, generation of a small leakage current can be prevented when a high current is fed to the element.

In the nitride semiconductor laser element according to the aforementioned aspect, the light absorption layer is formed excluding a first width, and the nitride semiconductor laser element further comprises an electrode layer coming into ohmic contact with the second nitride semiconductor laser with a width smaller than the first width. According to this structure, the width of a current passing region can be reduced beyond the width of optical confinement. Thus, light absorption by the light absorption layer can be reduced while simultaneously strengthening current narrowing, whereby reduction of the threshold current and improvement of the slope efficiency can be attained.

In the nitride semiconductor laser element according to the aforementioned aspect, the light absorption layer is formed excluding a first width, and the nitride semiconductor laser element further comprises an electrode layer coming into ohmic contact with the second nitride semiconductor laser with a width larger than the first width. According to this structure, it is possible to improve heat radiation characteristics of the element by forming a large-area electrode on the second nitride semiconductor layer since an electrode has a high thermal conductivity. Consequently, the life of the element can be improved. Further, the surface of the element can be so flattened that a contact area with a submount is increased and adhesion is improved when the element is assembled in the junction-down system, whereby the heat radiation characteristics are improved. It is possible to improve the life of the element also by this. Further, the contact area of the electrode layer can be so increased that contact resistance can be reduced.

The nitride semiconductor laser element according to the aforementioned aspect further comprises an electric isolation region of high resistance formed by introducing a third impurity element into at least part of a region other than the current passing region over a region passing through the emission layer from the surface of the second nitride semiconductor layer. According to this structure, p-type semiconductors or a p-type semiconductor and an n-type semiconductor can be electrically isolated from each other. Therefore, an element having a flat surface on the second-nitride-semiconductor-layer side can be formed. Further, a plurality of elements can be easily integrated.

In the nitride semiconductor laser element according to the aforementioned aspect, the electric isolation region may be formed by ion-implanting the third impurity element. According to this structure, the impurity element can be introduced from the surface up to a deep position in the ion implantation, whereby a deep electric isolation region can be easily formed.

The nitride semiconductor laser element according to the aforementioned aspect introduces a fourth impurity element into a region other than the current passing region and at least part of a region other than the electric isolation region over a region passing through the emission layer from the surface of the second nitride semiconductor layer so that the region passing through the emission layer from the second nitride semiconductor layer has the same conductivity type as the first nitride semiconductor layer. According to this structure, the element having a flat surface on the second-nitride-semiconductor-layer side can be easily formed by forming an electrode on the first-nitride-semiconductor-layer side and an electrode on the second-nitride-semiconductor-layer side oppositely to the substrate.

In the nitride semiconductor laser element according to the aforementioned aspect, the nitride semiconductor laser element includes a nitride semiconductor laser element, assembled in a junction-down system, mounted on a base for heat radiation from the surface of a side closer to the emission layer. According to this structure, irregularity on the surface of an element region is so small that stress applied to the element region can be reduced by assembling the element in the junction-down system, whereby deterioration of the element characteristics can be suppressed as a result. Further, the element can be homogeneously welded to a submount or the like when assembled in the junction-down system, whereby the heat radiation characteristics of the element are improved.

In the nitride semiconductor laser element according to the aforementioned aspect, the light absorption layer is divided into a plurality of parts between the current passing region and side ends of the element. According to this structure, a region for forming the light absorption layer can be inhibited from increase, whereby light absorption can be inhibited from excessiveness in the vicinity of the emission layer. Consequently, increase of the threshold current can be suppressed.

In the nitride semiconductor laser element according to the aforementioned aspect, a portion of the light absorption layer closer to the current passing region has a smaller depth than a portion of the light absorption layer closer to the side ends of the element. According to this structure, light absorption can be further inhibited from excessiveness in the vicinity of the emission layer.

In the nitride semiconductor laser element according to the aforementioned aspect, the portion of the light absorption layer closer to the current passing region has a depth not reaching the emission layer. According to this structure, light absorption can be easily inhibited from excessiveness in the vicinity of the emission layer.

In the nitride semiconductor laser element according to the aforementioned aspect, a first width between side ends of the light absorption layer in the vicinity of a cavity end surface of the element is smaller than a second width between side ends of a portion of the light absorption layer in the vicinity of the central portion of the element. According to this structure, transverse optical confinement can be excellently performed on the cavity end surface of the element, whereby a transverse mode can be stabilized. Thus, outbreak of kinks (bending of current-light output characteristics) resulting from higher mode oscillation can be suppressed. Further, light absorption in the vicinity of the emission layer can be inhibited from excessiveness at the central portion of the element, whereby increase of the threshold current can be suppressed. Consequently, the beam shape can be stabilized while suppressing increase of the threshold current, reduction of slope efficiency and reduction of a kink level.

In the nitride semiconductor laser element according to the aforementioned aspect, a boundary region between a region of the light absorption layer having the first width and a region having the second width has a width gradually enlarging to approach from the first width to the second width. According to this structure, abrupt change of light absorption can be so suppressed that coupling loss can be suppressed between a portion close to the cavity end surface of the element and a portion close to the central portion of the element. Thus, output characteristics can be inhibited from reduction.

In the nitride semiconductor laser element according to the aforementioned aspect, the boundary region between the region of the light absorption layer having the first width and the region having the second width is formed in a tapered shape in plan view. According to this structure, the width of the boundary region between the region having the first width and the region having the second width in the light absorption layer can be formed to be gradually increased to approach from the first width to the second width.

### BRIEF DESCRIPTION OF THE DRAWINGS

FIG. 1 is a sectional view showing the structure of a nitride semiconductor laser element according to a first embodiment of the present invention.

FIG. 2 is an enlarged sectional view showing an MQW emission layer of the nitride semiconductor laser element according to the first embodiment shown in FIG. 1.

FIG. 3 is an enlarged sectional view schematically showing ion-implanted regions.

FIG. 4 is a sectional view for illustrating a fabrication process for the nitride semiconductor laser element according to the first embodiment shown in FIG. 1.

FIG. 5 is a sectional view for illustrating the fabrication process for the nitride semiconductor laser element according to the first embodiment shown in FIG. 1.

FIG. 6 is a sectional view for illustrating the fabrication process for the nitride semiconductor laser element according to the first embodiment shown in FIG. 1.

FIG. 7 is a sectional view for illustrating the fabrication process for the nitride semiconductor laser element according to the first embodiment shown in FIG. 1.

FIG. 8 is a graph showing simulation results of carbon concentration and crystal defect concentration profiles in the nitride semiconductor laser element according to the first embodiment shown in FIG. 1.

FIG. 9 is a graph showing results of measurement of the carbon concentration profile by SIMS in the nitride semiconductor laser element according to the first embodiment shown in FIG. 1.

FIG. 10 is a sectional view showing the structure of a nitride semiconductor laser element according to a second embodiment of the present invention.

FIG. 11 is a sectional view for illustrating a fabrication process for the nitride semiconductor laser element according to the second embodiment shown in FIG. 10.

FIG. 12 is a sectional view for illustrating the fabrication process for the nitride semiconductor laser element according to the second embodiment shown in FIG. 10.

FIG. 13 is a sectional view for illustrating the fabrication process for the nitride semiconductor laser element according to the second embodiment shown in FIG. 10.

FIG. 14 is a sectional view showing the structure of a nitride semiconductor laser element according to a third embodiment of the present invention.

FIG. 15 is a sectional view for illustrating a fabrication process for the nitride semiconductor laser element according to the third embodiment shown in FIG. 14.

FIG. 16 is a sectional view for illustrating the fabrication process for the nitride semiconductor laser element according to the third embodiment shown in FIG. 14.

FIG. 17 is a sectional view for illustrating the fabrication process for the nitride semiconductor laser element according to the third embodiment shown in FIG. 14.

FIG. 18 is a sectional view showing the structure of a nitride semiconductor laser element according to a fourth embodiment of the present invention.

FIG. 19 is a sectional view showing the structure of a nitride semiconductor laser element according to a fifth embodiment of the present invention.

FIG. 20 is a sectional view for illustrating a fabrication process for the nitride semiconductor laser element according to the fifth embodiment shown in FIG. 19.

FIG. 21 is a sectional view for illustrating the fabrication process for the nitride semiconductor laser element according to the fifth embodiment shown in FIG. 19.

FIG. 22 is a sectional view for illustrating the fabrication process for the nitride semiconductor laser element according to the fifth embodiment shown in FIG. 19.

FIG. 23 is a sectional view for illustrating the fabrication process for the nitride semiconductor laser element according to the fifth embodiment shown in FIG. 19.

FIG. 24 is a sectional view for illustrating the fabrication process for the nitride semiconductor laser element according to the fifth embodiment shown in FIG. 19.

FIG. 25 is a sectional view showing the structure of a nitride semiconductor laser element according to a sixth embodiment of the present invention.

FIG. 26 is a sectional view for illustrating a fabrication process for the nitride semiconductor laser element according to the sixth embodiment shown in FIG. 25.

FIG. 27 is a sectional view for illustrating the fabrication process for the nitride semiconductor laser element according to the sixth embodiment shown in FIG. 25.

FIG. 28 is a sectional view for illustrating the fabrication process for the nitride semiconductor laser element according to the sixth embodiment shown in FIG. 25.

FIG. 29 is a sectional view showing the structure of a nitride semiconductor laser element according to a seventh embodiment of the present invention.

FIG. 30 is a sectional view for illustrating a fabrication process for the nitride semiconductor laser element according to the seventh embodiment shown in FIG. 29.

FIG. 31 is a sectional view for illustrating the fabrication process for the nitride semiconductor laser element according to the seventh embodiment shown in FIG. 29.

FIG. 32 is a sectional view for illustrating the fabrication process for the nitride semiconductor laser element according to the seventh embodiment shown in FIG. 29.

FIG. 33 is a sectional view for illustrating the fabrication process for the nitride semiconductor laser element according to the seventh embodiment shown in FIG. 29.

FIG. 34 is a sectional view showing the structure of a nitride semiconductor laser element according to an eighth embodiment of the present invention.

FIG. 35 is a sectional view for illustrating a fabrication process for the nitride semiconductor laser element according to the eighth embodiment shown in FIG. 34.

FIG. 36 is a sectional view for illustrating the fabrication process for the nitride semiconductor laser element according to the eighth embodiment shown in FIG. 34.

FIG. 37 is a sectional view for illustrating the fabrication process for the nitride semiconductor laser element according to the eighth embodiment shown in FIG. 34.

FIG. 38 is a sectional view for illustrating the fabrication process for the nitride semiconductor laser element according to the eighth embodiment shown in FIG. 34.

FIG. 39 is a sectional view showing the structure of a nitride semiconductor laser element according to a ninth embodiment of the present invention.

FIG. 40 is a sectional view for illustrating a fabrication process for the nitride semiconductor laser element according to the ninth embodiment shown in FIG. 39.

FIG. 41 is a sectional view for illustrating the fabrication process for the nitride semiconductor laser element according to the ninth embodiment shown in FIG. 39.

FIG. 42 is a sectional view for illustrating the fabrication process for the nitride semiconductor laser element according to the ninth embodiment shown in FIG. 39.

FIG. 43 is a sectional view for illustrating the fabrication process for the nitride semiconductor laser element according to the ninth embodiment shown in FIG. 39.

FIG. 44 is a sectional view showing the structure of a nitride semiconductor laser element according to a tenth embodiment of the present invention.

FIG. 45 is a sectional view for illustrating a fabrication process for the nitride semiconductor laser element according to the tenth embodiment shown in FIG. 44.

FIG. 46 is a sectional view for illustrating the fabrication process for the nitride semiconductor laser element according to the tenth embodiment shown in FIG. 44.

FIG. 47 is a sectional view showing the structure of a nitride semiconductor laser element according to an eleventh embodiment of the present invention.

FIG. 48 is a sectional view for illustrating a fabrication process for the nitride semiconductor laser element according to the eleventh embodiment shown in FIG. 47.

FIG. 49 is a sectional view for illustrating the fabrication process for the nitride semiconductor laser element according to the eleventh embodiment shown in FIG. 47.

FIG. 50 is a sectional view for illustrating the fabrication process for the nitride semiconductor laser element according to the eleventh embodiment shown in FIG. 47.

FIG. 51 is a sectional view for illustrating the fabrication process for the nitride semiconductor laser element according to the eleventh embodiment shown in FIG. 47.

FIG. 52 is a sectional view showing the structure of a nitride semiconductor laser element according to a twelfth embodiment of the present invention.

FIG. 53 is a sectional view for illustrating a fabrication process for the nitride semiconductor laser element according to the twelfth embodiment shown in FIG. 52.

FIG. 54 is a sectional view for illustrating the fabrication process for the nitride semiconductor laser element according to the twelfth embodiment shown in FIG. 52.

FIG. 55 is a sectional view for illustrating the fabrication process for the nitride semiconductor laser element according to the twelfth embodiment shown in FIG. 52.

FIG. 56 is a sectional view for illustrating the fabrication process for the nitride semiconductor laser element according to the twelfth embodiment shown in FIG. 52.

FIG. 57 is a sectional view showing the structure of a nitride semiconductor laser element according to a thirteenth embodiment of the present invention.

FIG. 58 is a sectional view for illustrating a fabrication process for the nitride semiconductor laser element according to the thirteenth embodiment shown in FIG. 57.

FIG. 59 is a sectional view for illustrating the fabrication process for the nitride semiconductor laser element according to the thirteenth embodiment shown in FIG. 57.

FIG. 60 is a sectional view for illustrating the fabrication process for the nitride semiconductor laser element according to the thirteenth embodiment shown in FIG. 57.

FIG. 61 is a sectional view for illustrating the fabrication process for the nitride semiconductor laser element according to the thirteenth embodiment shown in FIG. 57.

FIG. 62 is a sectional view for illustrating the fabrication process for the nitride semiconductor laser element according to the thirteenth embodiment shown in FIG. 57.

FIG. 63 is a sectional view showing the structure of a nitride semiconductor laser element according to a fourteenth embodiment of the present invention.

FIG. 64 is a sectional view for illustrating a fabrication process for the nitride semiconductor laser element according to the fourteenth embodiment shown in FIG. 63.

FIG. 65 is a sectional view for illustrating the fabrication process for the nitride semiconductor laser element according to the fourteenth embodiment shown in FIG. 63.

FIG. 66 is a sectional view for illustrating the fabrication process for the nitride semiconductor laser element according to the fourteenth embodiment shown in FIG. 63.

FIG. 67 is a sectional view showing the structure of a nitride semiconductor laser element according to a fifteenth embodiment of the present invention.

FIG. 68 is a sectional view for illustrating a fabrication process for the nitride semiconductor laser element according to the fifteenth embodiment shown in FIG. 67.

FIG. 69 is a sectional view for illustrating the fabrication process for the nitride semiconductor laser element according to the fifteenth embodiment shown in FIG. 67.

FIG. 70 is a sectional view for illustrating the fabrication process for the nitride semiconductor laser element according to the fifteenth embodiment shown in FIG. 67.

FIG. 71 is a sectional view showing the structure of a nitride semiconductor laser element according to a sixteenth embodiment of the present invention.

FIG. 72 is a sectional view for illustrating a fabrication process for the nitride semiconductor laser element according to the sixteenth embodiment shown in FIG. 71.

FIG. 73 is a sectional view for illustrating the fabrication process for the nitride semiconductor laser element according to the sixteenth embodiment shown in FIG. 71.

FIG. 74 is a sectional view for illustrating the fabrication process for the nitride semiconductor laser element according to the sixteenth embodiment shown in FIG. 71.

FIG. 75 is a sectional view for illustrating the fabrication process for the nitride semiconductor laser element according to the sixteenth embodiment shown in FIG. 71.

FIG. 76 is a sectional view for illustrating the fabrication process for the nitride semiconductor laser element according to the sixteenth embodiment shown in FIG. 71.

FIG. 77 is a sectional view showing the structure of a nitride semiconductor laser element according to a seventeenth embodiment of the present invention.

FIG. 78 is a sectional view for illustrating a fabrication process for the nitride semiconductor laser element according to the seventeenth embodiment shown in FIG. 77.

FIG. 79 is a sectional view for illustrating the fabrication process for the nitride semiconductor laser element according to the seventeenth embodiment shown in FIG. 77.

FIG. 80 is a sectional view for illustrating the. fabrication process for the nitride semiconductor laser element according to the seventeenth embodiment shown in FIG. 77.

FIG. 81 is a sectional view for illustrating the fabrication process for the nitride semiconductor laser element according to the seventeenth embodiment shown in FIG. 77.

FIG. 82 is a sectional view for illustrating the fabrication process for the nitride semiconductor laser element according to the seventeenth embodiment shown in FIG. 77.

FIG. 83 is a sectional view for illustrating the fabrication process for the nitride semiconductor laser element according to the seventeenth embodiment shown in FIG. 77.

FIG. 84 is a sectional view for illustrating the fabrication process for the nitride semiconductor laser element according to the seventeenth embodiment shown in FIG. 77.

FIG. 85 is a sectional view showing the structure of a nitride semiconductor laser element according to an eighteenth embodiment of the present invention.

FIG. 86 is a sectional view for illustrating a fabrication process for the nitride semiconductor laser element according to the eighteenth embodiment shown in FIG. 85.

FIG. 87 is a sectional view for illustrating the fabrication process for the nitride semiconductor laser element according to the eighteenth embodiment shown in FIG. 85.

FIG. 88 is a sectional view showing the structure of a nitride semiconductor laser element according to a nineteenth embodiment of the present invention.

FIG. 89 is a sectional view for illustrating a fabrication process for the nitride semiconductor laser element according to the nineteenth embodiment shown in FIG. 88.

FIG. 90 is a sectional view for illustrating the fabrication process for the nitride semiconductor laser element according to the nineteenth embodiment shown in FIG. 88.

FIG. 91 is a sectional view for illustrating the fabrication process for the nitride semiconductor laser element according to the nineteenth embodiment shown in FIG. 88.

FIG. 92 is a sectional view for illustrating the fabrication process for the nitride semiconductor laser element according to the nineteenth embodiment shown in FIG. 88.

FIG. 93 is a sectional view showing the structure of a nitride semiconductor laser element according to a twentieth embodiment of the present invention.

FIG. 94 is a sectional view for illustrating a fabrication process for the nitride semiconductor laser element according to the twentieth embodiment shown in FIG. 93.

FIG. 95 is a sectional view for illustrating the fabrication process for the nitride semiconductor laser element according to the twentieth embodiment shown in FIG. 93.

FIG. 96 is a sectional view for illustrating the fabrication process for the nitride semiconductor laser element according to the twentieth embodiment shown in FIG. 93.

FIG. 97 is a sectional view for illustrating the fabrication process for the nitride semiconductor laser element according to the twentieth embodiment shown in FIG. 93.

FIG. 98 is a sectional view showing the structure of a nitride semiconductor laser element according to a twenty-first embodiment of the present invention.

FIG. 99 is an enlarged sectional view showing an MQW emission layer of the nitride semiconductor laser element according to the twenty-first embodiment shown in FIG. 98.

FIG. 100 is a characteristic diagram showing current-to-optical output characteristics of the nitride semiconductor laser element according to the twenty-first embodiment shown in FIG. 98 and a conventional (comparative) nitride semiconductor laser element;

FIG. 101 is a sectional view for illustrating a fabrication process for the nitride semiconductor laser element according to the twenty-first embodiment shown in FIG. 98.

FIG. 102 is a sectional view for illustrating the fabrication process for the nitride semiconductor laser element according to the twenty-first embodiment shown in FIG. 98.

FIG. 103 is a sectional view for illustrating the fabrication process for the nitride semiconductor laser element according to the twenty-first embodiment shown in FIG. 98.

FIG. 104 is a sectional view for illustrating the fabrication process for the nitride semiconductor laser element according to the twenty-first embodiment shown in FIG. 98.

FIG. 105 is a sectional view for illustrating the fabrication process for the nitride semiconductor laser element according to the twenty-first embodiment shown in FIG. 98.

FIG. 106 is a sectional view showing the structure of a nitride semiconductor laser element according to a twenty-second embodiment of the present invention.

FIG. 107 is a sectional view for illustrating a fabrication process for the nitride semiconductor laser element according to the twenty-second embodiment shown in FIG. 106.

FIG. 108 is a sectional view for illustrating the fabrication process for the nitride semiconductor laser element according to the twenty-second embodiment shown in FIG. 106.

FIG. 109 is a sectional view for illustrating the fabrication process for the nitride semiconductor laser element according to the twenty-second embodiment shown in FIG. 106.

FIG. 110 is a sectional view showing the structure of a nitride semiconductor laser element according to a twenty-third embodiment of the present invention.

FIG. 111 is a sectional view for illustrating a fabrication process for the nitride semiconductor laser element according to the twenty-third embodiment shown in FIG. 110.

FIG. 112 is a sectional view for illustrating the fabrication process for the nitride semiconductor laser element according to the twenty-third embodiment shown in FIG. 110.

FIG. 113 is a sectional view for illustrating the fabrication process for the nitride semiconductor laser element according to the twenty-third embodiment shown in FIG. 110.

FIG. 114 is a sectional view for illustrating the fabrication process for the nitride semiconductor laser element according to the twenty-third embodiment shown in FIG. 110.

FIG. 115 is a sectional view showing the structure of a nitride semiconductor laser element according to a twenty-fourth embodiment of the present invention.

FIG. 116 is a sectional view for illustrating a fabrication process for the nitride semiconductor laser element according to the twenty-fourth embodiment shown in FIG. 115.

FIG. 117 is a sectional view for illustrating the fabrication process for the nitride semiconductor laser element according to the twenty-fourth embodiment shown in FIG. 115.

FIG. 118 is a sectional view for illustrating the fabrication process for the nitride semiconductor laser element according to the twenty-fourth embodiment shown in FIG. 115.

FIG. 119 is a sectional view showing the structure of a nitride semiconductor laser element according to a twenty-fifth embodiment of the present invention.

FIG. 120 is a sectional view for illustrating a fabrication process for the nitride semiconductor laser element according to the twenty-fifth embodiment shown in FIG. 119.

FIG. 121 is a sectional view for illustrating the fabrication process for the nitride semiconductor laser element according to the twenty-fifth embodiment shown in FIG. 119.

FIG. 122 is a sectional view for illustrating the fabrication process for the nitride semiconductor laser element according to the twenty-fifth embodiment shown in FIG. 119.

FIG. 123 is a sectional view for illustrating the fabrication process for the nitride semiconductor laser element according to the twenty-fifth embodiment shown in FIG. 119.

FIG. 124 is a sectional view showing the structure of a nitride semiconductor laser element according to a twenty-sixth embodiment of the present invention.

FIG. 125 is a sectional view for illustrating a fabrication process for the nitride semiconductor laser element according to the twenty-sixth embodiment shown in FIG. 124.

FIG. 126 is a sectional view for illustrating the fabrication process for the nitride semiconductor laser element according to the twenty-sixth embodiment shown in FIG. 124.

FIG. 127 is a sectional view for illustrating the fabrication process for the nitride semiconductor laser element according to the twenty-sixth embodiment shown in FIG. 124.

FIG. 128 is a sectional view for illustrating the fabrication process for the nitride semiconductor laser element according to the twenty-sixth embodiment shown in FIG. 124.

FIG. 129 is a sectional view showing the structure of a nitride semiconductor laser element according to a twenty-seventh embodiment of the present invention.

FIG. 130 is a sectional view for illustrating a fabrication process for the nitride semiconductor laser element according to the twenty-seventh embodiment shown in FIG. 129.

FIG. 131 is a sectional view for illustrating the fabrication process for the nitride semiconductor laser element according to the twenty-seventh embodiment shown in FIG. 129.

FIG. 132 is a sectional view for illustrating the fabrication process for the nitride semiconductor laser element according to the twenty-seventh embodiment shown in FIG. 129.

FIG. 133 is a sectional view for illustrating the fabrication process for the nitride semiconductor laser element according to the twenty-seventh embodiment shown in FIG. 129.

FIG. 134 is a sectional view showing the structure of a nitride semiconductor laser element according to a twenty-eighth embodiment of the present invention.

FIG. 135 is a sectional view for illustrating a fabrication process for the nitride semiconductor laser element according to the twenty-eighth embodiment shown in FIG. 134.

FIG. 136 is a sectional view for illustrating the fabrication process for the nitride semiconductor laser element according to the twenty-eighth embodiment shown in FIG. 134.

FIG. 137 is a sectional view for illustrating the fabrication process for the nitride semiconductor laser element according to the twenty-eighth embodiment shown in FIG. 134.

FIG. 138 is a sectional view for illustrating the fabrication process for the nitride semiconductor laser element according to the twenty-eighth embodiment shown in FIG. 134.

FIG. 139 is a sectional view showing the structure of a nitride semiconductor laser element according to a twenty-ninth embodiment of the present invention.

FIG. 140 is a sectional view for illustrating a fabrication process for the nitride semiconductor laser element according to the twenty-ninth embodiment shown in FIG. 139.

FIG. 141 is a sectional view for illustrating the fabrication process for the nitride semiconductor laser element according to the twenty-ninth embodiment shown in FIG. 139.

FIG. 142 is a sectional view for illustrating the fabrication process for the nitride semiconductor laser element according to the twenty-ninth embodiment shown in FIG. 139.

FIG. 143 is a sectional view for illustrating the fabrication process for the nitride semiconductor laser element according to the twenty-ninth embodiment shown in FIG. 139.

FIG. 144 is a sectional view showing the structure of a nitride semiconductor laser element according to a thirtieth embodiment of the present invention.

FIG. 145 is a sectional view for illustrating a fabrication process for the nitride semiconductor laser element according to the thirtieth embodiment shown in FIG. 144.

FIG. 146 is a sectional view for illustrating the fabrication process for the nitride semiconductor laser element according to the thirtieth embodiment shown in FIG. 144.

FIG. 147 is a sectional view for illustrating the fabrication process for the nitride semiconductor laser element according to the thirtieth embodiment shown in FIG. 144.

FIG. 148 is a sectional view for illustrating the fabrication process for the nitride semiconductor laser element according to the thirtieth embodiment shown in FIG. 144.

FIG. 149 is a sectional view showing the structure of a nitride semiconductor laser element according to a thirty-first embodiment of the present invention.

FIG. 150 is an enlarged sectional view showing an MQW emission layer of the nitride semiconductor laser element according to the thirty-first embodiment shown in FIG. 149.

FIG. 151 is a front elevational view of the nitride semiconductor laser element according to the thirty-first embodiment shown in FIG. 149.

FIG. 152 is a sectional view of the nitride semiconductor laser element according to the thirty-first embodiment shown in FIG. 149 taken along the line 800-800.

FIG. 153 is a plan view showing regions for forming ion-implanted light absorption layers of the nitride semiconductor laser element according to the thirty-first embodiment shown in FIG. 149.

FIG. 154 is a perspective view for illustrating a fabrication process for the nitride semiconductor laser element according to the thirty-first embodiment shown in FIG. 149.

FIG. 155 is a perspective view for illustrating the fabrication process for the nitride semiconductor laser element according to the thirty-first embodiment shown in FIG. 149.

FIG. 156 is a perspective view for illustrating the fabrication process for the nitride semiconductor laser element according to the thirty-first embodiment shown in FIG. 149.

FIG. 157 is a perspective view for illustrating the fabrication process for the nitride semiconductor laser element according to the thirty-first embodiment shown in FIG. 149.

FIG. 158 is a perspective view for illustrating the fabrication process for the nitride semiconductor laser element according to the thirty-first embodiment shown in FIG. 149.

FIG. 159 is a perspective view for illustrating the fabrication process for the nitride semiconductor laser element according to the thirty-first embodiment shown in FIG. 149.

FIG. 160 is a perspective view for illustrating the fabrication process for the nitride semiconductor laser element according to the thirty-first embodiment shown in FIG. 149.

FIG. 161 is a perspective view for illustrating the fabrication process for the nitride semiconductor laser element according to the thirty-first embodiment shown in FIG. 149.

FIG. 162 is a perspective view for illustrating the fabrication process for the nitride semiconductor laser element according to the thirty-first embodiment shown in FIG. 149.

FIG. 163 is a perspective view for illustrating the fabrication process for the nitride semiconductor laser element according to the thirty-first embodiment shown in FIG. 149.

FIG. 164 is a perspective view for illustrating the fabrication process for the nitride semiconductor laser element according to the thirty-first embodiment shown in FIG. 149.

FIG. 165 is a perspective view showing the structure of a nitride semiconductor laser element according to a thirty-second embodiment of the present invention.

FIG. 166 is a front elevational view of the nitride semiconductor laser element according to the thirty-second embodiment shown in FIG. 165.

FIG. 167 is a sectional view of the nitride semiconductor laser element according to the thirty-second embodiment shown in FIG. 165 taken along the line 900-900.

FIG. 168 is a perspective view for illustrating a fabrication process for the nitride semiconductor laser element according to the thirty-second embodiment shown in FIG. 165.

FIG. 169 is a perspective view for illustrating the fabrication process for the nitride semiconductor laser element according to the thirty-second embodiment shown in FIG. 165.

FIG. 170 is a perspective view for illustrating the fabrication process for the nitride semiconductor laser element according to the thirty-second embodiment shown in FIG. 165.

FIG. 171 is a perspective view for illustrating the fabrication process for the nitride semiconductor laser element according to the thirty-second embodiment shown in FIG. 165.

FIG. 172 is a perspective view for illustrating the fabrication process for the nitride semiconductor laser element according to the thirty-second embodiment shown in FIG. 165.

FIG. 173 is a sectional view showing the structure of a conventional nitride semiconductor laser element.

### BEST MODE FOR CARRYING OUT THE INVENTION

Embodiments of the present invention are now described with reference to the drawings.

### First Embodiment

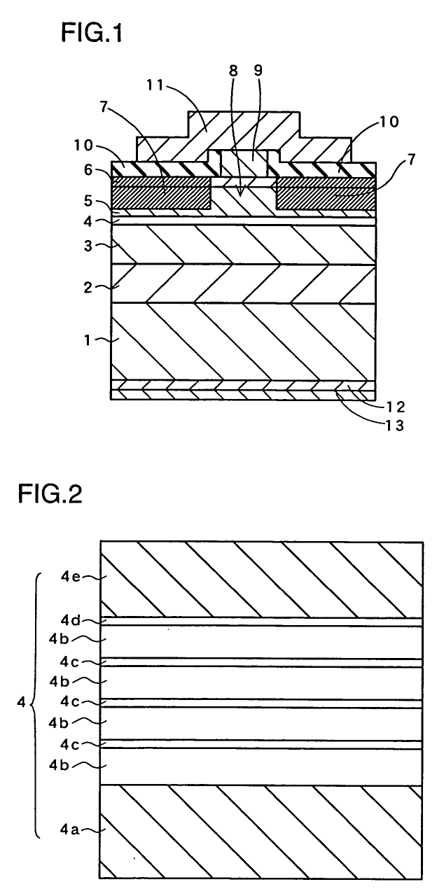

First, the structure of a nitride semiconductor laser element according to a first embodiment is described with reference to FIGS. 1 and 2. According to this first embodiment, an n-type layer 2 of GaN having a thickness of about 1 μm, an n-type cladding layer 3 of Al_{0.08}Ga_{0.92}N having a thickness of about 1 μm and an MQW emission layer 4 are formed on an n-type GaN substrate 1 in this order. The MQW emission layer 4 includes an MQW active layer in which three quantum well layers 4c of In_{X}Ga_{1-X}N each having a thickness of about 8 nm and four barrier layers 4b of In_{Y}Ga_{1-Y}N each having a thickness of about 16 nm are alternately stacked. In the MQW active layer according to the first embodiment, the values X and Y are set to 0.13 and 0.05 respectively. An n-type light guide layer 4a of Al_{0.01}Ga_{0.99}N having a thickness of about 0.1 μm is formed on the lower surface of the MQW active layer. Further, a p-type cap layer 4d of Al_{0.1}Ga_{0.9}N having a thickness of about 20 nm and a p-type light guide layer 4e of Al_{0.01}Ga_{0.99}N having a thickness of about 0.1 μm are formed on the upper surface of the MQW active layer in this order. The MQW emission layer 4 is an example of the “emission layer” in the present invention, and the n-type layer 2 and the n-type cladding layer 3 are examples of the “first nitride semiconductor layer” in the present invention.

A p-type cladding layer 5 of Al_{0.08}Ga_{0.92}N having a thickness of about 0.28 μm and a p-type contact layer 6 of Al_{0.01}Ga_{0.99}N having a thickness of about 0.07 μm are formed on the MQW emission layer 4. The p-type cladding layer 5 and the p-type contact layer 6 are examples of the “second nitride semiconductor layer” in the present invention.

According to the first embodiment, ion-implanted light absorption layers 7, formed by ion-implanting carbon (C), having an implantation depth of about 0.32 μm are provided. Carbon is an example of the “first impurity element” in the present invention, and the ion-implanted light absorption layers 7 are examples of the “light absorption layer” in the present invention. In this case, the peak depth of the concentration of the ion-implanted carbon is located in regions of the p-type cladding layer 5 at about 0.23 μm from the upper surface of the p-type contact layer 6. The peak concentration at this peak depth is about 1.0×10²⁰ cm⁻³. In this case, the ion-implanted light absorption layers 7 contain a larger number of crystal defects than the remaining regions due to implantation of a large quantity of ions into a semiconductor. A non-ion-implanted region (non-implanted region) forming a current passing region 8 is formed with a width of about 2.1 μm.

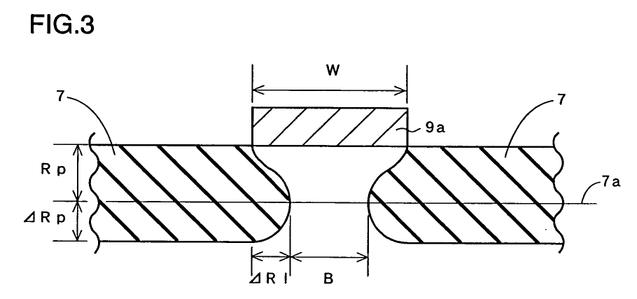

FIG. 3 is an enlarged sectional view schematically showing ion-implanted regions. The ion-implanted light absorption layers 7 indicate the ion-implanted regions, and a mask layer 9a indicates a mask layer in ion implantation. FIG. 3 shows no layered structure of nitride semiconductor layers. Referring to FIG. 3, symbol Rp denotes the peak depth, and a solid line 7a shows the position of the peak depth. In the nitride semiconductor laser element according to the embodiment of the present invention, Rp+ΔRp has been defined as the implantation depth (thickness of the ion-implanted light absorption layers 7). Symbol ΔRp denotes the standard deviation of a range. Transverse spreading (ΔR1) of ions is caused under the mask layer 9a in ion implantation. Assuming that W represents the width of the mask layer 9a in ion implantation, the width B of a region 8a, not subjected to ion implantation, located under the mask layer 9a is expressed as B=W−2×ΔR1. Sectional views other than FIG. 3 illustrate no transverse spreading of ions, in order to simplify the figures.

The ion-implanted light absorption layers 7 in the first embodiment function as light absorption layers due to crystal defects contained in the ion-implanted light absorption layers 7 in a large number and also function as current narrowing layers due to high resistance. In order to sufficiently perform not only current narrowing but also transverse optical confinement in the ion-implanted light absorption layers 7, the maximum value of the impurity concentration of the ion-implanted carbon is preferably at least about 5×10¹⁹ cm⁻³. Thus, the ion-implanted light absorption layers 7, containing a larger number of crystal defects than the current passing region 8, can absorb light through the crystal defects contained in a large number.

A p-side ohmic electrode 9 consisting of a Pt layer having a thickness of about 1 nm, a Pd layer having a thickness of about 100 nm, an Au layer having a thickness of about 240 nm and an Ni layer having a thickness of about 240 nm in ascending order is formed on the upper surface of the current passing region 8 of the p-type contact layer 6 in a striped (elongated) shape with an electrode width of about 2.2 μm. Insulator films 10 of SiO₂ are formed to cover the side surfaces of the p-side ohmic electrode 9 and the upper surface of the p-type contact layer 6. A p-side pad electrode 11 consisting of a Ti layer having a thickness of about 100 nm, a Pt layer having a thickness of about 150 nm and an Au layer having a thickness of about 3 μm in ascending order is formed on the insulator films 10 to be in contact with the upper surface of the p-side ohmic electrode 9.

An n-side ohmic electrode 12 consisting of an Al layer having a thickness of about 6 nm, an Si layer having a thickness of about 2 nm, an Ni layer having a thickness of about 10 nm and an Au layer having a thickness of about 100 nm successively from the side closer to the back surface of the n-type GaN substrate 1 is formed on the back surface of the n-type GaN substrate 1. An n-side pad electrode 13 consisting of an Ni layer having a thickness of about 10 nm and an Au layer having a thickness of about 700 nm successively from the side closer to the n-side ohmic electrode 12 is formed on the back surface of the n-side ohmic electrode 12.

In the nitride semiconductor laser element according to the first embodiment, as hereinabove described, the ion-implanted light absorption layers 7 formed by ion-implanting carbon into the regions of the p-type cladding layer 5 and the p-type contact layer 6 formed on the MQW emission layer 4 other than the current passing region 8 are so provided that the ion-implanted light absorption layers 7 can be formed with excellent reproducibility due to excellent reproducibility of ion implantation. Thus, transverse optical confinement can be controlled with excellent reproducibility. Consequently, the yield can be improved as compared with a conventional nitride semiconductor laser element having a ridge portion.

In the nitride semiconductor laser element according to the first embodiment, further, the ion-implanted light absorption layers 7 formed by ion implantation are so provided as hereinabove described that no irregularity or high-density crystal defects are formed on the interfaces between the ion-implanted light absorption layers 7 and the current passing region 8 dissimilarly to a conventional structure having a ridge portion formed by etching. Thus, generation of a leakage current resulting from crystal defects can be remarkably suppressed.

In a fabrication process for the nitride semiconductor laser element according to the first embodiment, implanted ions are peaked in the p-type cladding layer 5 as described above, whereby crystal defects can be formed in the p-type cladding layer 5 with sufficient density. Thus, the ion-implanted light absorption layers 7 having a sufficient light absorption effect can be formed in the p-type cladding layer 5. Consequently, the nitride semiconductor laser element has a sufficient transverse optical confinement effect. Further, the ion-implanted light absorption layers 7 are formed separately from the MQW emission layer 4 by a first distance of 0.03 μm in the depth direction so that the MQW emission layer 4 located under the ion-implanted light absorption layers 7 has a small number of crystal defects, whereby reduction of the life of the element can be suppressed.

In the nitride semiconductor laser element according to the first embodiment, as hereinabove described, the ion-implanted light absorption layers 7 formed by ion implantation are so provided that no conventional projecting ridge portion is necessary. Thus, when the element is mounted on a heat radiation base in a junction-down system from the surface closer to the MQW emission layer 4, the element characteristics are not disadvantageously deteriorated due to stress applied to a projecting ridge portion. Further, no such disadvantage is caused either that heat radiation characteristics are deteriorated due to reduction of a contact area with the heat radiation base resulting from a projecting ridge portion.

In the nitride semiconductor laser element according to the first embodiment, as hereinabove described, the insulator films 10 are so formed on the ion-implanted light absorption layers 7 that generation of a small leakage current can be prevented when a high current is injected into the element.

The fabrication process for the nitride semiconductor laser element according to the first embodiment is now described with reference to FIGS. 1 to 9.

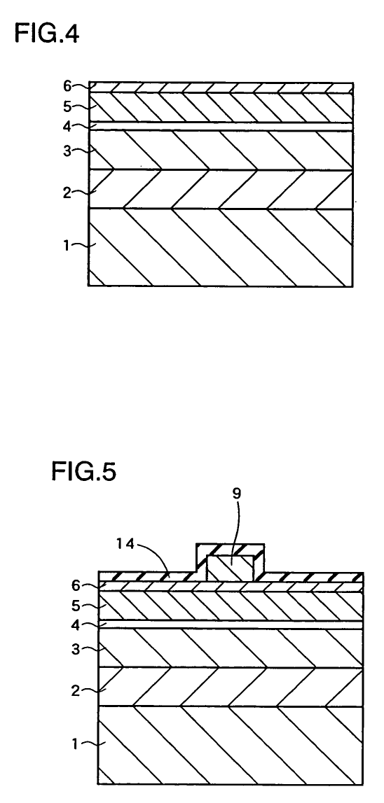

As shown in FIG. 4, the n-type layer 2 of GaN having the thickness of about 1 μm and the n-type cladding layer 3 of Al_{0.08}Ga_{0.92}N having the thickness of about 1 μm are successively formed on the n-type GaN substrate 1 by MOCVD (Metal Organic Chemical Vapor Deposition: metal organic chemical vapor deposition). The MQW emission layer 4 consisting of the MQW active layer in which the n-type light guide layer 4a of Al_{0.01}Ga_{0.99}N having the thickness of about 0.1 μm, the three quantum well layers 4c of In_{X}Ga_{1-X}N each having the thickness of about 8 nm and the four barrier layers 4b of In_{Y}Ga_{1-Y}N each having the thickness of about 16 nm are stacked, the p-type cap layer 4d of Al_{0.1}Ga_{0.9}N having the thickness of about 20 nm and the p-type light guide layer 4e of Al_{0.01}Ga_{0.99}N having the thickness of about 0.1 μm is formed on this n-type cladding layer 3, as shown in FIG. 2. The p-type cladding layer 5 of Al_{0.08}Ga_{0.92}N having the thickness of about 0.28 μm and the p-type contact layer 6 of Al_{0.01}Ga_{0.99}N having the thickness of about 0.07 μm are successively formed on this MQW emission layer 4. Si is added as an n-type dopant, and Mg is added as a p-type dopant.

As shown in FIG. 5, the p-side ohmic electrode 9 consisting of the Pt layer having the thickness of about 1 nm, the Pd layer having the thickness of about 100 nm, the Au layer having the thickness of about 240 nm and the Ni layer having the thickness of about 240 nm in ascending order is formed on the upper surface of the p-type contact layer 6 for forming the current passing region 8 by a lift-off method in the striped (elongated) shape with the electrode width of about 2.2 μm. When the electrode width of the p-side ohmic electrode 9 is in the range of about 1 μm to about 6 μm, a current path can be sufficiently ensured while transverse optical confinement can also be excellently performed.

In other words, contact areas of the p-side ohmic electrode 9 and the p-type contact layer 6 are reduced if the electrode width of the p-side ohmic electrode 9 is set to not more than about 1 μm, to increase contact resistance. When ion implantation is performed through this p-side ohmic electrode 9 serving as a mask, crystal defects are introduced also in the transverse direction, as described later. Thus, this region has high resistance and hence the effective width of the current passing region 8 is reduced to result in excess current density. Consequently, temperature rise is increased to cause increase of an operating current or reduction of the element life. In an extreme case, further, there is an apprehension that no effective current path can be ensured and no current can be injected into the element as a result. If the electrode width of the p-side ohmic electrode 9 is rendered larger than 6 μm, on the other hand, the width of the current passing region 8 is excessively increased to excessively reduce the current density. Consequently, a threshold current may be remarkably increased. Further, the ion-implanted light absorption layers 7 are so excessively separated from an emission portion of the MQW emission layer 4 that transverse optical confinement may be insufficient. Therefore, the electrode width of the p-side ohmic electrode 9 is preferably set in the range of about 1 μm to about 6 μm.

Then, a through film 14 of SiO₂ having a thickness of about 60 nm is formed by plasma CVD to cover the overall upper surfaces of the p-side ohmic electrode 9 and the p-type contact layer 6.

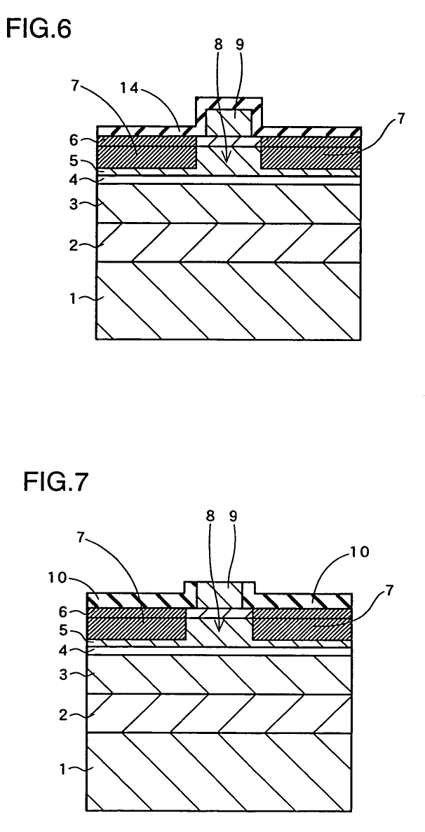

As shown in FIG. 6, the p-side ohmic electrode 9 is employed as a mask for ion-implanting a large quantity of carbon into prescribed regions of the p-type contact layer 6 and the p-type cladding layer 5 through the through film 14, thereby forming the ion-implanted light absorption layers 7 having the ion implantation depth (thickness) of about 0.32 μm from the upper surface of the p-type contact layer 6. Thus, the current passing region 8 having the current passing width of about 2.1 μm is formed. According to the first embodiment, carbon was ion-implanted under conditions of ion implantation energy of about 95 keV and a dose of about 2.3×10¹⁵ cm⁻². This ion implantation was performed from a direction inclined from a direction ([0001] direction of the p-type contact layer 6) perpendicular to the surface of the p-type contact layer 6 by about 70 in the stripe direction of the p-side ohmic electrode 9.

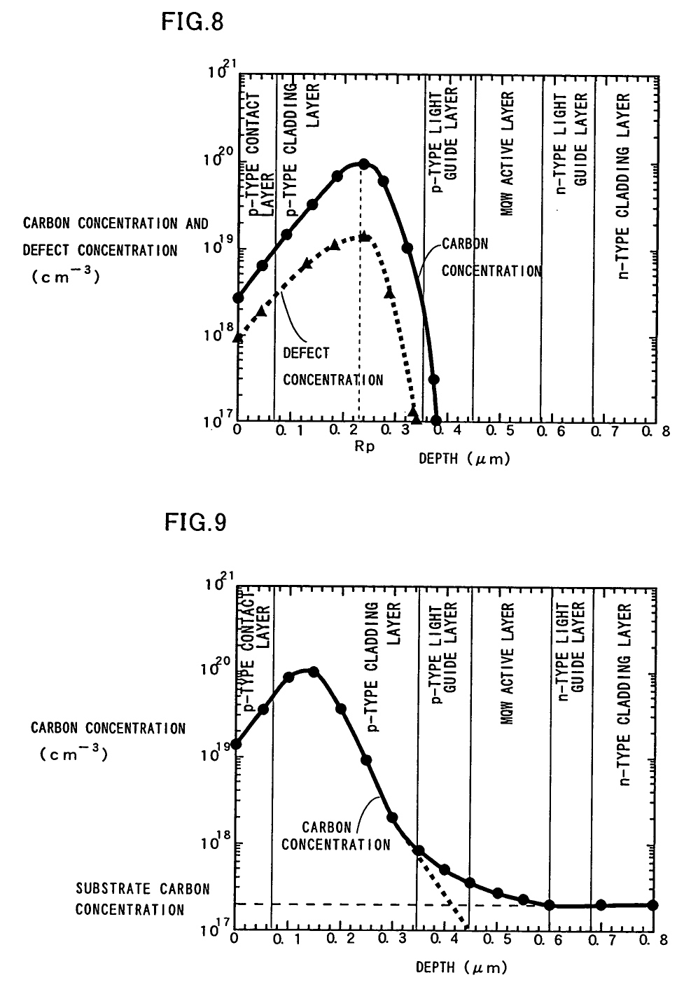

FIG. 8 shows simulation results of a carbon concentration profile in the depth direction of the element in the case of performing ion implantation under the ion implantation conditions (implantation energy: about 95 keV, dose: about 2.3×10¹⁵ cm⁻²) according to this first embodiment and a crystal defect concentration profile caused in a crystal due to the ion implantation. This simulation was made with simulation software referred to as TRIM, provided to the public by engineers of IBM corporation. Referring to FIG. 8, the peak depth Rp of the carbon concentration is about 0.23 μm while the carbon concentration at this peak depth Rp is about 1.0×10²⁰ cm⁻³ in the simulation results according to the ion implantation conditions of the first embodiment. Further, the standard deviation ΔRp of this graph is about 0.1 μm.

When spreading distribution of carbon and crystal defects in a direction (transverse direction) perpendicular to the ion implantation direction was simulated by simulation through TRIM, it has been recognized that transverse spreading (ΔR1) of about 0.12 μm is caused as schematically shown in FIG. 2. Thus, according to the first embodiment, the width of the current passing region 8 defined by the width of the ion-implanted light absorption layers 7 is set to a value in consideration of transverse implantation spreading of introduced ions from the width of the mask layer in ion implantation. In the nitride semiconductor laser element according to the first embodiment, the sum (about 2.3 μm) of the width (about 2.2 μm) of the p-side ohmic electrode 9 and the thickness (about 0.1 μm in total of the right and left portions) of the portions of the through film 14 formed on the side surfaces of the p-side ohmic electrode 9 corresponds to the width W of the mask layer in ion implantation. The width (about 2.1 μm) of the current passing region 8 corresponding to the width B of the non-ion-implanted region located under the mask layer is obtained by subtracting about 0.2 μm, which is twice the transverse implantation spreading (ΔR1), from this width of the mask layer.

Referring to FIG. 8, peaks are present in the p-type cladding layer 5 in both of the carbon concentration and the crystal defect concentration according to the first embodiment. More specifically, it has been recognized by the simulation that the peak depth of the crystal defect concentration distribution is shallower by about 0.02 μm than that of the carbon concentration distribution although this is not obvious from FIG. 8.

FIG. 9 shows results of measurement of carbon concentration distribution according to SIMS (Secondary Ion Mass Spectroscopy) analysis of the element according to the ion implantation conditions of the first embodiment. As to measurement conditions according to SIMS analysis, Cs⁺ ions were employed as primary ions while a primary ion acceleration voltage was set to 15 kV and a primary ion current was set to 25 nA. The primary ions were applied by raster-scanning the primary ions in a region of 120 by 120 μm² of a sample under these measurement conditions. At this time, C⁻ ions (secondary ions) coming out from a region of 60 μm in diameter on the sample were detected thereby measuring the carbon concentration distribution in the depth direction. While the carbon concentration is constant (about 2×10¹⁷ cm⁻³) on a position of at least about 0.6 μm in implantation depth in FIG. 9, this is the concentration of carbon not introduced by ion implantation but originally existing in a nitride semiconductor layer formed by crystal growth. The concentration profile of a low-concentration region shown by a broken line in FIG. 9 is shown by excluding the concentration (about 2×10¹⁷ cm⁻³) of carbon originally contained in the nitride semiconductor layer in consideration of this.

Referring to FIG. 9, it has also been recognized that the peak of the carbon concentration distribution is in the p-type cladding layer 5 also in the actual carbon concentration measurement according to SIMS analysis, similarly to the aforementioned simulation results. The peak depth of the carbon concentration in the measurement results according to this SIMS analysis was about 0.15 μm from the upper surface of the p-type contact layer 6.

As hereinabove described, the peak depth Rp of the carbon concentration distribution was at the level of about 0.23 μm from the upper surface of the p-type contact layer 6 in the simulation results according to TRIM, while the peak depth of the carbon concentration according to SIMS analysis was at the level of about 0.15 μm from the upper surface of the p-type contact layer 6. Thus, deviation of about 0.08 μm takes place between the trial calculated value of the peak depth of the carbon concentration according to TRIM and the measured value of the peak depth according to SIMS analysis when ion-implanting carbon according to the conditions of the first embodiment. The magnitude of this deviation varies with the type of the implanted element and the implantation conditions. When ion-implanting silicon under conditions of implantation energy of 110 keV and a dose of 1×10¹⁵ cm⁻², for example, a trial calculated value of the peak depth according to TRIM is about 0.15 μm, and a measured value of the peak depth according to SIMS is about 0.10 μm. Thus, a trial calculated value of the peak depth of the concentration of the implanted impurity according to TRIM and a measured value of the peak depth of the concentration of the implanted impurity according to SIMS are not necessarily completely coincident with each other. On the other hand, an implanted impurity concentration profile according to ion implantation can attain extremely high reproducibility so far as implantation conditions are set. Thus, it is known that a plurality of elements having similar implanted impurity concentration profiles can be easily obtained. Each embodiment according to the present invention is described with trial calculated values according to the aforementioned TRIM in principle.

After the ion-implanted light absorption layers 7 are formed by ion implantation as described above, the through film 14 is removed by wet etching with a hydrofluoric acid etchant. Thereafter the insulator films 10 of SiO₂ having the thickness of about 200 nm are formed by plasma CVD to cover the overall upper surfaces of the p-type contact layer 6 and the p-side ohmic electrode 9, as shown in FIG. 7. A resist film (not shown) having an opening on the upper surface of the p-side ohmic electrode 9 is formed by photolithography. This resist film is employed as a mask for removing a portion of the insulator films 10 located on the upper surface of the p-side ohmic electrode 9 by RIE (reactive ion etching) with CF₄ gas. Thus, the upper surface of the p-side ohmic electrode 9 is exposed.

Finally, the p-side pad electrode 11 consisting of the Ti layer having the thickness of about 100 nm, the Pt layer having the thickness of about 150 nm and the Au layer having the thickness of about 3 μm in ascending order is vacuum-evaporated onto the upper surfaces of the insulator films 10 to be in contact with the exposed upper surface of the p-side ohmic electrode 9, as shown in FIG. 1. The back surface of the n-type GaN substrate 1 is polished into a prescribed thickness (100 μm, for example), and the n-side ohmic electrode 12 consisting of the Al layer having the thickness of about 6 nm, the Si layer having the thickness of about 2 nm, the Ni layer having the thickness of about 10 nm an the Au layer having the thickness of about 100 nm from the side closer to the back surface of the n-type GaN substrate 1 is thereafter formed on the back surface of the n-type GaN substrate 1. Further, the n-side pad electrode 13 consisting of the Ni layer having the thickness of about 10 nm and the Au layer having the thickness of about 700 nm from the side closer to the n-side ohmic electrode 12 is formed on the n-side ohmic electrode 12, thereby completing the nitride semiconductor laser element according to the first embodiment.

In the fabrication process for the nitride semiconductor laser element according to the first embodiment, channeling of carbon can be suppressed by implanting carbon from the direction inclined by about 70 from the [0001] direction of the p-type contact layer 6 as hereinabove described, whereby carbon can be inhibited from deep implantation into the element. Consequently, controllability of the implantation profile in the depth direction is increased. In particular, the current passing region 8 provided under the p-side ohmic electrode 9 can be prevented from implantation of ions by performing ion implantation from the direction inclined in the stripe direction of the p-side ohmic electrode 9.

In the fabrication process for the nitride semiconductor laser element according to the first embodiment, as hereinabove described, the upper surface of the element is covered with the through film 14 before ion implantation so that channeling of carbon can be more effectively prevented. Thus, carbon can be further inhibited from deep implantation into the element, whereby controllability of the implantation profile in the depth direction is further improved.

In the fabrication process for the nitride semiconductor laser element according to the first embodiment, as hereinabove described, the p-side ohmic electrode 9 employed as the mask for ion implantation can be utilized as a contact electrode, whereby fabrication steps can be simplified.

### Second Embodiment

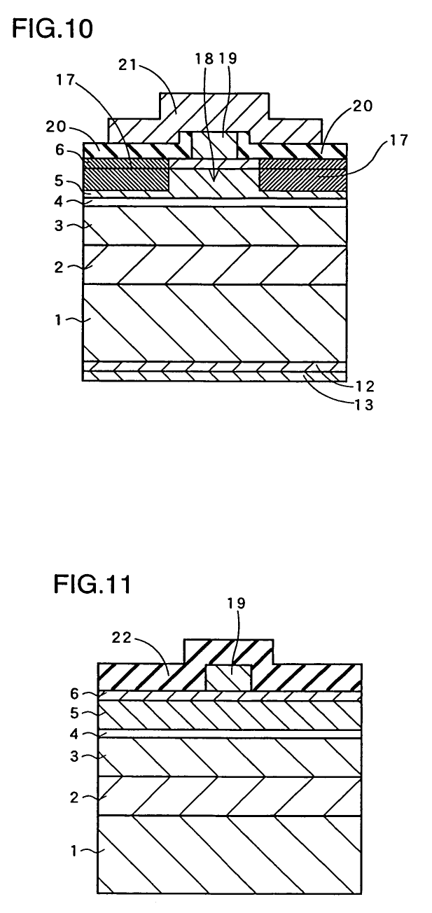

Referring to FIG. 10, the width of a current passing region is increased while no through film is formed in this second embodiment, dissimilarly to the first embodiment. The remaining structure of the second embodiment is similar to that of the first embodiment.

Referring to FIG. 10, an n-type layer 2, an n-type cladding layer 3, an MQW emission layer 4, a p-type cladding layer 5 and a p-type contact layer 6 are formed on an n-type GaN substrate 1 in this order according to this second embodiment, similarly to the first embodiment.

According to the second embodiment, ion-implanted light absorption layers 17, formed by ion-implanting carbon (C), having an implantation depth of about 0.32 μm are provided similarly to the first embodiment. The ion-implanted light absorption layers 17 are examples of the “light absorption layer” in the present invention, and carbon is an example of the “first impurity element” in the present invention. In this case, the peak depth of the concentration of ion-implanted carbon is located in regions of the p-type cladding layer 5 at about 0.23 μm from the upper surface of the p-type contact layer 6. The peak concentration at this peak depth is about 1.0×10²⁰ cm⁻³. In this case, the ion-implanted light absorption layers 17 contain a larger number of crystal defects than the remaining regions due to implantation of a large quantity of ions into a semiconductor. A non-ion-implanted region (non-implanted region) forming a current passing region 18 is formed with a width of about 2.8 μm. The width (about 2.8 μm) of the current passing region 18 in a nitride semiconductor laser element according to this second embodiment is larger than the width (about 2.1 μm) of the current passing region 8 of the nitride semiconductor laser element according to the first embodiment.

The ion-implanted light absorption layers 17 in the second embodiment function as light absorption layers due to crystal defects contained in the ion-implanted light absorption layers 17 in a large number and also function as current narrowing layers due to high resistance. In order to sufficiently perform not only current narrowing but also transverse optical confinement in the ion-implanted light absorption layers 17, the maximum value of the impurity concentration of ion-implanted carbon is preferably at least about 5×10¹⁹ cm⁻³. Thus, the ion-implanted light absorption layers 17, containing a larger number of crystal defects than the current passing region 18, can absorb light due to the crystal defects contained in a large number.

A p-side ohmic electrode 19 is formed on the upper surface of the current passing region 18 of the p-type contact layer 6 in a striped (elongated) shape with an electrode width of about 2.0 μm, similarly to the first embodiment. Thus, the electrode width (about 2.0 μm) of the p-side ohmic electrode 19 is smaller than the width (about 2.8 μm) of the current passing region 18 in the second embodiment. Insulator films 20 are formed to cover the side surfaces of the p-side ohmic electrode 19 and the p-type contact layer 6. A p-side pad electrode 21 is formed on the insulator films 20 to be in contact with the upper surface of the p-side ohmic electrode 19. An n-side ohmic electrode 12 and an n-side pad electrode 13 are formed on the back surface of the n-type GaN substrate 1 from the side closer to the back surface of the n-type GaN substrate 1. The thicknesses and compositions of the respective layers 19 to 21 are similar to those of the respective layers 9 to 11 in the first embodiment respectively. It is known that a current injected into a p side is generally introduced into an MQW active layer without much diffusing all around in a nitride semiconductor laser element easily falling short of p-type carrier concentration. Therefore, a current injected from the p-side electrode reaches the MQW active layer in the current passing region 18 without much spreading in the transverse direction.

In the nitride semiconductor laser element according to the second embodiment, as hereinabove described, light absorption in locations immediately under the electrodes having high emission strength can be further suppressed by reducing the width of the p-side ohmic electrode 19 beyond the interval (width of the current passing region 18) between the ion-implanted light absorption layers 17. Thus, increase of a threshold current and reduction of slope efficiency (current-optical output characteristics) can be suppressed.

A fabrication process for the nitride semiconductor laser element according to the second embodiment is now described with reference to FIGS. 10 to 13. The fabrication process according to the second embodiment is described with reference to a fabrication process of increasing the width of the current passing region 18 through a non-implanted region enlarging film while forming no through film.

First, the layers up to the p-type contact layer 6 are formed through a process similar to that of the first embodiment shown in FIG. 4. As shown in FIG. 11, the p-side ohmic electrode 19 having the width of about 2 μm is formed on the upper surface of the p-type contact layer 6 by a lift-off method in a striped shape, similarly to the first embodiment.

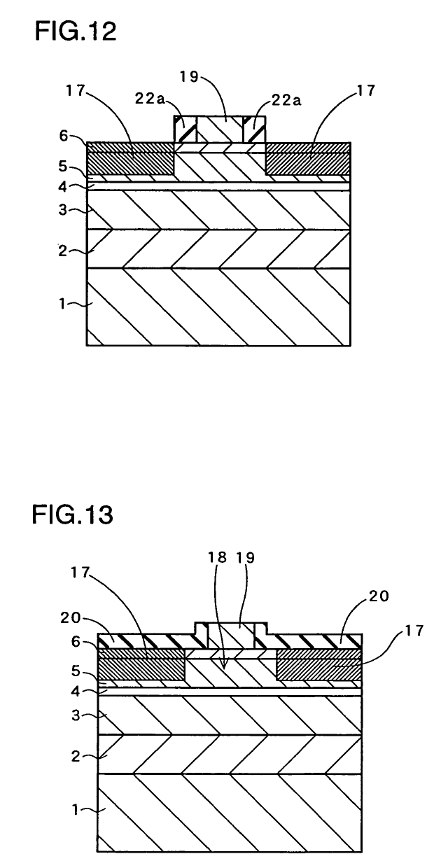

Thereafter a non-implanted region enlarging film 22 of SiO₂ having a thickness of about 500 nm is formed by plasma CVD to cover the overall upper surfaces of the p-side ohmic electrode 19 and the p-type contact layer 6 according to the second embodiment. The non-implanted region enlarging film 22 is anisotropically etched by RIE employing CF₄ gas. Thus, non-implanted region enlarging films 22a having a width of about 500 nm are formed on both side wall portions of the p-side ohmic electrode 19 respectively, as shown in FIG. 12. Thereafter the p-side ohmic electrode 19 and the non-implanted region enlarging films 22a are employed as masks (width of masks: about 3 μm) for performing ion implantation. In other words, carbon is ion-implanted under conditions of ion implantation energy of about 80 keV and a dose of about 2.3×10¹⁵ cm⁻², thereby forming the ion-implanted light absorption layer 17. Thereafter the non-implanted region enlarging films 22a removed by wet etching with a hydrofluoric etchant.

As shown in FIG. 13, the insulator films 20 of SiO₂ having a thickness of about 200 nm are formed by plasma CVD to cover the overall surfaces of p-type contact layer 6 and the p-side ohmic electrode 19. The upper surface of the p-side ohmic electrode 19 is exposed by photolithography and RIE with CF₄ gas, similarly to the first embodiment.

Finally, the p-side pad electrode 21 is formed on the insulator films 20 to be in contact with the upper surface of the p-side ohmic electrode 19 while the n-type GaN substrate 1 is polished into a prescribed thickness and the n-side ohmic electrode 12 and the n-side pad electrode 13 are thereafter formed on this back surface of this n-type GaN substrate 1 through a process similar to that of the first embodiment, thereby completing the nitride semiconductor laser element according to the second embodiment as shown in FIG. 10.

### Third Embodiment

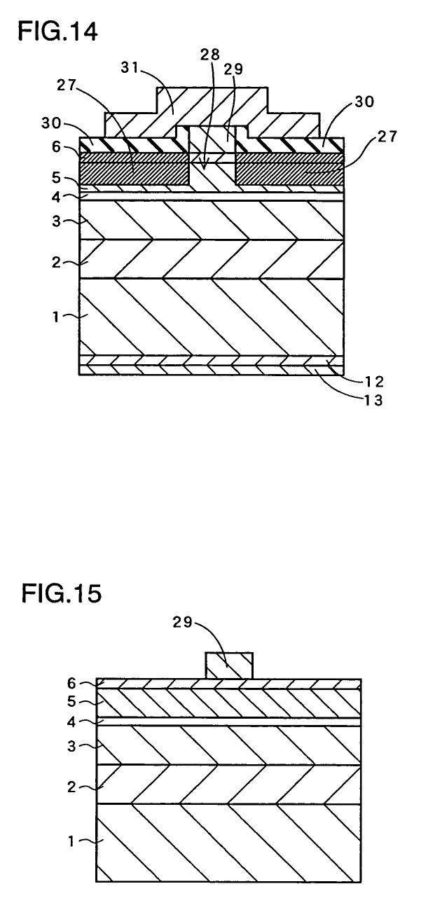

Referring to FIG. 14, the width of a current passing region is reduced while no through film is formed in this third embodiment, dissimilarly to the first embodiment. The remaining structure of the third embodiment is similar to that of the first embodiment.

Referring to FIG. 14, an n-type layer 2, an n-type cladding layer 3, an MQW emission layer 4, a p-type cladding layer 5 and a p-type contact layer 6 are formed on an n-type GaN substrate 1 in this order according to this third embodiment, similarly to the first embodiment.

According to the third embodiment, ion-implanted light absorption layers 27, formed by ion-implanting carbon (C), having an implantation depth of about 0.32 μm are provided. The ion-implanted light absorption layers 27 are examples of the “light absorption layer” in the present invention, and carbon is an example of the “first impurity element” in the present invention. In this case, the peak depth of the concentration of the ion-implanted carbon is located in regions of the p-type cladding layer 5 at about 0.23 μm from the upper surface of the p-type contact layer 6. The peak concentration at this peak depth is about 1.0×10²⁰ cm⁻³. In this case, the ion-implanted light absorption layers 27 contain a larger number of crystal defects than the remaining regions due to introduction of a large quantity of ions into a semiconductor. A non-ion-implanted region (non-implanted region) forming a current passing region 28 is formed with a width of about 2.0 μm.

The ion-implanted light absorption layers 27 in the third embodiment function as light absorption layers due to crystal defects contained in the ion-implanted light absorption layers 27 in a large number and also function as current narrowing layers due to high resistance. In order to sufficiently perform not only current narrowing but also transverse optical confinement in the ion-implanted light absorption layers 27, the maximum value of the impurity concentration of the ion-implanted carbon is preferably at least about 5×10⁹ cm⁻³. Thus, the ion-implanted light absorption layers 27, containing a larger number of crystal defects than the current passing region 28, can absorb light due to the crystal defects contained in a large number.

A p-side ohmic electrode 29 is formed on the upper surface of the current passing region 28 of the p-type contact layer 6 in a striped shape with an electrode width of about 2.2 μm, similarly to the first embodiment. According to the third embodiment, the electrode width (about 2.2 μm) of the p-side ohmic electrode 29 is substantially identical to the width (about 2.0 μm) of the current passing region 28. Insulator films 30 are formed to cover the side surfaces of the p-side ohmic electrode 29 and the p-type contact layer 6. A p-side pad electrode 31 is formed on the insulator films 30 to be in contact with the upper surface of the p-side ohmic electrode 29. An n-side ohmic electrode 12 and an n-side pad electrode 13 are formed on the back surface of the n-type GaN substrate 1 from the side closer to the back surface of the n-type GaN substrate 1. The thicknesses and compositions of the respective layers 29 to 31 are similar to those of the respective layers 9 to 11 of the first embodiment respectively.

In a nitride semiconductor laser element according to the third embodiment, effects substantially similar to those of the first embodiment can be attained by substantially equalizing the electrode width of the p-side ohmic electrode 29 and the width of the current passing region 28 with each other, as hereinabove described. However, a threshold current is slightly increased while slope efficiency is slightly reduced as compared with the first embodiment.

A fabrication process for the nitride semiconductor laser element according to the third embodiment is now described with reference to FIGS. 14 to 17. The fabrication process with no formation of a through film is described with reference to the third embodiment.

First, the layers up to the p-type contact layer 6 are formed through a process similar to that of the first embodiment shown in FIG. 4. As shown in FIG. 15, the p-side ohmic electrode 29 having the width of about 2.2 μm is formed on the upper surface of the p-type contact layer 6 in the striped shape by a lift-off method, similarly to the first embodiment.

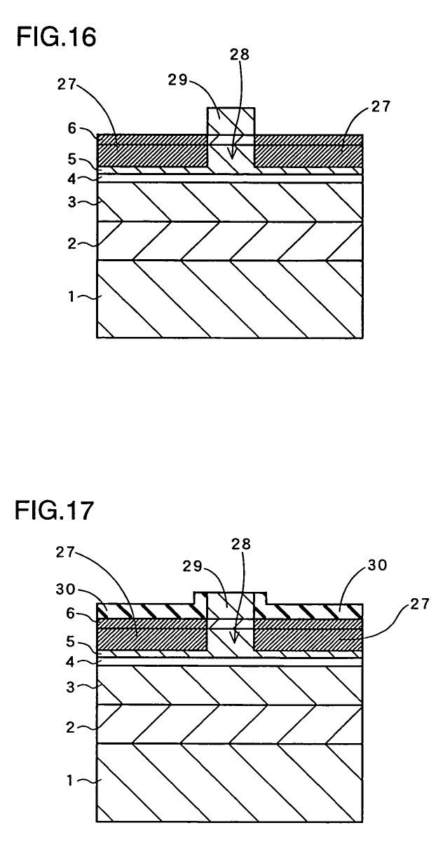

According to the third embodiment, carbon is thereafter directly ion-implanted through the p-side ohmic electrode 29 serving as a mask with no formation of a through film thereby forming the ion-implanted light absorption layers 27 having the implantation depth of about 0.32 μm, as shown in FIG. 16. The ion implantation in the third embodiment was performed under conditions of ion implantation energy of about 80 keV and a dose of about 2.3×10¹⁵ cm⁻².

As shown in FIG. 17, the insulator films 30 having the thickness of 200 nm and consisting of SiO₂ are formed to cover the overall upper surfaces of the p-type contact layer 6 and the p-side ohmic electrode 29 by plasma CVD. The upper surface of the p-side ohmic electrode 29 is exposed by photolithography and RIE with CF₄ gas, similarly to the first embodiment.

Finally, the p-side pad electrode 31 is formed on the p-side ohmic electrode 29 and the insulator films 30 while the n-type GaN substrate 1 is polished into a prescribed thickness and the n-side ohmic electrode 12 and the n-side pad electrode 13 are thereafter formed on the back surface of the n-type GaN substrate 1 successively from the side closer to the back surface of the n-type GaN substrate 1, thereby completing the nitride semiconductor laser element according to the third embodiment shown in FIG. 14.

In the fabrication process for the nitride semiconductor laser element according to the third embodiment, steps of forming and removing a through film are unnecessary as hereinabove described, whereby the fabrication steps can be simplified.

### Fourth Embodiment

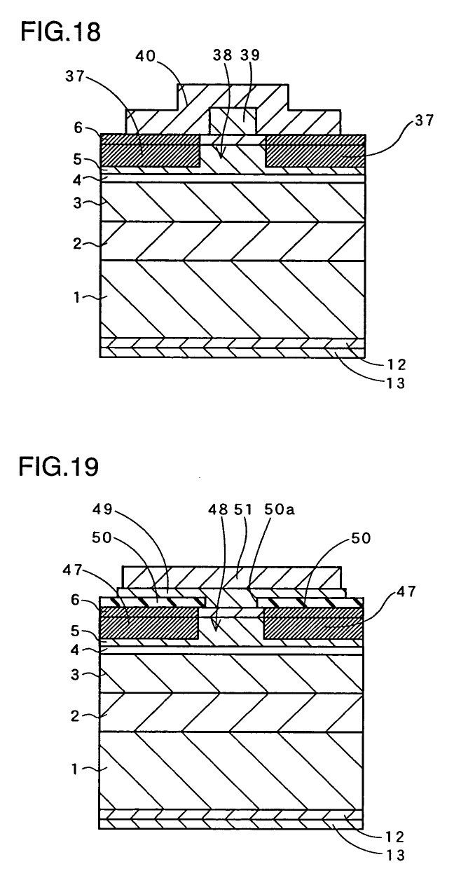

Referring to FIG. 18, an example of forming no insulator films between a p-type contact layer and a p-side pad electrode in the structure of the first embodiment is described with reference to this fourth embodiment. The remaining structure of the fourth embodiment is similar to that of the first embodiment.

First, the structure of a nitride semiconductor laser element according to the fourth embodiment is described with reference to FIG. 18. According to this fourth embodiment, an n-type layer 2, an n-type cladding layer 3, an MQW emission layer 4, a p-type cladding layer 5 and a p-type contact layer 6 are formed on an n-type GaN substrate 1 in this order according to this fourth embodiment, similarly to the first embodiment.

According to the fourth embodiment, ion-implanted light absorption layers 37, formed by ion-implanting carbon (C), having an implantation depth of about 0.32 μm are provided. The ion-implanted light absorption layers 37 are examples of the “light absorption layer” in the present invention, and carbon is an example of the “first impurity element” in the present invention. In this case, the peak depth of the concentration of the ion-implanted carbon is located in regions of the p-type cladding layer 5 at about 0.23 μm from the upper surface of the p-type contact layer 6. The peak concentration at this peak depth is about 1.0×10²⁰ cm⁻³. In this case, the ion-implanted light absorption layers 37 contain a larger number of crystal defects than the remaining regions due to introduction of a large quantity of ions into a semiconductor. A non-ion-implanted region (non-implanted region) for forming a current passing region 38 is formed with a width of about 2.1 μm.

The ion-implanted light absorption layers 37 in the fourth embodiment function as light absorption layers due to the crystal defects contained in the ion-implanted light absorption layers 37 in a large number, while functioning also as current narrowing layers due to high resistance. In order to sufficiently perform not only current narrowing but also transverse optical confinement in the ion-implanted light absorption layers 37, the maximum value of the impurity concentration of the ion-implanted carbon is preferably at least about 5×10¹⁹ cm⁻³. Thus, the ion-implanted light absorption layers 37, containing a larger number of crystal defects than the current passing region 38, can absorb light through the crystal defects contained in a large number.

A p-side ohmic electrode 39 is formed on the upper surface of the current passing region 38 of the p-type contact layer 6 in a striped shape with an electrode width of about 2.2 μm. Further, a p-side pad electrode 40 is directly formed without through insulator films to be in contact with the upper surfaces of the p-side ohmic electrode 39 and the p-type contact layer 6. An n-side ohmic electrode 12 and an n-side pad electrode 13 are formed on the back surface of the n-type GaN substrate 1 successively from the side closer to the back surface of the n-type GaN substrate 1. The thicknesses and compositions of the respective layers 39 and 40 are similar to those of the respective layers 9 and 11 in the first embodiment respectively.

In the nitride semiconductor laser element according to the fourth embodiment, no insulator films are formed between the p-type contact layer 6 and the p-side pad electrode 40 as hereinabove described, whereby a step of forming insulator films can be omitted.

In the nitride semiconductor laser element according to the fourth embodiment, further, no insulator films are present between the p-type contact layer 6 and the p-side pad electrode 40 as hereinabove described so that effects substantially similar to those of the first embodiment can be attained as to application in the range of a normal current, although a small leakage current may be generated through crystal defects of the ion-implanted light absorption layers 37 when a high current is applied to the element.

A fabrication process for the nitride semiconductor laser element according to the fourth embodiment is similar to the fabrication process according to the first embodiment except that no insulator film forming step is included.

### Fifth Embodiment

Referring to FIG. 19, an example of thinly forming an insulator film of ZrO₂ on a p-type contact layer dissimilarly to the first embodiment is described with reference to this fifth embodiment. The remaining structure of the fifth embodiment is similar to that of the first embodiment.

First, the structure of a nitride semiconductor laser element according to the fifth embodiment is described with reference to FIG. 19. According to this fifth embodiment, an n-type layer 2, an n-type cladding layer 3, an MQW emission layer 4, a p-type cladding layer 5 and a p-type contact layer 6 are formed on an n-type GaN substrate 1 in this order according to this fifth embodiment, similarly to the first embodiment.

According to the fifth embodiment, ion-implanted light absorption layers 47, formed by ion-implanting carbon (C), having an implantation depth of about 0.32 μm are provided similarly to the first embodiment. The ion-implanted light absorption layers 47 are examples of the “light absorption layer” in the present invention, and carbon is an example of the “first impurity element” in the present invention. In this case, the peak depth of the concentration of the ion-implanted carbon is located in regions of the p-type cladding layer 5 at about 0.23 μm from the upper surface of the p-type contact layer 6. The peak concentration at this peak depth is about 1.0×10²⁰ cm⁻³. In this case, the ion-implanted light absorption layers 47 contain a larger number of crystal defects than the remaining regions due to introduction of a large quantity of ions into a semiconductor. A non-ion-implanted region (non-implanted region) for forming a current passing region 48 is formed with a width of about 2.1 μm.

The ion-implanted light absorption layers 47 in the fifth embodiment function as light absorption layers due to the crystal defects contained in the ion-implanted light absorption layers 47 in a large number, while functioning also as current narrowing layers due to high resistance. In order to sufficiently perform not only current narrowing but also transverse optical confinement in the ion-implanted light absorption layers 47, the maximum value of the impurity concentration of the ion-implanted carbon is preferably at least about 5×10¹⁹ cm⁻³. Thus, the ion-implanted light absorption layers 47, containing a larger number of crystal defects than the current passing region 48, can absorb light through the crystal defects contained in a large number.

According to the fifth embodiment, an insulator film 50 of ZrO₂ having an opening 50a on the upper surface of the current passing region 48 of the p-type contact layer 6 with a small thickness of about 50 nm is formed. The width of this opening 50a is formed smaller than the width of the current passing region 48. A p-side ohmic electrode 49 is formed on this insulator film 50 to be in contact with the upper surface of the p-type contact layer 6 through the opening 50a of the insulator film 50 while extending on the upper surface of the insulator film 50. A p-side pad electrode 51 is formed on the upper surface of the p-side ohmic electrode 49. An n-side ohmic electrode 12 and an n-side pad electrode 13 are formed on the back surface of the n-type GaN substrate 1 successively from the side closer to the back surface of the n-type GaN substrate 1.

In the nitride semiconductor laser element according to the fifth embodiment, as hereinabove described, the thickness of the insulator film 50 consisting of ZrO₂ is so extremely small (50 nm) that the surface of the p-side pad electrode 51 can be further flattened. Thus, when the element is mounted on a heat radiation base in a junction-down system from the surface closer to the MQW emission layer 4, the element characteristics are not disadvantageously deteriorated due to stress applied to a conventional projecting ridge portion. Further, the element surface is further flattened so that no such disadvantage is caused either that heat radiation characteristics are deteriorated due to reduction of a contact area with the heat radiation base resulting from a projecting ridge portion.

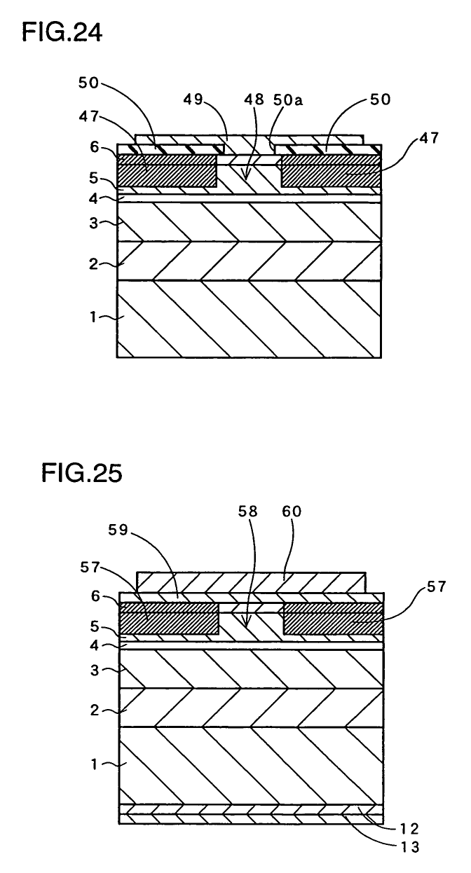

A fabrication process for the nitride semiconductor laser element according to the fifth embodiment is now described with reference to FIGS. 19 to 24.

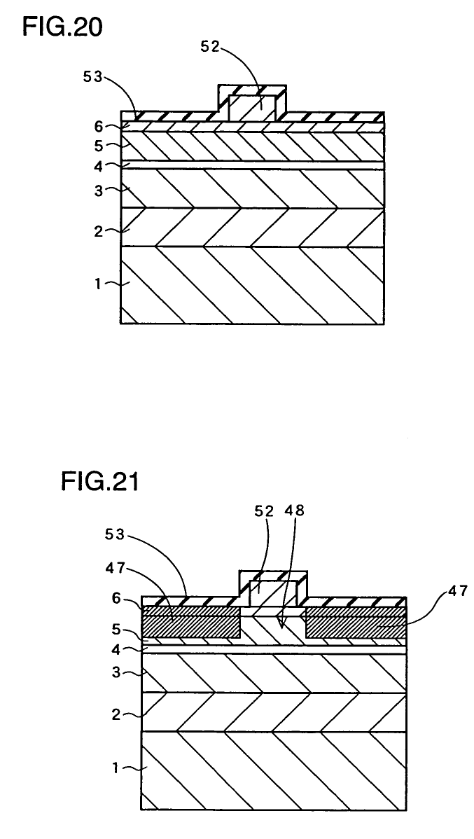

First, the layers up to the p-type contact layer 6 are formed through a process similar to that of the first embodiment shown in FIG. 4. As shown in FIG. 20, an ion implantation mask (not shown) of SiO₂ having a thickness of about 1.0 μm is formed on the upper surface of the p-type contact layer 6 by plasma CVD. This ion implantation mask is patterned through photolithography and etching, thereby forming a striped ion implantation mask layer 52 of SiO₂ having a thickness of about 2.2 μm. A through film 53 of SiO₂ is formed to cover the overall upper surfaces of the ion implantation mask layer 52 and the p-type contact layer 6, similarly to the first embodiment.

As shown in FIG. 21, the ion implantation mask layer 52 of SiO₂ is employed as a mask for ion-implanting carbon through the through film 53 under conditions similar to those in the first embodiment, thereby forming the ion-implanted light absorption layers 47. Thereafter the through film 53 is removed through dry etching with CF₄ gas.

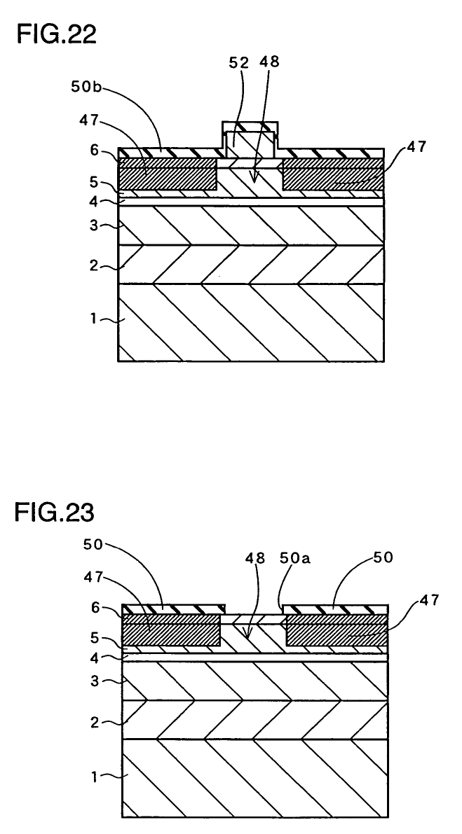

As shown in FIG. 22, an insulator film 50b of ZrO₂ having a thickness of about 50 nm is thereafter evaporated by EB evaporation from a direction perpendicular to the element to cover the overall upper surfaces of the p-type contact layer 6 and the ion implantation mask layer 52 of SiO₂ according to the fifth embodiment. In this case, the insulator film 50b is hardly formed on the side wall portions of the ion implantation mask layer 52 due to the evaporation from the direction perpendicular to the element.

As shown in FIG. 23, etching is performed with a hydrofluoric acid etchant for removing the ion implantation mask layer 52 of SiO₂ and parts of the insulator film 50b of ZrO₂. In this case, the insulator film 50b of ZrO₂ is so hardly etched that only the parts of the insulator film 50b located on the side wall portions of the ion implantation mask layer 52 are completely removed. Thus, the ion implantation mask layer 52 of SiO₂ is completely removed after the parts of the insulator film 50b located on the side wall portions of the ion implantation mask layer 52 are removed. Consequently, the insulator film 50 having the opening 50a on the upper surface of the current passing region 48 is formed as shown in FIG. 23.

Finally, the p-side ohmic electrode 49 and the p-side pad electrode 51 are formed on the insulator film 50 to be in contact with the upper surface of the p-type contact layer 6 through the opening. Further, the n-type GaN substrate 1 is polished into a prescribed thickness and the n-side ohmic electrode 12 and the n-side pad electrode 13 are thereafter formed on the back surface of the n-type GaN substrate 1, thereby completing the nitride semiconductor laser element according to the fifth embodiment shown in FIG. 19. The thicknesses and compositions of the respective layers 51, 12 and 13 are similar to those of the respective layers 11 to 13 in the first embodiment respectively.

In the fabrication process for the nitride semiconductor laser element according to the fifth embodiment, as hereinabove described, SiO₂ allowing easy wet etching is employed as the material for the ion-implanted mask layer 52 while ZrO₂ different from SiO₂ is employed as the material for the insulator film 50b so that the opening 50a can be easily formed in the insulator film 50b by removing the ion implantation mask layer 52 of SiO₂ by wet etching after ion implantation, whereby productivity can be improved.

### Sixth Embodiment

Referring to FIG. 25, an example of excluding the insulator film 50 from the structure according to the fifth embodiment is described with reference to this sixth embodiment.

Referring to FIG. 25, an n-type layer 2, an n-type cladding layer 3, an MQW emission layer 4, a p-type cladding layer 5 and a p-type contact layer 6 are formed on an n-type GaN substrate 1 in this order according to this sixth embodiment, similarly to the first embodiment.

According to the sixth embodiment, ion-implanted light absorption layers 57, formed by ion-implanting carbon (C), having an implantation depth of about 0.32 μm are provided similarly to the first embodiment. The ion-implanted light absorption layers 57 are examples of the “light absorption layer” in the present invention, and carbon is an example of the “first impurity element” in the present invention. In this case, the peak depth of the concentration of the ion-implanted carbon is located in regions of the p-type cladding layer 5 at about 0.23 μm from the upper surface of the p-type contact layer 6. The peak concentration at this peak depth is about 1.0×10²⁰ cm⁻³. In this case, the ion-implanted light absorption layers 57 contain a larger number of crystal defects than the remaining regions due to introduction of a large quantity of ions into a semiconductor. A non-ion-implanted region (non-implanted region) for forming a current passing region 58 is formed with a width of about 2.1 μm.

The ion-implanted light absorption layers 57 in the sixth embodiment function as light absorption layers due to the crystal defects contained in the ion-implanted light absorption layers 57 in a large number, while functioning also as current narrowing layers due to high resistance. In order to sufficiently perform not only current narrowing but also transverse optical confinement in the ion-implanted light absorption layers 57, the maximum value of the impurity concentration of the ion-implanted carbon is preferably at least about 5×10¹⁹ cm⁻³. Thus, the ion-implanted light absorption layers 57, containing a larger number of crystal defects than the current passing region 58, can absorb light through the crystal defects contained in a large number.

According to the sixth embodiment, a p-side ohmic electrode 59 is formed to cover the overall upper surface of the p-type contact layer 6. A p-side pad electrode 60 is formed on this p-side ohmic electrode 59. An n-side ohmic electrode 12 and an n-side pad electrode 13 are formed on the back surface of the n-type GaN substrate 1 successively from the side closer to the back surface of the n-type GaN substrate 1.

In the nitride semiconductor laser element according to the sixth embodiment, as hereinabove described, the p-side ohmic electrode 59 is directly formed on the p-type contact layer 6 so that the surface of the p-side pad electrode 60 can be completely flattened. Thus, when the element is mounted on a heat radiation base in a junction-down system from the surface closer to the MQW emission layer 4, stress applied to the current passing region 58 can be further reduced as compared with the conventional ridge structure and the structures according to the first to fifth embodiments, whereby the element characteristics can be further inhibited from deterioration. Further, the element surface is so completely flattened that a contact area with the heat radiation base can be increased, whereby more excellent heat radiation characteristics can be attained.

In the nitride semiconductor laser element according to the sixth embodiment, the thermal conductivity of the p-side ohmic electrode 59 is larger as compared with an insulator film of SiO₂ or the like, whereby the heat radiation characteristics of the element can be further improved by directly forming the large-area p-side ohmic electrode 59 on the p-type contact layer 6. Consequently, the element life can be improved.

A fabrication process for the nitride semiconductor element according to the sixth embodiment shown in FIG. 25 is now described with reference to FIGS. 25 to 28. The fabrication process according to the sixth embodiment is similar to the fabrication process according to the fifth embodiment except that no process of forming an insulator film of ZrO₂ is included.

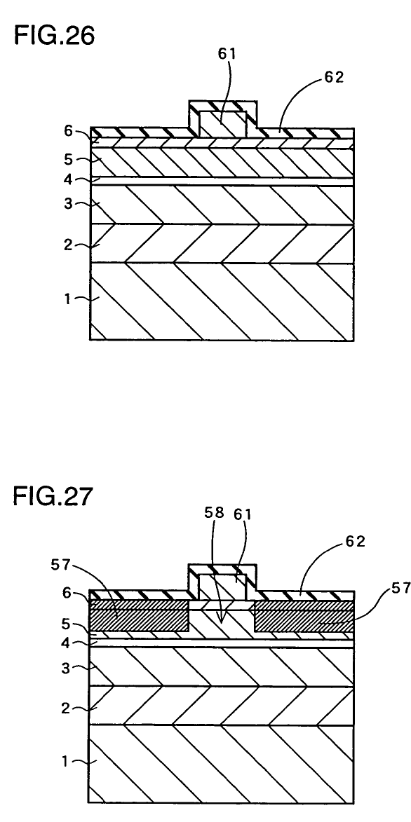

First, the layers up to the p-type contact layer 6 are formed through a process similar to that of the first embodiment shown in FIG. 4. Then, an ion implantation mask (not shown) of SiO₂ having a thickness of about 1.0 μm is formed on the upper surface of the p-type contact layer 6 by plasma CVD. This ion implantation mask is patterned through photolithography and etching, thereby forming a striped ion implantation mask layer 61 having a thickness of about 2.2 μm as shown in FIG. 26. A through film 62 of SiO₂ is formed to cover the overall upper surfaces of the p-type contact layer 6 and the ion-implanted mask layer 61, similarly to the first embodiment.

As shown in FIG. 27, the ion implantation mask layer 61 of SiO₂ is employed as a mask for ion-implanting carbon through the through film 62 under conditions similar to those in the first embodiment, thereby forming the ion-implanted light absorption layers 57.

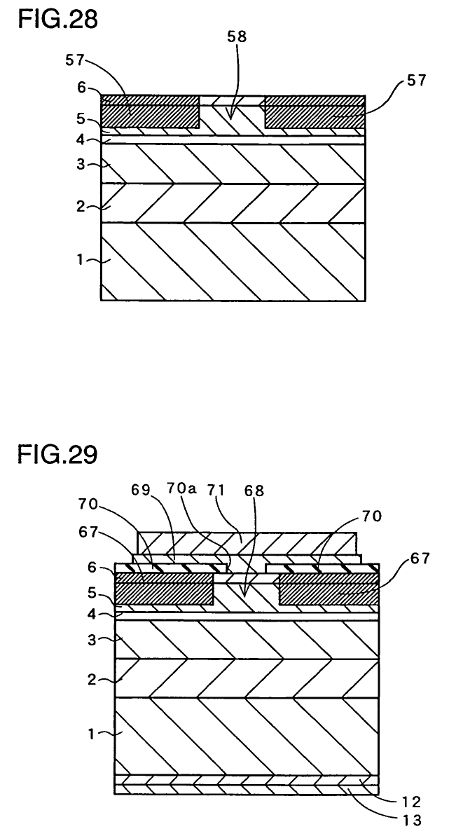

According to the sixth embodiment, the through film 62 of SiO₂ and the ion implantation mask layer 61 of SiO₂ are completely removed by wet etching with a hydrofluoric acid etchant, as shown in FIG. 28.

Finally, the p-side ohmic electrode 59 and the p-side pad electrode 60 are formed on the overall upper surface of the p-type contact layer 6. Further, the n-type GaN substrate 1 is polished into a prescribed thickness and the n-side ohmic electrode 12 and the n-side pad electrode 13 are thereafter formed on the back surface of the n-type GaN substrate 1 successively from the side closer to the back surface of the n-type GaN substrate 1, thereby completing the nitride semiconductor laser element according to the sixth embodiment shown in FIG. 25.

In the fabrication process for the nitride semiconductor laser element according to the sixth embodiment, no insulator film 50 is formed dissimilarly to the fifth embodiment, whereby the fabrication steps can be simplified.

### Seventh Embodiment

Referring to FIG. 29, the structure of this seventh embodiment is similar to the structure of the fifth embodiment except that the contact area between a p-type contact layer consisting of p-type Al_{0.01}Ga_{0.99}N and a p-side ohmic electrode is small as compared with the structure of the fifth embodiment.

Referring to FIG. 29, an n-type layer 2, an n-type cladding layer 3, an MQW emission layer 4, a p-type cladding layer 5 and a p-type contact layer 6 are formed on an n-type GaN substrate 1 in this order according to this seventh embodiment, similarly to the first embodiment.

According to the seventh embodiment, ion-implanted light absorption layers 67, formed by ion-implanting carbon (C), having an implantation depth of about 0.32 μm are provided similarly to the first embodiment. The ion-implanted light absorption layers 67 are examples of the “light absorption layer” in the present invention, and carbon is an example of the “first impurity element” in the present invention. In this case, the peak depth of the concentration of the ion-implanted carbon is located in regions of the p-type contact layer 6 at about 0.23 μm from the upper surface of the p-type contact layer 6. The peak concentration at this peak depth is about 1.0×10²⁰ cm⁻³. In this case, the ion-implanted light absorption layers 67 contain a larger number of crystal defects than the remaining regions due to introduction of a large quantity of ions into a semiconductor. A non-ion-implanted region (non-implanted region) for forming a current passing region 68 is formed with a width of about 2.1 μm.

The ion-implanted light absorption layers 67 in the seventh embodiment function as light absorption layers due to the crystal defects contained in the ion-implanted light absorption layers 67 in a large number, while functioning also as current narrowing layers due to high resistance. In order to sufficiently perform not only current narrowing but also transverse optical confinement in the ion-implanted light absorption layers 67, the maximum value of the impurity concentration of the ion-implanted carbon is preferably at least about 5×10¹⁹ cm⁻³. Thus, the ion-implanted light absorption layers 67, containing a larger number of crystal defects than the current passing region 68, can absorb light through the crystal defects contained in a large number.

According to the seventh embodiment, an insulator film 70 of ZrO₂ having an opening 70a (about 1.0 μm in width) on the upper surface of the current passing region 68 of the p-type contact layer 6 with a small thickness of about 50 nm is formed. The width of this opening 70a is formed smaller than the width (about 2.2 μm) of the current passing region 68 and smaller than the width of the opening 50a (see FIG. 19) in the fifth embodiment. A p-side ohmic electrode 69 is formed on this insulator film 70 to be in contact with the upper surface of the p-type contact layer 6 through the opening 70a of the insulator film 70. A p-side pad electrode 71 is formed to be in contact with the upper surface of the p-side ohmic electrode 69. An n-side ohmic electrode 12 and an n-side pad electrode 13 are formed on the back surface of the n-type GaN substrate 1 successively from the side closer to the back surface of the n-type GaN substrate 1.

In a nitride semiconductor laser element according to the seventh embodiment, as hereinabove described, the opening 70a of the insulator film 70 is rendered so small as compared with the fifth embodiment that the contact width between the p-side ohmic electrode 69 and the p-type contact layer 6 can be reduced, whereby the width of current narrowing can be further reduced as compared with the fifth embodiment.

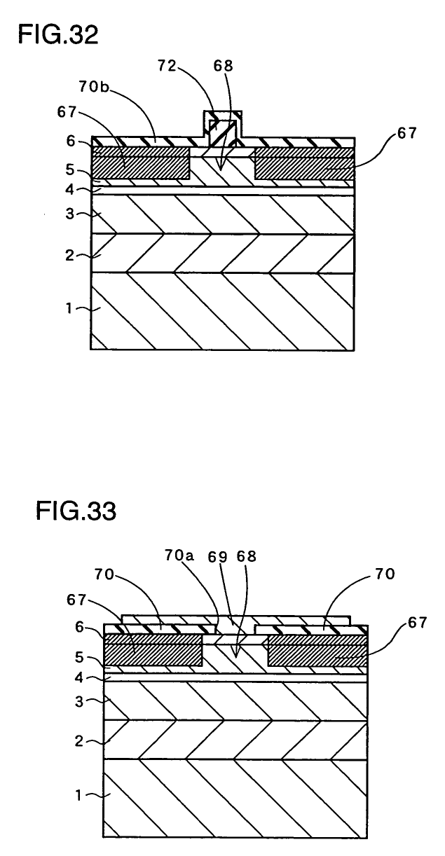

A fabrication process for the nitride semiconductor laser element according to the seventh embodiment is now described with reference to FIGS. 29 to 33. In this seventh embodiment, the fabrication process other than that of narrowly forming the opening of the insulator film of ZrO₂ on the p-type contact layer is similar to that of the fifth embodiment.

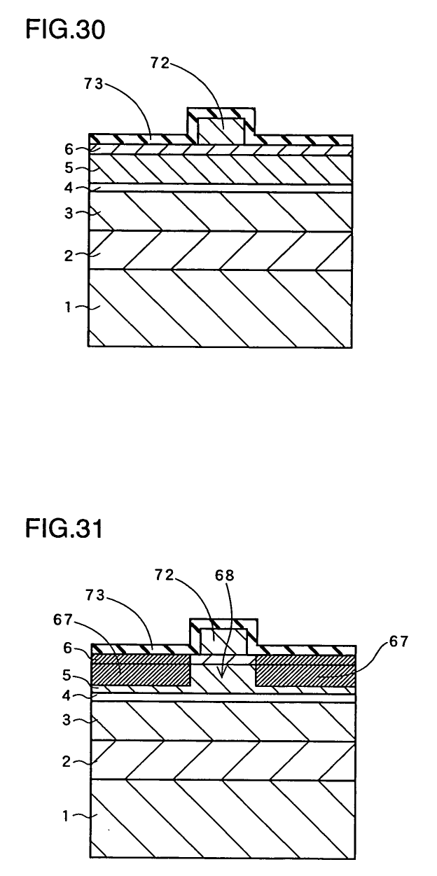

First, the layers up to the p-type contact layer 6 are formed through a process similar to that of the first embodiment shown in FIG. 4. Then, an ion implantation mask layer (not shown) of SiO₂ having a thickness of about 1 μm is formed on the upper surface of the p-type contact layer 6 by plasma CVD. This ion implantation mask layer is patterned through photolithography and etching, thereby forming a striped ion implantation mask layer 72 of SiO₂ having a width of about 2.2 μm, as shown in FIG. 30. A through film 73 of SiO₂ is formed to cover the overall surfaces of the p-type contact layer 6 and the ion implantation mask layer 72, similarly to the first embodiment.

As shown in FIG. 31, the ion implantation mask layer 72 of SiO₂ is employed as a mask for ion-implanting carbon through the through film 73 under conditions similar to those in the first embodiment, thereby forming the ion-implanted light absorption layers 67.

According to the seventh embodiment, the through film 73 is thereafter removed through dry etching with CF₄ gas while isotropically etching the ion implantation mask layer 72 thereby reducing the mask width of the ion implantation mask layer 72 to about 1.0 μm. Thereafter an insulator film 70b of ZrO₂ having a thickness of about 50 nm is evaporated by EB evaporation from a direction perpendicular to the element to cover the overall upper surfaces of the p-type contact layer 6 and the ion implantation mask layer 72. In this case, the insulator film 70b of ZrO₂ is hardly formed on the side wall portions of the ion implantation mask layer 72 of SiO₂ due to the evaporation from the direction perpendicular to the element.

As shown in FIG. 33, etching is performed with a hydrofluoric acid etchant for removing the ion implantation mask layer 72 of SiO₂ and parts of the insulator film 70b of ZrO₂. In this case, the insulator film 70b of SiO₂ is so hardly etched that only the parts of the insulator film 70b located on the side wall portions of the ion implantation mask layer 72 are completely removed. Thus, the ion implantation mask layer 72 of SiO₂ is completely removed after the parts of the insulator film 70b located on the side wall portions of the ion implantation mask layer 72 are removed. Consequently, the insulator film 70 having the opening 70a (about 1.0 μm in width) on the upper surface of the current passing region 68 is formed as shown in FIG. 33.

Finally, the p-side ohmic electrode 69 and the p-side pad electrode 71 are formed on the insulator film 70 to be in contact with the upper surface of the p-type contact layer 6 through the opening 70a. Further, the n-type GaN substrate 1 is polished into a prescribed thickness and the n-side ohmic electrode 12 and the n-side pad electrode 13 are thereafter formed on the back surface of the n-type GaN substrate 1, thereby completing the nitride semiconductor laser element according to the seventh embodiment shown in FIG. 29.

In the fabrication process for the nitride semiconductor laser element according to the seventh embodiment, as hereinabove described, SiO₂ allowing easy wet etching is employed as the material for the ion-implanted mask layer 72 while ZrO₂ different from SiO₂ is employed as the material for the insulator film 70b so that the opening 70a can be easily formed in the insulator film 70b by removing the ion implantation mask layer 72 of SiO₂ by wet etching after ion implantation, whereby productivity can be improved.

### Eighth Embodiment

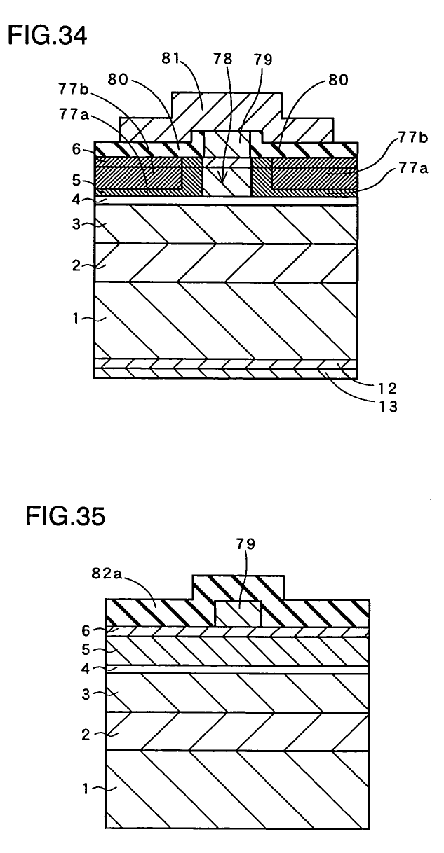

Referring to FIG. 34, an example of forming current narrowing layers and light absorption layers respectively by performing ion implantation twice dissimilarly to the aforementioned first to seventh embodiments is described with reference to this eighth embodiment. The remaining structure of the eighth embodiment is similar to that of the second embodiment.

Referring to FIG. 34, an n-type layer 2, an n-type cladding layer 3, an MQW emission layer 4, a p-type cladding layer 5 and a p-type contact layer 6 are formed on an n-type GaN substrate 1 in this order according to this eighth embodiment, similarly to the first embodiment.

According to the eighth embodiment, boron (B) is ion-implanted into partial regions of the p-type cladding layer 5 and the p-type contact layer 6, thereby forming current narrowing layers 77a having a thickness (implantation depth) of about 0.34 μm. Boron is an example of the “second impurity element” in the present invention. The peak depth of the boron concentration of these current narrowing layers 77a is located in regions of the p-type cladding layer 5 at a depth of about 0.25 μm from the upper surface of the p-type contact layer 6. The boron concentration at this peak depth is about 1.0×10¹⁹ cm⁻³. These current narrowing layers 77a perform current narrowing with respect to a current injected from a p side, thereby forming a current passing region 78. The current passing region 78 is formed with a width of about 1.8 μm.

According to the eighth embodiment, further, carbon is so ion-implanted as to form ion-implanted light absorption layers 77b having a thickness (implantation depth) of about 0.32 μm on regions farther from the MQW emission layer 4 and the current passing region 78 than the current narrowing layers 77a. The peak depth of the carbon concentration of these ion-implanted light absorption layers 77b is located in the p-type cladding layer 5 at a depth of about 0.23 μm from the upper surface of the p-type contact layer 6. The carbon concentration at this peak depth is about 1.0×10²⁰ cm⁻³. Thus, current narrowing can be performed in the current narrowing layers 77a while transverse optical confinement can be performed in the ion-implanted light absorption layers 77b. The ion-implanted light absorption layers 77b are formed excluding a first width (width of about 2.8 μm). Carbon ion-implanted in formation of the ion-implanted light absorption layers 77b is an example of the “first impurity elementn in the present invention, and the ion-implanted light absorption layers 77b are examples of the “light absorption layer” in the present invention.

A p-side ohmic electrode 79 is formed on the upper surface of the current passing region 78 of the p-type contact layer 6 in a striped shape, similarly to the second embodiment. Insulator films 80 are formed to cover the side surfaces of the p-side ohmic electrode 79 and the upper surface of the p-type contact layer 6. A p-side pad electrode 81 is formed on these insulator films 80 to be in contact with the upper surface of the p-side ohmic electrode 79. An n-side ohmic electrode 12 and an n-type pad electrode 13 are formed on the back surface of the n-type GaN substrate 1 successively from the side closer to the back surface of the n-type GaN substrate 1. The thicknesses and compositions of the respective layers 79 to 81 are similar to those of the respective layers 9 to 11 in the second embodiment respectively.

In a nitride semiconductor laser element according to the eighth embodiment, as hereinabove described, the ion-implanted light absorption layers 77b are formed excluding the first width while the current narrowing layers 77a are formed excluding the width (second width) of the current passing region 78, and the first width is larger than the second width and the region of the second width is formed in the region of the first width. Thus, light absorption by the light absorption layers can be reduced while simultaneously strengthening current narrowing, whereby reduction of a threshold current and improvement of slope efficiency can be attained.

In the nitride semiconductor laser element according to the eighth embodiment, further, the ion-implanted light absorption layers 77b are formed separately from the MQW emission layer 4 by a first distance of 0.03 μm while the current narrowing layers 77a are formed separately from the MQW emission layer 4 by a second distance of 0.01 μm as hereinabove described, whereby the first distance is larger than the second distance. Thus, light absorption by the light absorption layers can be reduced while simultaneously strengthening current narrowing, whereby reduction of the threshold current and improvement of the slope efficiency can be attained.

In the nitride semiconductor laser element according to the eighth embodiment, as hereinabove described, ion implantation is set to two types of implantation conditions while the respective implanted regions are so varied that the shape of the light absorption layers and the shape of the current narrowing layers can be easily controlled independently of each other. More specifically, the interval between the ion-implanted light absorption layers 77b can be independently changed while keeping the width of the current passing region 78 constant at a small width, for example. Thus, the degree of transverse optical confinement can be varied without remarkably changing the threshold current, whereby the horizontal divergence angle of a laser beam can be controlled.

In the nitride semiconductor laser element according to the eighth embodiment, as hereinabove described, boron is ion-implanted at the first time while carbon is ion-implanted at the second time so that introduced elements are different from each other at the first and second times, whereby the concentration profiles of the introduced impurity elements can be easily varied respectively.

In the nitride semiconductor laser element according to the eighth embodiment, as hereinabove described, a relatively light element such as boron is so ion-implanted that the current narrowing layers 77a can be prevented from excess formation of crystal defects.

In the nitride semiconductor laser element according to the eighth embodiment, as hereinabove described, a relatively heavy element such as carbon is so ion-implanted that crystal defects can be introduced into the ion-implanted light absorption layers 77b with a low dose. Thus, carbon introduced into the ion-implanted light absorption layers 77b can be inhibited from exerting bad influence on the characteristics of the element by diffusing into the MQW emission layer 4.

A fabrication process for the nitride semiconductor laser element according to the eighth embodiment is now described with reference to FIGS. 34 to 38. With reference to this eighth embodiment, the fabrication process of forming the current narrowing layers and the light absorption layers through different ion implantation steps respectively dissimilarly to the second embodiment is described. The remaining structure of the fabrication process according to the eighth embodiment is similar to that of the fabrication process according to the second embodiment.

First, the layers up to the p-type contact layer 6 are formed through a process similar to that of the first embodiment shown in FIG. 4. As shown in FIG. 35, the p-side ohmic electrode 79 having the width of about 2 μm is formed on the upper surface of the p-type contact layer 6 in the striped shape by a lift-off method, similarly to the first embodiment.

According to the eighth embodiment, an SiO₂ film 82a having a thickness of about 500 nm is thereafter formed by plasma CVD to cover the overall upper surfaces of the p-side ohmic electrode 79 and the p-type contact layer 6.

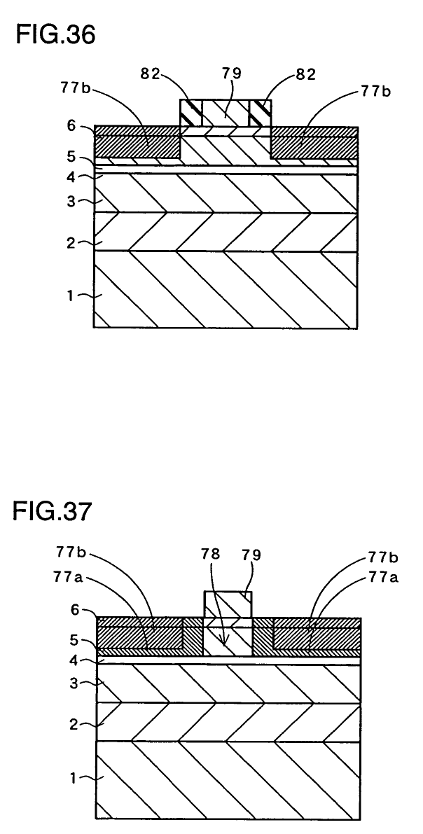

As shown in FIG. 36, the SiO₂ film 82a is anisotropically etched by RIE employing CF₄ gas, thereby forming non-implanted region enlarging films 82 of SiO₂ having a thickness of about 500 nm on the side wall portions of the p-side ohmic electrode 79. According to the eighth embodiment, ion implantation is performed through the p-side ohmic electrode 79 and the non-implanted region enlarging films 82 serving as masks (width of the masks: about 3 μm). In other words, carbon was ion-implanted under conditions of ion implantation energy of about 80 keV and a dose of about 2.3×10¹⁵ cm⁻². Thus, the ion-implanted light absorption layers 77b are formed. Thereafter the non-implanted region enlarging films 82 are completely removed.

As shown in FIG. 37, boron is ion-implanted through the p-side ohmic electrode 79 serving as a mask under ion implantation conditions of ion implantation energy of about 70 keV and a dose of about 2.3×10¹⁴ cm⁻². Thus, the current narrowing layers 77a are formed.

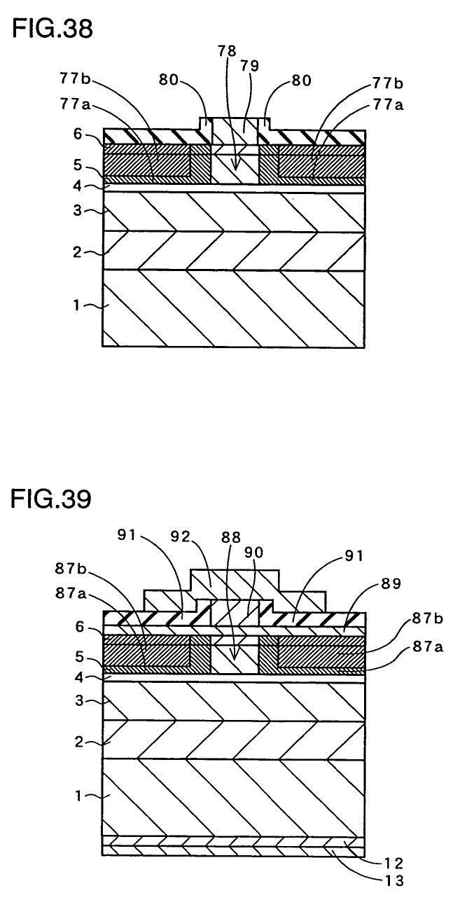

As shown in FIG. 38, the insulator films 80 of SiO₂ having a thickness of about 200 nm are formed by plasma CVD to cover the side surfaces of the p-side ohmic electrode 79 and the upper surface of the p-type contact layer 6. The upper surface of the p-side ohmic electrode 79 is exposed by photolithography and RIE with CF₄ gas, similarly to the second embodiment.

Finally, the p-side pad electrode 81 is formed on the p-side ohmic electrode 79 and the insulator films 80 while forming the n-side ohmic electrode 12 and the n-side pad electrode 13 on the back surface, polished into the prescribed thickness, of the n-type GaN substrate 1 successively from the side closer to the back surface of the n-type GaN substrate 1 through a process similar to that of the second embodiment, thereby completing the nitride semiconductor laser element according to the eighth embodiment shown in FIG. 34.

### Ninth Embodiment

Referring to FIG. 39, an example of forming a p-side ohmic electrode to cover the overall upper surface of a p-type contact layer in the structure of the eighth embodiment is described with reference to this ninth embodiment. The remaining structure of the ninth embodiment is similar to that of the eighth embodiment.

Referring to FIG. 39, an n-type layer 2, an n-type cladding layer 3, an MQW emission layer 4, a p-type cladding layer 5 and a p-type contact layer 6 are formed on an n-type GaN substrate 1 in this order according to this ninth embodiment, similarly to the first embodiment.

According to this ninth embodiment, silicon (Si) is ion-implanted into partial regions of the p-type cladding layer 5 and the p-type contact layer 6, thereby forming current narrowing layers 87a having a thickness (implantation depth) of about 0.34 μm. The peak depth of the silicon concentration of these current narrowing layers 87a is located in regions of the p-type cladding layer 5 at a depth of about 0.24 μm from the upper surface of the p-type contact layer 6. The silicon concentration at this peak depth is about 1.0×10¹⁹ cm⁻³. The current narrowing layers 87a perform current narrowing with respect to a current injected from a p side, thereby forming a current passing region 88 having a depth of about 1.6 μm. Silicon (Si) ion-implanted in formation of the current narrowing layers 87a is an example of the “second impurity element” in the present invention.

According to the ninth embodiment, further, silicon is so ion-implanted as to form ion-implanted light absorption layers 87b having a thickness of about 0.28 μm on regions farther from the MQW emission layer 4 and the current passing region 88 than the current narrowing layers 87a. The peak depth of the silicon concentration of these ion-implanted light absorption layers 87b is located in the p-type cladding layer 5 at a depth of about 0.2 μm from the upper surface of the p-type contact layer 6. The silicon concentration at this peak depth is about 1.0×10²⁰ cm⁻³. Thus, current narrowing can be performed in the current narrowing layers 87a while transverse optical confinement can be performed in the ion-implanted light absorption layers 87b. The ion-implanted light absorption layers 87b are formed excluding a first width (width of about 1.8 μm). Silicon ion-implanted in formation of the ion-implanted light absorption layers 87b is an example of the “first impurity element” in the present invention, and the ion-implanted light absorption layers 87b are examples of the “light absorption layer” in the present invention.

According to the ninth embodiment, a p-side ohmic electrode 89 is formed to cover the overall upper surface of the p-type contact layer 6. An ion implantation electrode mask layer 90 having a width of about 1.8 μm is formed on the upper surface of a portion of the p-side ohmic electrode 89 located on the current passing region 88 in a striped shape with a thickness of about 500 nm. Insulator films 91 are formed on the side surfaces of the ion implantation electrode mask layer 90 and the upper surface of the p-side ohmic electrode 89. A p-side pad electrode 92 is formed on these insulator films 91 to be in contact with the upper surface of the ion implantation electrode mask layer 90. An n-side ohmic electrode 12 and an n-type pad electrode 13 are formed on the back surface of the n-type GaN substrate 1 successively from the side closer to the back surface of the n-type GaN substrate 1. The thicknesses and compositions of the respective layers 91 and 92 are similar to those of the respective layers 10 and 11 in the first embodiment respectively.

In a nitride semiconductor laser element according to the ninth embodiment, as hereinabove described, the p-side ohmic electrode 89 is formed to cover the overall upper surface of the p-type contact layer 6 so that the contact areas of the p-type contact layer 6 and the p-side ohmic electrode 89 can be increased, whereby contact resistance can be reduced.

A fabrication process for the nitride semiconductor laser element according to the ninth embodiment is now described with reference to FIGS. 39 to 43. With reference to this ninth embodiment, the fabrication process of forming the current narrowing layers and the light absorption layers through two ion implantation steps respectively while forming the p-side ohmic electrode to cover the overall upper surface of the p-type contact layer similarly to the eighth embodiment is described.

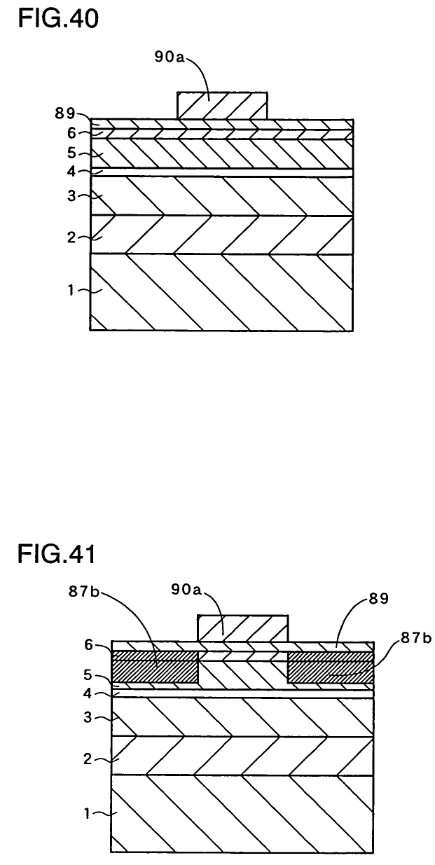

First, the layers up to the p-type contact layer 6 are formed through a process similar to that of the first embodiment shown in FIG. 4. As shown in FIG. 40, the p-side ohmic electrode 89 consisting of a Pt layer having a thickness of about 1 nm and a Pd layer having a thickness of about 10 nm is formed to cover the overall upper surface of the p-type contact layer 6. An Ni layer (not shown) is formed on the p-side ohmic electrode 89 with a thickness of about 600 nm. Thereafter a resist film (not shown) having a stripe width of about 2.0 μm is formed and thereafter wet-etched with nitric acid. Thereafter this resist film is removed thereby forming a striped ion implantation electrode mask layer 90a having a width of about 2.0 μm.

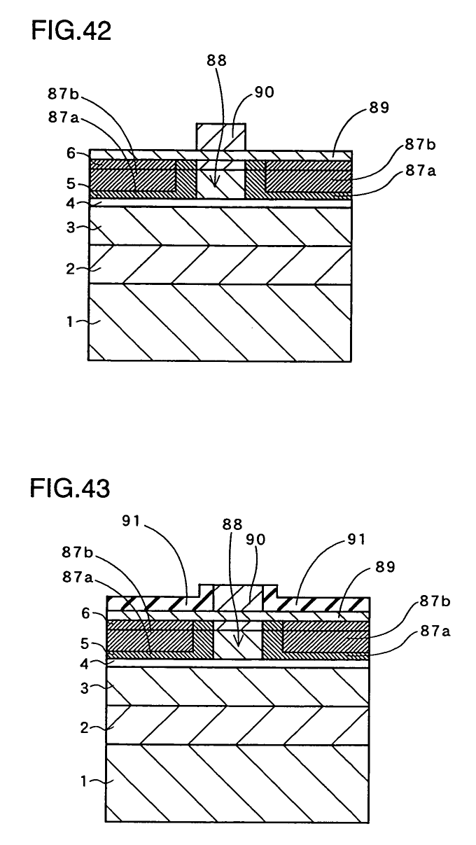

According to the ninth embodiment, the ion implantation electrode mask layer 90a of Ni is employed as a mask for ion-implanting silicon through the p-side ohmic electrode 89 under ion implantation conditions of implantation energy of about 160 keV and a dose of about 2.0×10¹⁵ cm⁻² thereby forming the ion-implanted light absorption layers 87b having the thickness of about 0.28 μm, as shown in FIG. 41. The ion implantation electrode mask layer 90a having the width of about 2.0 μm is isotropically wet-etched, thereby forming the ion implantation electrode mask layer 90 having the width of about 1.8 μm as shown in FIG. 42. The ion implantation electrode mask layer 90 is employed as a mask for ion-implanting silicon under ion implantation conditions of implantation energy of about 190 keV and a dose of about 2.5×10¹⁴ cm⁻², thereby forming the current narrowing layers 87a having the thickness of about 0.34 μm.

As shown in FIG. 43, insulator films 91 of SiO₂ having a thickness of about 200 nm are formed by plasma CVD to cover the overall surfaces of the p-side ohmic electrode and the ion implantation electrode mask layer 90. The upper surface of the ion implantation electrode mask layer 90 is exposed by photolithography and RIE with CF₄ gas.

Finally, the p-side pad electrode 92 is formed on the insulator films 91 to be in contact with the upper surface of the ion implantation electrode mask layer 90 while forming the n-side ohmic electrode 12 and the n-side pad electrode 13 on the back surface, polished into a prescribed thickness, of the n-type GaN substrate 1 successively from the side closer to the back surface of the n-type GaN substrate 1 through a process similar to that of the first embodiment, thereby completing the nitride semiconductor laser element according to the ninth embodiment shown in FIG. 39.

In the fabrication process for the nitride semiconductor laser element according to the ninth embodiment, as hereinabove described, the overall upper surface of the element is covered with the p-side ohmic electrode 89 in advance of ion implantation, whereby the introduced ions can be prevented from channeling. Thus, the introduced elements can be inhibited from deep implantation. The p-side ohmic electrode 89 is an example of the “through film” in the present invention.

While the insulator films 91 of SiO₂ have been formed on the p-side ohmic electrode 89 in the ninth embodiment as hereinabove described, the insulator films may not be provided. In this case, films formed on the upper surface of the p-type contact layer 6 are entirely made of metals, whereby heat radiation characteristics of the element can be further improved. Consequently, the element life can be improved.

### Tenth Embodiment

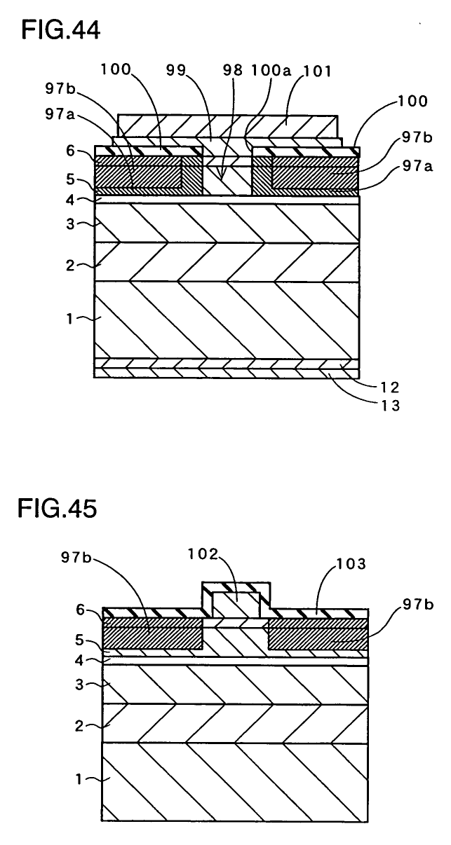

Referring to FIG. 44, a case of forming current narrowing layers and light absorption layers through two ion implantation steps respectively similarly to the eighth embodiment is described with reference to this tenth embodiment. In this tenth embodiment, the current narrowing layers were formed with a low dose in order not to introduce excess crystal defects into crystals. The remaining structure of the tenth embodiment is similar to that of the seventh embodiment.

Referring to FIG. 44, an n-type layer 2, an n-type cladding layer 3, an MQW emission layer 4, a p-type cladding layer 5 and a p-type contact layer 6 are formed on an n-type GaN substrate 1 in this order according to this tenth embodiment, similarly to the first embodiment.

According to the tenth embodiment, silicon is ion-implanted into partial regions of the p-type cladding layer 5 and the p-type contact layer 6, thereby forming current narrowing layers 97a having a thickness (implantation depth) of about 0.34 μm. Silicon is an example of the “second impurity element” in the present invention. The peak depth of the silicon concentration of these current narrowing layers 97a is located in regions of the p-type cladding layer 5 at a depth of about 0.24 μm from the upper surface of the p-type contact layer 6. The silicon concentration at this peak depth is about 1.0×10¹⁹ cm⁻³. These current narrowing layers 97a perform current narrowing with respect to a current injected from a p side, thereby forming a current passing region 98 having a width of about 1.8 μm.

According to the tenth embodiment, further, carbon is so ion-implanted as to form ion-implanted light absorption layers 97b having a thickness (implantation depth) of about 0.32 μm on regions farther from the MQW emission layer 4 and the current passing region 98 than the current narrowing layers 97a. The peak depth of the carbon concentration of these ion-implanted light absorption layers 97b is located in regions of the p-type cladding layer 5 at a depth of about 0.23 μm from the upper surface of the p-type contact layer 6. The carbon concentration at this peak depth is about 1.0×10²⁰ cm⁻³. Thus, current narrowing can be performed in the current narrowing layers 97a while transverse optical confinement can be performed in the ion-implanted light absorption layers 97b. The ion-implanted light absorption layers 97b are formed excluding a first width (width of about 2.1 μm). Carbon ion-implanted in formation of the ion-implanted light absorption layers 97b is an example of the “first impurity element” in the present invention, and the ion-implanted light absorption layers 97b are examples of the “light absorption layer” in the present invention.

An insulator film 100 of ZrO₂ having an opening on the upper surface of the current passing region 98 of the p-type contact layer 6 with a small thickness of about 50 nm is formed on the upper surface of the p-type contact layer 6, similarly to the seventh embodiment. A p-side ohmic electrode 99 is formed on this insulator film 100 to be in contact with the upper surface of the p-type contact layer 6 through the opening 100a of the insulator film 100. A p-side pad electrode 101 is formed to be in contact with the upper surface of the p-side ohmic electrode 99. An n-side ohmic electrode 12 and an n-side pad electrode 13 are formed on the back surface of the n-type GaN substrate 1 successively from the side closer to the back surface of the n-type GaN substrate 1. The thicknesses and compositions of the respective layers 101, 12 and 13 are similar to those of the respective layers 11 to 13 of the first embodiment respectively.

In a nitride semiconductor laser element according to the tenth embodiment, as hereinabove described, ion implantation is set to two types of implantation conditions while the respective implanted regions are so varied that the shape of the light absorption layers and the shape of the current narrowing layers can be easily controlled independently of each other. More specifically, the interval between the ion-implanted light absorption layers 97b can be independently changed while keeping the width of the current passing region 98 constant at a small width, for example. Thus, the degree of transverse optical confinement can be varied without remarkably changing the threshold current, whereby the horizontal divergence angle of a laser beam can be controlled.

In the nitride semiconductor laser element according to the tenth embodiment, as hereinabove described, silicon which is a dopant of a reverse conductivity type is so ion-implanted into p-type semiconductor regions (the p-type cladding layer 5 and the p-type contact layer 6) that nitride semiconductor layers of the reverse conductivity type (n type) can be easily formed. Thus, the current narrowing layers 97a can be easily formed. Consequently, the current narrowing layers 97a can be formed with a low dose. Thus, increase of the number of crystal defects in the current narrowing layers 97a can be suppressed.

A fabrication process for the nitride semiconductor laser element according to the ninth embodiment is now described with reference to FIGS. 44 to 46. According to the tenth embodiment, the fabrication process other than that of forming the current narrowing layers and the light absorption layers through two ion implantation steps respectively is similar to the fabrication process according to the seventh embodiment.

First, the layers up to the p-type contact layer 6 are formed through a process similar to that of the first embodiment shown in FIG. 4. As shown in FIG. 45, an ion implantation mask layer 102 having a width of about 2.3 μm and a through film 103 are successively formed on the p-type contact layer 6. Thereafter the ion implantation mask layer 102 is employed as a mask for ion-implanting carbon under conditions similar to those in the first embodiment, thereby forming the ion-implanted light absorption layers 97b. Thereafter the through film 103 is removed by dry etching with CF₄.

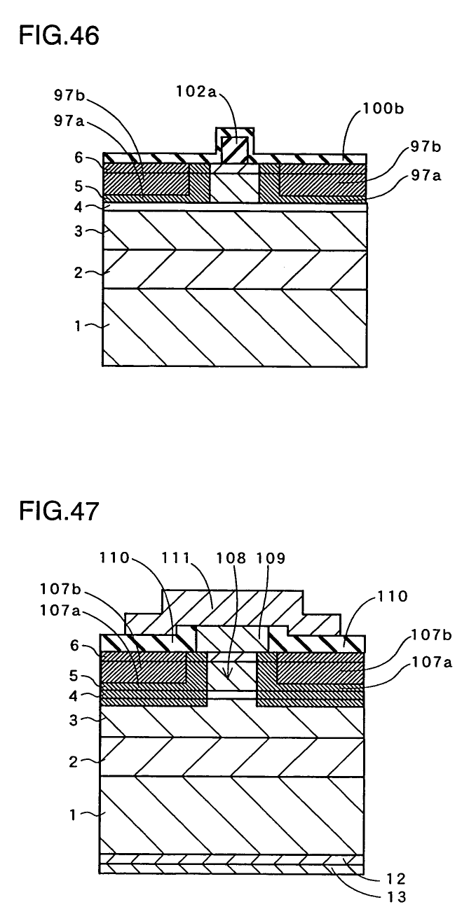

According to the tenth embodiment, the ion implantation mask layer 102 having the width of about 2.3 μm is isotropically etched thereby forming an ion implantation mask layer 102a having a width of about 2.0 μm, as shown in FIG. 46. An insulator film 100b of ZrO₂ having a thickness of about 50 nm is formed to cover the overall upper surfaces of the p-type contact layer 6 and the ion implantation mask layer 102a.

According to the tenth embodiment, the ion implantation mask layer 102a is employed as a mask for ion-implanting silicon through the insulator film 100b under low-dose ion implantation conditions of implantation energy of about 190 keV and a dose of about 2.5×10¹⁴ cm⁻². Thus, the current narrowing layers 97a having the thickness of about 0.34 μm are formed. In the current narrowing layers 97a formed by low-dose ion implantation, increase of the number of crystal defects is suppressed.

Thereafter etching is performed with a hydrofluoric acid etchant similarly to the seventh embodiment, thereby removing the ion implantation mask layer 102a of SiO₂ and parts of the insulator film 100b of ZrO₂. In this case, the insulator film 100b consisting of ZrO₂ is so hardly etched that only the parts of the insulator film 100b located on the side wall portions of the ion implantation mask layer 102a are completely removed. Thus, the ion implantation mask layer 102a of SiO₂ is completely removed after the parts of the insulator film 100b located on the side wall portions of the ion implantation mask layer 102a are removed. Consequently, the insulator film 100 having the opening 100a on the upper surface of the current passing region 98 is formed as shown in FIG. 44.

Finally, the p-side ohmic electrode 99 and the p-side pad electrode 101 are formed on the insulator film 100 to be in contact with the upper surface of the p-type contact layer 6 through the opening 100a. The n-type GaN substrate 1 is polished into a prescribed thickness and the n-side ohmic electrode 12 and the n-side pad electrode 13 are thereafter formed on the back surface of the n-type GaN substrate 1 successively from the side closer to the back surface of the n-type GaN substrate 1, thereby completing the nitride semiconductor laser element according to the tenth embodiment shown in FIG. 44.

In the fabrication process for the nitride semiconductor laser element according to the tenth embodiment, as hereinabove described, the overall surface of the element is covered with the insulator film 100b or the through film 103 in advance of ion implantation, whereby implanted ions can be prevented from channeling. Thus, introduced elements can be inhibited from deep implantation. The insulator film 102b and the through film 103 are examples of the “through film” in the present invention.

### Eleventh Embodiment

Referring to FIG. 47, an example of forming current narrowing layers by thermal diffusion of hydrogen atoms while forming light absorption layers by ion implantation of silicon is described with reference to this eleventh embodiment. In a nitride semiconductor laser element according to this eleventh embodiment, the current narrowing layers are formed over an n-type cladding layer, an MQW emission layer, a p-type cladding layer and a p-type contact layer. The remaining structure of the eleventh embodiment is similar to that of the first embodiment.

Referring to FIG. 47, an n-type layer 2, an n-type cladding layer 3, an MQW emission layer 4, a p-type cladding layer 5 and a p-type contact layer 6 are formed on an n-type GaN substrate 1 in this order according to this eleventh embodiment, similarly to the first embodiment.

According to the eleventh embodiment, current narrowing layers 107a formed by thermally diffusing hydrogen are formed on partial regions of the p-type cladding layer 5 and the p-type contact layer 6. These current narrowing layers 107a have a thickness (diffusion regions) reaching partial upper portions of the n-type cladding layer 3 from the upper surface of the p-type contact layer 6. These current narrowing layer 107a perform current narrowing with respect to currents injected from a p side and an n side, thereby forming a current passing region 108 having a width of about 1.4 μm. Hydrogen is an example of the “second impurity element” in the present invention.

According to the eleventh embodiment, further, silicon is so ion-implanted as to form ion-implanted light absorption layers 107b having a thickness of about 0.34 μm on regions farther from the MQW emission layer 4 and the current passing region 108 than the current narrowing layers 107a. The peak depth of the silicon concentration of these ion-implanted light absorption layers 107b is located in regions of the p-type cladding layer 5 at a depth of about 0.24 μm from the upper surface of the p-type contact layer 6. The silicon concentration at this peak depth is about 1.0×10²⁰ cm⁻³. Thus, current narrowing can be performed in the current narrowing layers 107a while transverse optical confinement can be performed in the ion-implanted light absorption layers 107b. The ion-implanted light absorption layers 107b are formed excluding a first width (width of about 1.9 μm). The ion-implanted light absorption layers 107b are examples of the “light absorption layer” in the present invention, and Si is an example of the “first impurity element” in the present invention.

A p-side ohmic electrode 109 having a width of about 2.0 μm is formed on the upper surface of the current passing region 108 of the p-type contact layer 6 in a striped shape. Insulator films 110 are formed to cover the side surfaces of the p-side ohmic electrode 109 and the upper surface of the p-type contact layer 6. A p-side pad electrode 111 is formed on these insulator films 110 to be in contact with the upper surface of the p-side ohmic electrode 109. An n-side ohmic electrode 12 and an n-side pad electrode 13 are formed on the back surface of the n-type GaN substrate 1 successively from the side closer to the back surface of the n-type GaN substrate 1. The thicknesses and compositions of the respective layers 109 to 111 are similar to those of the respective layers 9 to 11 of the first embodiment respectively.

In the nitride semiconductor laser element according to the eleventh embodiment, as hereinabove described, the ion-implanted light absorption layers 107b are formed separately from the MQW emission layer 4 by a first distance of 0.01 μm in the depth direction while the current narrowing layers 107a are formed in the MQW emission layer 4, whereby the first distance is larger than a second distance. In the eleventh embodiment, the second distance defined by the interval between the MQW emission layer 4 and the current narrowing layers 107a is zero. Thus, light absorption by the light absorption layers can be reduced while simultaneously strengthening current narrowing, whereby reduction of a threshold current and improvement of slope efficiency can be attained.

In the nitride semiconductor laser element according to the eleventh embodiment, as hereinabove described, the current narrowing layers 107a are formed by thermal diffusion of hydrogen atoms while the ion-implanted light absorption layers 107b are formed by ion implantation, whereby the current passing region 108 can be limited to a narrow range through the current narrowing layers 107a while the ion-implanted light absorption layers 107b can be provided separately from a current path. Thus, the ion-implanted light absorption layers 107b can be inhibited from excess light absorption while the threshold current can be reduced and a horizontal divergence angle of a laser beam can be controlled.

A fabrication process for the nitride semiconductor laser element according to the eleventh embodiment is now described with reference to FIGS. 47 to 51. Referring to this eleventh embodiment, the process of forming the current narrowing layers by thermal diffusion of hydrogen atoms while forming the light absorption layers by ion implantation is described. The remaining structure of the eleventh embodiment is similar to that of the first embodiment.

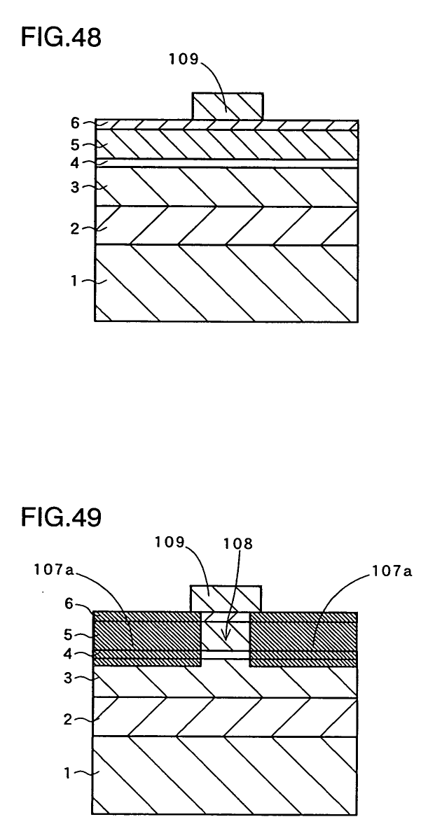

First, the layers up to the p-type contact layer 6 are formed through a process similar to that of the first embodiment shown in FIG. 4. As shown in FIG. 48, the striped p-side ohmic electrode 109 consisting of a Pt layer having a thickness of about 1 nm, a Pd layer having a thickness of about 50 nm, an Au layer having a thickness of about 240 nm and an Ni layer having a thickness of about 240 nm in ascending order is formed on part of the upper surface of the p-type contact layer 6 with a stripe width of about 2.0 μm.

According to the eleventh embodiment, the p-side ohmic electrode 109 is employed as a mask for diffusing hydrogen atoms into the element by holding the element in an NH₃ atmosphere having a substrate temperature of about 800° C., thereby forming the current narrowing layers 107a over the n-type cladding layer 3, the MQW emission layer 4, the p-type cladding layer 5 and the p-type contact layer 6. In this case, the hydrogen atoms diffused into the element couple with carriers of p-type semiconductor layers for inactivating functions as acceptors. Thus, the resistance of regions containing the diffused hydrogen atoms is increased. These hydrogen atoms isotropically diffuse in the element, whereby the width of regions not increased in resistance is smaller than the width (about 2.0 μm) of the p-side ohmic electrode 109 serving as the mask. Thus, the current passing region 108 having the width of about 1.4 μm is formed.

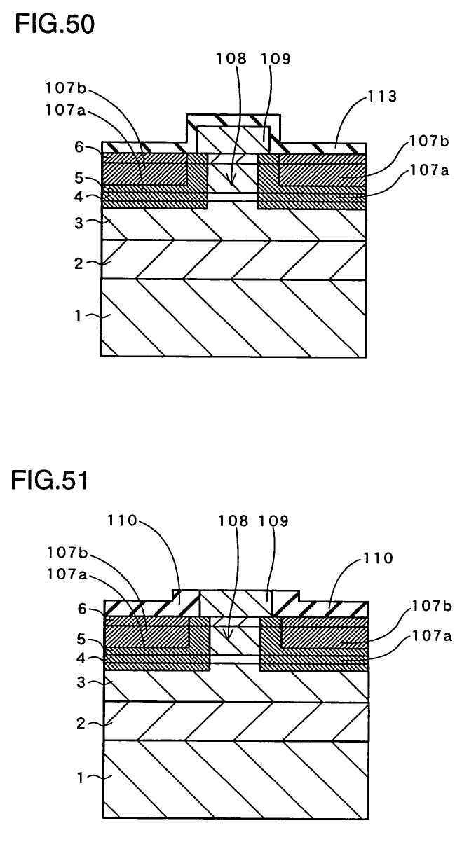

As shown in FIG. 50, a through film 113 of SiO₂ having a thickness of about 60 nm is formed by plasma CVD to cover the overall upper surfaces of the p-side ohmic electrode 109 and the p-type contact layer 6. The p-side ohmic electrode 109 is employed as a mask for ion-implanting silicon through the through film 113, thereby forming the ion-implanted light absorption layers 107b having the thickness (implantation depth) of about 0.34 μm. In this case, the ion implantation was performed under conditions of ion implantation energy of about 190 keV and a dose of about 2.5×10¹⁵ cm⁻². Thereafter the through film 113 is removed with a hydrofluoric acid etchant.

As shown in FIG. 51, the insulator films 110 of SiO₂ having a thickness of about 200 nm are formed by plasma CVD to cover the overall surfaces of the p-side ohmic electrode 109 and the p-side ohmic electrode 109. The upper surface of the p-side electrode 109 is exposed by photolithography and RIE with CF₄ gas, similarly to the first embodiment.

Finally, the p-side pad electrode 111 is formed on the insulator films 110 to be in contact with the upper surface of the p-side ohmic electrode 109 through a process similar to that of the first embodiment. The n-type GaN substrate 1 is polished into a prescribed thickness and the n-side ohmic electrode 12 and the n-side pad electrode 13 are thereafter formed on the back surface of the n-type GaN substrate 1, thereby completing the nitride semiconductor laser element according to the eleventh embodiment shown in FIG. 47.

In the fabrication process for the nitride semiconductor laser element according to the eleventh embodiment, as hereinabove described, the element is heat-treated in an atmosphere containing hydrogen atoms for diffusing the hydrogen atoms into p-type semiconductor regions, whereby the current narrowing layers 107a extending over the n-type cladding layer 3, the MQW emission layer 4, the p-type cladding layer 5 and the p-type contact layer 6 can be easily formed. In this case, crystal defects are so hardly introduced as compared with a case of forming current blocking regions by ion implantation that reliability of the element can be improved. In particular, the ion-implanted light absorption layers 107b formed by ion implantation are formed on regions separated from an emission part of the MQW emission layer 4, whereby the emission part can be further effectively prevented from formation of crystal defects.

### Twelfth Embodiment

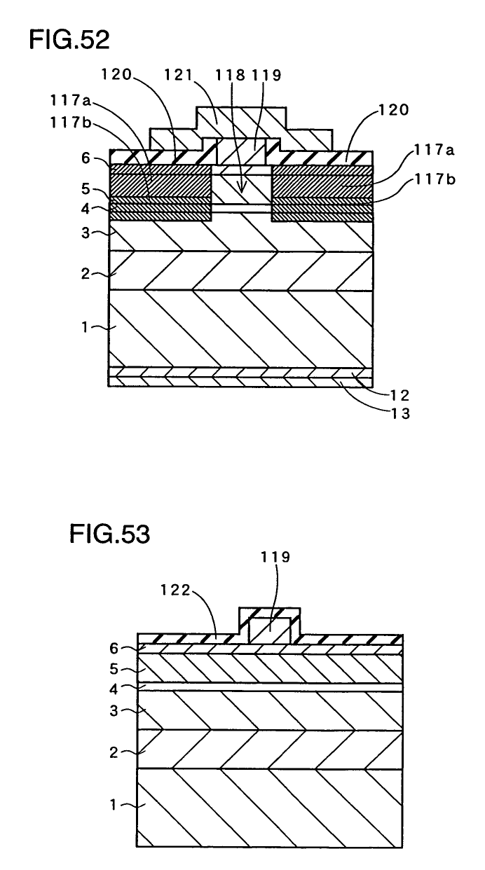

Referring to FIG. 52, a case of forming current narrowing layers and light absorption layers extending over an n-type cladding layer, an MQW emission layer, a p-type cladding layer and a p-type contact layer by ion-implanting silicon twice respectively is described with reference to this twelfth embodiment. The remaining structure of the twelfth embodiment is similar to that of the first embodiment.

Referring to FIG. 52, an n-type layer 2, an n-type cladding layer 3, an MQW emission layer 4, a p-type cladding layer 5 and a p-type contact layer 6 are formed on an n-type GaN substrate 1 in this order according to this twelfth embodiment, similarly to the first embodiment.

According to the twelfth embodiment, silicon (Si) is ion-implanted into partial regions of the layers from the n-type cladding layer 3 to the p-type contact layer 6 thereby forming current narrowing layers 117b having a thickness (implantation depth) of about 0.73 μm over the n-type cladding layer 3, the MQW emission layer 4, the p-type cladding layer 5 and the p-type contact layer 6. The peak depth of the silicon concentration of these current narrowing layers 117b is located in regions of the MQW emission layer 4 at a depth of about 0.55 μm from the upper surface of the p-type contact layer 6. The silicon concentration at this peak depth is about 1.0×10¹⁹ cm⁻³. These current narrowing layers 117b perform current narrowing with respect to currents injected from a p side and an n side, thereby forming a current passing region 118 having a width of about 1.9 μm. Silicon is an example of the “second impurity element” in the present invention.

Further, silicon is ion-implanted again under different conditions, thereby forming ion-implanted light absorption layers 117a having the same width as the current narrowing layers 117b and a thickness of about 0.34 μm. The peak depth of the silicon concentration of these ion-implanted light absorption layers 117a is at a level of about 0.24 μm from the upper surface of the p-type contact layer 6. The silicon concentration at this peak depth is about 1.0×10²⁰ cm⁻³. Thus, current narrowing can be performed in the current narrowing layers 117b while transverse optical confinement can be performed in the ion-implanted light absorption layers 117a. The ion-implanted light absorption layers 117a are formed excluding a first width (width of about 2.1 μm). Silicon is an example of the “first impurity element” in the present invention, and the ion-implanted light absorption layers 117a are examples of the “light absorption layer” in the present invention.

A p-side ohmic electrode 119 having a width of about 2.2 μm is formed on the upper surface of the current passing region 118 of the p-type contact layer 6 in a striped shape. Insulator films 120 are formed to cover the side surfaces of the p-side ohmic electrode 119 and the upper surface of the p-type contact layer 6. A p-side pad electrode 121 is formed on these insulator films 120 to be in contact with the upper surface of the p-side ohmic electrode 119. An n-side ohmic electrode 12 and an n-type pad electrode 13 are formed on the back surface of the n-type GaN substrate 1 successively from the side closer to the back surface of the n-type GaN substrate 1. The thicknesses and compositions of the respective layers 119 to 121 are similar to those of the respective layers 9 to 11 in the first embodiment respectively.

In a nitride semiconductor laser element according to the twelfth embodiment, as hereinabove described, ion implantation is performed under two types of implantation conditions for changing respective implanted regions (implantation depths), whereby the shape of the light absorption layers and the shape of the current narrowing layers can be easily controlled independently of each other. More specifically, current narrowing can be sufficiently performed with the current narrowing layers 117b, having the large thickness (implantation depth), reaching the upper surface of the p-type contact layer 6 from the n-type cladding layer 3 having relatively small light absorption while transverse optical confinement can be performed with the ion-implanted light absorption layers 117a, having a small thickness, reaching the upper surface of the p-type contact layer 6 from the p-type cladding layer 5. Thus, current density can be increased while excess light absorption can be suppressed. Consequently, a threshold current can be reduced and a horizontal divergence angle of a laser beam can be controlled.

A fabrication process for the nitride semiconductor laser element according to the twelfth embodiment is now described with reference to FIGS. 52 to 56. According to this twelfth embodiment, the fabrication process other than that of forming the current narrowing layers and the light absorption layers over the n-type cladding layer, the MQW emission layer, the p-type cladding layer and the p-type cladding layer through two ion implantation steps respectively is similar to that according to the first embodiment.

First, the layers up to the p-type contact layer 6 are formed through a process similar to that of the first embodiment shown in FIG. 4. As shown in FIG. 53, the p-side ohmic electrode 119 consisting of a Pt layer having a thickness of about 1 nm, a Pd layer having a thickness of about 50 nm, an Au layer having a thickness of about 240 nm and an Ni layer having a thickness of about 240 nm is formed on part of the upper surface of the p-type contact layer 6 in a striped shape with an electrode width of about 2.2 μm.

Thereafter a through film 122 of SiO₂ having a thickness of about 60 nm is formed by plasma CVD to cover the overall upper surfaces of the p-side ohmic electrode 119 and the p-type contact layer 6.

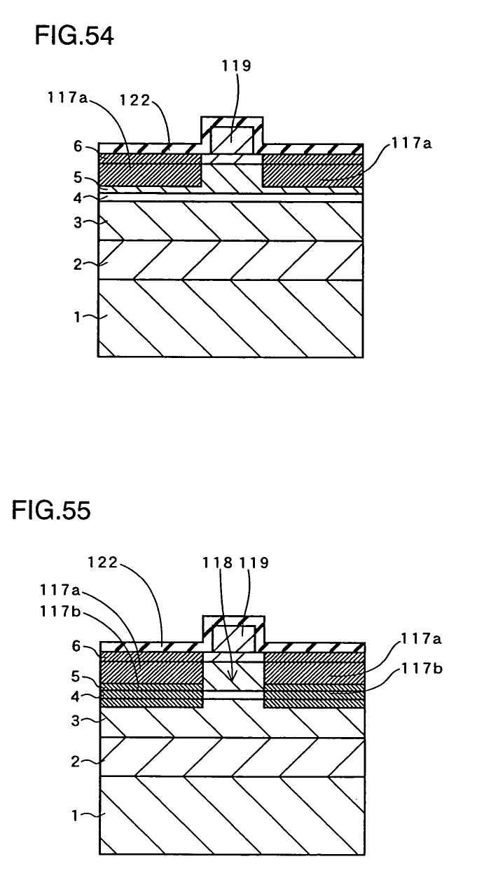

According to the twelfth embodiment, the p-side ohmic electrode 119 is employed as a mask for ion-implanting silicon through the through film 122 under ion implantation conditions of implantation energy of about 190 keV and a dose of about 2.5×10¹⁵ cm⁻², as shown in FIG. 54. Thus, the ion-implanted light absorption layers 117a having the thickness of about 0.34 μm are formed.

As shown in FIG. 55, the p-side ohmic electrode 119 is again employed as a mask for ion-implanting silicon under ion implantation conditions of implantation energy of about 400 keV and a dose of about 4.5×10¹⁴ cm⁻², thereby forming the current narrowing layers 117b having the thickness of about 0.73 μm. Thus, the current passing region 118 having the width of about 1.9 μm is formed. Thereafter the through film 122 is removed by wet etching.

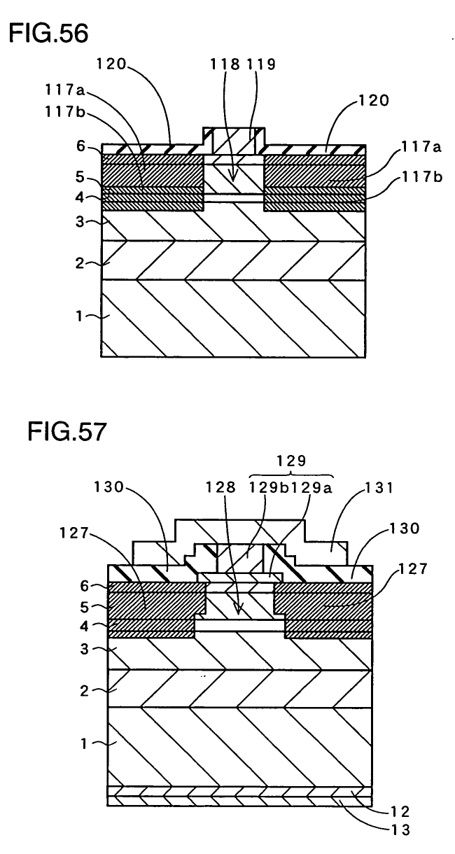

As shown in FIG. 56, the insulator films 120 of SiO₂ having a thickness of about 200 nm are formed by plasma CVD to cover the overall upper surfaces of the p-side ohmic electrode 119 and the p-type contact layer 6. The upper surface of the p-side ohmic electrode 119 is exposed by photolithography and RIE with CF₄ gas, similarly to the first embodiment.

Finally, the p-side pad electrode 121 is formed to be in contact with the upper surface of the p-side ohmic electrode 119 through a process similar to that of the first embodiment. The n-type GaN substrate 1 is polished into a prescribed thickness and the n-side ohmic electrode 12 and the n-side pad electrode 13 are thereafter formed on the back surface of this n-type GaN substrate 1, thereby completing the nitride semiconductor laser element according to the twelfth embodiment shown in FIG. 52.

### Thirteenth Embodiment

Referring to FIG. 57, an example of forming stepped ion-implanted light absorption layers by ion-implanting silicon through a mask of a projecting p-side ohmic electrode having a step is described with reference to this thirteenth embodiment.

Referring to FIG. 57, an n-type layer 2, an n-type cladding layer 3, an MQW emission layer 4, a p-type cladding layer 5 and a p-type contact layer 6 are formed on an n-type GaN substrate 1 in this order according to this thirteenth embodiment, similarly to the first embodiment.

According to the thirteenth embodiment, stepped ion-implanted light absorption layers 127 formed by ion-implanting silicon (Si) are provided. Silicon is an example of the “first impurity element” in the present invention. The ion-implanted light absorption layers 127 are examples of the “light absorption layer” in the present invention. A non-ion-implanted region (non-implanted region) forming a current passing region 128 is formed stepwise with a width of about 1.4 μm in the range up to an implantation depth (thickness) of about 0.33 μm from the upper surface of the p-type contact layer 6 and a width of about 1.8 μm in the range up to an implantation depth of about 0.77 μm further therefrom. Current narrowing is performed through narrow-interval regions of the ion-implanted light absorption layer 127 in the range up to the implantation depth (thickness) of about 0.33 μm from the upper surface of the p-type contact layer 6. The peak depth of the silicon concentration in these regions is located in regions of the p-type cladding layer 5 at a depth of about 0.14 μm from the upper surface of the p-type contact layer 6. The silicon concentration at this peak depth is about 1.0×10²⁰ cm⁻³. Further, transverse optical confinement is performed through wide-interval regions of the ion-implanted light absorption layers 127 in the range from the implantation depth (thickness) of about 0.33 μm up to the implantation depth of about 0.77 μm from the upper surface of the p-type contact layer 6. The peak depth of the silicon concentration in these regions is located in regions of the MQW emission layer 4 at a depth of about 0.59 μm from the upper surface of the p-type contact layer 6. The silicon concentration at this peak depth is about 1.0×10²⁰ cm⁻³.

A projecting p-side ohmic electrode 129, having a step, consisting of a Pt electrode 129a having a thickness of 140 nm with an electrode width of about 2.2 μm and an Ni electrode 129b having a thickness of about 600 nm with an electrode width of about 1.8 μm is formed on the upper surface of the current passing region 128 in a striped shape. Insulator films 130 are formed to cover the side surfaces of the p-side ohmic electrode 129 and the upper surface of the p-type contact layer 6. A p-side pad electrode 131 is formed on these insulator films 130 to be in contact with the upper surface of the p-side ohmic electrode 129. An n-side ohmic electrode 12 and an n-side pad electrode 13 are formed on the back surface of the n-type GaN substrate 1 successively from the side closer to the back surface of the n-type GaN substrate 1.

In a nitride semiconductor laser element according to the thirteenth embodiment, as hereinabove described, the ion-implanted light absorption layers 127 functioning also as current narrowing layers are so formed stepwise that sufficient current narrowing can be performed through the narrow-interval regions of the ion-implanted light absorption layers 127 and proper transverse optical confinement can be performed through the wide-interval regions of the ion-implanted light absorption layers 127 closer to an emission part of the MQW emission layer 4. Thus, current density can be increased while excess light absorption can be suppressed. Consequently, a threshold current can be reduced and a horizontal divergence angle of a laser beam can be controlled.

A fabrication process for the nitride semiconductor laser element according to the thirteenth embodiment is now described with reference to FIGS. 57 to 62. With reference to the thirteenth embodiment, the example of forming the stepped ion-implanted light absorption layers having the current narrowing function through single ion implantation by employing a projecting mask layer having a step is described. The remaining structure of the thirteenth embodiment is similar to that of the first embodiment.

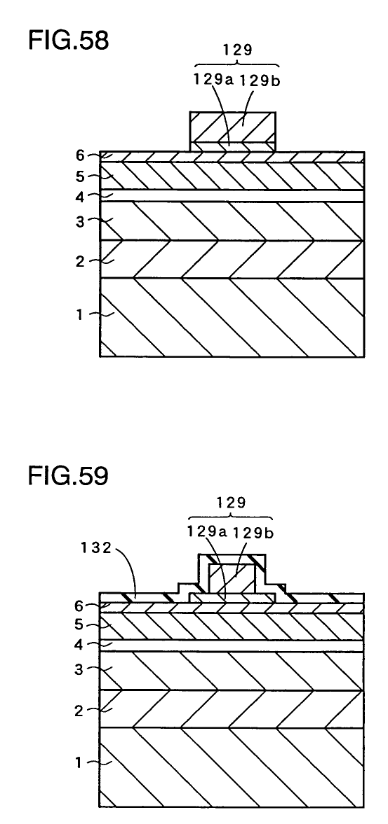

First, the layers up to the p-type contact layer 6 are formed through a process similar to that of the first embodiment shown in FIG. 4. Then, the p-side ohmic electrode 129 consisting of the Pt electrode 129a having the thickness of about 140 nm and the Ni electrode 129b having the thickness of about 600 nm is formed on the upper surface of the p-type contact layer 6 by a lift-off method in the striped shape with the electrode width of about 2.2 μm, as shown in FIG. 58.

As shown in FIG. 59, only the Ni electrode 129b forming the upper portion of the p-side ohmic electrode 129 is isotropically wet-etched thereby reducing only the electrode width of the Ni electrode 129b to about 1.8 μm. Thus, the projecting p-side ohmic electrode 129 including the step is formed. Thereafter a through film 132 of SiO₂ having a thickness of about 10 nm is formed by plasma CVD to cover the overall upper surfaces of the p-side ohmic electrode 129 and the p-type contact layer 6.

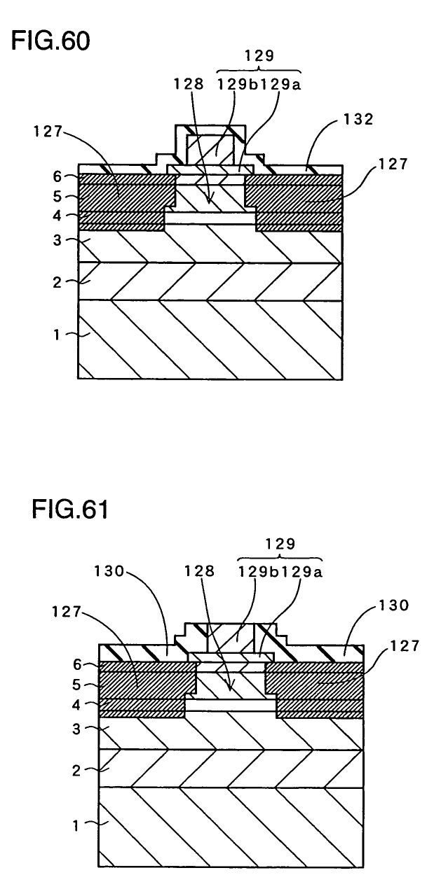

According to the thirteenth embodiment, the projecting p-side ohmic electrode 129 having the step is employed as a mask for ion-implanting silicon through the through film 132 thereby forming the stepped ion-implanted light absorption layers 127, as shown in FIG. 60. According to the thirteenth embodiment, silicon is ion-implanted under ion implantation conditions of ion implantation energy of about 400 keV and a dose of about 4.5×10¹⁵ cm⁻². Thus, the stepped ion-implanted light absorption layers 127 are formed through single ion implantation. In this case, the peak depth of the concentration of silicon introduced into the narrow-interval regions of the ion-implanted light absorption layers 127 is located in the regions of the p-type cladding layer 5 at the depth of about 0.14 μm from the upper surface of the p-type contact layer 6. The silicon concentration at this peak depth is about 1.0×10²⁰ cm⁻³. The peak depth of the concentration of silicon introduced into the wide-interval regions of the ion-implanted light absorption layers 127 is located in the regions of the MQW emission layer 4 at the depth of about 0.59 μm from the upper surface of the p-type contact layer 6. The silicon concentration at this peak depth is about 1.0×10²⁰ cm⁻³. Thereafter the through film 132 is removed by wet etching.

As shown in FIG. 61, the insulator films 130 of SiO₂ having a thickness of about 200 nm are formed by plasma CVD to cover the overall upper surfaces of the p-side ohmic electrode 129 and the p-type contact layer 6. The upper surface of the p-side ohmic electrode 129 is exposed by photolithography and RIE with CF₄ gas, similarly to the first embodiment.

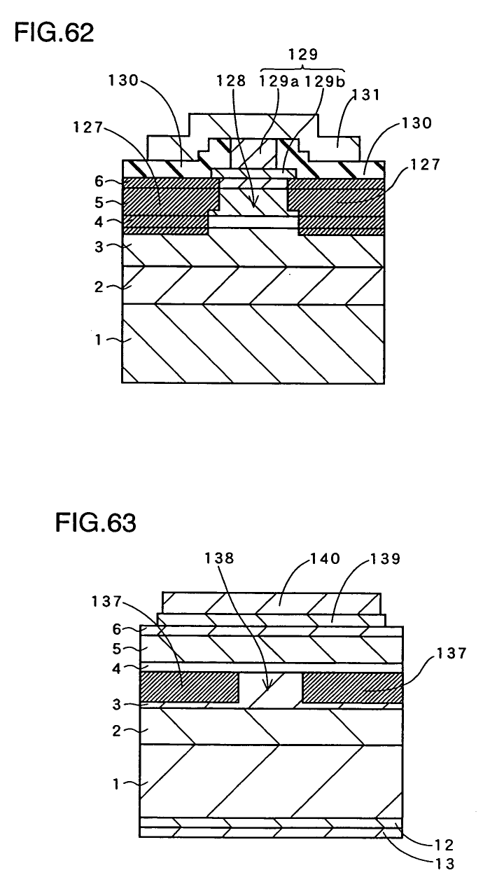

Finally, the p-side pad electrode 131 is formed on the upper surfaces of the insulator films 130 to be in contact with the upper surface of the p-side ohmic electrode 129 as shown in FIG. 62, through a process similar to that of the first embodiment. The n-type GaN substrate 1 is polished into a prescribed thickness and the n-side ohmic electrode 12 and the n-side pad electrode 13 are thereafter formed on the back surface of this n-type GaN substrate 1, thereby completing the nitride semiconductor laser element according to the thirteenth embodiment shown in FIG. 57.

In the fabrication process for the nitride semiconductor laser element according to the thirteenth embodiment, as hereinabove described, ion implantation is performed through the mask consisting of the projecting p-side ohmic electrode 129 having the step, whereby the stepped ion-implanted light absorption layers 127 consisting of regions having different implantation depths can be formed through single ion implantation. Thus, the ion-implantation light absorption layers 127 allowing individual control of the width of the current passing region 128 and the quantity of light absorption can be formed through single ion implantation. Therefore, current narrowing and transverse optical confinement of the laser beam can be so properly set that current density can be increased while excess light absorption can be suppressed. Thus, a threshold current can be reduced and a horizontal divergence angle of the laser beam can be controlled.

### Fourteenth Embodiment

Referring to FIG. 63, a example of forming ion-implanted light absorption layers in an n-type cladding layer by ion-implanting magnesium (Mg) into the n-type cladding layer in advance of formation of an MQW emission layer is described with reference to this fourteenth embodiment.

Referring to FIG. 63, an n-type layer 2, an n-type cladding layer 3, an MQW emission layer 4, a p-type cladding layer 5 and a p-type contact layer 6 are formed on an n-type GaN substrate 1 in this order according to this fourteenth embodiment, similarly to the first embodiment.

According to the fourteenth embodiment, ion-implanted light absorption layers 137, formed by ion-implanting magnesium (Mg), having an implantation depth of about 0.65 μm are provided on partial regions of the n-type cladding layer 3. The ion-implanted light absorption layers 137 are examples of the “light absorption layer” in the present invention, and magnesium is an example of the “first impurity element” in the present invention. In this case, the peak depth of the concentration of ion-implanted magnesium is located in regions of the n-type cladding layer 3 at about 0.48 μm from the upper surface of the n-type cladding layer 3. The peak concentration at this peak depth is about 1.0×10²⁰ cm⁻³. In this case, the ion-implanted light absorption layers 137 contain a larger number of crystal defects than the remaining regions due to implantation of a large quantity of ions into a semiconductor. A non-ion-implanted region (non-implanted region) forming a current passing region 138 is formed with a width of about 1.9 μm.

A p-side ohmic electrode 139 consisting of a Pt layer having a thickness of about 1 nm, a Pd layer having a thickness of about 100 nm, an Au layer having a thickness of about 240 nm and an Ni layer having a thickness of about 240 nm in ascending order is formed to cover the overall upper surface of the p-type contact layer 6. A p-side pad electrode 140 is formed on this p-side ohmic electrode 139. An n-side ohmic electrode 12 and an n-side pad electrode 13 are formed on the back surface of the n-type GaN substrate 1 successively from the side closer to the back surface of the n-type GaN substrate 1.

In a nitride semiconductor laser element according to the fourteenth embodiment, as hereinabove described, the impurity concentration of the implanted ions is peaked in the n-type cladding layer 3, whereby crystal defects can be formed in the n-type cladding layer 3 with sufficient density. Consequently, the ion-implanted light absorption layers 137 having a sufficient light absorption effect can be formed in the n-type cladding layer 3.

A fabrication process for the nitride semiconductor laser element according to the fourteenth embodiment is now described with reference to FIGS. 63 to 66. According to the fourteenth embodiment, a process other than that of forming the ion-implanted light absorption layers in the n-type cladding layer by implanting ions into the n-type cladding layer in advance of formation of the MQW emission layer is similar to the fabrication process according to the sixth embodiment.

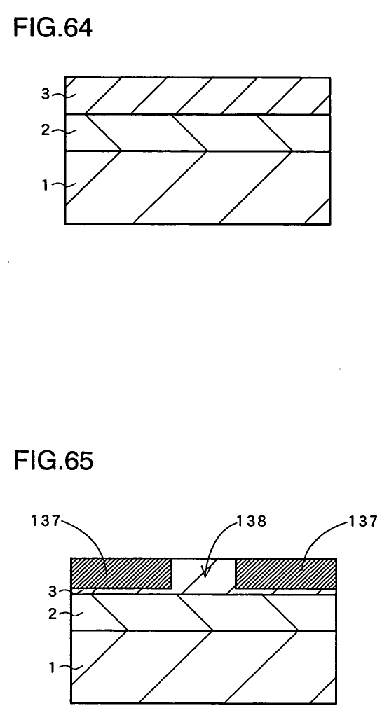

Referring to FIG. 64, the n-type layer 2 and the n-type cladding layer 3 are formed on the n-type GaN substrate 1 by MOCVD in the thirteenth embodiment.

According to the fourteenth embodiment, a striped ion implantation mask layer (not shown) having a width of about 2.3 μm is formed on the upper surface of the n-type cladding layer 3 by a lift-off method. This ion implantation mask layer is employed as a mask for ion-implanting magnesium, thereby forming the ion-implanted light absorption layers 137 having the implantation depth (thickness) of about 0.65 μm from the upper surface of the n-type cladding layer 3 as shown in FIG. 65. In this case, the peak depth of the impurity concentration of the ion-implanted light absorption layers 137 is located in the regions of the n-type cladding layer 3 at the depth of about 0.48 μm from the upper surface of the n-type cladding layer 3. The impurity concentration at this peak depth is about 1.0×10²⁰ cm⁻³. Thereafter the ion implantation mask layer is removed by wet etching.

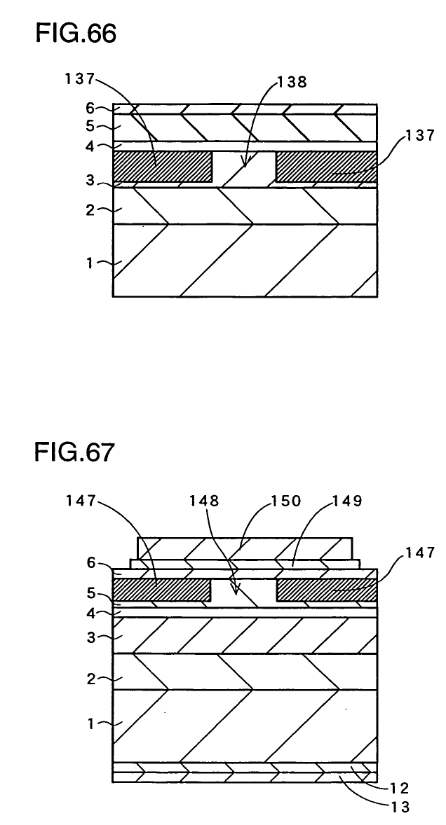

As shown in FIG. 66, the MQW emission layer 4, the p-type cladding layer 5 and the p-type contact layer 6 are successively formed on the n-type cladding layer 3 by MOCVD, similarly to the first embodiment. The ion-implanted light absorption layers 137 are annealed due to temperature rise in this crystal growth.

Finally, the p-side ohmic electrode 139 and the p-side pad electrode 140 are formed substantially on the overall upper surface of the p-type contact layer 6. Further, the n-type GaN substrate 1 is polished into a prescribed thickness and the n-side ohmic electrode 12 and the n-side pad electrode 13 are thereafter formed on the back surface of the n-type GaN substrate 1 successively from the side closer the back surface of the n-type GaN substrate 1, thereby completing the nitride semiconductor laser element according to the fourteenth embodiment shown in FIG. 63.

In the fabrication process for the nitride semiconductor laser element according to the fourteenth embodiment, as hereinabove described, the MQW emission layer 4 is formed after formation of the ion-implanted light absorption layers 137, whereby the MQW emission layer 4 can be prevented from increase of the number of crystal defects following ion implantation. Thus, reduction of the element life can be suppressed.

In the fabrication process for the nitride semiconductor laser element according to the fourteenth embodiment, as hereinabove described, no ions are implanted into p-type semiconductor regions (the p-type cladding layer 5 and the p-type contact layer 6), whereby reduction of the number of carriers resulting from crystal defects can be suppressed. This is particularly effective since it is difficult to improve carrier density of a p-type semiconductor region in a nitride semiconductor. Further, the p-type contact layer 6 having a small number of crystal defects can be formed with a wide area, whereby contact resistance between the p-type contact layer 6 and the p-side ohmic electrode 139 can be reduced.

In the fabrication process for the nitride semiconductor laser element according to the fourteenth embodiment, as hereinabove described, crystal growth is performed after increasing the temperature again after forming the ion-implanted light absorption layers 137, whereby the number of crystal defects in the ion-implanted light absorption layers 137 can be reduced by annealing through temperature rise. Thus, the light absorption coefficient of the ion-implanted light absorption layers 137 can be easily adjusted.

### Fifteenth Embodiment

Referring to FIG. 67, an example of forming ion-implanted light absorption layers in a p-type cladding layer by implanting ions into the p-type cladding layer in advance of formation of a p-type contact layer is described with reference to this fifteenth embodiment.

Referring to FIG. 67, an n-type layer 2, an n-type cladding layer 3, an MQW emission layer 4, a p-type cladding layer 5 and a p-type contact layer 6 are formed on an n-type GaN substrate 1 in this order according to this fifteenth embodiment, similarly to the first embodiment.

According to the fifteenth embodiment, ion-implanted light absorption layers 147, formed by ion-implanting carbon (C), having an implantation depth of about 0.27 μm are provided in partial regions of the p-type cladding layer 5. The ion-implanted light absorption layers 147 are examples of the “light absorption layer” in the present invention, and carbon is an example of the “first impurity element” in the present invention. In this case, the peak depth of the concentration of ion-implanted carbon is located in regions of the p-type cladding layer 5 at about 0.19 μm from the upper surface of the p-type cladding layer 5. The peak concentration at this peak depth is about 1.0×10²⁰ cm⁻³. In this case, the ion-implanted light absorption layers 147 contain a larger number of crystal defects than the remaining regions due to implantation of a large quantity of ions into a semiconductor. A non-ion-implanted region (non-implanted region) forming a current passing region 148 is formed with a width of about 1.9 μm.

A p-side ohmic electrode 149 consisting of a Pt layer having a thickness of about 1 nm, a Pd layer having a thickness of about 100 nm, an Au layer having a thickness of about 240 nm and an Ni layer having a thickness of about 240 nm in ascending order is formed to substantially cover the overall upper surface of the p-type contact layer 6. A p-side pad electrode 150 is formed on this p-side ohmic electrode 149. An n-side ohmic electrode 12 and an n-side pad electrode 13 are formed on the back surface of the n-type GaN substrate 1 successively from the side closer to the back surface of the n-type GaN substrate 1.

In a nitride semiconductor laser element according to the fifteenth embodiment, as hereinabove described, the impurity concentration of the implanted ions is peaked in the p-type cladding layer 5, whereby crystal defects can be formed in the p-type cladding layer 5 with sufficient density. Consequently, the ion-implanted light absorption layers 147 having a sufficient light absorption effect can be formed in the p-type cladding layer 5.

In the nitride semiconductor laser element according to the fifteenth embodiment, as hereinabove described, no ions are implanted into the MQW emission layer 4, whereby the MQW emission layer can be prevented from increase of the number of crystal defects. Thus, reduction of the element life can be suppressed.

In the nitride semiconductor laser element according to the fifteenth embodiment, as hereinabove described, no ions are implanted into the p-type contact layer 6, whereby the p-type contact layer 6 having low crystal defect concentration can be formed with a wide area. Thus, carrier concentration of the p-type contact layer 6 can be improved while the contact areas between the p-type contact layer 6 and the p-side ohmic electrode 149 can be widened. Consequently, contact resistance can be lowered.

A fabrication process for the nitride semiconductor laser element according to the fifteenth embodiment is now described with reference to FIGS. 67 to 70. According to the fifteenth embodiment, a process other than that of forming the ion-implanted light absorption layers in the p-type cladding layer by implanting ions into the p-type cladding layer in advance of formation of the p-type contact layer is similar to the fabrication process according to the sixth embodiment.

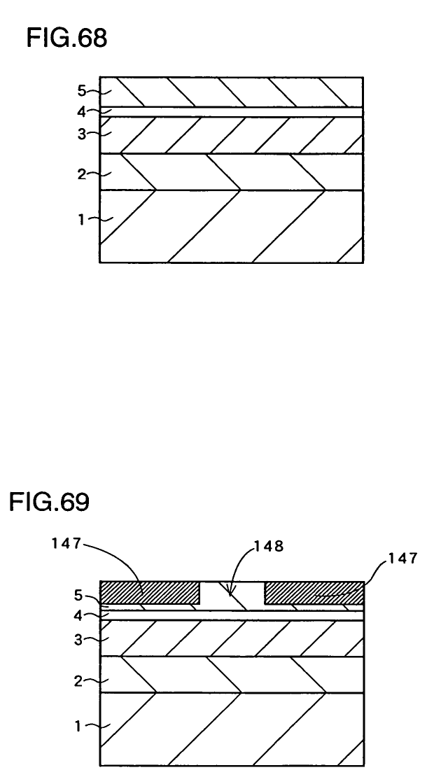

As shown in FIG. 68, the n-type layer 2, the n-type cladding layer 3, the MQW emission layer 4 and the p-type cladding layer 5 are formed on the n-type GaN substrate 1 by MOCVD, similarly to the first embodiment.

According to the fifteenth embodiment, a striped ion implantation mask layer (not shown) having a width of about 2.1 μm is formed on the upper surface of the p-type cladding layer 5 by a lift-off method. This ion implantation mask layer is employed as a mask for ion-implanting carbon (C) thereby forming the ion-implanted light absorption layers 147 having the implantation depth (thickness) of about 0.27 μm from the upper surface of the p-type cladding layer 5, as shown in FIG. 69. According to the fifteenth embodiment, carbon is ion-implanted under ion implantation conditions of ion implantation energy of about 65 keV and a dose of about 2.0×10¹⁵ cm⁻². Thereafter the ion implantation mask layer is removed by wet etching.

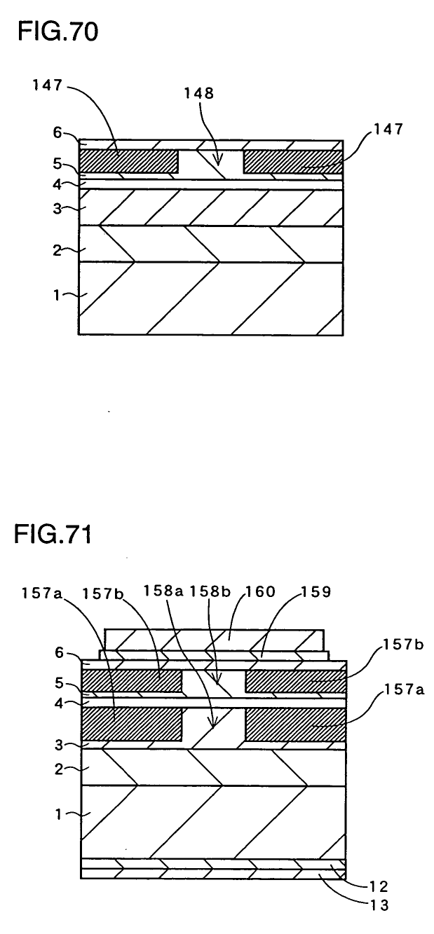

As shown in FIG. 70, the p-type contact layer 6 is formed by MOCVD to cover the overall upper surface of the p-type cladding layer 5. The ion-implanted light absorption layers 147 are annealed due to temperature rise in this crystal growth.

Finally, the p-side ohmic electrode 149 and the p-side pad electrode 150 are formed substantially on the overall upper surface of the p-type contact layer 6. Further, the n-type GaN substrate 1 is polished into a prescribed thickness and the n-side ohmic electrode 12 and the n-side pad electrode 13 are thereafter formed on the back surface of the n-type GaN substrate 1 successively from the side closer the back surface of the n-type GaN substrate 1, thereby completing the nitride semiconductor laser element according to the fifteenth embodiment shown in FIG. 67.

In the fabrication process for the nitride semiconductor laser element according to the fifteenth embodiment, as hereinabove described, crystal growth for forming the p-type contact layer 6 is performed after increasing the temperature again after forming the ion-implanted light absorption layers 147, whereby the number of crystal defects in the ion-implanted light absorption layers 147 can be reduced by annealing through temperature rise.

### Sixteenth Embodiment

Referring to FIG. 71, an example of forming two types of ion-implanted light absorption layers by separately implanting ions into an n-type cladding layer and a p-type cladding layer respectively is described with reference to this sixteenth embodiment.

Referring to FIG. 71, an n-type layer 2, an n-type cladding layer 3, an MQW emission layer 4, a p-type cladding layer 5 and a p-type contact layer 6 are formed on an n-type GaN substrate 1 in this order according to this sixteenth embodiment, similarly to the first embodiment.

According to the sixteenth embodiment, ion-implanted light absorption layers 157a, formed by ion-implanting magnesium (Mg), having an implantation depth of about 0.65 μm are provided on partial regions of the n-type cladding layer 3, similarly to the fourteenth embodiment. The ion-implanted light absorption layers 157a are examples of the “light absorption layer” in the present invention, and magnesium is an example of the “first impurity element” in the present invention. In this case, the peak depth of the concentration of ion-implanted magnesium is located in regions of the n-type cladding layer 3 at about 0.48 μm from the upper surface of the n-type cladding layer 3. The peak concentration at this peak depth is about 1.0×10²⁰ cm⁻³. In this case, the ion-implanted light absorption layers 157a contain a larger number of crystal defects than the remaining regions due to implantation of a large quantity of ions into a semiconductor. A non-ion-implanted region (non-implanted region) forming a current passing region 158a is formed with a width of about 1.9 μm.

According to the sixteenth embodiment, further, ion-implanted light absorption layers 157b, formed by ion-implanting carbon (C), having an implantation depth of about 0.27 μm are provided on partial regions of the p-type cladding layer 5, similarly to the fifteenth embodiment. The ion-implanted light absorption layers 157b are examples of the “light absorption layer” in the present invention, and carbon is an example of the “first impurity element” in the present invention. In this case, the peak depth of the concentration of ion-implanted carbon is located in regions of the p-type cladding layer 5 at about 0.19 μm from the upper surface of the p-type cladding layer 5. The peak concentration at this peak depth is about 1.0×10²⁰ cm⁻³. In this case, the ion-implanted light absorption layers 157b contain a larger number of crystal defects than the remaining regions due to implantation of a large quantity of ions into a semiconductor. A non-ion-implanted region (non-implanted region) forming a current passing region 158 is formed with a width of about 1.9 μm.

A p-side ohmic electrode 159 consisting of a Pt layer having a thickness of about 1 nm, a Pd layer having a thickness of about 100 nm, an Au layer having a thickness of about 240 nm and an Ni layer having a thickness of about 240 nm in ascending order is formed to substantially cover the overall upper surface of the p-type contact layer 6. A p-side pad electrode 160 is formed on this p-side ohmic electrode 159. An n-side ohmic electrode 12 and an n-side pad electrode 13 are formed on the back surface of the n-type GaN substrate 1 successively from the side closer to the back surface of the n-type GaN substrate 1.

In a nitride semiconductor laser element according to the sixteenth embodiment, as hereinabove described, the current passing regions 158a and 158b are formed under and above the MQW emission layer 4 respectively, whereby sufficient current confinement can be performed.

In the nitride semiconductor laser element according to the sixteenth embodiment, as hereinabove described, the ion-implanted light absorption layers 157a and 157b are formed under and above the MQW emission layer 4 respectively, whereby sufficient transverse optical confinement can be performed.

A fabrication process for the nitride semiconductor laser element according to the sixteenth embodiment is now described with reference to FIGS. 71 to 76. According to this sixteenth embodiment, a fabrication process other than that of separately forming the ion-implanted light absorption layers by implanting ions into the n-type cladding layer and the p-type cladding layer respectively is similar to the fabrication process according to the sixth embodiment.

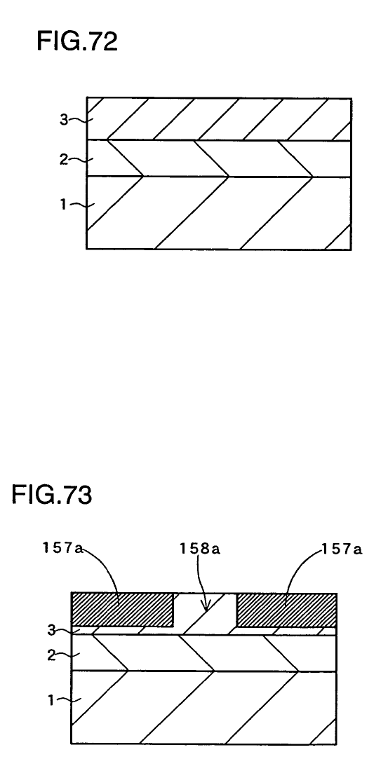

Referring to FIG. 72, the n-type layer 2 and the n-type cladding layer 3 are formed on the n-type GaN substrate 1 by MOCVD according to the sixteenth embodiment.

According to the sixteenth embodiment, a striped ion implantation mask layer (not shown) having a width of about 2.3 μm is formed on the upper surface of the n-type cladding layer 3 by a lift-off method, similarly to the fourteenth embodiment. This ion implantation mask layer is employed as a mask for ion-implanting magnesium, thereby forming the ion-implanted light absorption layers 157a having the implantation depth (thickness) of about 0.65 μm from the upper surface of the n-type cladding layer 3 as shown in FIG. 73. According to the sixteenth embodiment, magnesium is ion-implanted under ion implantation conditions of ion implantation energy of about 260 keV and a dose of about 4.3×10¹⁵ cm⁻². In this case, the peak depth of the impurity concentration of the ion-implanted light absorption layers 157a is located in the regions of the n-type cladding layer 3 at the depth of about 0.48 μm from the upper surface of the n-type cladding layer 3. The impurity concentration at this peak depth is about 1.0×10²⁰ cm⁻³. Thereafter the ion implantation mask layer is removed by wet etching.

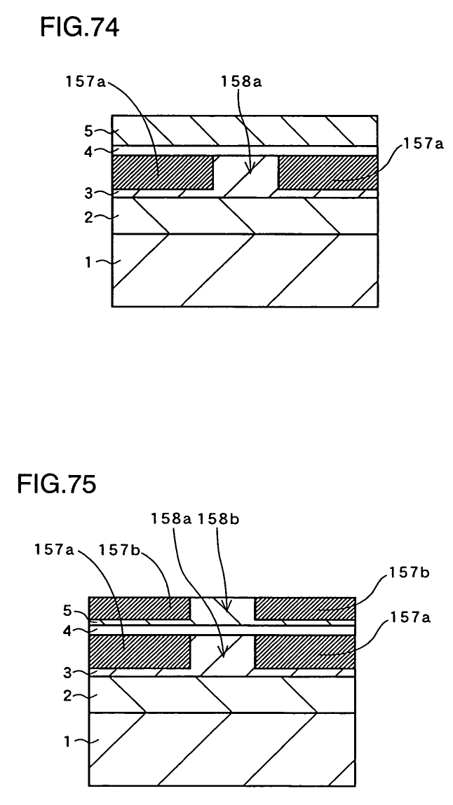

As shown in FIG. 74, the MQW emission layer 4 and the p-type cladding layer 5 are successively formed on the n-type cladding layer 3 by MOCVD, similarly to the first embodiment. The ion-implanted light absorption layers 157a are annealed due to temperature rise in this crystal growth.

According to the sixteenth embodiment, another striped ion implantation mask layer (not shown) having a width of about 2.1 μm is formed on the current passing region 148a on the upper surface of the p-type cladding layer 5 by a lift-off method, similarly to the fifteenth embodiment. This ion implantation mask layer is employed as a mask for ion-implanting carbon (C) thereby forming the ion-implanted light absorption layers 157b having the implantation depth (thickness) of about 0.27 μm from the upper surface of the p-type cladding layer 5, as shown in FIG. 75. According to the sixteenth embodiment, carbon is ion-implanted under ion implantation conditions of ion implantation energy of about 65 keV and a dose of about 2.0×10¹⁵ cm⁻². Thereafter the ion implantation mask layer is removed by wet etching.

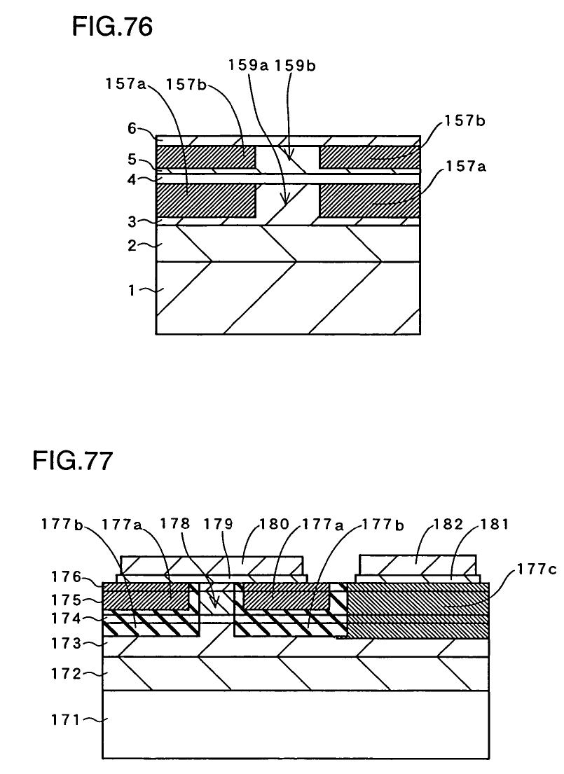

Then, the p-type contact layer 6 is formed on the p-type cladding layer 5 by MOCVD, as shown in FIG. 76. The ion-implanted light absorption layers 157a and 157b are annealed through temperature rise in this crystal growth.

Finally, the p-side ohmic electrode 159 and the p-side pad electrode 160 are formed substantially on the overall upper surface of the p-type contact layer 6. Further, the n-type GaN substrate 1 is polished into a prescribed thickness and the n-side ohmic electrode 12 and the n-side pad electrode 13 are thereafter formed on the back surface of the n-type GaN substrate 1 successively from the side closer to the back surface of the n-type GaN substrate 1, thereby completing the nitride semiconductor laser element according to the sixteenth embodiment shown in FIG. 71.

### Seventeenth Embodiment

Referring to FIG. 77, an example of applying the present invention to a planar nitride semiconductor laser element is described with reference to this seventeenth embodiment.

First, the structure of a nitride semiconductor laser element according to the seventeenth embodiment is described with reference to FIG. 77. According to the seventeenth embodiment, an n-type contact layer 172 of GaN having a thickness of about 1.0 μm, an n-type cladding layer 173 of Al_{0.08}Ga_{0.92}N having a thickness of about 1 μm, an MQW emission layer 174 of InGaN, a p-type cladding layer 175 of Al_{0.08}Ga_{0.92}N having a thickness of about 0.28 μm and a p-type contact layer 176 of Al_{0.01}Ga_{0.99}N having a thickness of about 0.07 μm are formed on an insulating sapphire substrate 171 in this order. The n-type contact layer 172 and the n-type cladding layer 173 are examples of the “first nitride semiconductor layer” in the present invention, and the p-type cladding layer 175 and the p-type contact layer 176 are examples of the “second nitride semiconductor layer” in the present invention.

According to the seventeenth embodiment, ion-implanted light absorption layers 177a, formed by ion-implanting carbon (C), having an implantation depth of about 0.32 μm are provided excluding a first width of about 2.1 μm on a left-side region of the sapphire substrate 171, similarly to the first embodiment. Carbon is an example of the “first impurity element” in the present invention, and the ion-implanted light absorption layers 177a are examples of the “light absorption layer” in the present invention. In this case, the peak depth of the concentration of ion-implanted carbon is located in regions of the p-type cladding layer 175 at about 0.23 μm from the upper surface of the p-type contact layer 176. The peak concentration at this peak depth is about 1.0×10²⁰ cm⁻³. In this case, the ion-implanted light absorption layers 177a contain a larger number of crystal defects than the remaining regions due to implantation of a large quantity of ions into a semiconductor.

The ion-implanted light absorption layers 177a in the seventeenth embodiment function as light absorption layers due to crystal defects contained in the ion-implanted light absorption layers 177a in a large number. In order to sufficiently perform transverse optical confinement in the ion-implanted light absorption layers 177a, the maximum value of the impurity concentration of ion-implanted carbon is preferably at least about 1×10²⁰ cm⁻³. Thus, the ion-implanted light absorption layers 177a can absorb light due to the crystal defects contained in a large number.

Further, current narrowing layers (high-resistance layers) 177b, formed by ion-implanting carbon (C), having an implantation depth of about 0.76 μm are provided on the left-side region of the sapphire substrate 171. In this case, the peak depth of the concentration of ion-implanted carbon is located in regions of about 0.61 μm from the upper surface of the p-type contact layer 176. The peak concentration at this peak depth is about 1.0×10¹⁹ cm⁻³. A non-ion-implanted region (non-implanted region) forming a current passing region 178 is formed with a width of about 1.6 μm. Carbon is an example of the “second impurity element” in the present invention.

A p-side ohmic electrode 179 consisting of a Pt layer having a thickness of about 1 nm, a Pd layer having a thickness of about 100 nm, an Au layer having a thickness of about 240 nm and an Ni layer having a thickness of about 240 nm in ascending order is formed on the upper surface of the current passing region 178 on the left-side region of the p-type contact layer 176 in a striped shape. A p-side pad electrode 180 is formed to substantially cover the overall upper surface of the p-side ohmic electrode 179.

An n-type inversion layer 177c formed by inverting a p-type portion to an n type by ion-implanting a large quantity of silicon (n-type dopant) on a region reaching part of the n-type cladding layer 173 from the upper surface of the p-type contact layer 176 is provided on a right-side region of the sapphire substrate 171. This n-type inversion layer 177c is formed with an implantation depth (thickness) of about 0.73 μm from the upper surface of the p-type contact layer 176. Silicon is an example of the “fourth impurity element” in the present invention.

An n-side ohmic electrode 181 consisting of an Al layer having a thickness of about 6 nm, an Si layer having a thickness of about 2 nm, an Ni layer having a thickness of about 10 nm and an Au layer having a thickness of about 100 nm in ascending order is formed to substantially cover the overall upper surface of the n-type inversion layer 177c. An n-side pad electrode 182 consisting of an Ni layer having a thickness of about 10 nm and an Au layer having a thickness of about 700 nm is formed on this n-side ohmic electrode 181.

In the nitride semiconductor laser element according to the seventeenth embodiment, as hereinabove described, the ion-implanted light absorption layers 177a and the n-type inversion layer 177c are formed by ion implantation so that no conventional projecting ridge portion is necessary. Thus, when the element is mounted on a heat radiation base in a junction-down system from the surface closer to the MQW emission layer 4, the element characteristics are not disadvantageously deteriorated due to stress applied to a projecting ridge portion. Further, heat radiation characteristics are not inconveniently deteriorated due to reduction of a contact area with the heat radiation base resulting from a projecting ridge portion.

The remaining effects of the seventeenth embodiment are similar to those of the first embodiment.

A fabrication process for the nitride semiconductor laser element according to the seventeenth embodiment is now described with reference to FIGS. 77 to 84.

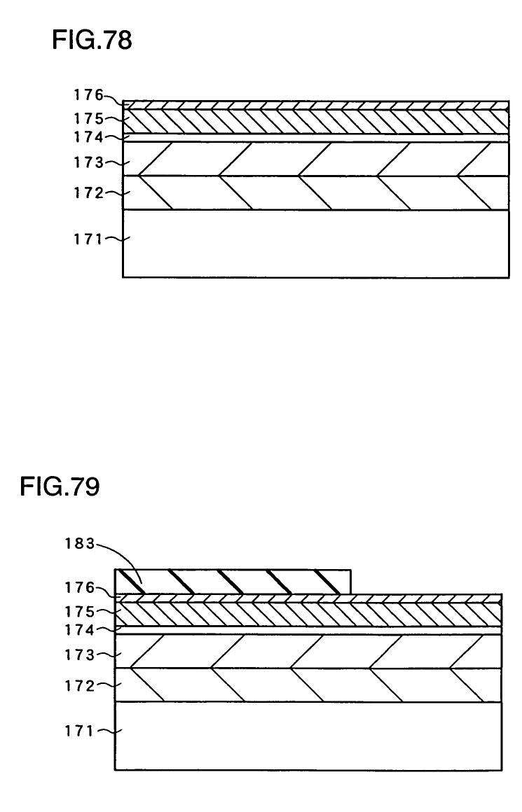

First, the n-type contact layer 172 of GaN having the thickness of about 1.0 μm, the n-type cladding layer 173 of Al_{0.08}Ga_{0.92}N having the thickness of about 1.0 μm, the MQW emission layer 174 of InGaN, the p-type cladding layer 175 of Al_{0.08}Ga_{0.92}N having the thickness of about 0.28 μm and the p-type contact layer 176 of Al_{0.01}Ga_{0.99}N having the thickness of about 0.07 μm are successively formed on the sapphire substrate 171 by MOCVD, as shown in FIG. 78.

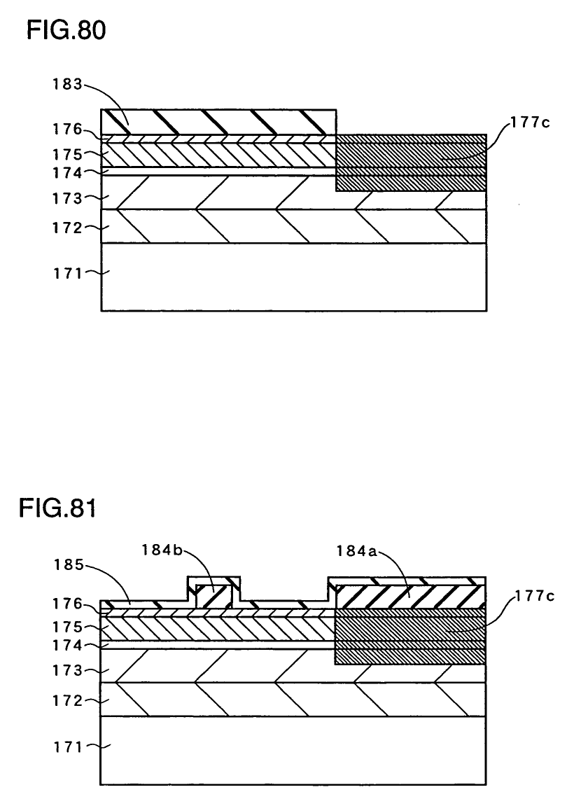

According to the seventeenth embodiment, an SiO₂ layer (not shown) having a thickness of about 1.0 μm is formed to substantially cover the overall upper surface of the p-type contact layer 176. A striped ion implantation mask layer 183 having a width of about 300 μm is formed on the left-side region by photolithography and etching with a hydrofluoric etchant, as shown in FIG. 79. As shown in FIG. 80, this ion-implanted mask layer 183 is employed as a mask for ion-implanting silicon (n-type dopant) into portions of the p-type contact layer 176, the p-type cladding layer 175, the MQW emission layer 174 and the n-type cladding layer 173 located on the right-side region while performing lamp annealing in an N₂/H₂ gas mixture atmosphere of about 1000° C. for about 30 seconds, thereby forming the n-type inversion layer 177c having the implantation depth (thickness) of about 0.73 μm from the upper surface of the p-type contact layer 176.

This ion implantation was performed under conditions of ion implantation energy of about 400 keV and a dose of about 4.3×10¹⁵ cm⁻². In this case, the peak depth of the concentration of silicon introduced into the n-type inversion layer 177c is at a level of about 0.55 μm from the upper surface of the p-type contact layer 176. The silicon concentration at this peak depth is about 1.0×10²⁰ cm⁻³. Thereafter the ion implantation mask layer 183 is removed by wet etching with a hydrofluoric acid etchant.

Then, another SiO₂ layer (not shown) having a thickness of about 1.0 μm is formed on the overall upper surfaces of the n-type contact layer 176 and the n-type inversion layer 177c. As shown in FIG. 81, striped ion implantation masks 184a and 184b of SiO₂ are formed on the overall upper surface of the n-type inversion region 177c on the right-side region and the portion of the p-type contact layer 176 located on the current passing region 178 of the left-side region respectively by photolithography and etching. In this case, the ion implantation mask layer 184b on the upper surface of the current passing region 178 has a width of about 2.2 μm. A through film 185 of SiO₂ having a thickness of about 60 nm is formed to cover the overall upper surfaces of the ion implantation mask layer 184a, the ion implantation mask layer 184b and the p-type contact layer 176.

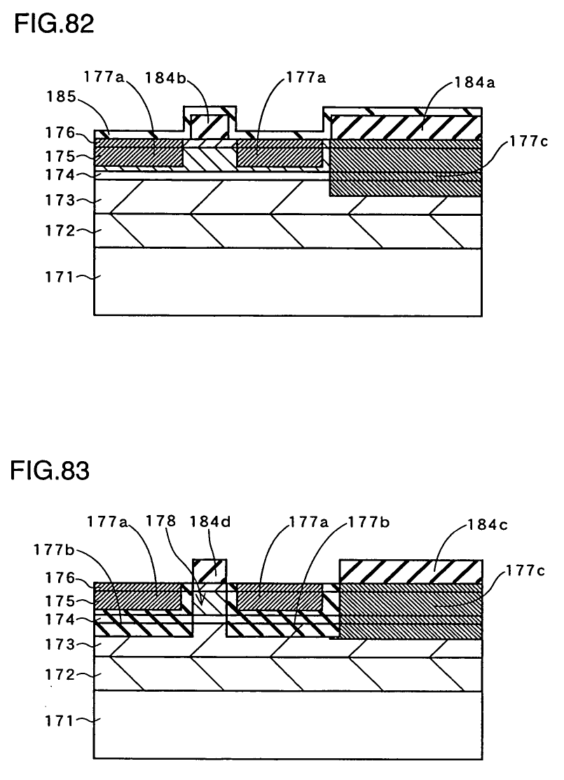

As shown in FIG. 82, the ion implantation mask layers 184a and 184b are employed as masks for ion-implanting carbon through the through film 185, thereby forming the ion-implanted light absorption layers 177a having the implantation depth (thickness) of about 0.32 μm from the upper surface of the p-type contact layer 176. According to the seventeenth embodiment, carbon is ion-implanted under ion implantation conditions of ion implantation energy of about 95 keV and a dose of about 2.3×10¹⁵ cm⁻². In this case, the peak depth of the impurity concentration of the ion-implanted light absorption layers 177a is located in regions of the p-type cladding layer 175 at a depth of about 0.23 μm from the upper surface of the p-type contact layer 176. The peak concentration at this peak depth is about 1.0×10²⁰ cm⁻³. Thereafter the through film 185 is removed by wet etching with a hydrofluoric acid etchant.

As shown in FIG. 83, the ion implantation mask layers 184a and 184b are selectively etched by about 0.15 μm as to transverse single sides. Thus, an ion implantation mask layer 184d having a width of about 2.0 μm is formed. The ion implantation mask layers 184c an 184d are employed as masks for ion-implanting carbon, thereby forming the current narrowing layers (high-resistance layers) 177b having the implantation depth of about 0.76 μm from the upper surface of the p-type contact layer 176. According to the seventeenth embodiment, ion implantation is performed under ion implantation conditions of ion implantation energy of about 230 keV and a dose of about 3.5×10¹⁴ cm⁻². In this case, the peak depth of the carbon concentration of the current narrowing layers 177b is located in regions of about 0.61 μm from the upper surface of the p-type contact layer 176. The carbon concentration at this peak depth is about 1.0×10¹⁹ cm⁻³. Thereafter the ion implantation mask layers 184c and 184d are removed by wet etching with a hydrofluoric acid etchant.

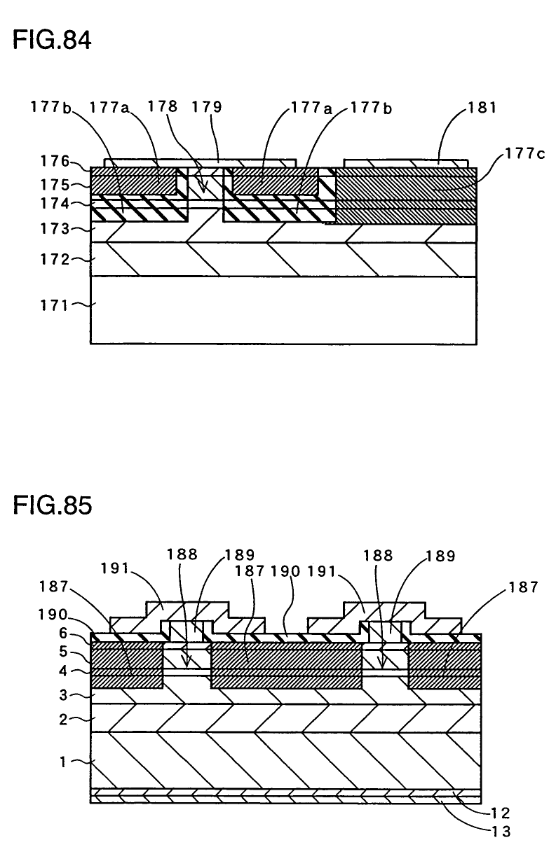

As shown in FIG. 84, the p-side ohmic electrode 179 consisting of the Pt layer having the thickness of about 1 nm, the Pd layer having the thickness of about 100 nm, the Au layer having the thickness of about 240 nm and the Ni layer having the thickness of about 240 nm in ascending order is formed on the upper surface of the region of the p-type contact layer 176 (left-side region) forming the current passing region 178 in the striped shape by a lift-off method. Further, the n-side ohmic electrode 181 consisting of the Al layer having the thickness of about 6 nm, the Si layer having the thickness of about 2 nm, the Ni layer having the thickness of about 10 nm and the Au layer having the thickness of about 100 nm in ascending order is formed on the n-type inversion layer 177c (right-side region) in a striped shape by the lift-off method.

Finally, the p-side pad electrode 180 and the n-side pad electrode 182 are formed to be in contact with the upper surfaces of the p-side ohmic electrode 179 and the n-side ohmic electrode 181 respectively, thereby completing the nitride semiconductor laser element according to the seventeenth embodiment shown in FIG. 77.

In the fabrication process for the nitride semiconductor laser element according to the seventeenth embodiment, as hereinabove described, p-type regions and n-type regions can be formed in the same semiconductor layers by performing heat treatment after ion-implanting a dopant having a reverse conductivity (n type) to p-type semiconductor layers in a large quantity.

In the fabrication process for the nitride semiconductor laser element according to the seventeenth embodiment, as hereinabove described, p-n regions can be electrically isolated from each other through the current narrowing layers (high-resistance layers) 177b formed by ion-implanting carbon, whereby a plurality of elements can be easily integrated in the same substrate. Carbon, which is the “second impurity element” in the present invention, is also the “third impurity element” in the present invention. The current narrowing layers 177b are examples of the “electric isolation region” in the present invention. Consequently, integration of a plurality of nitride semiconductor laser elements or integration of an electronic device such as a transistor and a nitride semiconductor laser element can be easily performed.

In the fabrication process for the nitride semiconductor laser element according to the seventeenth embodiment, as hereinabove described, no formation of a ridge portion requiring strict etching is necessary, whereby the yield can be improved.

### Eighteenth Embodiment

Referring to FIG. 85, an example of integrating a plurality of nitride semiconductor laser elements while locating concentration peaks of implanted ions in MQW emission layers is described with reference to this eighteenth embodiment.

Referring to FIG. 85, an n-type layer 2, an n-type cladding layer 3, an MQW emission layer 4, a p-type cladding layer 5 and a p-type contact layer 6 are formed on an n-type GaN substrate 1 in this order according to this eighteenth embodiment, similarly to the first embodiment.

According to the eighteenth embodiment, ion-implanted light absorption layers 187, formed by ion-implanting carbon (C), having an implantation depth of about 0.61 μm are provided on partial regions of the n-type cladding layer 3, the MQW emission layer 4, the p-type cladding layer 5 and the p-type contact layer 6. Carbon is an example of the “first impurity element” in the present invention, and the ion-implanted light absorption layers 187 are examples of the “light absorption layer” in the present invention. In this case, the peak depth of the concentration of ion-implanted carbon is located in regions of the MQW emission layer 4 at about 0.61 μm from the upper surface of the p-type contact layer 6. The peak concentration at this peak depth is about 1.0×10¹⁸ cm⁻³ to about 1.0×10¹⁹ cm⁻³. In this case, the ion-implanted light absorption layers 187 contain a larger number of crystal defects than the remaining regions due to implantation of a large quantity of ions into a semiconductor. These ion-implanted light absorption layers 187 form two types of emission regions. Non-ion-implanted regions (non-implanted regions) forming current passing regions 188 are formed with a width of about 2.6 μm.

Thus, the concentration of implanted carbon reaches the maximum values in the MQW emission layer 4 according to the eighteenth embodiment, whereby crystal defect concentration is maximized in the MQW emission layer 4 while the light absorption coefficient is also maximized in the MQW emission layer 4.

P-side ohmic electrodes 189 are formed on the upper surfaces of the current passing regions 188 of the p-type contact layer 6 with an electrode width of about 2.9 μm in a striped shape, similarly to the first embodiment. Insulator films 190 are formed to cover the side surfaces of the p-side ohmic electrodes 189 and the p-type contact layer 6. P-side pad electrodes 191 are formed on the insulator films 190 to be in contact with the upper surfaces of the p-side ohmic electrodes 189. An n-side ohmic electrode 12 and an n-side pad electrode 13 are formed on the back surface of the n-type GaN substrate 1 successively from the side closer to the back surface of the n-type GaN substrate 1. The thicknesses and compositions of the respective layers 189 to 191 are similar to those of the respective layers 9 to 11 of the first embodiment respectively.

In a nitride semiconductor laser element according to the eighteenth embodiment, as hereinabove described, the carbon concentration reaches the maximum value in the MQW emission layer 4 while the light absorption coefficient is also maximized in the MQW emission layer 4, whereby strong complex refractive index difference can be formed in the in-plane direction of the MQW emission layer 4. Thus, transverse optical confinement can be excellently performed also through ion implantation with a small dose.

In the nitride semiconductor laser element according to the eighteenth embodiment, as hereinabove described, the ion-implanted light absorption layers 187 are so increased in resistance that the MQW emission layer 4 and p-type semiconductor layers of each element can be electrically isolated from those of another element adjacent thereto in the same substrate when a plurality of elements are formed in the same substrate. Thus, a plurality of semiconductor laser elements can be easily integrated in the same substrate. The ion-implanted light absorption layers 187 are also examples of the “electric isolation region” in the present invention. Carbon, which is the “first impurity element” in the present invention, is also the “third impurity element” in the present invention.

A fabrication process for the nitride semiconductor laser element according to the eighteenth embodiment is now described with reference to FIGS. 85 to 87. With reference to the fabrication process according to the eighteenth embodiment, a fabrication process of locating concentration peaks of implanted ions in the MQW emission layer while forming a plurality of emission regions in the same substrate is described.

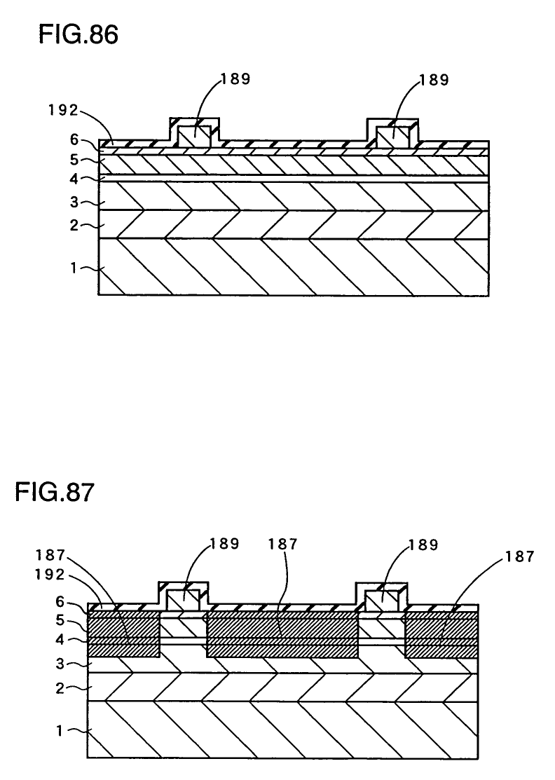

First, the layers up to the p-type contact layer 6 are formed through a process similar to that of the first embodiment show in FIG. 4. As shown in FIG. 86, the two p-side ohmic electrodes 189 having the width of about 2.9 μm are formed on the upper surface of the p-type contact layer 6 in the striped shape at a prescribed interval by a lift-off method, similarly to the first embodiment. A through film 192 of SiO₂ having a thickness of about 60 nm is formed by plasma CVD to cover the overall upper surfaces of the p-side ohmic electrodes 189 and the p-type contact layer 6.

As shown in FIG. 87, the p-side ohmic electrodes 189 are employed as masks for ion-implanting carbon through the through film 192 thereby forming the ion-implanted light absorption layers 187 having an implantation depth (thickness) of about 0.75 μm from the upper surface of the p-type contact layer 6. According to the eighteenth embodiment, carbon is ion-implanted under ion implantation conditions of ion implantation energy of about 250 keV and a dose of about 3.5×10¹³ cm⁻² to 3.5×10¹⁴ cm⁻². Thus, the ion-implanted light absorption layers 187 having the carbon concentration maximized in the MQW emission layer 4 are formed. Thereafter the through film 192 is removed by wet etching with a hydrofluoric acid etchant.

The insulator films 190 of SiO₂ having a thickness of about 200 nm are formed by plasma CVD to cover the overall upper surfaces of the p-type contact layer 6 and the p-side ohmic electrodes 189. The upper surfaces of the p-side ohmic electrodes 189 are exposed by photolithography and RIE with CF₄ gas, similarly to the first embodiment.

Finally, the p-side pad electrodes 191 are formed on the insulator films 190 to be in contact with the exposed upper surfaces of the p-side ohmic electrodes 189 through a process similar to that of the first embodiment. Further, the n-side ohmic electrode 12 and the n-side pad electrode 13 are formed on the back surface, polished into a prescribed thickness, of the n-type GaN substrate 1 from the side closer to the back surface of the n-type GaN substrate 1, thereby completing the nitride semiconductor laser element according to the eighteenth embodiment shown in FIG. 85.

### Nineteenth Embodiment

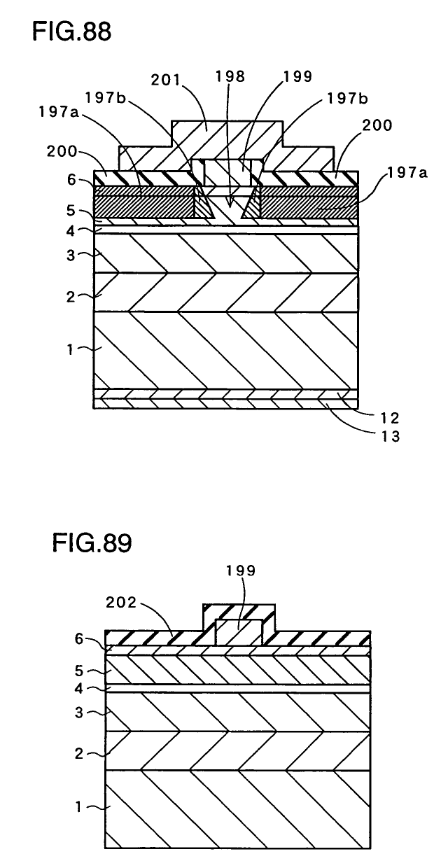

Referring to FIG. 88, an example of forming ion-implanted light absorption layers and current narrowing layers by carrying out a plurality of ion implantation steps with phosphorus (P) and carbon (C) while carrying out the respective ion implantation steps from different angles is described with reference to this nineteenth embodiment. The remaining structure of the nineteenth embodiment is similar to that of the first embodiment.

Referring to FIG. 88, an n-type layer 2, an n-type cladding layer 3, an MQW emission layer 4, a p-type cladding layer 5 and a p-type contact layer 6 are formed on an n-type GaN substrate 1 in this order according to this nineteenth embodiment, similarly to the first embodiment.

According to the nineteenth embodiment, ion-implanted light absorption layers 197a, formed by ion-implanting phosphorus (P), having an implantation depth of about 0.32 μm are provided on partial regions of the p-type cladding layer 5 and the p-type contact layer 6 excluding a first width of about 2.8 μm. Phosphorus is an example of the “first impurity element” in the present invention, and the ion-implanted light absorption layers 197a are examples of the “light absorption layer” in the present invention. In this case, the peak depth of the concentration of ion-implanted phosphorus is located in regions of the p-type cladding layer 5 at a depth of about 0.22 μm from the upper surface of the p-type contact layer 6. The phosphorus concentration at this peak depth is about 1.0×10²⁰ cm⁻³.

Current narrowing layers 197b, formed by ion-implanting carbon (C), having an implantation depth of about 0.28 μm are provided on other partial regions of the p-type cladding layer 5 and the p-type contact layer 6 inside the ion-implanted light absorption layers 197a. Carbon is an example of the “second impurity element” in the present invention. In this case, the peak depth of the concentration of ion-implanted carbon is located in regions of the p-type cladding layer 5 at a depth of about 0.2 μm from the upper surface of the p-type contact layer 6. The carbon concentration at this peak depth is about 1.0×10¹⁹ cm⁻³. The current narrowing layers 197b perform current narrowing with respect to a current injected from a p side, thereby forming an inverse-trapezoidal current passing region 198 having a width inclinatorily changed in the range of about 2.5 μm to about 2.0 μm.

A p-side ohmic electrode 199 is formed on the upper surface of the current passing region 198 of the p-type contact layer 6 with an electrode width of about 2.9 μm in a striped shape, similarly to the first embodiment. Insulator films 200 are formed to cover the side surfaces of the p-side ohmic electrode 199 and the p-type contact layer 6. A p-side pad electrode 201 is formed on the insulator films 200 to be in contact with the upper surface of the p-side ohmic electrode 199. An n-side ohmic electrode 12 and an n-side pad electrode 13 are formed on the back surface of the n-type GaN substrate 1 from the side closer to the back surface of the n-type GaN substrate 1. The thicknesses and compositions of the respective layers 199 to 201 are similar to those of the respective layers 9 to 11 in the first embodiment respectively.

A fabrication process for a nitride semiconductor laser element according to the nineteenth embodiment is now described with reference to FIGS. 88 to 92.

First, the layers up to the p-type contact layer 6 are formed through a process similar to that of the first embodiment shown in FIG. 4. Then, the p-side ohmic electrode 199 is formed on the upper surface of the p-type contact layer 6 with the electrode width of about 2.9 μm in the striped shape by a lift-off method, as shown in FIG. 89. A through film 202 of SiO₂ having a thickness of about 60 nm is formed by plasma CVD to cover the overall upper surfaces of the p-side ohmic electrode 199 and the p-type contact layer 6.

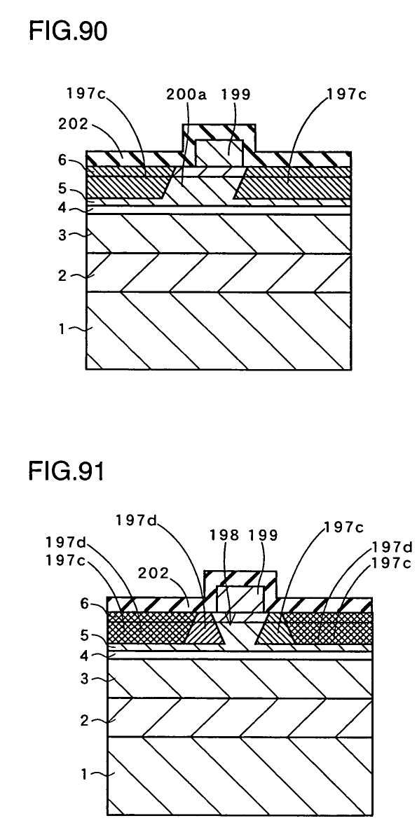

According to the nineteenth embodiment, carbon is ion-implanted from a direction inclined at a prescribed angle about the stripe direction of the p-side ohmic electrode 199 from a direction perpendicular to the p-side ohmic electrode 199, as shown in FIG. 90. More specifically, the p-side ohmic electrode 199 is employed as a mask for performing first ion implantation from an angle inclined by about 30° clockwise from the direction perpendicular to the p-type contact layer 6 ([0001] direction of the p-type contact layer 6) in a plane perpendicular to the stripe direction of the p-side ohmic electrode 199 through the through film 202. Thus, high-resistance layers 197c having an implantation depth (thickness) of about 0.28 μm from the upper surface of the p-type contact layer 6 are formed. In the first ion implantation according to the nineteenth embodiment, carbon is ion-implanted under ion implantation conditions of ion implantation energy of about 95 keV and a dose of about 2.3×10¹⁴ cm⁻².

Then, second ion implantation is performed from an angle inclined by about 30° anticlockwise from the direction perpendicular to the p-type contact layer 6 ([0001] direction of the p-type contact layer 6) in the plane perpendicular to the stripe direction of the p-side ohmic electrode 199. Thus, high-resistance layers 197d having an implantation depth (thickness) of about 0.28 μm from the upper surface of the p-type contact layer 6 are formed, as shown in FIG. 91. Second ion implantation conditions according to the nineteenth embodiment are similar to the first ion implantation conditions.

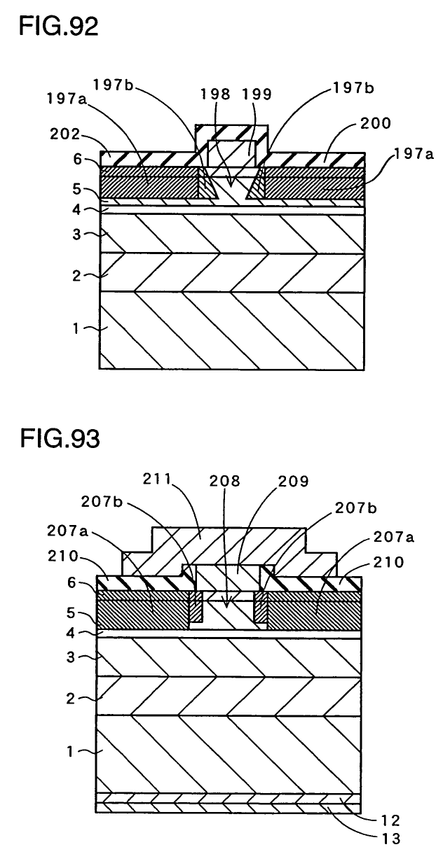

Further, phosphorus was ion-implanted from a direction inclined by about 70 in the stripe direction of the p-side ohmic electrode 199 from the direction perpendicular to the p-type contact layer 6, as shown in FIG. 92. In this third ion implantation, phosphorus is ion-implanted under ion implantation conditions of ion implantation energy of about 200 keV and a dose of about 2.5×10¹⁵ cm⁻². Thus, regions formed by the first to third ion implantation steps overlap with each other, thereby forming the current narrowing layers 197b and the ion-implanted light absorption layers 197a as shown in FIG. 92.

Thereafter the through film 202 is removed by wet etching with a hydrofluoric etchant. The insulator films 200 of SiO₂ having a thickness of about 200 nm are formed by plasma CVD to cover the overall upper surfaces of the p-type contact layer 6 and the p-side ohmic electrode 199, as shown in FIG. 88. The upper surface of the p-side ohmic electrode 199 is by photolithography and RIE with CF₄ gas, similarly to the first embodiment.

Finally, the p-side pad electrode 201 is formed on the insulator films 200 to be in contact with the exposed upper surface of the p-side ohmic electrode 199 through a process similar to that of the first embodiment. Further, the n-side ohmic electrode 12 and the n-side pad electrode 13 are formed on the back surface, polished into a prescribed thickness, of the n-type GaN substrate 1 from the side closer to the back surface of the n-type GaN substrate 1, thereby completing the nitride semiconductor laser element according to the nineteenth embodiment shown in FIG. 88.

In the fabrication process for the nitride semiconductor laser element according to the nineteenth embodiment, as hereinabove described, the width of the current passing region 198 can be easily rendered smaller than the width of the p-side ohmic electrode 199 serving as the mask by performing ion implantation a plurality of times while varying the ion implantation angle. Thus, sufficient current narrowing can be performed without carrying out a complicated step of forming a plurality of ion implantation mask layers or the like.

### Twentieth Embodiment

Referring to FIG. 93, an example of forming current narrowing layers by performing heat treatment in a gas phase containing Si thereby diffusing Si atoms in a semiconductor while forming ion-implanted light absorption layers by performing ion implantation is described with reference to this twentieth embodiment. The remaining structure of the twentieth embodiment is similar to that of the first embodiment.

Referring to FIG. 93, an n-type layer 2, an n-type cladding layer 3, an MQW emission layer 4, a p-type cladding layer 5 and a p-type contact layer 6 are formed on an n-type GaN substrate 1 in this order according to this twentieth embodiment, similarly to the first embodiment.

According to the twentieth embodiment, ion-implanted light absorption layers 207a, formed by ion-implanting silicon (Si) excluding a first width of about 1.8 μm, having an implantation depth of about 0.34 μm are provided on partial regions of the p-type cladding layer 5 and the p-type contact layer 6. Silicon is an example of the “first impurity elementn in the present invention, and the ion-implanted light absorption layers 207a are examples of the “light absorption layer” in the present invention. In this case, the peak depth of the concentration of ion-implanted silicon is located in regions of the p-type cladding layer 5 at a depth of about 0.24 μm from the upper surface of the p-type contact layer 6. The silicon concentration at this peak depth is about 1.0×10²⁰ cm⁻³.

Current narrowing layers 207b formed by thermally diffusing Si are provided inside the ion-implanted light absorption layers 207a. These current narrowing layers 207a perform current narrowing with respect to a current injected from a p side, thereby forming a current passing region 208 having a width of about 1.5 μm.

A p-side ohmic electrode 209 is formed on the upper surface of the current passing region 208 of the p-type contact layer 6 with an electrode width of about 2.0 μm in a striped shape, similarly to the first embodiment. Insulator films 210 are formed to cover the side surfaces of the p-side ohmic electrode 209 and the p-type contact layer 6. A p-side pad electrode 211 is formed on the insulator films 210 to be in contact with the upper surface of the p-side ohmic electrode 209. An n-side ohmic electrode 12 and an n-side pad electrode 13 are formed on the back surface of the n-type GaN substrate 1 from the side closer to the back surface of the n-type GaN substrate 1. The thicknesses and compositions of the respective layers 209 to 211 are similar to those of the respective layers 9 to 11 in the first embodiment respectively.

A fabrication process for a nitride semiconductor laser element according to the twentieth embodiment is now described with reference to FIGS. 93 to 97. With reference to this twentieth embodiment, a case of forming the current narrowing layers by thermal diffusion is described.

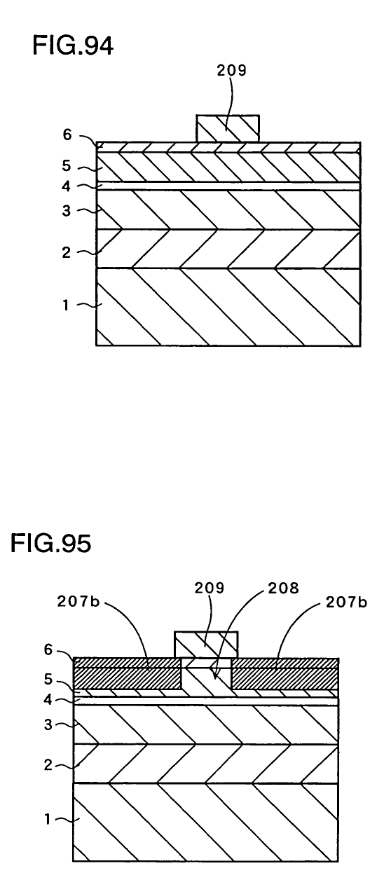

First, the layers up to the p-type contact layer 6 are formed through a process similar to that of the first embodiment shown in FIG. 4. Then, the p-side ohmic electrode 209 consisting of a Pt layer having a thickness of about 1 nm, a Pd layer having a thickness of about 50 nm, an Au layer having a thickness of about 240 nm and an Ni layer having a thickness of about 240 nm in ascending order is formed on the upper surface of the p-type contact layer 6 with the electrode width of about 2.0 μm in the striped shape by a lift-off method, as shown in FIG. 94.

According to the twentieth embodiment, the p-side ohmic electrode 209 is employed as a mask for increasing the substrate temperature to about 750° C. while holding the element in an SiH₄ gas atmosphere thereby thermally diffusing silicon (Si) atoms into the element, as shown in FIG. 95. Thus, the current narrowing layers 207b increased in resistance are formed. The silicon atoms introduced into the element so isotropically diffuse that the width of the current passing region 208 is smaller than that of the p-side ohmic electrode 209 serving as the mask. In this case, the width of the current passing region 208 is about 1.5 μm. Thus, the current narrowing layers 207b are so formed by thermal diffusion that the current narrowing layers 207b can be inhibited from formation of crystal defects.

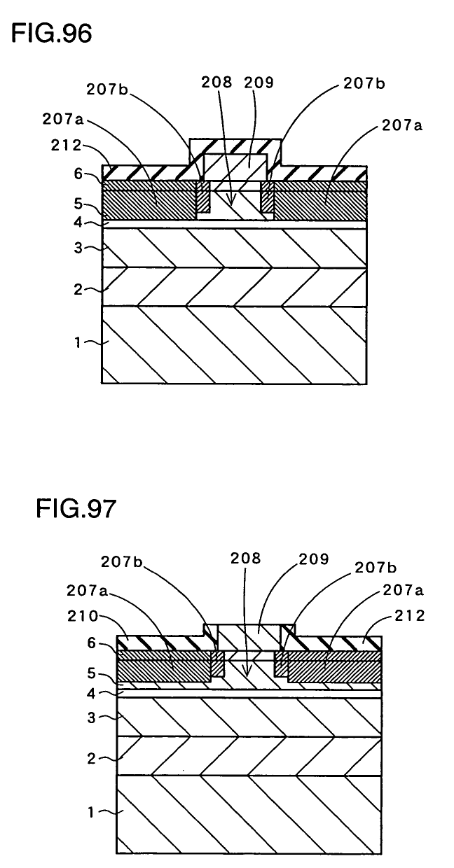

As shown in FIG. 96, a through film 212 of SiO₂ having a thickness of about 60 nm is formed by plasma CVD to cover the overall upper surfaces of the p-side ohmic electrode 209 and the p-type contact layer 6.

According to the twentieth embodiment, the p-side ohmic electrode 209 is employed as the mask for ion-implanting silicon (Si), thereby forming the ion-implanted light absorption layers 207a having the implantation depth (thickness) of about 0.34 μm from the upper surface of the p-type contact layer 6. According to the twentieth embodiment, silicon is ion-implanted under ion implantation conditions of ion implantation energy of about 190 keV and a dose of about 2.5×10¹⁵ cm⁻². In this case, the peak depth of the silicon concentration of the ion-implanted light absorption layers 207a is located in the regions of the p-type cladding layer 5 at the depth of about 0.24 μm from the upper surface of the p-type contact layer 6. The silicon concentration at this peak depth is about 1.0×10²⁰ cm⁻³. Thereafter the through film 212 is removed with a hydrofluoric acid etchant.

As shown in FIG. 97, the insulator films 210 of SiO₂ having a thickness of about 200 nm are formed by plasma CVD to cover the overall upper surfaces of the p-side ohmic electrode 209 and the p-type contact layer 6. The upper surface of the p-side ohmic electrode 209 is exposed by photolithography and RIE with CF₄ gas, similarly to the first embodiment.

Finally, the p-side pad electrode 211 is formed on the insulator films 210 to be in contact with the exposed upper surface of the p-side ohmic electrode 209 through a process similar to that of the first embodiment. Further, the n-side ohmic electrode 12 and the n-side pad electrode 13 are formed on the back surface, polished into a prescribed thickness, of the n-type GaN substrate 1 from the side closer to the back surface of the n-type GaN substrate 1, thereby completing the nitride semiconductor laser element according to the twentieth embodiment as shown in FIG. 93.

In the fabrication process for the nitride semiconductor laser element according to the twentieth embodiment, as hereinabove described, the current narrowing layers 207b increased in resistance are formed by thermally diffusing silicon having reverse conductivity into the p-type cladding layer 5 and the p-type contact layer 6, whereby the number of crystal defects in the vicinity of the current passing region 208 can be prevented from increase. Thus, increase of a threshold current can be suppressed.

### Twenty-First Embodiment

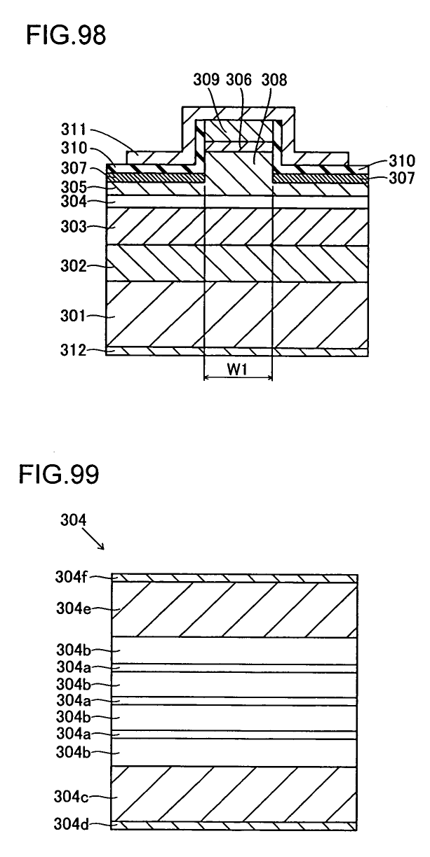

Referring to FIGS. 98 and 99, an example of forming a ridge portion on a p-type cladding layer while forming ion-implanted light absorption layers on regions of this p-type cladding layer other than the ridge portion is described with reference to this twenty-first embodiment.

First, the structure of a nitride semiconductor laser device according to the twenty-first embodiment is described with reference to FIGS. 98 and 99. According to the twenty-first embodiment, an n-type layer 302 of n-type GaN doped with Si having a thickness of about 100 nm and an atomic density of about 5×10¹⁸ cm⁻³ is formed on an n-type GaN substrate 301 doped with oxygen having a thickness of about 100 μm and an atomic density of about 5×10¹⁸ cm⁻³. An n-type cladding layer 303 of n-type Al_{0.05}Ga_{0.95}N doped with Si having a thickness of about 400 nm, an atomic density of about 5×10¹⁸ cm⁻³ and a carrier concentration of about 5×10¹⁸ cm⁻³ is formed on the n-type layer 302. The n-type layer 302 and the n-type cladding layer 303 are examples of the “first nitride semiconductor layer” in the present invention.

An MQW emission layer 304 is formed on the n-type cladding layer 303. This MQW emission layer 304 includes an MQW active layer in which three quantum well layers 304a of undoped In_{0.15}Ga_{0.85}N each having a thickness of about 3 nm and four barrier layers 304b of undoped In_{0.05}G_{0.95}N each having a thickness of about 20 nm are alternately stacked, as shown in FIG. 99. An n-type light guide layer 304c of n-type GaN doped with Si having a thickness of about 100 nm, an atomic density of about 5×10¹⁸ cm⁻³ and a carrier concentration of about 5×10^{11 cm}⁻³ and an n-type carrier blocking layer 304d of n-type Al_{0.1}Ga_{0.9}N doped with Si having a thickness of about 5 nm, an atomic density of about 5×10¹⁸ cm⁻³ and a carrier concentration of about 5×10¹⁸ cm⁻³ are formed on the lower surface of the MQW active layer successively from the side closer to the lower surface of the MQW active layer. Further, a p-type light guide layer 304e of p-type GaN doped with Mg having a thickness of about 100 nm, an atomic density of about 4×10¹⁹ cm⁻³ and a carrier concentration of about 5×10¹⁷ cm⁻³ and a p-type cap layer 304f of p-type Al_{0.1}Ga_{0.9}N doped with Mg having a thickness of about 20 nm, an atomic density of about 4×10¹⁹ cm⁻³ and a carrier concentration of about 5×10¹⁷ cm⁻³ are successively formed on the upper surface of the MQW active layer. The MQW emission layer 304 is an example of the “emission layer” in the present invention.

As shown in FIG. 98, a p-type cladding layer 305 of p-type Al_{0.05}Ga_{0.95}N doped with Mg having a projecting portion with an atomic density of about 4×10¹⁹ cm⁻³ and a carrier concentration of about 5×10¹⁷ cm⁻³ is formed on the MQW emission layer 304. The projecting portion of this p-type cladding layer 305 has a width of about 2 μm and a height of about 250 nm. Regions of the p-type cladding layer 305 other than the projecting portion have a thickness of about 150 nm. A p-type contact layer 306 of p-type GaN doped with Mg having a thickness of about 10 nm, an atomic density of about 4×10¹⁹ cm⁻³ and a carrier concentration of about 5×10¹⁷ cm⁻³ is formed on the projecting portion of the p-type cladding layer 305. The projecting portion of the p-type cladding layer 305 and the p-type contact layer 306 constitute a striped (elongated) ridge portion 308 having a width of about 2 μm and a height of about 260 nm. The p-type cladding layer 305 and the p-type contact layer 306 are examples of the “second nitride semiconductor layer” in the present invention.

According to the twenty-first embodiment, ion-implanted light absorption layers 307, formed by ion-implanting argon (Ar), having an implantation depth (thickness) of about 50 nm are provided on the surfaces of flat portions of the p-type cladding layer 305 other than the projecting portion constituting the ridge portion 308. Side ends of these ion-implanted light absorption layers 307 are substantially arranged immediately under side ends of the ridge portion 308. Therefore, the width (width of optical confinement) W1 between the side ends of the ion-implanted light absorption layers 307 is substantially identical to the width (width of current narrowing) (about 2 μm) of the ridge portion 308. Argon is an example of the “first impurity element” in the present invention, and the ion-implanted light absorption layers 307 are examples of the “light absorption layer” in the present invention.

A p-side ohmic electrode 309 consisting of a Pt layer having a thickness of about 5 nm, a Pd layer having a thickness of about 250 nm and an Au layer having a thickness of about 250 nm in ascending order is formed on the p-type contact layer 306 constituting the ridge portion 308. Insulator films 310 of SiN having a thickness of about 250 nm are formed on the surface of the p-type cladding layer 305 and the side surfaces of the p-type contact layer 306 and the p-side ohmic electrode 309. A p-side pad electrode 311 consisting of a Ti layer having a thickness of about 100 nm, a Pd layer having a thickness of about 100 nm and an Au layer having a thickness of about 3 μm in ascending order is formed on the upper surfaces of the insulator films 310 to be in contact with the upper surface of the p-side ohmic electrode 309. An n-side electrode 312 consisting of an Al layer having a thickness of about 10 nm, a Pt layer having a thickness of about 20 nm and an Au layer having a thickness of about 300 nm successively from the side closer to the back surface of the n-type GaN substrate 301 is formed on the back surface of the n-type GaN substrate 301.

Results obtained by measuring current-light output characteristics and leakage currents of a nitride semiconductor laser element according to the twenty-first embodiment shown in FIG. 98 and a conventional (comparative) nitride semiconductor laser element in order to investigate the difference in performance between these nitride semiconductor laser elements are now described.

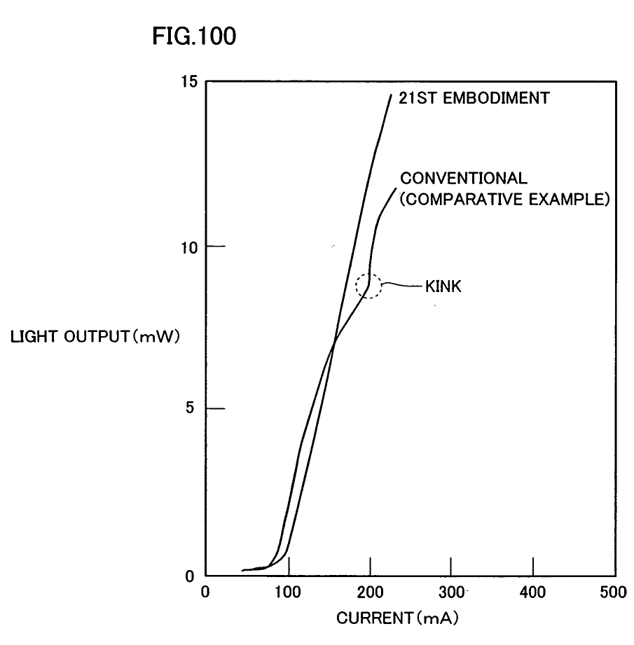

FIG. 100 is a characteristic diagram showing the current-light output characteristics of the nitride semiconductor laser element according to the twenty-first embodiment shown in FIG. 98 and the conventional (comparative) nitride semiconductor laser element. Referring to FIG. 100, the maximum light output is limited to about 9 mW due to outbreak of kinks in the conventional (comparative) nitride semiconductor laser element. On the other hand, it has been proved that a light output of at least 9 mW corresponding to the maximum light output of the conventional (comparative) example can be obtained with no kinks in the nitride semiconductor laser element according to the twenty-first embodiment. This is conceivably because the transverse mode was stabilized due to transverse optical confinement through the ion-implanted light absorption layers 307.

Table 1 shows the results obtained by measuring the leakage currents of the twenty-first embodiment shown in FIG. 98 and the conventional (comparative) nitride semiconductor laser element.

TABLE 1

| | Applied Voltage | Leakage Current |
|---|---|---|
| Conventional | About 10 V | About 1 μA ˜ about 2 μA |
| (Comparative Example) | | |
| 21st Embodiment | At least | Not more than about 0.1 μA |
| | about 10 V | |

Referring to the above Table 1, a leakage current of about 1 μA to about 2 μA was generated in the conventional (comparative) nitride semiconductor laser element when a voltage of about 10 V was applied. In the nitride semiconductor laser element according to the twenty-first embodiment, on the other hand, only a leakage current of not more than about 0.1 μm was generated also when a voltage of at least about 10 V was applied.

In the nitride semiconductor laser element according to the twenty-first embodiment, as hereinabove described, the ion-implanted light absorption layers 307 formed by ion implantation are so provided on the surface portions of the p-type cladding layer 305 other than the projecting portion constituting the ridge portion 308 that the ion-implanted light absorption layers 307 can be formed on the surface portions of the p-type cladding layer 305 other than the projecting portion constituting the ridge portion 308 with excellent reproducibility since ion implantation provides excellent reproducibility. Thus, transverse optical confinement can be controlled with excellent reproducibility. Consequently, the transverse mode can be stabilized with excellent reproducibility while performing current narrowing through the ridge portion 308. Further, the transverse mode can be so stabilized that outbreak of kinks (bending of the current-light output characteristics) resulting from higher mode oscillation can be suppressed. Thus, a high maximum light output can be obtained while the beam shape can be stabilized.

The ion-implanted light absorption layers 307 are so provided only on the surfaces of the flat portions of the p-type cladding layer 305 that a portion having high light intensity in the vicinity of the MQW emission layer 304 can be inhibited from excess light absorption, whereby increase of the threshold current can be suppressed.

A fabrication process for the nitride semiconductor laser element according to the twenty-first embodiment is now described with reference to FIGS. 98, 99 and 101 to 105.

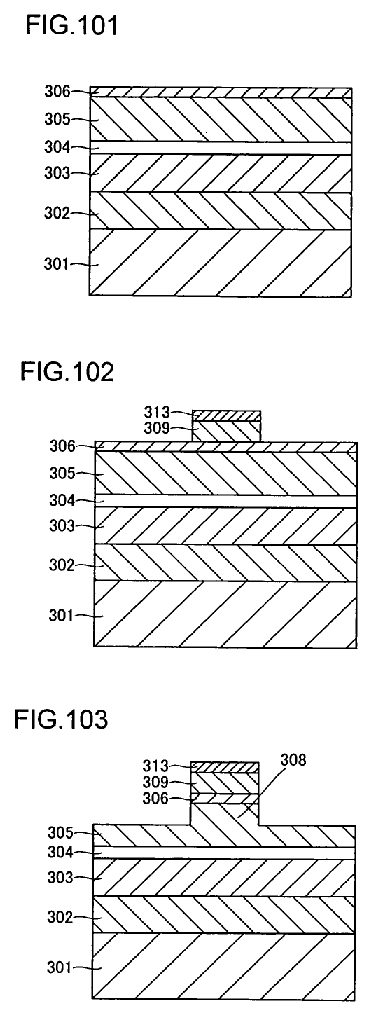

First, the n-type layer 302, the n-type cladding layer 303, the MQW emission layer 304, the p-type cladding layer 305 and the p-type contact layer 306 are successively grown on the n-type GaN substrate 301 by atmospheric pressure CVD under a pressure of about 1 atom (about 100 kPa), as shown in FIG. 101. The n-type GaN substrate 301 is formed by growing GaN on a GaAs substrate by HVPE and thereafter removing the GaAs substrate having a thickness of not more than 100 μm.

More specifically, the n-type GaN substrate 301 is held at a growth temperature of about 1100° C. for growing the n-type layer 302 of n-type GaN doped with Si having the thickness of about 100 nm and the atomic density of about 5×10¹⁸ cm⁻³ on the n-type GaN substrate 301 with carrier gas consisting of H₂ and N₂, source gas consisting of NH₃ and Ga(CH₃)₃ and dopant gas consisting of SiH₄. Thereafter Al(CH₃)₃ is further added to the source gas for growing the n-type cladding layer 303 of n-type Al_{0.05}Ga_{0.95}N doped with Si having the thickness of about 400 nm, the atomic density of about 5×10¹⁸ cm⁻³ and the carrier concentration of about 5×10¹⁸ cm⁻³ on the n-type layer 302.

As shown in FIG. 99, the n-type carrier blocking layer 304d of n-type Al_{0.1}Ga_{0.9}N doped with Si having the thickness of about 5 nm, the atomic density of about 5×10¹⁸ cm⁻³ and the carrier concentration of about 5×10¹⁸ cm⁻³ is grown on the n-type cladding layer 303 (see FIG. 101).

Then, the substrate temperature is held at a growth temperature of 800° C. for growing the n-type light guide layer 304c of n-type GaN doped with Si having the atomic density of about 5×10¹⁸ cm⁻³ and the carrier concentration of about 5×10¹⁸ cm⁻³ on the n-type carrier blocking layer 304d with carrier gas consisting of H₂ and N₂, source gas consisting of NH₃ and Ga(CH₃)₃ and dopant gas consisting of SiH₄.

Thereafter In(CH₃)₃ is further added to the source gas for alternately growing the three quantum well layers 304a of undoped In_{0.15}Ga_{0.85}N each having the thickness of about 3 nm and the four barrier layers 304b of undoped In_{0.05}G_{0.95}N each having the thickness of about 20 nm on the n-type light guide layer 304c without employing dopant gas thereby forming the MQW active layer.

The source gas is changed to NH₃ and Ga(CH₃)₃ while employing dopant gas consisting of CP₂Mg for growing the p-type light guide layer 304e of p-type GaN doped with Mg having the thickness of about 100 nm, the atomic density of about 4×10¹⁹ cm⁻³ and the carrier concentration of about 5×10¹⁷ cm⁻³ on the MQW active layer. Thereafter Al(CH₃)₃ is further added to the source gas for growing the p-type cap layer 304f of p-type Al_{0.1}Ga_{0.9}N doped with Mg having the thickness of about 20 nm, the atomic density of about 4×10¹⁹ cm⁻³ and the carrier concentration of about 5×10¹⁷ cm⁻³ on the p-type light guide layer 304e. Thus, the MQW emission layer 304 consisting of the quantum well layers 304a, the barrier layers 304b, the n-type light guide layer 304c, the n-type carrier blocking layer 304d, the p-type light guide layer 304e and the p-type cap layer 304f is formed.

As shown in FIG. 101, the substrate temperature is held at a growth temperature of 1100° C. for growing the p-type cladding layer 305 of p-type Al_{0.05}Ga_{0.95}N doped with Mg having the thickness of about 400 nm, the atomic density of about 4×10¹⁹ cm⁻³ and the carrier concentration of about 5×10¹⁷ cm⁻³ on the MQW emission layer 304 with carrier gas consisting of H₂ and N₂, source gas consisting of NH₃, Ga(CH₃)₃ and Al(CH₃)₃ and dopant gas consisting of CP₂Mg. Thereafter the source gas is changed to NH₃ and Ga(CH₃)₃ for growing the p-type contact layer 306 of p-type GaN doped with Mg having the thickness of about 10 nm, the atomic density of about 4×10¹⁹ cm⁻³ and the carrier concentration of about 5×10¹⁷ cm⁻³ on the p-type cladding layer 305.

Thereafter annealing is performed in a nitrogen gas atmosphere under a temperature condition of about 800° C.

As shown in FIG. 102, the p-side ohmic electrode 309 consisting of the Pt layer having the thickness of about 5 nm, the Pd layer having the thickness of about 250 nm and the Au layer having the thickness of about 250 nm in ascending order and an Ni layer 313 having a thickness of about 250 nm are successively formed on the p-type contact layer 306, and the p-side ohmic electrode 309 and the Ni layer 313 are thereafter patterned into striped (elongated) shapes having a width of about 2 μm.

As shown in FIG. 103, the Ni layer 313 is employed as a mask for dry-etching portions of the p-type contact layer 306 and the p-type cladding layer 305 having a thickness of about 250 nm from the upper surfaces with Cl₂ gas. Thus, the striped (elongated) ridge portion 308, constituted of the projecting portion of the p-type cladding layer 305 and the p-type contact layer 306, having the width of about 2 μm and the height of about 260 nm is formed. Thereafter the Ni layer 313 is removed.

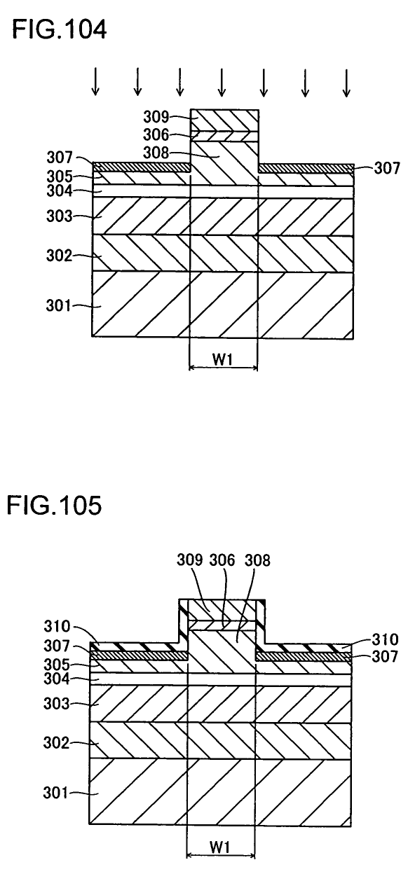

According to the twenty-first embodiment, the p-side ohmic electrode 309 is employed as a mask for ion-implanting argon (Ar) into the flat portions of the p-type cladding layer 305 other than the projecting portion constituting the ridge portion 308 thereby forming the ion-implanted light absorption layers 307 having the ion implantation depth (thickness) of about 50 nm, as shown in FIG. 104. At this time, the p-side ohmic electrode 309 having the width (about 2 μm) substantially identical to that of the ridge portion 308 is so employed as the mask that the side ends of the ion-implanted light absorption layers 307 are substantially arranged immediately under the side ends of the ridge portion 308 while the width (width of optical confinement) WI between the side ends of the ion-implanted light absorption layers 307 is about 2 μm. Ion implantation conditions for argon are implantation energy of about 40 keV, a dose of about 1×10¹² cm⁻² to about 1×10¹³ cm⁻² and an implantation temperature of the room temperature. Ion implantation is performed from a direction inclined by about 70 in the longitudinal direction of the p-side ohmic electrode 309.

As shown in FIG. 105, the insulator films 310 of SiN having the thickness of about 250 nm are thereafter formed to cover the overall surface and a portion of the insulator films 310 located on the upper surface of the p-side ohmic electrode 309 is removed. Thus, the upper surface of the p-side ohmic electrode 309 is exposed.

Finally, the p-side pad electrode 311 consisting of the Ti layer having the thickness of about 100 nm, the Pd layer having the thickness of about 100 nm and the Au layer having the thickness of about 3 μm in ascending order is formed on the upper surfaces of the insulator films 310 by vacuum evaporation to be in contact with the upper surface of the p-side ohmic electrode 309, as shown in FIG. 98. Further, the n-side electrode 312 consisting of the Al layer having the thickness of about 10 nm, the Pt layer having the thickness of about 20 nm and the Au layer having the thickness of about 300 nm successively from the side closer to the back surface of the n-type GaN substrate 301 is formed on the back surface of the n-type GaN substrate 301 by vacuum evaporation. Thus, the nitride semiconductor laser element according to the twenty-first embodiment is completed.

In the fabrication process for the nitride semiconductor laser element according to the twenty-first embodiment, as hereinabove described, the ridge portion 308 is formed before forming the ion-implanted light absorption layers 307 by ion-implanting argon (Ar) so that the implantation depth may not be increased, whereby the implantation energy can be reduced to about 40 keV. Thus, the spreading width of the impurity profile can be so reduced that the implantation depth can be precisely controlled. Consequently, the impurity element (argon) can be prevented from reaching the MQW emission layer 304, whereby the MQW emission layer 304 can be prevented from damage by the impurity element (argon).

### Twenty-Second Embodiment

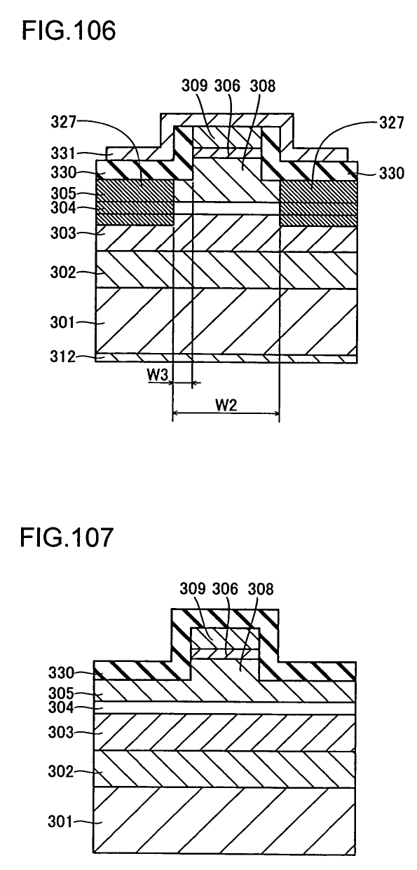

Referring to FIG. 106, an example of increasing the width between side ends of ion-implanted light absorption layers (width of optical confinement) beyond the width of a ridge portion (width of current narrowing) while setting an ion implantation depth to a level reaching an n-type cladding layer dissimilarly to the twenty-first embodiment is described with reference to this twenty-second embodiment. The remaining structure of the twenty-second embodiment is similar to that of the twenty-first embodiment.

Referring to FIG. 106, an n-type layer 302, an n-type cladding layer 303, an MQW emission layer 304, a p-type cladding layer 305 and a p-type contact layer 306 are successively formed on an n-type GaN substrate 301 according to this twenty-second embodiment, similarly to the twenty-first embodiment. A projecting portion of the p-type cladding layer 305 and the p-type contact layer 306 constitute a striped (elongated) ridge portion 308 having a width of about 2 μm and a height of about 260 nm.

According to the twenty-second embodiment, ion-implanted light absorption layers 327, formed by ion-implanting carbon (C), having an implantation depth (thickness) of about 300 nm are provided. These ion-implanted light absorption layers 327 are formed over the surfaces of flat portions of the p-type cladding layer 305 other than the projecting portion constituting the ridge portion 308 to the MQW emission layer 304 and the n-type cladding layer 303. Further, the side ends of the ion-implanted light absorption layers 327 are arranged on positions transversely separated from the side ends of the ridge portion 308 by the thickness (not more than about 2 μm) of insulator films 330 described later. Therefore, the width W2 (width of optical confinement) between the side ends of the ion-implanted light absorption layers 327 has a size (not more than about 6 μm) larger than the width (width of current narrowing) (about 2 μm) of the ridge portion 308. Further, the peak depth of the impurity concentration of the ion-implanted light absorption layers 327 is located in portions of the p-type cladding layer 305 at about 130 nm from the surfaces of the flat portions of the p-type cladding layer 305 other than the projecting portion constituting the ridge portion 308. The ion-implanted light absorption layers 327 are examples of the “light absorption layer” in the present invention.

A p-side ohmic electrode 309 is formed on the p-type contact layer 306 constituting the ridge portion 308. The insulator films 330 of SiO₂ also having a function as masks for ion implantation are formed on the surface of the p-type cladding layer 305 and the side surfaces of the p-type contact layer 306 and the p-side ohmic electrode 309. The thickness of these insulator films 330 is not more than about 2 μm, substantially identically to the width W3 between the side ends of the ridge portion 308 and the side ends of the ion-implanted light absorption layers 327. A p-side pad electrode 331 having a thickness and a composition similar to those in the twenty-first embodiment is formed on the upper surfaces of the insulator films 330 to be in contact with the upper surface of the p-side ohmic electrode 309. An n-side electrode 312 is formed on the back surface of the n-type GaN substrate 301.

Results obtained by measuring aspect ratios of beams in order to investigate difference between beam shapes according near field patterns of an ion-implanted nitride semiconductor laser element according to the twenty-second embodiment shown in FIG. 106 and a conventional (comparative) non-ion-implanted nitride semiconductor laser element are now described. Table 2 shows the results of this measurement.

TABLE 2

| | | Dose: about | Dose: about |
|---|---|---|---|
| | | 1 × 10¹³ cm⁻² | 1 × 10¹⁴ cm⁻² |
| | Non- | Implanted Ions: | Implanted Ions: |
| | Implanted | Carbon (C) | Carbon (C) |
| Aspect Ratio | 4:1 | 2:1 | 1:1 |
| (transverse: | | | |
| longitudinal) | | | |

Referring to the above Table 2, the aspect ratio (transverse:longitudinal) of the beam was 4:1 in the conventional (comparative) non-ion-implanted nitride semiconductor laser element. In the ion-implanted nitride semiconductor laser element according to the twenty-second embodiment, on the other hand, the aspect ratio (transverse:longitudinal) of the beam was 2:1 when the dose was about 1×10¹³ cm⁻². Further, the aspect ratio (transverse:longitudinal) of the beam was 1:1 when the dose was about 1×10¹⁴ cm⁻². This is conceivably because transverse spreading of light was suppressed due to transverse optical confinement through the ion-implanted light absorption layers 327. Further, light absorption is increased as the dose is increased, and hence the aspect ratio is conceivably improved so that the beam approaches a true circle.

In the nitride semiconductor laser element according to the twenty-second embodiment, as hereinabove described, the width W2 (width of optical confinement) between the side ends of the ion-implanted light absorption layers 327 is rendered larger than the width (about 2 μm) of the ridge portion 308 so that the portion having high light intensity in the vicinity of the MQW emission layer 304 can be inhibited from excess light absorption while current narrowing can be strengthened. Thus, transverse optical confinement of the MQW emission layer 304 can be excellently performed while further suppressing increase of the threshold current. Consequently, the transverse mode can be so further stabilized that the beam shape can be further stabilized. Further, outbreak of kinks (bending of current-light output characteristics) resulting from higher mode oscillation can be so further suppressed that a higher maximum light output can be obtained.

According to the twenty-second embodiment, further, the ion-implanted light absorption layers 327 formed by ion implantation are so provided on the regions of the p-type cladding layer 305 other than the projecting portion constituting the ridge portion 308 that the ion-implanted light absorption layers 327 can be formed with excellent reproducibility, whereby transverse optical confinement can be controlled with excellent reproducibility. Consequently, the transverse mode can be stabilized with excellent reproducibility while performing current narrowing through the ridge portion 308.

A fabrication process for the nitride semiconductor laser element according to the twenty-second embodiment is now described with reference to FIGS. 106 to 109.

First, the layers up to the striped (elongated) ridge portion 308, constituted of the projecting portion of the p-type cladding layer 305 and the p-type contact layer 306, having the width of about 2 μm and the height of about 260 nm are formed as shown in FIG. 107 through a fabrication process similar to that of the twenty-first embodiment shown in FIGS. 101 to 103. Thereafter the insulator film 330 of SiO₂ having the thickness of not more than about 2 μm is formed to cover the overall surface.

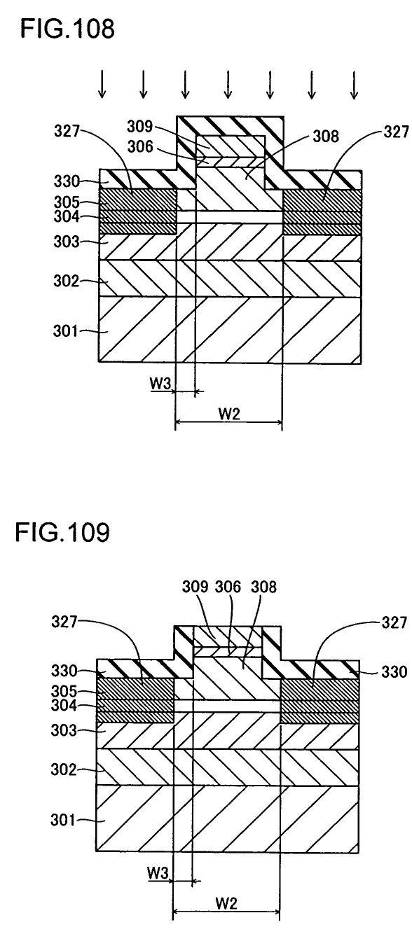

According to the twenty-second embodiment, the insulator film 330 is employed as a mask for ion-implanting carbon (C), as shown in FIG. 108. Thus, the ion-implanted light absorption layers 327 having the ion implantation depth (thickness) of about 300 nm are formed over the surfaces of the flat portions of the p-type cladding layer 305 other than the projecting portion constituting the ridge portion 308 to the MQW emission layer 304 and the n-type cladding layer 303. At this time, not only the portion of the insulator film 330 located on the upper surface of the ohmic electrode 309 but also the portions located on the side ends of the ridge portion 308 form the mask, whereby the side ends of the ion-implanted light absorption layers 327 are formed on the positions transversely separated from the side ends of the ridge portion 308 by the thickness (not more than about 2 μm) of the insulator film 330. Therefore, the width (width of optical confinement) W2 between the side ends of the ion-implanted light absorption layers 327 exceeds the width (width of current narrowing) (about 2 μm) of the ridge portion 308 while the width W3 between the side ends of the ridge portion 308 and the side ends of the ion-implanted light absorption layers 327 is not more than about 2 μm. Further, the peak depth of the impurity concentration of the ion-implanted light absorption layers 327 is located in the portions of the p-type cladding layer 305 at about 130 nm from the surfaces of the flat portions of the p-type cladding layer 305 other than the projecting portion constituting the ridge portion 308. Ion implantation conditions for carbon are implantation energy of about 95 keV, a dose of about 1×10¹³ cm⁻² to about 1×10¹⁴ cm⁻² and an implantation temperature of the room temperature. This ion implantation is performed from a direction inclined by about 70 in the longitudinal direction of the p-side ohmic electrode 309.

Thereafter the portion of the insulator film 330 located on the upper surface of the p-side ohmic electrode 309 is removed, as shown in FIG. 109. Thus, the upper surface of the p-side ohmic electrode 309 is exposed.

Finally, the p-side pad electrode 331 having the thickness and the composition similar to those in the twenty-first embodiment is formed on the upper surfaces of the insulator films 330 to be in contact with the upper surface of the p-side ohmic electrode 309, as shown in FIG. 106. Further, the n-side electrode 312 is formed on the back surface of the n-type GaN substrate 301. Thus, the nitride semiconductor laser element according to the twenty-second embodiment is completed.

### Twenty-Third Embodiment

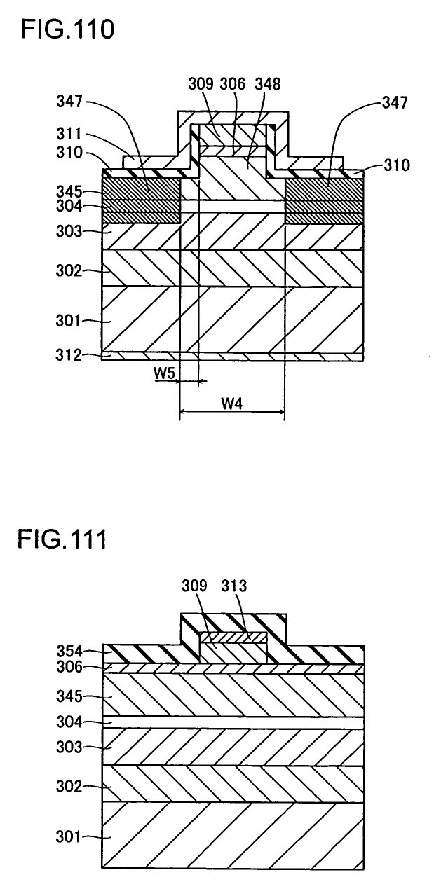

Referring to FIG. 110, an example of forming a ridge portion after ion implantation dissimilarly to the aforementioned twenty-first and twenty-second embodiments is described with reference to this twenty-third *embodiment. The remaining structure of the twenty-third embodiment is similar to that of the twenty-first embodiment.

Referring to FIG. 110, an n-type layer 302, an n-type cladding layer 303 and an MQW emission layer 304 are successively formed on an n-type GaN substrate 301 according to this twenty-third embodiment, similarly to the twenty-first embodiment.

According to the twenty-third embodiment, a p-type cladding layer 345 of p-type Al_{0.05}Ga_{0.95}N doped with Mg having a projecting portion is formed on the MQW emission layer 304. The projecting portion of this p-type cladding layer 345 has a width of about 2 μm and a height of about 260 nm. Further, flat portions of the p-type cladding layer 345 other than the projecting portion have a thickness of about 140 nm. A p-type contact layer 306 is formed on the projecting portion of the p-type cladding layer 345. The projecting portion of the p-type cladding layer 345 and the p-type contact layer 306 constitute a striped (elongated) ridge portion 348 having a width of about 2 μm and a height of about 270 nm. The p-type cladding layer 345 is an example of the “second nitride semiconductor layer” in the present invention.

According to the twenty-third embodiment, ion-implanted light absorption layers 347, formed by ion-implanting carbon (C), having an implantation depth (thickness) of about 240 nm are provided. These ion-implanted light absorption layers 347 are formed over the surfaces of the flat portions of the p-type cladding layer 345 other than the projecting portion constituting the ridge portion 348 to the MQW emission layer 304 and the n-type cladding layer 303. Further, the side ends of the ion-implanted light absorption layers 347 are arranged on positions transversely separated from the side ends of the ridge portion 348 by the thickness (not more than about 2 μm) of an ion implantation mask 354 described later. Therefore, the width (width of optical confinement) W4 between the side ends of the ion-implanted light absorption layers 347 has a size (not more than about 6 μm) larger than the width (width of current narrowing) (about 2 μm) of the ridge portion 348. The peak depth of the impurity concentration of the ion-implanted light absorption layers 347 is located on the surfaces of the flat portions of the p-type cladding layer 345 other than the projecting portion constituting the ridge portion 348. The ion-implanted light absorption layers 347 are examples of the “light absorption layer” in the present invention.

A p-side ohmic electrode 309 is formed on the p-type contact layer 306 constituting the ridge portion 348. Insulator films 310 are formed on the surface of the p-type cladding layer 345 and the side surfaces of the p-type contact layer 306 and the p-side ohmic electrode 309. A p-side pad electrode 311 is formed on the upper surfaces of the insulator films 310 to be in contact with the upper surface of the p-side ohmic electrode 309. An n-side electrode 312 is formed on the back surface of the n-type GaN substrate 301.

In a nitride semiconductor laser element according to the twenty-third embodiment, as hereinabove described, the peak depth of the impurity concentration of the ion-implanted light absorption layers 347 is located on the surfaces of the flat portions of the p-type cladding layer 345 other than the projecting portion constituting the ridge portion 348 so that a portion having high light intensity in the vicinity of the MQW emission layer 304 can be inhibited from excess light absorption, whereby increase of the threshold current can be suppressed.

The remaining effects of the twenty-third embodiment are similar to those of the twenty-second embodiment.

A fabrication process for the nitride semiconductor laser element according to the twenty-third embodiment is now described with reference to FIGS. 110 to 114.

First, the n-type layer 302, the n-type cladding layer 303 and the MQW emission layer 304 are successively formed on the n-type GaN substrate 301 through a fabrication process similar to that of the first embodiment, as shown in FIG. 111. Then, the p-type cladding layer 345 of p-type Al_{0.05}Ga_{0.95}N having a thickness of about 400 nm and the p-type contact layer 306 are successively formed on the MQW emission layer 304. Thereafter annealing is performed in a nitrogen gas atmosphere under a temperature condition of about 800° C. Then, the p-side ohmic electrode 309 and an Ni layer 313 are successively formed on the p-type contact layer 306, and the p-side ohmic electrode 309 and the Ni layer 313 are thereafter patterned into striped (elongated) shapes having a width of about 2 μm. Then, the ion implantation mask 354 of SiO₂ having the thickness of not more than about 2 μm is formed to cover the overall surface.

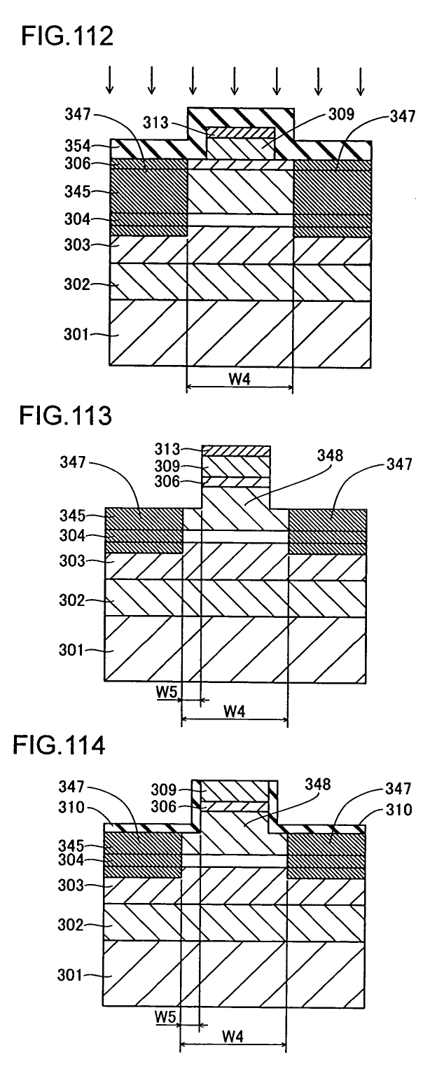

According to the twenty-third embodiment, the ion implantation mask 354 is employed as a mask for ion-implanting carbon (C), as shown in FIG. 112. Thus, the ion-implanted light absorption layers 347 having an ion implantation depth (thickness) of about 510 nm are formed over the upper surface portion of the p-type contact layer 306 other than the region formed with the p-side ohmic electrode 309 to the MQW emission layer 304 and the n-type cladding layer 303. At this time, not only the portion of the ion implantation mask 354 located on the upper surface of the Ni layer 313 but also portions located on the side ends of the p-side ohmic electrode 309 and the Ni layer 313 form the mask, whereby the side ends of the ion-implanted light absorption layers 347 are formed on positions transversely separated from the side ends of the p-side ohmic electrode 309 and the Ni layer 313 by the thickness (not more than about 2 μm) of the ion implantation mask 354. Therefore, the width (width of optical confinement) W4 between the side ends of the ion-implanted light absorption layers 347 exceeds the width (about 2 μm) of the p-side ohmic electrode 309 and the Ni layer 313. Further, the peak depth of the impurity concentration of the ion-implanted light absorption layers 347 is located in portions of the p-type cladding layer 345 at about 270 nm from the upper surface of the p-type contact layer 306 other than the region formed with the p-side ohmic electrode 309. Ion implantation conditions for carbon are implantation energy of about 190 keV, a dose of about 1×10¹³ cm⁻² to about 1×10¹⁴ cm⁻² and an implantation temperature of the room temperature. This ion implantation is performed from a direction inclined by about 70 in the longitudinal direction of the p-side ohmic electrode 309. Thereafter the ion implantation mask 354 is removed.

As shown in FIG. 113, the Ni layer 313 is employed as a mask for partially dry-etching the p-type contact layer 306 and the p-type cladding layer 345 by a thickness of about 260 nm from the upper surfaces with Cl₂ gas. Thus, the striped (elongated) ridge portion 348, constituted of the projecting portion of the p-type cladding layer 345 and the p-type contact layer 306, having the width of about 2 μm and the height of about 270 nm is formed. According to this etching, the peak depth of the impurity concentration of the ion-implanted light absorption layers 347 having Gaussian distribution is located on the surfaces of the flat portions of the p-type cladding layer 345 other than the projecting portion constituting the ridge portion 348. Further, the width (width of optical confinement) W4 between the side ends of the ion-implanted light absorption layers 347 has the size (not more than about 6 μm) larger than the width (width of current narrowing) (about 2 μm) of the ridge portion 348, while the width W5 between the side ends of the ridge portion 348 and the side ends of the ion-implanted light absorption layers 347 is substantially identical to the thickness (not more than about 2 μm) of the ion implantation mask 354 (see FIG. 112). Thereafter the Ni layer 313 is removed.

Then, the insulator films 310 are formed to cover the overall surface and the portion of the insulator films 310 located on the upper surface of the p-side ohmic electrode 309 is thereafter removed, as shown in FIG. 114. Thus, the upper surface of the p-side ohmic electrode 309 is exposed.

Finally, the p-side pad electrode 311 is formed on the upper surfaces of the insulator films 310 to be in contact with the upper surface of the p-side ohmic electrode 309, as shown in FIG. 110. Further, the n-side electrode 312 is formed on the back surface of the n-type GaN substrate 301. Thus, the nitride semiconductor laser element according to the twenty-third embodiment is completed.

In the fabrication process for the nitride semiconductor laser element according to the twenty-third embodiment, as hereinabove described, the ridge portion 348 is formed by forming the ion-implanted light absorption layers 347 over the upper surface of the p-type contact layer 306 to the MOW emission layer 304 and the n-type cladding layer 303 and thereafter performing etching up to the peak depth of the impurity concentration of the ion-implanted light absorption layers 347, whereby the depth of the impurity concentration of the ion-implanted light absorption layers 347 having the Gaussian distribution can be easily located on the surface portions of the p-type cladding layer 347. Further, the spreading width of the impurity profile is increased due to the high implantation energy of about 190 keV. Thus, the profile in the vicinity of the peak depth of the impurity (carbon) concentration can be flattened, whereby the light absorption function of the ion-implanted light absorption layers 347 can be flattened (uniformized). Consequently, transverse optical confinement can be stabilized.

### Twenty-Fourth Embodiment

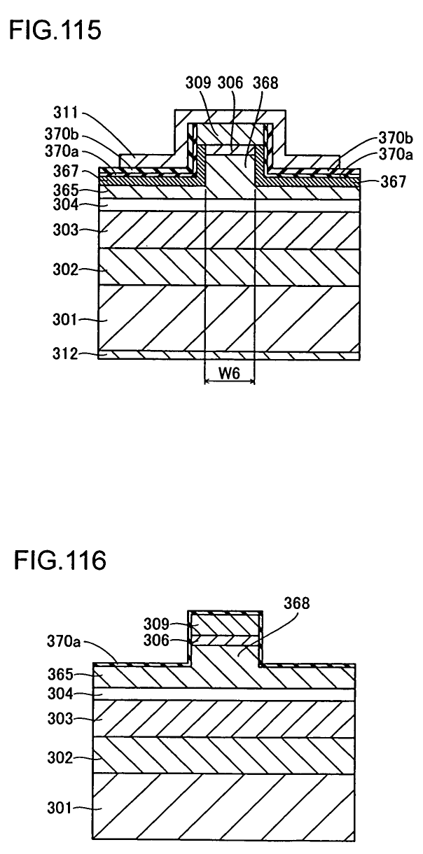

Referring to FIG. 115, an example of forming ion-implanted light absorption layers on both side portions of a ridge portion and flat portions of a p-type cladding layer other than a projecting portion constituting the ridge portion dissimilarly to the aforementioned twenty-first to twenty-third embodiment is described with reference to this twenty-fourth embodiment. The remaining structure of the twenty-fourth embodiment is similar to that of the twenty-first embodiment.

Referring to FIG. 115, an n-type layer 302, an n-type cladding layer 303 and an MQW emission layer 304 are successively formed on an n-type GaN substrate 301 in this twenty-fourth embodiment, similarly to the twenty-first embodiment.

A p-type cladding layer 365 of p-type Al_{0.05}Ga_{0.95}N doped with Mg having a projecting portion is formed on the MQW emission layer 304. The projecting portion of this p-type cladding layer 365 has a width of about 2 μm and a height of about 300 nm. Further, flat portions of the p-type cladding layer 365 other than the projecting portion are formed in a striped (elongated) shape having a thickness of about 100 nm. A p-type contact layer 306 is formed on the projecting portion of the p-type cladding layer 365. The projecting portion of the p-type cladding layer 365 and the p-type contact layer 306 constitute a striped (elongated) ridge portion 368 having a width of about 2 μm and a height of about 310 nm. The p-type cladding layer 365 is an example of the “second nitride semiconductor layer” in the present invention.

According to the twenty-fourth embodiment, ion-implanted light absorption layers 367, formed by ion-implanting carbon (C), having longitudinal and transverse implantation depths (thicknesses) of about 200 nm are provided on both side surfaces of the ridge portion 368 and the flat portions of the p-type cladding layer 365 other than the projecting portion. Therefore, the width (width of optical confinement) W6 between side ends of the ion-implanted light absorption layers 367 has a size (about 1.6 μm) smaller than the width (about 2 μm) of the ridge portion 368. The ion-implanted light absorption layers 367 are examples of the “light absorption layer” in the present invention.

A p-side ohmic electrode 309 is formed on the p-type contact layer 306 constituting the ridge portion 368. Channeling prevention films 370a of SiN having a thickness of about 40 nm are formed on the surface of the p-type cladding layer 365 and the side surfaces of the p-type contact layer 306 and the p-side ohmic electrode 309. These channeling prevention films 370a have a function of suppressing channeling in an ion implantation process. Insulator films 370b of SiN having a thickness of about 210 nm are formed on the surfaces of the channeling prevention films 370a. A p-side pad electrode 311 is formed on the upper surfaces of the insulator films 370b to be in contact with the upper surface of the p-side ohmic electrode 309. An n-side electrode 312 is formed on the back surface of the n-type GaN substrate 301.

In a nitride semiconductor laser element according to the twenty-fourth embodiment, as hereinabove described, the ion-implanted light absorption layers 367 are provided on both side surfaces of the ridge portion 368 and the flat portions of the p-type cladding layer 365 other than the projecting portion so that transverse optical confinement can be excellently performed through both side surfaces of the ridge portion 368 and the flat portions of the ridge portion 368 of the p-type cladding layer 365.

The remaining effects of the twenty-fourth embodiment are similar to those of the twenty-first embodiment.

A fabrication process for the nitride semiconductor laser element according to the twenty-fourth embodiment is now described with reference to FIGS. 115 to 118.

As shown in FIG. 116, the n-type layer 302, the n-type cladding layer 303 and the MQW emission layer 304 are successively formed on the n-type GaN substrate 301 through a fabrication process similar to that of the twenty-first embodiment. The p-type cladding layer 365 of p-type Al_{0.05}Ga_{0.95}N doped with Mg having a thickness of about 400 nm and the p-type contact layer 306 are successively formed on the MQW emission layer 304. Thereafter annealing is performed in a nitrogen gas atmosphere under a temperature condition of about 800° C. Then, the p-side ohmic electrode 309 and an Ni layer (not shown) are successively formed on the p-type contact layer 306, and the p-side ohmic electrode 309 and the Ni layer are thereafter patterned into striped (elongated) shapes having a width of about 2 μm. Then, the Ni layer is employed as a mask for partially etching the p-type contact layer 306 and the p-type cladding layer 365 by a thickness of about 300 nm from the upper surfaces. Thus, the striped (elongated) ridge portion 368, constituted of the projecting portion of the p-type cladding layer 365 and the p-type contact layer 306, having the width of about 2 μm and the height of about 310 nm is formed. Then, the Ni layer is removed and the channeling prevention films 370a of SiN having the thickness of about 40 nm are thereafter formed to cover the overall surface.

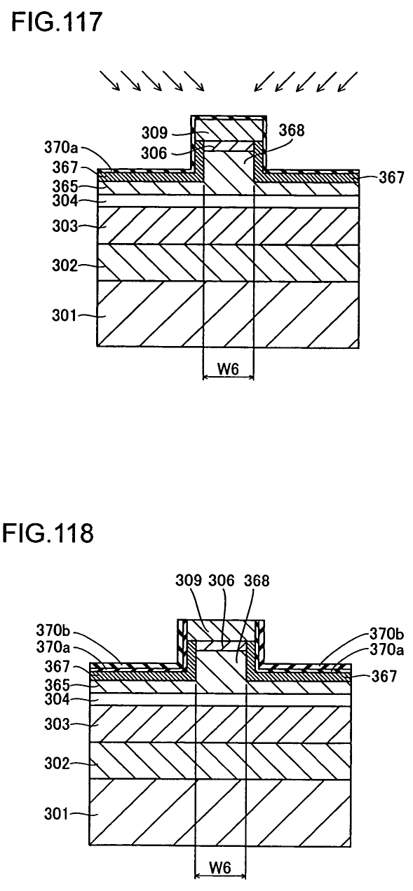

According to the twenty-fourth embodiment, the p-side ohmic electrode 309 is employed as a mask for ion-implanting carbon (C) through the channeling prevention films 370a, as shown in FIG. 117. At this time, ion implantation is performed from an oblique direction of 45° once each time so that ions are implanted into both side portions of the ridge portion 368. Thus, the ion-implanted light absorption layers 367 having the longitudinal and transverse implantation depths (thicknesses) of about 200 nm are formed on both side surfaces of the ridge portion 368 and the flat portions of the p-type cladding layer 365 other than the projecting portion. Further, the width (width of optical confinement) W6 between the side ends of the ion-implanted light absorption layers 367 is about 1.6 μm. In addition, ion-implanted regions are so increased in resistance that the current narrowing width also reaches the width W6. Ion implantation conditions for carbon are implantation energy of about 95 keV, a dose of about 1×10¹³ cm⁻² to about 1×10¹⁴ cm⁻² and an implantation temperature of the room temperature.

Thereafter the insulator films 370b of SiN having the thickness of about 210 nm are formed to cover the overall surface and portions of the channeling prevention layers 370a and the insulator films 370b located on the upper surface of the p-side ohmic electrode 309 are removed, as shown in FIG. 118. Thus, the upper surface of the p-side ohmic electrode 309 is exposed.

Finally, the p-side pad electrode 311 is formed on the upper surfaces of the insulator films 370b to be in contact with the upper surface of the p-side ohmic electrode 309. Further, the n-side electrode 312 is formed on the back surface of the n-type GaN substrate 301. Thus, the nitride semiconductor laser element according to the twenty-fourth embodiment is completed.

In the fabrication process for the nitride semiconductor laser element according to the twenty-fourth embodiment, as hereinabove described, the ridge portion 368 is formed before forming the ion-implanted light absorption layers 367 by ion-implanting carbon (C) so that the implantation depth may not be increased, whereby the implantation energy can be reduced to about 95 keV. Thus, the impurity element (carbon) can be prevented from reaching the MQW emission layer 304 similarly to the twenty-first embodiment, whereby the MQW emission layer 304 can be prevented from damage by the impurity element (carbon).

### Twenty-Fifth Embodiment

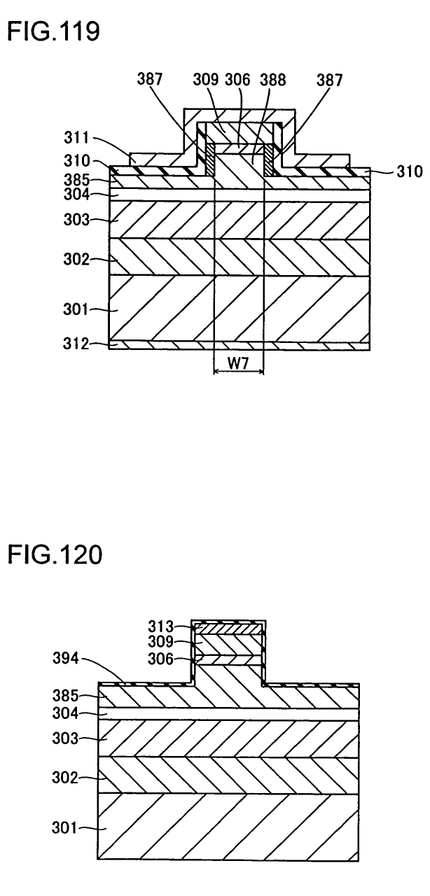

Referring to FIG. 119, an example of forming ion-implanted light absorption layers only on both side surfaces of a ridge portion dissimilarly to the aforementioned twenty-first to twenty-fourth embodiments is described with reference to this twenty-fifth embodiment. The remaining structure of the twenty-fifth embodiment is similar to that of the twenty-first embodiment.

Referring to FIG. 119, an n-type layer 302, an n-type cladding layer 303 and an MQW emission layer 304 are successively formed on an n-type GaN substrate 301 according to this twenty-fifth embodiment, similarly to the twenty-first embodiment.

According to the twenty-fifth embodiment, a p-type cladding layer 385 of p-type Al_{0.05}Ga_{0.95}N doped with Mg having a projecting portion is formed on the MQW emission layer 304. The projecting portion of this p-type cladding layer 385 is formed in a striped (elongated) shape having a width of about 2 μm and a height of about 300 nm. Further, flat portions of the p-type cladding layer 385 other than the projecting portion have a thickness of about 100 nm. A p-type contact layer 306 is formed on the projecting portion of the p-type cladding layer 385. The projecting portion of the p-type cladding layer 385 and the p-type contact layer 306 constitute a striped (elongated) ridge portion 388 having a width of about 2 μm and a height of about 310 nm. The p-type cladding layer 385 is an example of the “second nitride semiconductor layer” in the present invention.

According to the twenty-fifth embodiment, ion-implanted light absorption layers 387, formed by ion-implanting carbon (C), having a transverse implantation depth (thickness) of about 200 nm are provided on both side surfaces of the ridge portion 388. Therefore, the width (width of optical confinement) W7 between side ends of the ion-implanted light absorption layers 387 has a size (about 1.6 μm) smaller than the width (about 2 μm) of the ridge portion 388. The ion-implanted light absorption layers 387 are examples of the “light absorption layer” in the present invention.

A p-side ohmic electrode 309 is formed on the p-type contact layer 306 constituting the ridge portion 388. Insulator films 310 are formed on the surface of the p-type cladding layer 385 and the side surfaces of the p-type contact layer 306 and the p-side ohmic electrode 309. A p-side pad electrode 311 is formed on the upper surfaces of the insulator films 310 to be in contact with the upper surface of the p-side ohmic electrode 309. An n-side electrode 312 is formed on the back surface of the n-type GaN substrate 301.

In a nitride semiconductor laser element according to the twenty-fifth embodiment, as hereinabove described, the ion-implanted light absorption layers 387 are so provided on both side surfaces of the ridge portion 388 that transverse optical confinement can be performed in the ridge portion 388.

The remaining effects of the twenty-fifth embodiment are similar to those of the twenty-first embodiment.

A fabrication process for the nitride semiconductor laser element according to the twenty-fifth embodiment is now described with reference to FIGS. 119 to 123.

As shown in FIG. 120, the n-type layer 302, the n-type cladding layer 303 and the MQW emission layer 304 are successively formed on the n-type GaN substrate 301 through a fabrication process similar to that of the twenty-first embodiment. Then, the p-type cladding layer 385 of p-type Al_{0.05}Ga_{0.95}N having a thickness of about 400 nm and the p-type contact layer 306 are successively formed on the MQW emission layer 304. Thereafter annealing is performed in a nitrogen gas atmosphere under a temperature condition of about 800° C. Then, the p-side ohmic electrode 309 and an Ni layer 313 are successively formed on the p-type contact layer 306, and the p-side ohmic electrode 309 and the Ni layer 313 are thereafter patterned into striped (elongated) shapes having a width of about 2 μm. Then, the Ni layer 313 is employed as a mask for partially etching the p-type contact layer 306 and the p-type cladding layer 385 by a thickness of about 150 nm from the upper surfaces. Thereafter a channeling prevention film 394 of SiN having a thickness of about 40 nm is formed to cover the overall surface.

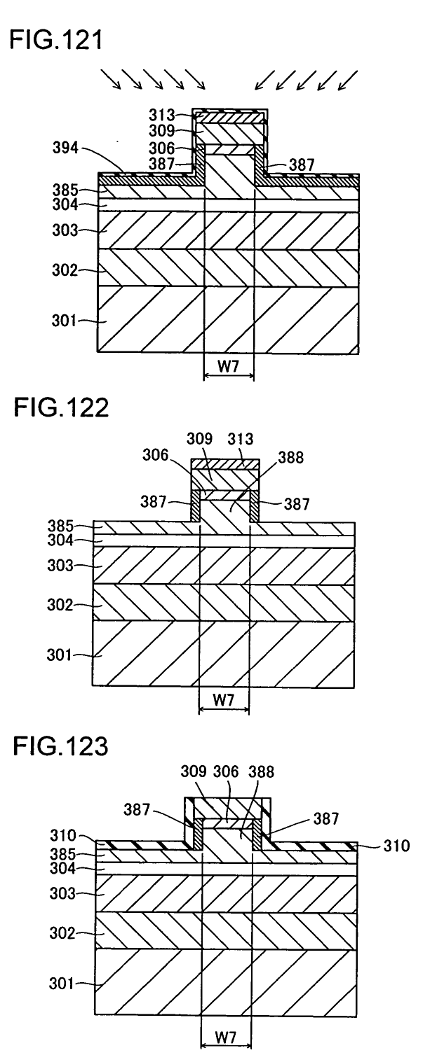

According to the twenty-fifth embodiment, the p-side ohmic electrode 309 and the Ni layer 313 are employed as masks for ion-implanting carbon, as shown in FIG. 121. At this time, ion implantation is performed from an oblique direction of 45° once each time so that ions are implanted into both sides of the projecting portion of the p-type cladding layer 385 and the p-type contact layer 306. Thus, the ion-implanted light absorption layers 387 having longitudinal and transverse implantation depths (thicknesses) of about 200 nm are formed on both side surfaces of the projecting portion of the p-type cladding layer 385 and the p-type contact layer 306 and the flat portions of the p-type cladding layer 385 other than the projecting portion. Further, the width (width of optical confinement) W7 between the side ends of the ion-implanted light absorption layers 387 is about 1.6 μm. In addition, ion-implanted regions are so increased in resistance that the current narrowing width also reaches the width W7. Ion implantation conditions for carbon are implantation energy of about 95 keV, a dose of about 1×10¹³ cm⁻² to about 1×10¹⁴ cm⁻² and an implantation temperature of the room temperature. Thereafter the channeling prevention film 394 is removed.

According to the twenty-fifth embodiment, the Ni layer 313 is employed as a mask for dry-etching the regions of the p-type cladding layer 385 formed with the ion-implanted light absorption layers 387 by a thickness of about 150 nm from the surface with Cl₂ gas, as shown in FIG. 122. Thus, portions of the ion-implanted light absorption layers 387 formed on the flat portions of the p-type cladding layer 385 are removed. Consequently, the ion-implanted light absorption layers 385 are arranged only on both side surfaces of the ridge portion 388. Further, the striped (elongated) ridge portion 388, constituted of the projecting portion of the p-type cladding layer 385 and the p-type contact layer 306, having the width of about 2 μm and the height of about 310 nm is formed by this etching. Thereafter the Ni layer 313 is removed.

Thereafter the insulator films 310 are formed to cover the overall surface and a portion of the insulator films 310 located on the upper surface of the p-side ohmic electrode 309 is removed, as shown in FIG. 123. Thus, the upper surface of the p-side ohmic electrode 309 is exposed.

Finally, the p-side pad electrode 311 is formed on the upper surfaces of the insulator films 310 to be in contact with the upper surface of the p-side ohmic electrode 309, as shown in FIG. 119. Further, the n-side electrode 312 is formed on the back surface of the n-type GaN substrate 301. Thus, the nitride semiconductor laser element according to the twenty-fifth embodiment is completed.

### Twenty-Sixth Embodiment

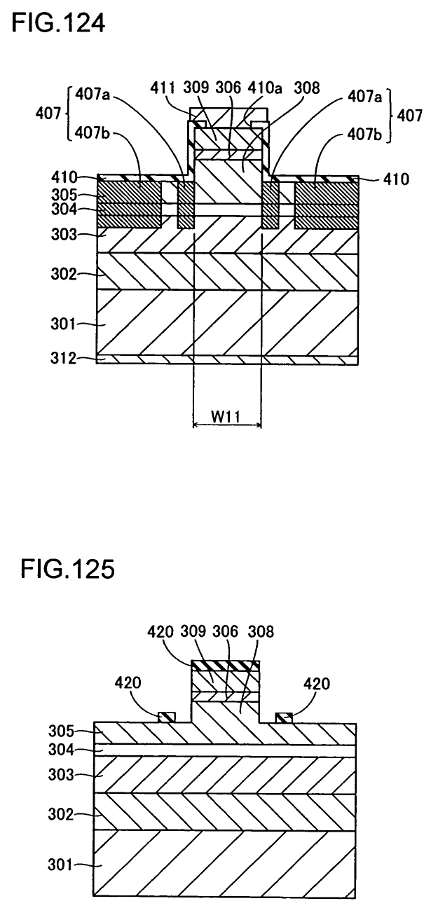

Referring to FIG. 124, an example of providing ion-implanted light absorption layers dividedly on side ends of a ridge portion and side ends of an element dissimilarly to the aforementioned twenty-first to twenty-fifth embodiments is described with reference to this twenty-sixth embodiment.

Referring to FIG. 124, an n-type layer 302, an n-type cladding layer 303, an MQW emission layer 304, a p-type cladding layer 305 and a p-type contact layer 306 are successively formed on an n-type GaN substrate 301 according to this twenty-sixth embodiment, similarly to the twenty-first embodiment. A projecting portion of the p-type cladding layer 305 and the p-type contact layer 306 constitute a striped (elongated) ridge portion 308 having a width of about 2 μm and a height of about 260 nm.

According to the twenty-sixth embodiment, ion-implanted light absorption layers 407, formed by ion-implanting carbon (C), having an implantation depth (thickness) of about 300 nm are provided. These ion-implanted light absorption layers 407 are divided into ion-implanted light absorption layers 407a provided on side ends of the ridge portion 308 and ion-implanted light absorption layers 407b provided on side ends of an element separated from the ion-implanted light absorption layers 407a at prescribed intervals. The ion-implanted light absorption layers 407a have a width of about 1 μm, while the ion-implanted light absorption layers 407b are arranged at intervals of about 1 μm from the ion-implanted light absorption layers 407a. The ion-implanted light absorption layers 407 are examples of the “light absorption layer” in the present invention. Side ends of the ion-implanted light absorption layers 407a closer to the ridge portion 308 are substantially arranged immediately under the side ends of the ridge portion 308. Thus, the width (width of optical confinement) W11 between the side ends of the ion-implanted light absorption layers 407a is substantially identical to the width (width of current narrowing) (about 2 μm) of the ridge portion 308.

A p-side ohmic electrode 309 is formed on the p-type contact layer 306 constituting the ridge portion 308. An insulator film 410 of SiO₂ having a thickness of about 200 nm is formed to cover the surfaces of the p-type cladding layer 305, the p-type contact layer 306 and the p-side ohmic electrode 309. This insulator film 410 has an opening 410a on the upper surface of the p-side ohmic electrode 309. A p-side pad electrode 411 consisting of a Ti layer having a thickness of about 100 nm, a Pd layer having a thickness of about 100 nm and an Au layer having a thickness of about 3 μm in ascending order is formed on a portion of the upper surface of the insulator film 410 located on the upper surface of the p-side ohmic electrode 309 to be in contact with the p-side ohmic electrode 309 through the opening 410a. An n-side electrode 312 is formed on the back surface of the n-type GaN substrate 301.

In a nitride semiconductor laser element according to the twenty-sixth embodiment, as hereinabove described, the ion-implanted light absorption layers 407 formed by ion implantation are so provided on regions of the p-type cladding layer 305 other than the projecting portion constituting the ridge portion 308 that the ion-implanted light absorption layers 407 can be formed with excellent reproducibility due to excellent reproducibility of ion implantation. Thus, transverse optical confinement can be controlled with excellent reproducibility. Consequently, the transverse mode can be stabilized with excellent reproducibility while performing current narrowing through the ridge portion 308. Further, the transverse mode can be so stabilized that outbreak of kinks (bending of current-light output characteristics) resulting from higher mode oscillation can be suppressed. Thus, a higher maximum light output can be obtained while the beam shape can be stabilized.

According to the twenty-sixth embodiment, further, the ion-implanted light absorption layers 407 are provided dividedly into the ion-implanted light absorption layers 407a on the side ends of the ridge portion 308 and the ion-implanted light absorption layers 407b on the side ends of the element so that regions formed with the ion-implanted light absorption layers 407 can be inhibited from increase, whereby a portion in the vicinity of the MQW emission layer 304 can be inhibited from excess light absorption. Consequently, increase of the threshold current can be suppressed.

A fabrication process for the nitride semiconductor laser element according to the twenty-sixth embodiment is now described with reference to FIGS. 124 to 128.

As shown in FIG. 125, the layers up to the striped (elongated) ridge portion 308, constituted of the projecting portion of the p-type cladding layer 305 and the p-type contact layer 306, having the width of about 2 μm and the height of about 260 nm are formed through a fabrication process similar to that of the twenty-first embodiment shown in FIGS. 101 to 103. Thereafter ion implantation masks 420 consisting of SiO₂ films having a thickness of about 800 nm are formed on the p-side ohmic electrode 309 and prescribed regions of the surfaces of flat portions of the p-type cladding layer 305 other than the projecting portion. At this time, the ion implantation masks 420 located on the surfaces of the flat portions of the p-type cladding layer 305 other than the projecting portion are formed to have a width of about 1 μm and to be arranged at intervals of about 1 μm from the side ends of the ridge portion 308.

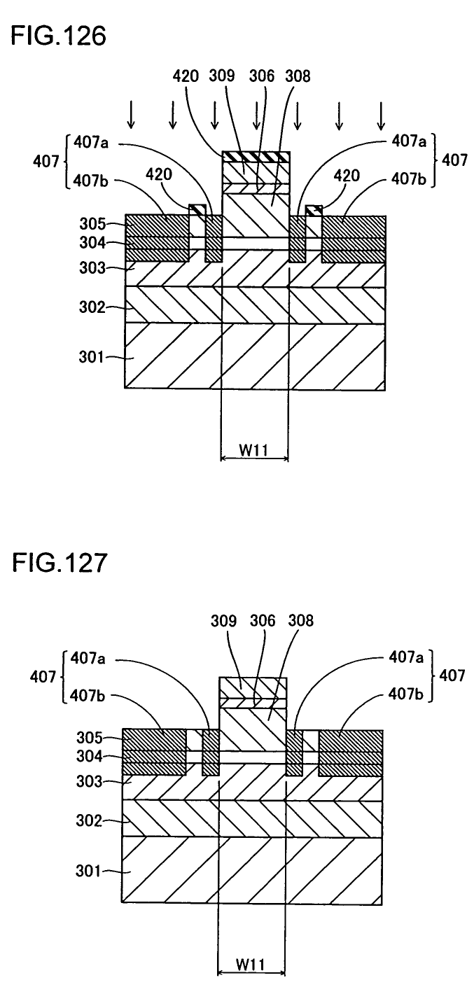

According to the twenty-sixth embodiment, the ion implantation masks 420 are thereafter employed as masks for ion-implanting carbon (C), as shown in FIG. 126. Thus, the ion-implanted light absorption layers 407 having the ion implantation depth (thickness) of about 300 nm are formed over the surfaces of the flat portions of the p-type cladding layer 305 other than the projecting portion to the MQW emission layer 304 and the n-type cladding layer 303. Ion implantation conditions for carbon are implantation energy of about 95 keV, a dose of about 5×10¹³ cm⁻² and an implantation temperature of the room temperature. This ion implantation is performed from a direction inclined by about 70 in the longitudinal direction of the p-side ohmic electrode 309. At this time, no ions are implanted into regions corresponding to the ion implantation masks 420, whereby the ion-implanted light absorption layers 407 are formed dividedly into the ion-implanted light absorption layers 407a on the side ends of the ridge portion 308 and the ion-implanted light absorption layers 407b on the side ends of the element. The ion-implanted light absorption layers 407a on the side ends of the ridge portion 308 have the width of about 1 μm, while the side ends closer to the ridge portion 308 are substantially arranged immediately under the side ends of the ridge portion 308. Therefore, the width (width of optical confinement) W11 between the side ends of the ion-implanted light absorption layers 407a reaches the size of about 2 μm substantially identical to the width (width of current narrowing) (about 2 μm) of the ridge portion 308. Further, the ion-implanted light absorption layers 407b are arranged at the intervals of about 1 μm from of the ion-implanted light absorption layers 407a.

Thereafter the ion implantation masks 420 are removed thereby obtaining the state shown in FIG. 127.

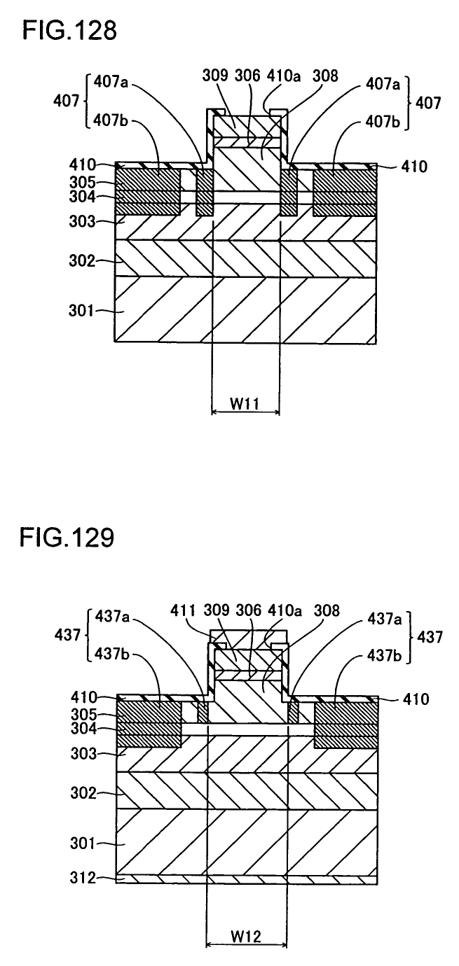

As shown in FIG. 128, an SiO₂ film (not shown) having a thickness of about 200 nm is formed to cover the overall surface, and a prescribed region of the SiO₂ film located on the upper surface of the p-side ohmic electrode 309 is removed. Thus, the insulator film 410 consisting of the SiO₂ film, having the opening 410a on the upper surface of the p-side ohmic electrode 309, having the thickness of about 200 nm is formed.

Finally, the p-side pad electrode 411 consisting of the Ti layer having the thickness of about 100 nm, the Pd layer having the thickness of about 100 nm and the Au layer having the thickness of about 3 μm in ascending order is formed on the upper surface of the portion of the insulator film 410 located on the upper surface of the p-side ohmic electrode 309 to be in contact with the p-side ohmic electrode 309 through the opening 410a, as shown in FIG. 124. Further, the n-side electrode 312 is formed on the back surface of the n-type GaN substrate 301. Thus, the nitride semiconductor laser element according to the twenty-sixth embodiment is completed.

### Twenty-Seventh Embodiment

Referring to FIG. 129, ion-implanted light absorption layers 437a having an implantation depth (thickness) of about 150 nm are formed on side ends of a ridge portion 308 according to this twenty-seventh embodiment, in the structure of the aforementioned twenty-sixth embodiment. In other words, the ion-implanted light absorption layers 437a provided on the side ends of the ridge portion 308 do not reach the interior of an MQW emission layer 304. These ion-implanted light absorption layers 437a and ion-implanted absorption layers 437b constitute ion-implanted light absorption layers 437 according to the twenty-seventh embodiment. The ion-implanted light absorption layers 437 are examples of the “light absorption layer” in the present invention.

Side ends of the ion-implanted light absorption layers 437a closer to the ridge portion 308 are arranged on positions separated from the side ends of the ridge portion 308 by about 0.2 μm. Thus, the width (width of optical confinement) W12 between the side ends of the ion-implanted light absorption layers 437a is about 2.4 μm, which is larger than the width (width of current narrowing) (about 2 μm) of the ridge portion 308. The ion-implanted light absorption layers 437a have a width of about 0.8 μm, while the ion-implanted light absorption layers 437b are arranged at intervals of about 1 μm from the ion-implanted light absorption layers 437a. The remaining structure of the twenty-seventh embodiment is similar to that of the aforementioned twenty-sixth embodiment.

According to the twenty-seventh embodiment, as hereinabove described, the implantation depth (thickness) of the ion-implanted light absorption layers 437a on the side ends of the ridge portion 308 is set to the implantation depth (thickness) of about 150 nm so that the ion-implanted light absorption layers 437a do not reach the interior of the MQW active layer 304, whereby light absorption in the vicinity of the MQW emission layer 304 can be further inhibited from excessiveness. Consequently, increase of a threshold current can be further suppressed.

The remaining effects of the twenty-seventh embodiment are similar to those of the aforementioned twenty-sixth embodiment.

A fabrication process for a nitride semiconductor laser device according to the twenty-seventh embodiment is now described with reference to FIGS. 129 to 133.

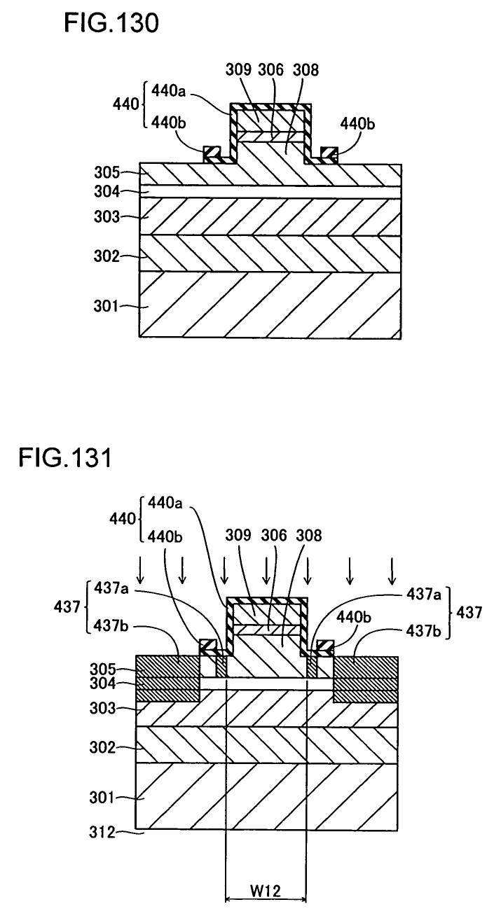

As shown in FIG. 130, layers up to the striped (elongated) ridge portion 308, constituted of a projecting portion of a p-type cladding layer 305 and a p-type contact layer 360, having a width of about 2 μm and a height of about 260 nm are formed through a fabrication process similar to that of the twenty-first embodiment shown in FIGS. 101 to 103. Thereafter an ion implantation mask 440a consisting of an SiO₂ film having a thickness of about 200 nm is formed on the upper surface and the side surfaces of a p-side ohmic electrode 309, the side surfaces of the ridge portion 308 and prescribed regions of the surfaces of flat portions of the p-type cladding layer 305 other than the projecting portion. At this time, the ion implantation mask 440a is so formed that side ends of the ion implantation mask 440a are arranged on positions separated by about 2 μm from the side ends of the ridge portion 308. Thereafter ion implantation masks 440b consisting of SiO₂ films having a thickness of about 600 nm and a width of about 1 μm are formed on side end regions of the ion implantation mask 440a. Thus, an ion implantation mask 440 consisting of the ion implantation mask 440a and the ion implantation masks 440b is formed. The thickness of side end regions (portions separated from the side ends of the ridge portion 308 by about 2 μm) of the ion implantation mask 440 is about 800 μm.

According to the twenty-seventh embodiment, the ion implantation mask 440 is employed as a mask for ion-implanting carbon (C) thereby forming the ion-implanted light absorption layers 437, as shown in FIG. 131. Ion implantation conditions for carbon are implantation energy of about 95 keV, a dose of about 5×10¹³ cm⁻² and an implantation temperature of the room temperature. This ion implantation is performed from a direction inclined by about 70 in the longitudinal direction of the p-side ohmic electrode 309. At this time, no ions are implanted into regions corresponding to the side end regions of the ion implantation mask 440 having the large thickness (about 800 nm), whereby the ion-implanted light absorption layers 437 are formed dividedly into the ion-implanted light absorption layers 437a on the side ends of the ridge portion 308 and the ion-implanted light absorption layers 437b on the side ends of the element.

No ions are implanted into regions corresponding to portions of the ion implantation mask layer 440 formed on the side surfaces of the ridge portion 308 and the p-side ohmic electrode 309 either. Further, the regions of the ion implantation mask 440 other than the side ends have a small thickness (about 200 nm), whereby ions are implanted into regions corresponding to the regions of the ion implantation mask 440 other than the side ends. However, the ion implantation depth is reduced as compared with the regions formed with no ion implantation mask 440.

Thus, the ion-implanted light absorption layers 437a provided on the side ends of the ridge portion 308 have the width of about 0.8 μm, while the side ends closer to the ridge portion 308 are arranged on the positions separated from the side ends of the ridge portion 308 by about 0.2 μm. Therefore, the width (width of optical confinement) W12 between the side ends of the ion-implanted light absorption layers 437a is about 2.4 μm, which is larger than the width (width of current narrowing) (about 2 μm) of the ridge portion 308. Further, the ion-implanted light absorption layers 437b are arranged at the intervals of about 1 μm from the ion-implanted light absorption layers 437a. The ion implantation depth (thickness) of the ion-implanted light absorption layers 437a is about 150 nm, and the ion implantation depth (thickness) of the ion-implanted light absorption layers 437b is about 300 nm.

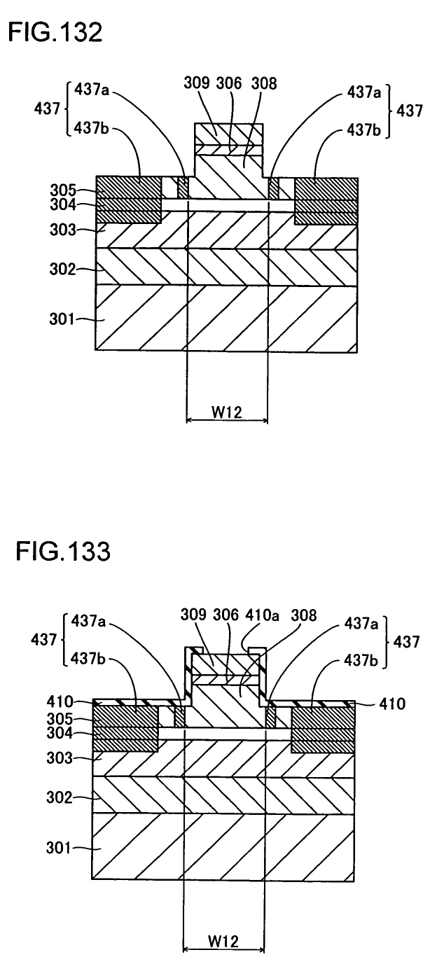

Thereafter the ion implantation mask layer 440 is removed thereby obtaining the state shown in FIG. 132.

As shown in FIG. 133, an insulator film 410 having an opening 410a on the upper surface of the p-side ohmic electrode 309 is formed through a process similar to that of the twenty-sixth embodiment shown in FIG. 128.

Finally, a p-side pad electrode 411 is formed on the upper surface of a portion of the insulator film 410 located on the upper surface of the p-side ohmic electrode 309 to be in contact with the upper surface of the p-side ohmic electrode 309 through the opening 410a. Further, an n-side electrode 312 is formed on the back surface of an n-type GaN substrate 301. Thus, a nitride semiconductor laser element according to the twenty-seventh embodiment is completed.

### Twenty-Eighth Embodiment

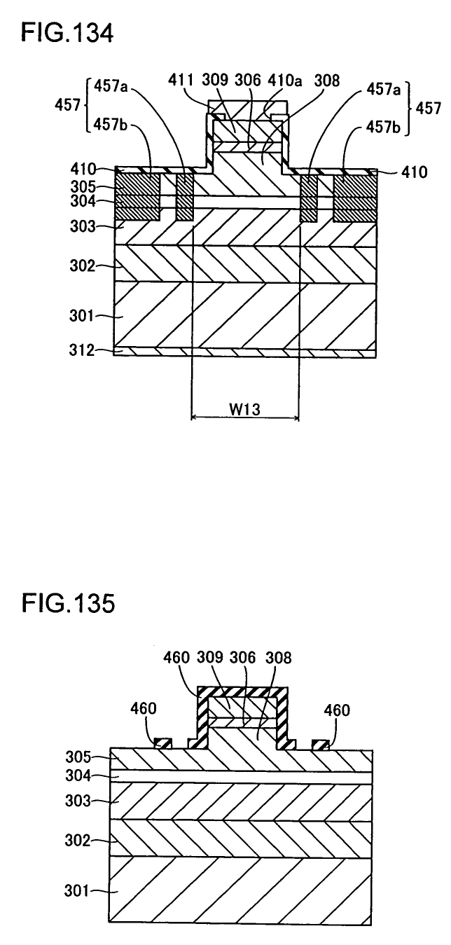

Referring to FIG. 134, an example of rendering the width (width of optical confinement) between side ends of ion-implanted light absorption layers larger than the width (width of current narrowing) of a ridge portion in the structure of the aforementioned twenty-sixth embodiment is described with reference to this twenty-eighth embodiment. The remaining structure of the twenty-eighth embodiment is similar to that of the aforementioned twenty-sixth embodiment.

Referring to FIG. 134, a projecting portion of a p-type cladding layer 305 and a p-type contact layer 306 constitute a striped (elongated) ridge portion 308 having a width of about 2 μm and a height of about 260 nm according to this twenty-eighth embodiment, similarly to the aforementioned twenty-sixth embodiment.

According to the twenty-eighth embodiment, ion-implanted light absorption layers 457, formed by ion-implanting carbon (C), having an implantation depth (thickness) of about 300 nm are provided. These ion-implanted light absorption layers 457 are provided dividedly into ion-implanted light absorption layers 457a provided on side ends of the ridge portion 308 and ion-implanted light absorption layers 457b provided on side ends of an element. The ion-implanted light absorption layers 457 are examples of the “light absorption layer” in the present invention. Side ends of the ion-implanted light absorption layers 457a closer to the ridge portion 308 are arranged on positions separated from the side ends of the ridge portion 308 by about 1 μm. Thus, the width (width of optical confinement) W13 between the side ends of the ion-implanted light absorption layers 457a is about 4 μm, which is larger than the width (width of current narrowing) (about 2 μm) of the ridge portion 308. Further, the ion-implanted light absorption layers 457a have a width of about 1 μm, while the ion-implanted light absorption layers 457b are arranged at intervals of about 1 μm from the ion-implanted light absorption layers 457a.

A p-side ohmic electrode 309 is formed on the p-type contact layer 306 constituting the ridge portion 308. An insulator film 410 is formed to cover the surfaces of the p-type cladding layer 305, the p-type contact layer 306 and the p-side ohmic electrode 309. This insulator film 410 has an opening 410a on the upper surface of the p-side ohmic electrode 309. A p-side pad electrode 411 is formed on the upper surface of the insulator film 410 to be in contact with the upper surface of the p-side ohmic electrode 309 through the opening 410a. An n-side electrode 312 is formed on the back surface of an n-type GaN substrate 301.

According to the twenty-eighth embodiment, as hereinabove described, the width (width of optical confinement) W13 between the side ends of the ion-implanted light absorption layers 457a closer to the side ends of the ridge portion 308 is set to about 4 μm which is larger than the width (width of current narrowing) (about 2 μm) of the ridge portion 308, whereby light absorption in the vicinity of the MQW emission layer 304 can be inhibited from excessiveness. Further, the ion-implanted light absorption layers 457 are provided dividedly into the ion-implanted light absorption layers 457a on the side ends of the ridge portion 308 and the ion-implanted light absorption layers 457b on the side ends of the element so that regions for forming the ion-implanted light absorption layers 457 can be inhibited from increase, whereby light absorption in the vicinity of the MQW emission layer 304 can be inhibited from excessiveness also by this. Consequently, increase of a threshold current can be further suppressed.

The remaining effects of the twenty-eighth embodiment are similar to those of the aforementioned twenty-sixth embodiment.

A fabrication process for a nitride semiconductor laser element according to the twenty-eighth embodiment is now described with reference to FIGS. 135 to 138.

First, the layers up to the striped (elongated) ridge portion 308, constituted of the projecting portion of the p-type cladding layer 305 and the p-type contact layer 306, having the width of about 2 μm and the height of about 260 nm are formed as shown in FIG. 135 through a fabrication process similar to that of the twenty-first embodiment shown in FIGS. 101 to 103. Thereafter ion implantation masks 460 consisting of SiO₂ films having a thickness of about 800 nm are formed on the upper surface and the side surfaces of the p-side ohmic electrode 309, the side surfaces of the ridge portion 308 and prescribed regions of the surfaces of flat portions of the p-type cladding layer 305 other than the projecting portion. At this time, the ion implantation masks 460 located on the surfaces of the flat portions of the p-type cladding layer 305 other than the projecting portion are formed to have a width of about 1 μm and to be arranged in a cycle of about 2 μm at intervals of about 1 μm. Further, the ion implantation masks 460 located on the surfaces of the flat portions of the p-type cladding layer 305 other than the projecting portion are so formed that the side ends thereof are arranged on positions separated from the side ends of the ridge portion 308 by about 3 μm.

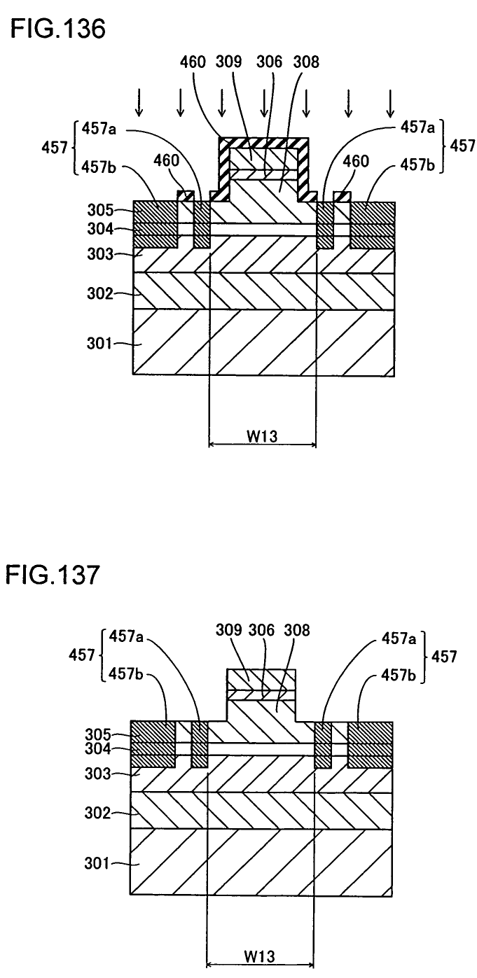

According to the twenty-eighth embodiment, the ion implantation masks 460 are thereafter employed as masks for ion-implanting carbon (C), as shown in FIG. 136. Thus, the ion-implanted light absorption layers 457 having the ion implantation depth (thickness) of about 300 nm are formed over the surfaces of the flat portions of the p-type cladding layer 305 other than the projecting portion to the MQW emission layer 304 and the n-type cladding layer 303. Ion implantation conditions for carbon are implantation energy of about 95 keV, a dose of about 5×10¹³ cm⁻² and an implantation temperature of the room temperature. This ion implantation is performed from a direction inclined by about 70 in the longitudinal direction of the p-side ohmic electrode 309. At this time, no ions are implanted into regions corresponding to the ion implantation masks 460, whereby the ion-implanted light absorption layers 457 are formed dividedly into the ion-implanted light absorption layers 457a on the side ends of the ridge portion 308 and the ion-implanted light absorption layers 457b on the side ends of the element. The ion-implanted light absorption layers 457a on the side ends of the ridge portion 308 have the width of about 1 μm, while the side ends closer to the ridge portion 308 are arranged on the positions separated from the side ends of the ridge portion 308 by about 1 μm. Thus, the width (width of optical confinement) W13 between the side ends of the ion-implanted light absorption layers 457a is about 4 μm, which is larger than the width (width of current narrowing) (about 2 μm) of the ridge portion 308. Further, the ion-implanted light absorption layers 457b are arranged at the intervals of about 1 μm from of the ion-implanted light absorption layers 457a.

Thereafter the ion implantation masks 460 are removed thereby obtaining the state shown in FIG. 137.

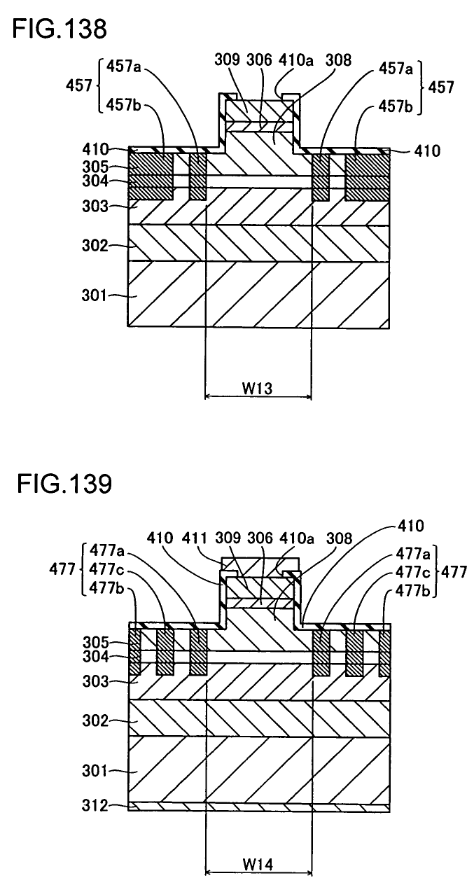

As shown in FIG. 138, the insulator film 410 having the opening 410a on the upper surface of the p-side ohmic electrode 309 is formed through a process similar to that of the twenty-sixth embodiment shown in FIG. 128.

Finally, the p-side pad electrode 411 is formed on the upper surface of the portion of the insulator film 410 located on the upper surface of the p-side ohmic electrode 309 to be in contact with the upper surface of the p-side ohmic electrode 309 through the opening 410a, as shown in FIG. 134. Further, the n-side electrode 312 is formed on the back surface of the n-type GaN substrate 301. Thus, the nitride semiconductor laser element according to the twenty-eighth embodiment is completed.

### Twenty-Ninth Embodiment

Referring to FIG. 139, an example of dividing ion-implanted light absorption layers provided between side ends of a ridge portion and side ends of an element into three types of ion-implanted light absorption layers dissimilarly to the aforementioned twenty-sixth to twenty-eighth embodiments is described with reference to this twenty-ninth embodiment. The remaining structure of the twenty-ninth embodiment is similar to that of the aforementioned twenty-eighth embodiment.

Referring to FIG. 139, a projecting portion of a p-type cladding layer 305 and a p-type contact layer 306 constitute a striped (elongated) ridge portion 308 having a width of about 2 μm and a height of about 260 nm according to this twenty-ninth embodiment, similarly to the twenty-eighth embodiment.

According to the twenty-ninth embodiment, ion-implanted light absorption layers 477, formed by ion-implanting carbon (C), having an implantation depth (thickness) of about 300 nm are provided. These ion-implanted light absorption layers 477 are provided dividedly into ion-implanted light absorption layers 477a provided on side ends of the ridge portion 308, ion-implanted light absorption layers 477b provided on side ends of an element and ion-implanted light absorption layers 477c provided between the ion-implanted light absorption layers 477a and the ion-implanted light absorption layers 477b. The ion-implanted light absorption layers 477 are examples of the “light absorption layer” in the present invention. Side ends of the ion-implanted light absorption layers 477a closer to the ridge portion 308 are arranged on positions separated from the side ends of the ridge portion 308 by about 1 μm. Thus, the width (width of optical confinement) W14 between the side ends of the ion-implanted light absorption layers 477a is about 4 μm, which is larger than the width (width of current narrowing) (about 2 μm) of the ridge portion 308. Further, the ion-implanted light absorption layers 477a and 477c have a width of about 1 μm. The ion-implanted light absorption layers 477c are arranged at intervals of about 1 μm from the ion-implanted light absorption layers 477a, while the ion-implanted light absorption layers 477b are arranged at intervals of about 1 μm from the ion-implanted light absorption layers 477c.

A p-side ohmic electrode 309 is formed on the p-type contact layer 306 constituting the ridge portion 308. Further, an insulator film 410 is formed to cover the surfaces of the p-type cladding layer 305, the p-type contact layer 306 and the p-side ohmic electrode 309. This insulator film 410 has an opening 410a on the upper surface of the p-side ohmic electrode 309. A p-side pad electrode 411 is formed on the upper surface of the insulator film 410 to be in contact with the upper surface of the p-side ohmic electrode 309 through the opening 410a. An n-side electrode 312 is formed on the back surface of an n-type GaN substrate 301.

According to the twenty-eighth embodiment, as hereinabove described, the width (width of optical confinement) W14 between the side ends of the ion-implanted light absorption layers 477a closer to the side ends of the ridge portion 308 is set to about 4 μm which is larger than the width (about 2 μm) of the ridge portion 308, whereby light absorption in the vicinity of an MQW emission layer 304 can be inhibited from excessiveness. Further, the ion-implanted light absorption layers 477 provided between the side ends of the ridge portion 308 and the side ends of the element are so divided into the three types of ion-implanted light absorption layers 477a, 477b and 477c that regions formed with the ion-implanted light absorption layers 477 can be further inhibited from increase as compared with the aforementioned twenty-eighth embodiment, whereby the light absorption in the vicinity of the MQW emission layer 304 can be further inhibited from excessiveness. Consequently, increase of a threshold current can be further suppressed as compared with the twenty-eighth embodiment.

The remaining effects of the twenty-ninth embodiment are similar to those of the aforementioned twenty-sixth embodiment.

A fabrication process for a nitride semiconductor laser element according to the twenty-ninth embodiment is now described with reference to FIGS. 139 to 143.

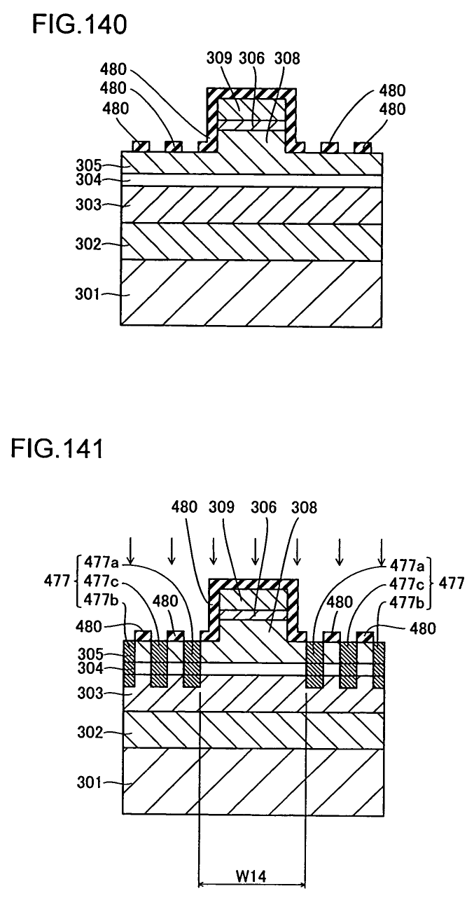

First, the layers up to the striped (elongated) ridge portion 308, constituted of the projecting portion of the p-type cladding layer 305 and the p-type contact layer 306, having the width of about 2 μm and the height of about 260 nm are formed as shown in FIG. 140 through a fabrication process similar to that of the twenty-first embodiment shown in FIGS. 101 to 103. Thereafter ion implantation masks 480 consisting of SiO₂ films having a thickness of about 800 nm are formed on the upper surface and the side surfaces of the p-side ohmic electrode 309, the side surfaces of the ridge portion 308 and prescribed regions of the surfaces of flat portions of the p-type cladding layer 305 other than the projecting portion. At this time, the ion implantation masks 480 located on the surfaces of the flat portions of the p-type cladding layer 305 other than the projecting portion are formed to have a width of about 1 μm and to be arranged in a cycle of about 2 μm at intervals of about 1 μm. Further, the ion implantation masks 480 located on the surfaces of the flat portions of the p-type cladding layer 305 other than the projecting portion are so formed that the side ends thereof are arranged on positions separated from the side ends of the ridge portion 308 by about 5 μm.

According to the twenty-ninth embodiment, the ion implantation masks 480 are thereafter employed as masks for ion-implanting carbon (C), as shown in FIG. 141. Thus, the ion-implanted light absorption layers 477 having the ion implantation depth (thickness) of about 300 nm are formed over the surfaces of the flat portions of the p-type cladding layer 305 other than the projecting portion to the MQW emission layer 304 and an n-type cladding layer 303. Ion implantation conditions for carbon are implantation energy of about 95 keV, a dose of about 5×10¹³ cm⁻² and an implantation temperature of the room temperature. This ion implantation is performed from a direction inclined by about 70 in the longitudinal direction of the p-side ohmic electrode 309. At this time, no ions are implanted into regions corresponding to the ion implantation masks 480, whereby the ion-implanted light absorption layers 477 are formed dividedly into the ion-implanted light absorption layers 477a on the side ends of the ridge portion 308, the ion-implanted light absorption layers 477b on the side ends of the element and the ion-implanted light absorption layers 477c provided between the ion-implanted light absorption layers 477a and the ion-implanted light absorption layers 477b. The ion-implanted light absorption layers 477a provided on the side ends of the ridge portion 308 have the width of about 1 μm, while the side ends closer to the ridge portion 308 are arranged on the positions separated from the side ends of the ridge portion 308 by about 1 μm. Thus, the width (width of optical confinement) W14 between the side ends of the ion-implanted light absorption layers 477a is about 4 μm, which is larger than the width (width of current narrowing) (about 2 μm) of the ridge portion 308. Further, the ion-implanted light absorption layers 477c are arranged at the intervals of about 1 μm from of the ion-implanted light absorption layers 477a, while the ion-implanted light absorption layers 477b are arranged at the intervals of about 1 μm from of the ion-implanted light absorption layers 477c.

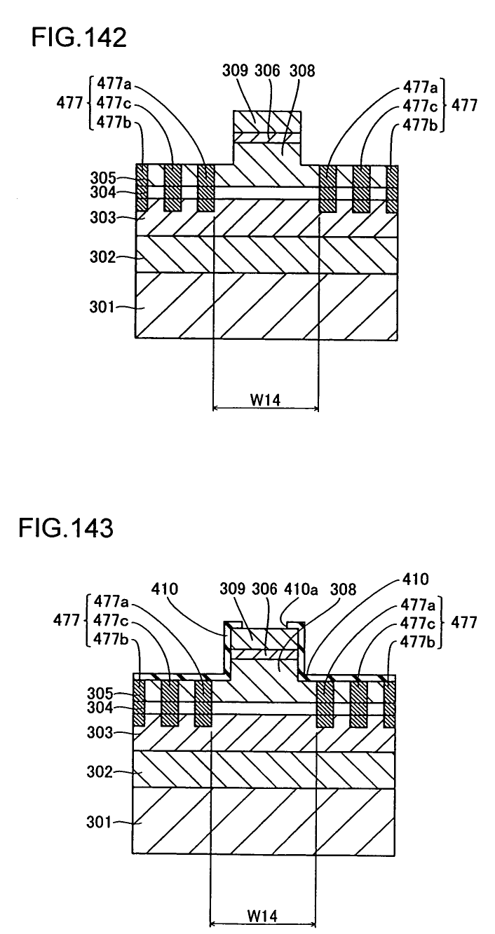

Thereafter the ion implantation masks 480 are removed thereby obtaining the state shown in FIG. 142.

As shown in FIG. 143, the insulator film 410 having the opening 410a on the upper surface of the p-side ohmic electrode 309 is formed through a process similar to that of the twenty-sixth embodiment shown in FIG. 128.

Finally, the p-side pad electrode 411 is formed on the upper surface of the portion of the insulator film 410 located on the upper surface of the p-side ohmic electrode 309 to be in contact with the p-side ohmic electrode 309 through the opening 410a, as shown in FIG. 139. Further, the n-side electrode 312 is formed on the back surface of the n-type GaN substrate 301. Thus, the nitride semiconductor laser element according to the twenty-ninth embodiment is completed.

### Thirtieth Embodiment

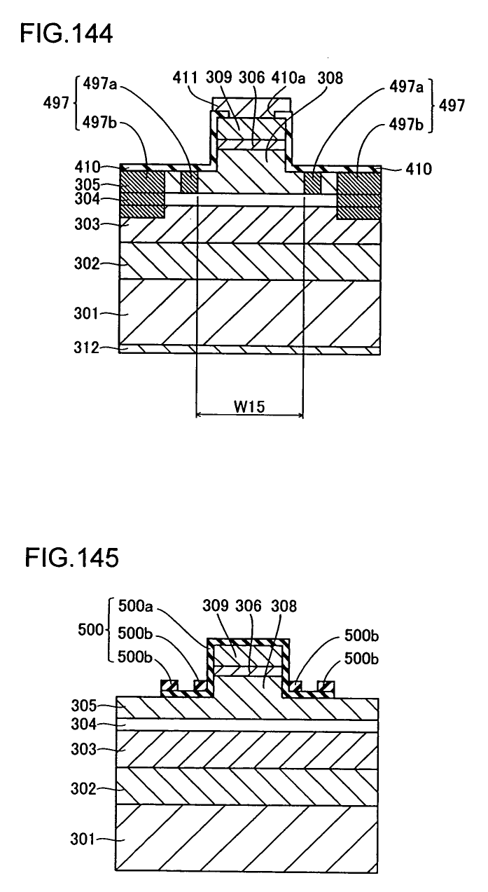

Referring to FIG. 144, ion-implanted light absorption layers 497a having an implantation depth (thickness) of about 150 nm are formed on side ends of a ridge portion 308 according to this thirtieth embodiment, in the structure of the aforementioned twenty-eighth embodiment. In other words, the ion-implanted light absorption layers 497a provided on the side ends of the ridge portion 308 do not reach the interior of an MQW emission layer 304. These ion-implanted light absorption layers 497a and ion-implanted absorption layers 497b constitute ion-implanted light absorption layers 497 of the thirtieth embodiment. The ion-implanted light absorption layers 497 are examples of the “light absorption layer” in the present invention.

Side ends of the ion-implanted light absorption layers 497a closer to the ridge portion 308 are arranged on positions separated from side ends of the ridge portion 308 by about 1 μm. Thus, the width (width of optical confinement) W15 between the side ends of the ion-implanted light absorption layers 497a is about 4 μm, which is larger than the width (width of current narrowing) (about 2 μm) of the ridge portion 308. Further, the ion-implanted light absorption layers 497a have a width of about 1 μm, while the ion-implanted light absorption layers 497b are arranged at intervals of about 1 μm from the ion-implanted light absorption layers 497a. The remaining structure of the thirtieth embodiment is similar to that of the aforementioned twenty-eighth embodiment.

According to the thirtieth embodiment, as hereinabove described, the implantation depth (thickness) of the ion-implanted light absorption layers 497a on the side ends of the ridge portion 308 is so set to the implantation depth (thickness) of about 150 nm that the ion-implanted light absorption layers 497a do not reach the interior of the MQW active layer 304, whereby light absorption in the vicinity of the MQW emission layer 304 can be further inhibited from excessiveness. Consequently, increase of a threshold current can be further suppressed.

The remaining effects of the thirtieth embodiment are similar to those of the aforementioned twenty-eighth embodiment.

A fabrication process for a nitride semiconductor laser element according to the thirtieth embodiment is now described with reference to FIGS. 144 to 148.

First, layers up to the striped (elongated) ridge portion 308, constituted of a projecting portion of a p-type cladding layer 305 and a p-type contact layer 306, having a width of about 2 μm and a height of about 260 nm are formed through a fabrication process similar to that of the twenty-first embodiment shown in FIGS. 101 to 103, as shown in FIG. 145. Thereafter an ion implantation mask 500a of an SiO₂ film having a thickness of about 200 nm is formed on the upper surface and the side surfaces of a p-side ohmic electrode 309, the side surfaces of the ridge portion 308 and prescribed regions on the surfaces of flat portions of the p-type cladding layer 305 other than the projecting portion. At this time, the ion implantation mask 500a is so formed that the side ends thereof are arranged on positions separated from the side ends of the ridge portion 308 by about 3 μm. Thereafter other ion implantation masks 500b of SiO₂ films having a thickness of about 600 nm are formed on prescribed regions of the ion implantation mask 500a located on the surfaces of the flat portions of the p-type cladding layer 305 other than the projecting portion. More specifically, the ion implantation masks 500b located on side end regions of the ion implantation mask 500a are formed with a width of about 1 μm while the ion implantation masks 500b located on regions of the ion implantation mask 500a closer to the ridge portion 308 are formed with a width of about 0.8 μm. Thus, an ion implantation mask 500 consisting of the ion implantation mask 500a and the ion implantation masks 500b is formed. The thicknesses of side end regions (portions separated from the side ends of the ridge portion 308 by about 3 μm) of the ion implantation mask 500 and regions of the ion implantation mask 500 closer to the ridge portion 308 are about 800 μm.

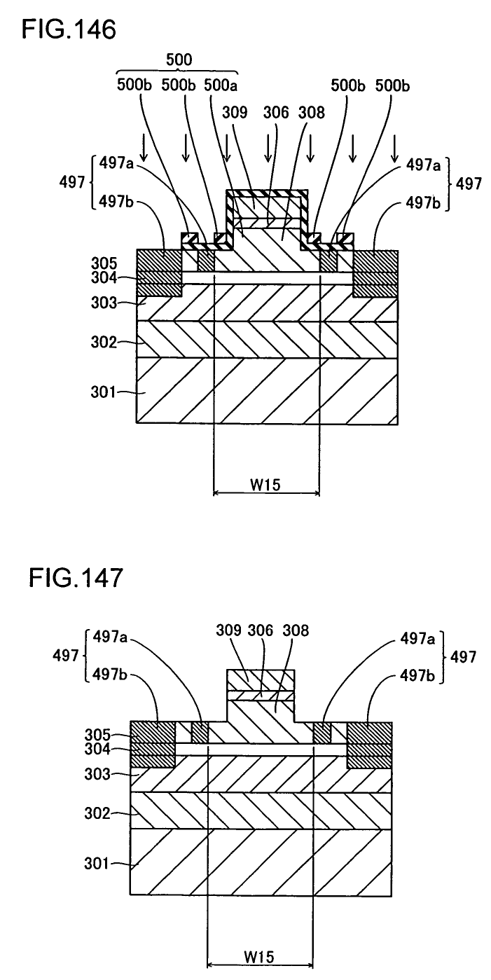

According to the thirtieth embodiment, the ion implantation mask 500 is thereafter employed as a mask for ion-implanting carbon (C), thereby forming the ion-implanted light absorption layers 497 as shown in FIG. 146. Ion implantation conditions for carbon are implantation energy of about 95 keV, a dose of about 5×10¹³ cm⁻² and an implantation temperature of the room temperature. This ion implantation is performed from a direction inclined by about 70 in the longitudinal direction of the p-side ohmic electrode 309. At this time, no ions are implanted into the regions corresponding to the side end regions of the ion implantation mask 500 having the large thickness (about 800 nm), whereby the ion-implanted light absorption layers 500 are formed dividedly into the ion-implanted light absorption layers 497a on the side ends of the ridge portion 308 and the ion-implanted light absorption layers 497b on the side ends of the element.

Further, no ions are implanted into the regions corresponding to the regions, having the large thickness (about 800 nm), of the ion implantation mask 500 closer to the ridge portion 308 either. In addition, the regions of the ion implantation mask 500 other than the side ends have the small thickness (about 200 nm), whereby ions are implanted into the regions corresponding to the regions of the ion implantation mask 500 other than the side ends. However, the ion implantation depth is smaller as compared with the regions formed with no ion implantation mask 500.

Thus, the ion-implanted light absorption layers 497a provided on the side ends of the ridge portion 308 have the width of about 1 μm, and the side ends closer to the ridge portion 308 are arranged on the positions separated from the side ends of the ridge portion 308 by about 1 μm. Therefore, the width (width of optical confinement) W15 between the side ends of the ion-implanted light absorption layer 497a is about 4 μm, which is larger than the width (width of current narrowing) (about 2 μm) of the ridge portion 308. Further, the ion-implanted light absorption layers 497b are arranged at the intervals of about 1 μm from the ion-implanted light absorption layers 497a. The ion implantation depth (thickness) of the ion-implanted light absorption layers 497a is about 150 nm, while the ion implantation depth (thickness) of the ion-implanted light absorption layers 497b is about 300 nm.

Thereafter the ion implantation mask layer 500 is removed, thereby obtaining the state shown in FIG. 147.

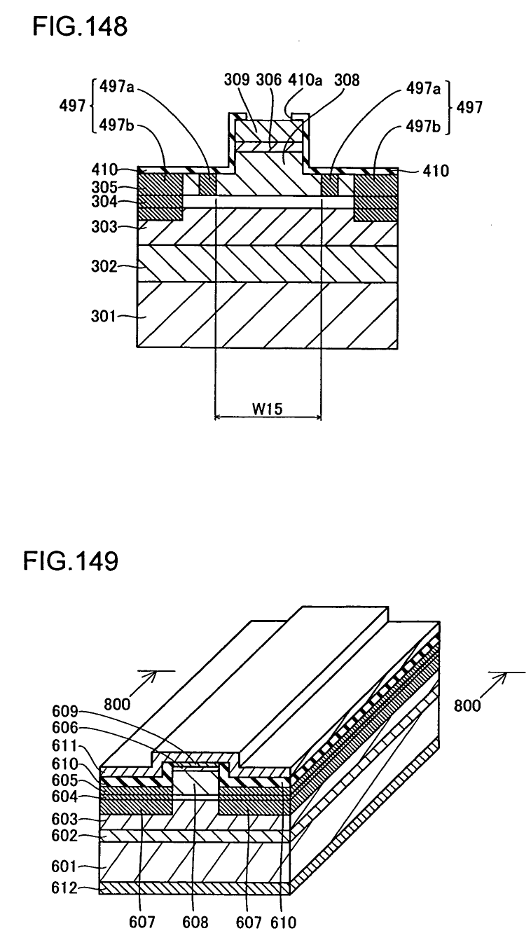

As shown in FIG. 148, an insulator film 410 having an opening 410a on the upper surface of the p-side ohmic electrode 309 is formed through a process similar to that of the twenty-sixth embodiment shown in FIG. 128.

Finally, a p-side pad electrode 411 is formed on the upper surface of the portion of the insulator film 410 located on the upper surface of the p-side ohmic electrode 309 to be in contact with the upper surface of the p-side ohmic electrode 309 through the opening 410a, as shown in FIG. 144. Further, an n-side electrode 312 is formed on the back surface of an n-type GaN substrate 301. Thus, the nitride semiconductor laser element according to the thirtieth embodiment is completed.

### Thirty-First Embodiment

Referring to FIGS. 149 to 153, an example of varying the width (width of optical confinement) between side ends of ion-implanted light absorption layers with a portion closer to a cavity end surface of an element and a portion closer to the central portion is described with reference to this thirty-first embodiment.

According to this thirty-first embodiment, an n-type buffer layer 602 of n-type GaN doped with Si having a thickness of about 1 μm is formed on an n-type GaN substrate 601, as shown in FIG. 149. An n-type cladding layer 603 of n-type Al_{0.07}Ga_{0.03}N doped with Si having. a thickness of about 1 μm is formed on the n-type buffer layer 602. The n-type buffer layer 602 and the n-type cladding layer 603 are examples of the “first nitride semiconductor layer” in the present invention.

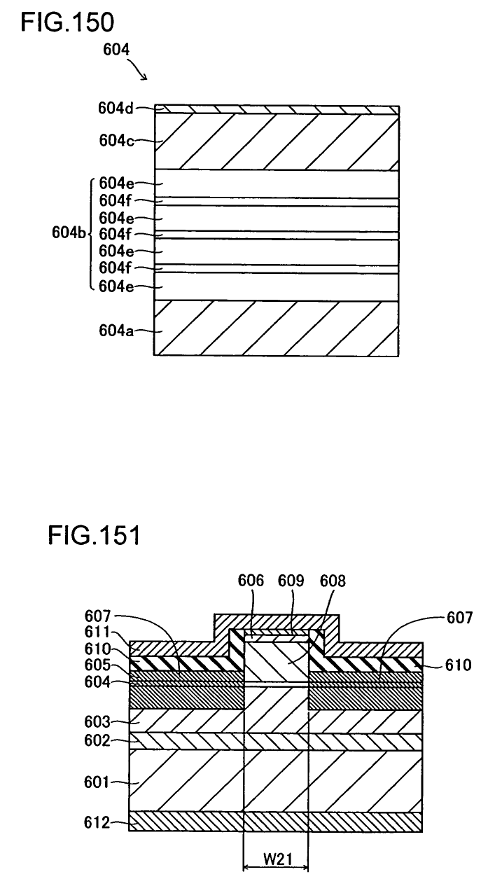

An MQW emission layer 604 is formed on the n-type cladding layer 603. This MQW emission layer 604 is constituted of an n-type light guide layer 604a, an MQW active layer 604b, an undoped light guide layer 604c and an undoped cap layer 604d, as shown in FIG. 150. The n-type light guide layer 604a is formed on the n-type cladding layer 603 (see FIG. 149), and consists of n-type In_{0.1}Ga_{0.9}N doped with Si having a thickness of about 0.1 μm. The MQW active layer 604b, formed on the n-type light guide layer 604a, has a structure obtained by alternately stacking four barrier layers 604e of undoped In_{0.02}Ga_{0.08}N each having a thickness of about 8 nm and three well layers 604f of undoped In_{0.15}Ga_{0.85}N each having a thickness of about 3.5 nm. The undoped light guide layer 604c, formed on the MQW active layer 604b, consists of undoped In_{0.1}Ga_{0.9}N having a thickness of about 0.1 μm. The undoped cap layer 604d, formed on the undoped light guide layer 604c, consists of Al_{0.15}Ga_{0.85}N having a thickness of about 20 nm.

As shown in FIG. 149, a p-type cladding layer 605 having a projecting portion and consisting of p-type Al_{0.07}Ga_{0.03}N doped with Mg having a thickness of about 0.4 μm is formed on the MQW emission layer 604. The thickness of the projecting portion of this p-type cladding layer 605 is about 0.35 μm, and the thickness of flat portions other than the projecting portion is about 0.05 μm. A p-type contact layer 606 of p-type GaN doped with Mg having a thickness of about 20 nm is formed on the projecting portion of the p-type cladding layer 605. The projecting portion of the p-type cladding layer 605 and the p-type contact layer 606 constitute a striped (elongated) ridge portion 608. The p-type cladding layer 605 and the p-type contact layer 606 are examples of the “second nitride semiconductor layer” in the present invention.

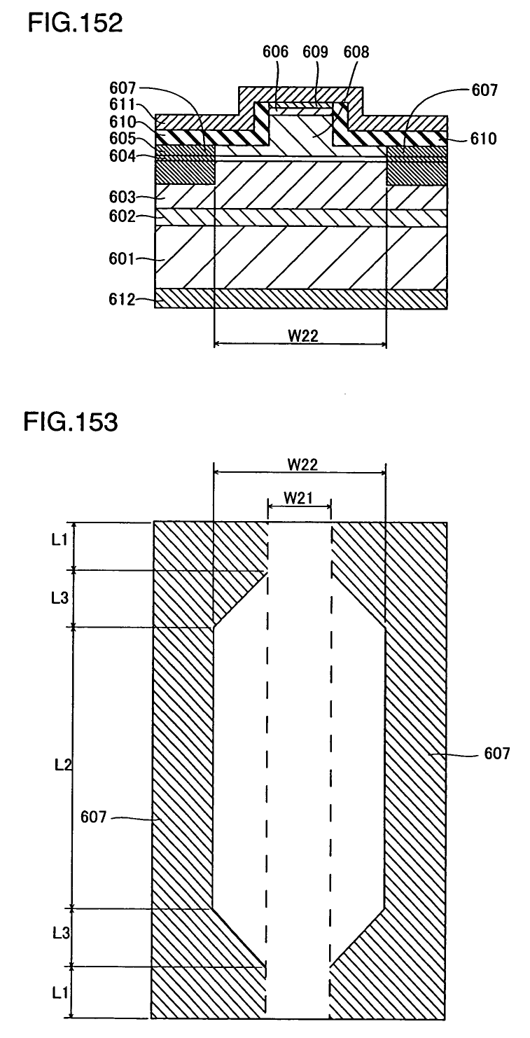

According to the thirty-first embodiment, ion-implanted light absorption layers 607 formed by ion-implanting carbon (C) are provided. These ion-implanted light absorption layers 607 have an implantation depth (about 0.4 μm) reaching the interior of the n-type cladding layer 603 from the surfaces of the flat portions of the p-type cladding layer 605 other than the projecting portion. The ion-implanted light absorption layers 607 are examples of the “light absorption layer” in the present invention. The width (width of optical confinement) between side ends of these ion-implanted light absorption layers 607 varies with portions close to a cavity end surface of an element and portions close to the central portion. More specifically, the width W21 between the side ends of portions of the ion-implanted light absorption layers 607 located in the vicinity of the cavity end surface of the element has a size (about 1.5 μm) substantially identical to the width (width of current narrowing) of the ridge portion 608, as shown in FIGS. 151 and 153. As shown in FIGS. 152 and 153, the width W22 between the side ends of portions of the ion-implanted light absorption layers 607 located in the vicinity of the central portion of the element has a size (about 7.5 μm) larger than the width (width of current narrowing) of the ridge portion 608. In other words, the width W21 (about 1.5 μm) between the side ends of the portions of the ion-implanted light absorption layers 607 located in the vicinity of the cavity end surface of the element has a smaller size than the width W22 (about 7.5 μm) between the side ends of the portions of the ion-implanted light absorption layers 607 located in the vicinity of the central portion of the element. As shown in FIG. 153, boundary regions between the portions of the ion-implanted light absorption layers 607 located in the vicinity of the cavity end surface of the element and the portions of the ion-implanted light absorption layers 607 located in the vicinity of the central portion of the element are formed in tapered shapes so that the width thereof is gradually changed. As to the detailed planar shape of the ion-implanted light absorption layers 607, the length L1 of the portions located in the vicinity of the cavity end surface of the element is about 20 μm, the length L2 of the portions located in the vicinity of the central portion of the element is about 500 μm and the length L3 of the tapered portions is about 30 μm.

As shown in FIG. 149, a p-side ohmic electrode 609 consisting of a Pt layer having a thickness of about 1 nm and a Pd layer having a thickness of about 20 nm in ascending order is formed on the p-type contact layer 606 constituting the ridge portion 608. Further, insulator films 610 of SiO₂ having a thickness of about 100 nm to about 300 nm are formed on the surface of the p-type cladding layer 605 and the side surfaces of the p-type contact layer 606 and the p-side ohmic electrode 609. A p-side pad electrode 611 consisting of a Ti layer having a thickness of about 100 nm, a Pd layer having a thickness of about 100 nm and an Au layer having a thickness of about 300 nm in ascending order is formed on the upper surfaces of the insulator films 610 to be in contact with the upper surface of the p-side ohmic electrode 609. An n-side electrode 612 consisting of an Al layer having a thickness of about 6 nm, a Pd layer having a thickness of about 10 nm and an Au layer having a thickness of about 300 nm from the side closer to the back surface of the n-type GaN substrate 601 is formed on the back surface of the n-type GaN substrate 601.

According to the thirty-first embodiment, as hereinabove described, the ion-implanted light absorption layers 607 formed by ion implantation are so provided on the regions of the p-type cladding layer 605 other than the projecting portion constituting the ridge portion 608 that the ion-implanted light absorption layers 607 can be formed with excellent reproducibility since ion implantation is excellent in reproducibility. Further, the width W21 between the side ends of the portions of the ion-implanted light absorption layers 607 located in the vicinity of the cavity end surface of the element is rendered smaller than the width W22 between the side ends of the portions of the ion-implanted light absorption layers 607 located in the vicinity of the central portion of the element so that transverse optical confinement can be excellently performed on the cavity end surface of the element, whereby the transverse mode can be stabilized. Thus, outbreak of kinks (bending of current-light output characteristics) resulting from higher mode oscillation can be suppressed. Further, light absorption in the vicinity of the MQW emission layer can be inhibited from excessiveness at the central portion of the element, whereby increase of a threshold current can be suppressed. Consequently, the beam shape can be stabilized while suppressing increase of the threshold current, reduction of slope efficiency and reduction of the kink level.

According to the thirty-first embodiment, further, the boundary regions between the portions of the ion-implanted light absorption layers 607 located in the vicinity of the cavity end surface of the element and the portions of the ion-implanted light absorption layers 607 located in the vicinity of the central portion of the element are formed in the tapered shapes so that the width thereof is gradually changed, whereby abrupt change of light absorption can be suppressed. Thus, coupling loss between portions close to the cavity end surface of the element and portions close to the central portion of the element can be so suppressed that reduction of output characteristics can be suppressed. Further, the boundary regions between the portions of the ion-implanted light absorption layers 607 located in the vicinity of the cavity end surface of the element and the portions of the ion-implanted light absorption layers 607 located in the vicinity of the central portion of the element are so formed in the tapered shapes that the width of the boundary regions between the portions of the ion-implanted light absorption layers 607 located in the vicinity of the cavity end surface of the element and the portions of the ion-implanted light absorption layers 607 located in the vicinity of the central portion of the element can be easily gradually changed.

A fabrication process for a nitride semiconductor laser element according to the thirty-first embodiment is now described with reference to FIGS. 149, 150 and 154 to 164.

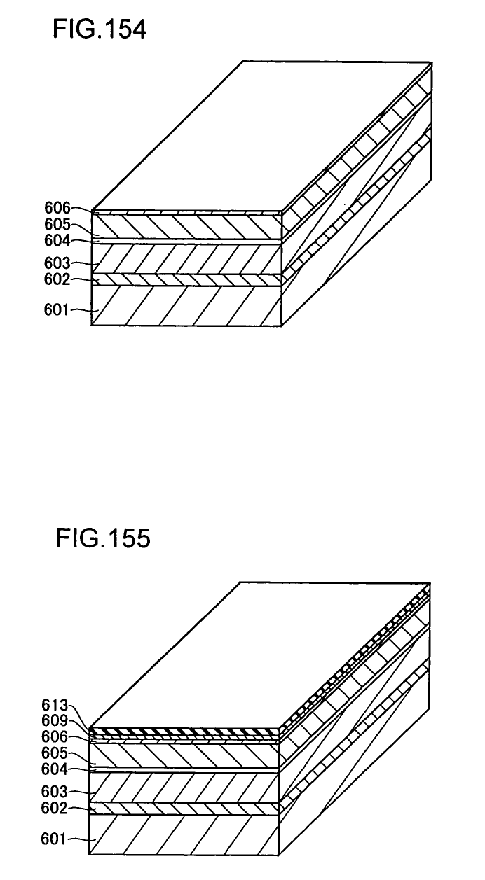

As shown in FIG. 154, the n-type buffer layer 602 of n-type GaN doped with Si having the thickness of about 1 μm and the n-type cladding layer 603 of n-type Al_{0.07}Ga_{0.03}N doped with Si having the thickness of about 1 μm are successively grown on the n-type GaN substrate 601 by MOCVD.

As shown in FIG. 150, the n-type light guide layer 604a of n-type In_{0.1}Ga_{0.9}N doped with Si having the thickness of about 0.1 μm and the MQW active layer 604b are thereafter successively grown on the n-type cladding layer 603 (see FIG. 154). In order to grow the MQW active layer 604b, the four barrier layers 604e of undoped In_{0.02}Ga_{0.08}N each having the thickness of about 8 nm and the three well layers 604f of undoped In_{0.15}Ga_{0.85}N each having the thickness of about 3.5 nm are alternately stacked. Then, the undoped light guide layer 604c of undoped In_{0.1}Ga_{0.9}N having the thickness of about 0.1 μm and the undoped cap layer 604d of Al_{0.15}Ga_{0.85}N having the thickness of about 20 nm are successively grown on the MQW active layer 604b. Thus, the MQW emission layer 604 consisting of the n-type light guide layer 604a, the MQW active layer 604b, the undoped light guide layer 604c and the undoped cap layer 604d is formed.

As shown in FIG. 154, the p-type cladding layer 605 consisting of p-type Al_{0.07}Ga_{0.03}N doped with Mg having the thickness of about 0.4 μm and the p-type contact layer 606 of p-type GaN doped with Mg having the thickness of about 20 nm are successively grown on the MQW emission layer 604.

As shown in FIG. 155, the p-side ohmic electrode 609 consisting of the Pt layer having the thickness of about 1 nm and the Pd layer having the thickness of about 20 nm in ascending order is formed on the p-type contact layer 606 by electron beam evaporation. Thereafter an SiO₂ film 613 having a thickness of about 200 μm to about 500 μm is formed on the p-side ohmic electrode 609 by plasma CVD or electron beam evaporation. This SiO₂ film 613 is employed as an etching mask in a step described later. Therefore, the SiO₂ film 613 is preferably formed by plasma CVD allowing formation of an excellent film.

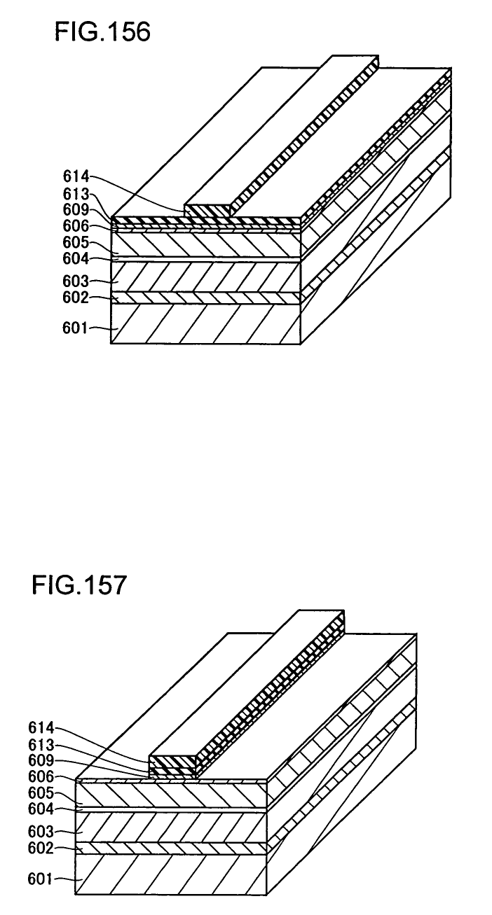

As shown in FIG. 156, a positive resist film 614 having a thickness of about 0.5 μm to about 1 μm is formed on a prescribed region of the SiO₂ film 613 in a striped (elongated) shape.

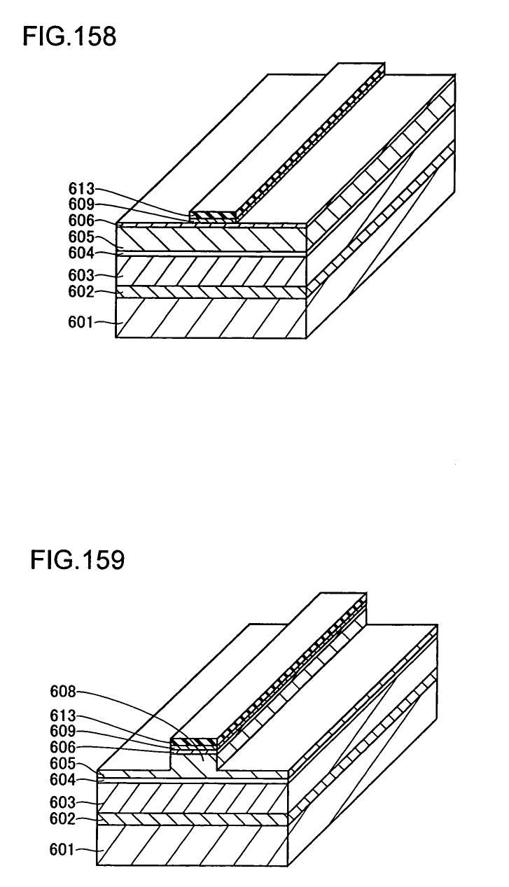

As shown in FIG. 157, the positive resist film 614 is employed as a mask for removing prescribed regions of the p-side ohmic electrode 609 and the SiO₂ film 613 by reactive ion etching (RIE: Reactive Ion Etching) with CF₄ gas. Etching conditions are a gas flow rate of about 10 sccm, a pressure of about 0.13 Pa and power of about 200 W. Thereafter the positive resist film 614 is removed through a resist stripper, thereby obtaining the state shown in FIG. 158.

As shown in FIG. 159, the SiO₂ film 613 is employed as a mask for partially removing the p-type contact layer 606 and the p-type cladding layer 605 by a thickness of about 0.35 μm from the upper surfaces by reactive ion etching with CF₄ gas. Thus, the striped (elongated) ridge portion 608 constituted of the projecting portion of the p-type cladding layer 605 and the p-type contact layer 606 is formed.

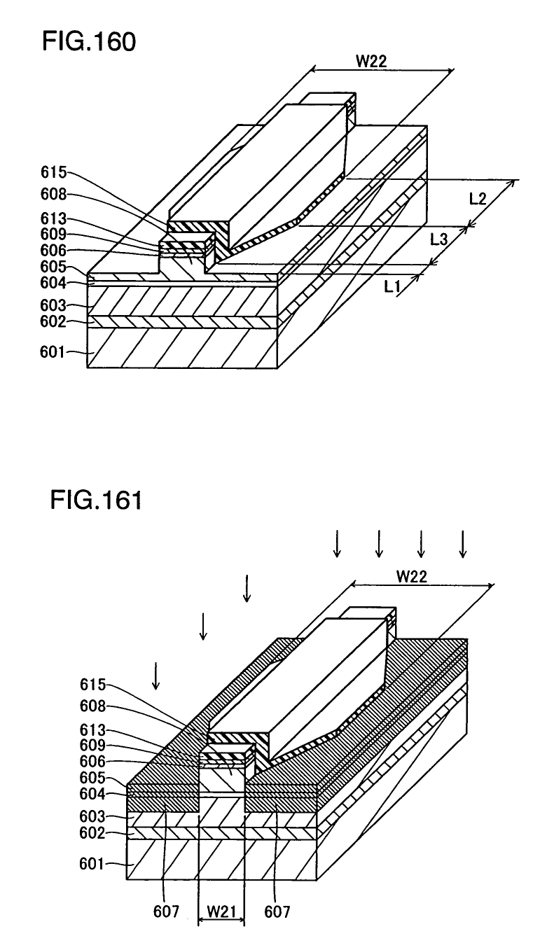

As shown in FIG. 160, an ion implantation mask 615 of positive resist having a thickness of about 1 μm is formed on prescribed regions of the upper surface and the side surfaces of the SiO₂ film 613, the side surfaces of the p-side ohmic electrode 609 and the ridge portion 608 and the surfaces of flat portions of the p-type cladding layer 605 other than the projecting portion. At this time, the length L1 of the ion implantation mask 615 from the cavity end surface of the element is set to about 20 μm, while the length L2 of a portion of the ion implantation mask 615 in the vicinity of the central portion of the element is set to about 500 μm. Further, the boundary region between the portion of the ion implantation mask 615 located in the vicinity of the cavity end surface of the element and the portion of the ion implantation mask 615 located in the vicinity of the central portion of the element is formed in a tapered shape so that the width thereof is gradually changed, while the length L3 of the tapered portion is set to about 30 μm. In addition, the width of the portion of the ion implantation mask 615 close to the central portion of the element is set to the width W22 (about 7.5 μm).

According to the thirty-first embodiment, the ion implantation mask 615 is thereafter employed as a mask for ion-implanting carbon (C), as shown in FIG. 161. Ion implantation conditions for carbon are implantation energy of about 95 keV, a dose of about 5×10¹³ cm⁻² and an implantation temperature of the room temperature. This ion implantation is performed from a direction inclined by about 70 in the longitudinal direction of the p-side ohmic electrode 609. Thus, the ion-implanted light absorption layers 607 having the ion implantation depth (thickness) reaching the interior of the n-type cladding layer 603 from the surfaces of the flat portions of the p-type cladding layer 605 other than the projecting portion are formed. The width W21 between the side ends of the portions of the ion-implanted light absorption layers 607 located in the vicinity of the cavity end surface of the element reaches the size (about 1.5 μm) substantially identical to the width (width of current narrowing) of the ridge portion 608, while the width W22 between the side ends of the portions of the ion-implanted light absorption layers 607 located in the vicinity of the central portion of the element reaches the size (about 7.5 μm) larger than the width (width of current narrowing) of the ridge portion 608. Further, the boundary regions between the portions of the ion-implanted light absorption layers 607 located in the vicinity of the cavity end surface of the element and the portions of the ion-implanted light absorption layers 607 located in the vicinity of the central portion of the element are formed in the tapered shapes so that the width thereof is gradually changed.

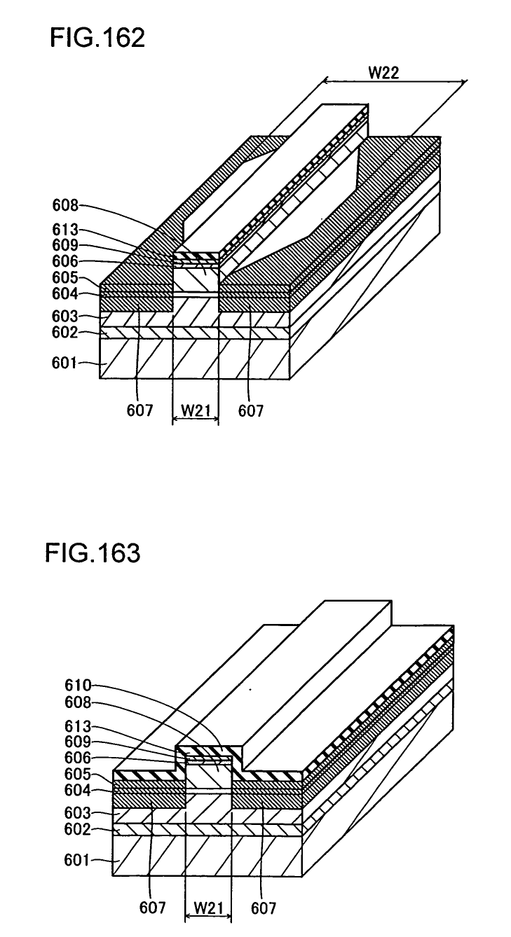

Then, the ion implantation mask 615 is removed through a resist stripper. Thereafter the ion implantation mask 615 is completely removed by ashing with plasma. Thus, the state shown in FIG. 162 is obtained.

As shown in FIG. 163, the insulator film 610 of SiO₂ having the thickness of about 100 nm to about 300 nm is formed to cover the overall surface.

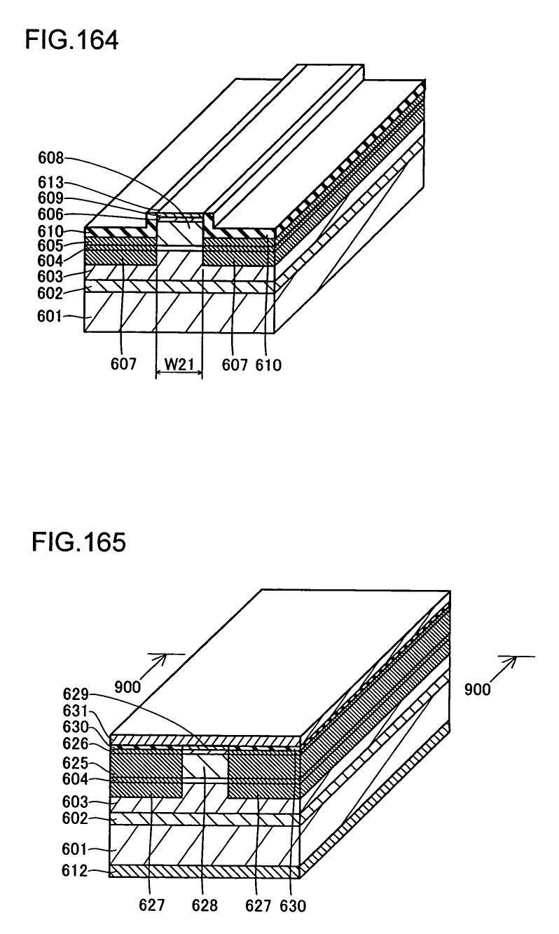

As shown in FIG. 164, the portion of the insulator film 610 located on the upper surface of the p-side ohmic electrode 609 is removed.

Finally, the p-side pad electrode 611 consisting of the Ti layer having the thickness of about 100 nm, the Pd layer having the thickness of about 100 nm and the Au layer having the thickness of about 300 nm in ascending order is formed on the upper surfaces of the insulator films 610 to be in contact with the upper surface of the p-side ohmic electrode 609, as show in FIG. 149. Further, the n-side electrode 612 consisting of the Al layer having the thickness of about 6 nm, the Pd layer having the thickness of about 10 nm and the Au layer having the thickness of about 300 nm from the side closer to the back surface of the n-type GaN substrate 601 is formed on the back surface of the n-type GaN substrate 601. Thus, the nitride semiconductor laser element according to the thirty-first embodiment is completed.

### Thirty-Second Embodiment

Referring to FIGS. 165 to 167, an example of forming no ridge portion dissimilarly to the aforementioned thirty-first embodiment is described with reference to this thirty-second embodiment. The remaining structure of the thirty-second embodiment is similar to that of the aforementioned thirty-first embodiment.

According to this thirty-first embodiment, an n-type buffer layer 602, an n-type cladding layer 603 and an MQW emission layer 604 are successively formed on an n-type GaN substrate 601, as shown in FIG. 165. A p-type cladding layer 625 of p-type Al_{0.07}Ga_{0.03}N doped with Mg having a thickness of about 0.4 μm is formed on the MQW emission layer 604. A p-type contact layer 626 of p-type GaN doped with Mg having a thickness of about 20 nm is formed on the p-type cladding layer 625. The p-type cladding layer 625 and the p-type contact layer 626 are examples of the “second nitride semiconductor layer” in the present invention.

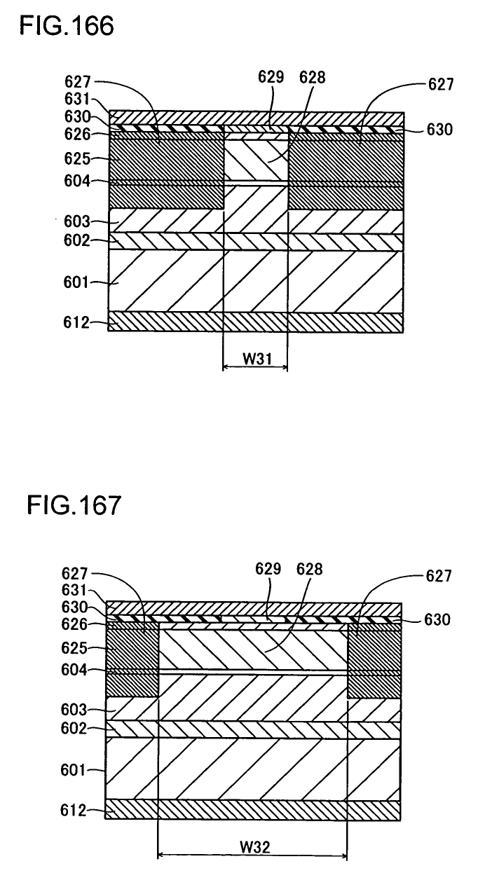

According to the thirty-second embodiment, ion-implanted light absorption layers 627 formed by ion-implanting carbon (C) are provided. These ion-implanted light absorption layers 607 have an implantation depth (thickness) reaching the interior of the n-type cladding layer 603 from the upper surface of the p-type contact layer 626. In other words, the ion-implanted light absorption layers 627 are formed up to positions of a depth of about 0.3 μm from the surface of the n-type cladding layer 603. The ion-implanted light absorption layers 627 are examples of the “light absorption layer” in the present invention. A region between side ends of the ion-implanted light absorption layers 627 functions as a current passing region 628. The width (width of optical confinement) between side ends of these ion-implanted light absorption layers 607 varies with portions close to a cavity end surface of an element and portions close to the central portion. In other words, the width W31 (about 1.5 μm) (see FIG. 166) between the side ends of portions of the ion-implanted light absorption layers 627 located in the vicinity of the cavity end surface of the element has a size smaller than the width W32 (about 7.5 μm) (see FIG. 167) between the side ends of the portions of the ion-implanted light absorption layers 627 located in the vicinity of the central portion of the element, as shown in FIGS. 166 and 167. Similarly to the aforementioned thirty-first embodiment shown in FIG. 153, further, boundary regions between the portions of the ion-implanted light absorption layers 627 located in the vicinity of the cavity end surface of the element and the portions of the ion-implanted light absorption layers 627 located in the vicinity of the central portion of the element are formed in tapered shapes so that the width thereof is gradually changed.

As shown in FIG. 165, a p-side ohmic electrode 629 consisting of a Pt layer having a thickness of about 1 nm and a Pd layer having a thickness of about 20 nm in ascending order is formed on a region of the p-type contact layer 626 formed with no ion-implanted light absorption layers 627. Further, insulator films 630 of SiO₂ having a thickness of about 100 nm to about 300 nm are formed on regions of the p-type contact layer 626 formed with the ion-implanted light absorption layers 627. A p-side pad electrode 631 consisting of a Ti layer having a thickness of about 100 nm, a Pd layer having a thickness of about 100 nm and an Au layer having a thickness of about 300 nm in ascending order is formed on the upper surfaces of the p-side ohmic electrode 629 and the insulator films 610. An n-side electrode 612 is formed on the back surface of the n-type GaN substrate 601.

According to the thirty-second embodiment, as hereinabove described, the ion-implanted light absorption layers 627 are provided while the portion between the side ends of these ion-implanted light absorption layers 627 is made to function as the current passing region 628, whereby fabrication steps can be simplified as compared with a case of forming a ridge portion. On the other hand, element output characteristics are reduced as compared with a case of performing current narrowing with a ridge portion. When employed for a playback information from an optical disk requiring no high output, however, no problem arises also when the output characteristics of the element are reduced.

The remaining effects of the thirty-second embodiment are similar to those of the aforementioned thirty-first embodiment.

A fabrication process for a nitride semiconductor laser element according to the thirty-second embodiment is now described with reference to FIGS. 165 and 168 to 172.

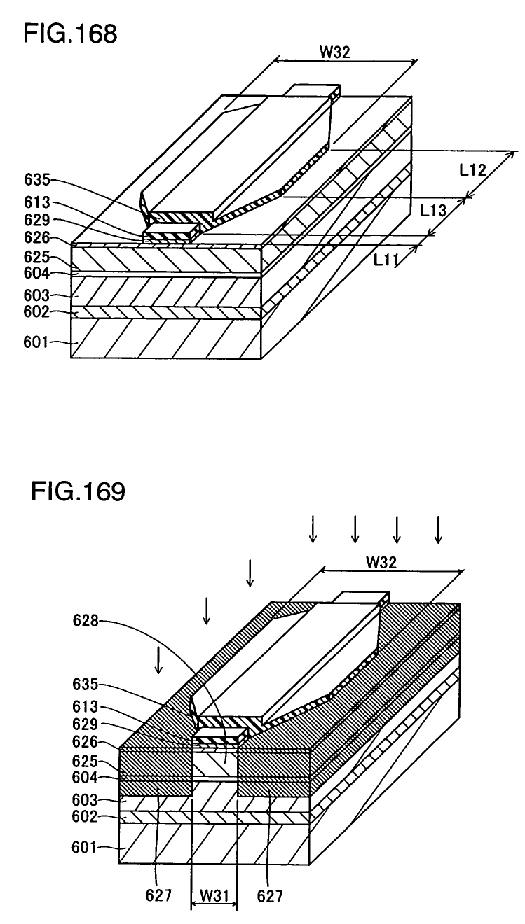

As shown in FIG. 168, layers up to the striped (elongated) p-side ohmic electrode 629 and an SiO₂ film 613 are formed through a fabrication process similar to that of the thirty-first embodiment shown in FIGS. 154 to 158. Thereafter an ion implantation mask 635 of positive resist having a thickness of about 1 μm is formed on prescribed regions of the upper surface and the side surfaces of the SiO₂ film 613, the side surfaces of the p-side ohmic electrode 629 and the upper surface of the p-type contact layer 626. At this time, the length L11 of the ion implantation mask 615 from the cavity end surface of the element is set to about 20 μm, while the length L12 of a portion in the vicinity of the central portion of the element is set to about 500 μm. Further, the boundary region between the portion of the ion implantation mask 635 located in the vicinity of the cavity end surface of the element and the portion of the ion implantation mask 635 located in the vicinity of the central portion of the element is formed in a tapered shape so that the width thereof is gradually changed, while the length L13 of the tapered portion is set to about 30 μm. In addition, the width of the portion of the ion implantation mask 635 close to the central portion of the element is set to the width W32 (about 7.5 μm).

According to the thirty-second embodiment, the ion implantation mask 635 is thereafter employed as a mask for ion-implanting carbon (C), as shown in FIG. 169. Thus, the ion-implanted light absorption layers 607 having the implantation depth (thickness) reaching the interior of the n-type cladding layer 603 from the upper surface of the p-type contact layer 626 are formed. Ion implantation conditions for carbon are implantation energy of about 95 keV, a dose of about 5×10¹³ cm⁻² and an implantation temperature of the room temperature. This ion implantation is performed from a direction inclined by about 70 in the longitudinal direction of the p-side ohmic electrode 629. The width W31 between the side ends of the portions of the ion-implanted light absorption layers 627 located in the vicinity of the cavity end surface of the element reaches the size (about 1.5 μm) substantially identical to the width of the p-side ohmic electrode 629, while the width W32 between the side ends of the portions of the ion-implanted light absorption layers 627 located in the vicinity of the central portion of the element reaches the size (about 7.5 μm) larger than the width of the p-side ohmic electrode 629. The region between the side ends of the ion-implanted light absorption layers 627 functions as the current passing region 628. Further, the boundary regions between the portions of the ion-implanted light absorption layers 627 located in the vicinity of the cavity end surface of the element and the portions of the ion-implanted light absorption layers 627 located in the vicinity of the central portion of the element are formed in the tapered shapes so that the width thereof is gradually changed.

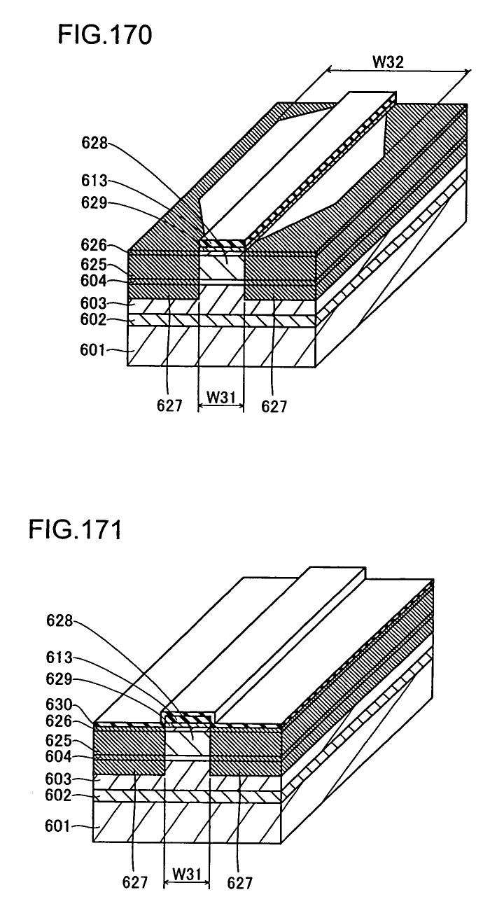

Then, the ion implantation mask 635 is removed through a resist stripper. Thereafter the ion implantation mask 635 is completely removed by ashing with plasma. Thus, the state shown in FIG. 170 is obtained.

As shown in FIG. 171, the insulator film 630 of SiO₂ having the thickness of about 100 nm to about 300 nm is formed to cover the overall surface.

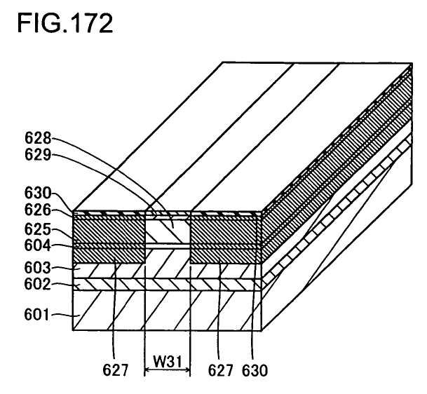

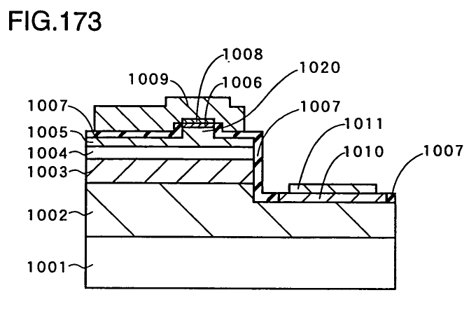

Thereafter the SiO₂ film 613 and the portion of the insulator film 630 located on the SiO₂ film 613 are removed, thereby exposing the p-side ohmic electrode 629 as shown in FIG. 172.

Finally, the p-side pad electrode 631 consisting of the Ti layer having the thickness of about 100 nm, the Pd layer having the thickness of about 100 nm and the Au layer having the thickness of about 300 nm in ascending order is formed on the upper surfaces of the p-side ohmic electrode 629 and the insulator films 630 to be in contact with the upper surface of the p-side ohmic electrode 609, as show in FIG. 165. Further, the n-side electrode 612 is formed on the back surface of the n-type GaN substrate 601. Thus, the nitride semiconductor laser element according to the thirty-second embodiment is completed.

The embodiments disclosed this time must be considered illustrative and not restrictive in all points. The scope of the present invention is shown not by the above description of the embodiments but by the scope of claim for patent, and all modifications within the meaning and range equivalent to the scope of claim for patent are included.

For example, while the ion-implanted light absorption layers have been formed by ion-implanting any element of carbon, silicon, boron, phosphorus, magnesium or argon in each of the aforementioned embodiments, the present invention is not restricted to this but another element may be ion-implanted. As to the implanted element, a dopant having conductivity reverse to the conductivity of the implanted-side semiconductor is preferably employed. Thus, the ion-implanted light absorption layers can be formed through ion implantation of a low dose. Further, a heavy element having a larger mass number than carbon is preferably employed. Thus, channeling of implanted ions can be prevented. In addition, either a group 3 element such as Al, Ga or In or a group 5 element such as As or Sb may be implanted. In particular, phosphorus or As, forming a deep level (isoelectronic trap), can form sufficient light absorption layers at a low dose. Further, nitrogen, oxygen and neon etc. can be listed as elements other than the above.

While the ion-implanted light absorption layers having introduced element concentration of about 1×10²⁰ cm⁻³ have been formed by ion-implanting a large quantity of elements in each of the aforementioned embodiments, the present invention is not restricted to this but the maximum value of the introduced element concentration may be at least about 5×10¹⁹ cm⁻³. Further, the maximum value of the crystal defect density of the ion-implanted light absorption layers may be at least about 5.0×10¹⁸ cm⁻³. In addition, the maximum value of the light absorption coefficient of the ion-implanted light absorption layers may be at least about 1×10⁴ cm⁻¹. If corresponding to any of these conditions, transverse optical confinement can be sufficiently performed.

While the ion-implanted light absorption layers 57 have been formed by simply ion-implanting carbon in the aforementioned sixth embodiment, the present invention is not restricted to this but heat treatment (annealing) may be performed after ion implantation. For example, heat treatment of about 10 minutes may be performed in an N₂/H₂ gas mixture atmosphere of about 500° C. in the process of the sixth embodiment shown in FIG. 27. Cleanliness of the p-type contact layer 6 is maintained by performing the heat treatment in the atmosphere containing H₂, whereby excellent p-side ohmic properties are obtained. In this case, the light absorption coefficient of the ion-implanted light absorption layers 57 is so reduced that the threshold current is reduced. The atmosphere gas in the heat treatment may not be the N₂/H₂ gas mixture. For example, the atmosphere gas may be N₂/NH₃ gas or NH₃ gas. Thus, it is possible to reduce the number of crystal defects in the ion-implantation light absorption layers 57 while adjusting (reducing) the degree of light absorption (light absorption coefficient) through the heat treatment.

While ion implantation has been performed through the through film having a first ion permeation region (SiO₂ of 10 nm) having first stopping power and a second ion permeation region (SiO₂ of 10 nm and Pt of 60 nm) having second stopping power more hardly permeating ions than the first ion permeation region in the aforementioned thirteenth embodiment, the present invention is not restricted to this but the first ion permeation region may be constituted of a through film having a small thickness and the second ion permeation region may be constituted of a through film having a large thickness. For example, the first ion permeation region may be constituted of an SiO₂ film of 10 nm and the second ion permeation region may be constituted of an SiO₂ film of 300 nm, or the second ion permeation region may be constituted of a Pt film of 60 nm while forming no through film on the first ion permeation region. Further, the first ion permeation region may be constituted of a through film consisting of a material having low density and the second ion permeation region may be constituted of a through film consisting of a material having high density. For example, the first ion permeation region may be constituted of an SiO₂ film of 60 nm and the second ion permeation region may be constituted of a Pt film of 60 nm.

While the case of electrically isolating p-type semiconductor layers from each other by forming the ion-implanted light absorption layers 187 increased in resistance by ion implantation has been described with reference to the aforementioned eighteenth embodiment, the present invention is not restricted to this but may be applied to a case of electrically isolating a p-type semiconductor layer and an n-type semiconductor layer from each other or a case of electrically isolating n-type semiconductor layers from each other. Further, while the example of integrating a semiconductor laser by electric isolation resulting from ion implantation has been shown in the eighteenth embodiment, the present invention is not restricted to this but may be applied to a case of performing integration of a light-emitting device such as a light-emitting diode, an electronic device such as an FET (Field Effect Transistor) or an HBT (Heterojunction Bipolar Transistor) or a photodetector. Further, the present invention is also applicable to an IC (Integrated Circuit), an OEIC (Optoelectronic Integrated Circuit) or an optical IC.

While a striped optical confinement region has been formed and a nitride semiconductor laser element having a waveguide structure of a striped structure has been formed in each of the aforementioned embodiments, a circular optical confinement region or the like may be formed by forming a circular non-implanted region or the like for preparing a vertical cavity type nitride semiconductor laser element.

While the ion-implanted light absorption layers 17 have been formed by ion-implanting a large quantity of carbon in the aforementioned second embodiment, the present invention is not restricted to this but ion implantation may be performed with an element such as hydrogen or boron at a low dose. For example, boron may be implanted at implantation energy of about 65 keV and a dose of about 1×10¹⁴ cm⁻². The peak intensity of the impurity concentration in this case is 8×10¹⁸ cm⁻³.

While the p-type contact layer of AlGaN or GaN has been employed in each of the aforementioned embodiments, the present invention is not restricted to this but a p-type contact layer consisting of InGaN may be employed.

While the ion-implanted light absorption layers 307 have been formed only on the surfaces of the flat portions of the p-type cladding layer 305 other than the projecting portion constituting the ridge portion 308 so that the side ends of the ion-implanted light absorption layers 307 are arranged substantially immediately under the side ends of the ridge portion 308 in the aforementioned twenty-first embodiment, the present invention is not restricted to this but the light absorption layers may be formed to reach the regions formed with the MQW emission layer and the n-type cladding layer so that the side ends of the light absorption layers are arranged substantially immediately under the side ends of the ridge portion.

While the ion-implanted light absorption layers 327 (347) have been formed to reach the n-type cladding layer 303 so that the side ends of the ion-implanted light absorption layers 327 (347) are arranged on the positions separated from the side ends of the ridge portion 308 (348) in each of the aforementioned twenty-second and twenty-third embodiments, the present invention is not restricted to this but the light absorption layers may be formed only on the surfaces of the flat portions of the p-type cladding layer other than the projecting portion constituting the ridge portion so that the side ends of the light absorption layers are arranged on the positions separated from the side ends of the ridge portion.

While the side ends of the ion-implanted light absorption layers 327 (347) have been separated from the side ends of the ridge portion 308 (348) in the range of not more than about 2 μm in each of the aforementioned twenty-second and twenty-third embodiments, the present invention is not restricted to this but the interval between the side ends of the light absorption layers and the side ends of the ridge portion may be in the range of not more than 5 μm.

While no heat treatment has been performed after ion implantation in each of the aforementioned twenty-first to twenty-fifth embodiments, the present invention is not restricted to this but heat treatment may be performed after ion implantation, in order to adjust the absorption coefficient of the light absorption layers. In this case, the heat treatment is preferably performed in nitrogen gas having a flow rate of about 1 L/min. under a temperature condition of not more than about 400° C. Adjustment of the absorption coefficient is performed by controlling the heat treatment time.

While the regions between the portions of the ion-implanted light absorption layers located in the vicinity of the cavity end surface of the element and the portions of the ion-implanted light absorption layers located in the vicinity of the central portion of the element have been formed in the tapered shapes in each of the aforementioned thirty-first and thirty-second embodiments, the present invention is not restricted but a shape other than the tapered shape may be employed so far as the width is gradually changed in the boundary regions between the portions of the ion-implanted light absorption layers located in the vicinity of the cavity end surface of the element and the portions of the ion-implanted light absorption layers located in the vicinity of the central portion of the element. Further, the boundary regions between the portions of the ion-implanted light absorption layers located in the vicinity of the cavity end surface of the element and the portions of the ion-implanted light absorption layers located in the vicinity of the central portion of the element may not be so shaped that the width is gradually changed. In this case, the structure of the element can be simplified. However, coupling loss is increased between the portions located in the vicinity of the cavity end surface of the element and the portions located in the vicinity of the central portion of the element, and hence the output characteristics are reduced.

1. A nitride semiconductor laser element comprising:
a first nitride semiconductor layer (2, 3, 172, 173, 302, 303, 602, 603);
an emission layer (4, 174, 304, 604) formed on said first nitride semiconductor layer;
a second nitride semiconductor layer (5, 6, 175, 176, 305, 306, 345, 365, 385, 605, 606, 625, 626) formed on said emission layer; and
a light absorption layer (7, 17, 27, 37, 47, 57, 67, 77b, 87b, 97b, 107b, 117a, 127, 137, 147, 157a, 157b, 177a, 187, 197a, 207a, 307, 327, 347, 367, 387, 407, 437, 457, 477, 497, 607, 627) formed by introducing a first impurity element into at least parts of regions of said first nitride semiconductor layer and said second nitride semiconductor layer other than a current passing region (8, 128, 138, 148, 158a, 158b, 178, 188, 198, 208, 628) wherein
said light absorption layer is formed excluding a first width,
the nitride semiconductor laser element further comprising an electrode layer coming into ohmic contact with said second nitride semiconductor layer with a width smaller than said first width.

2. The nitride semiconductor laser element according to claim 1, wherein the upper surface of said light absorption layer and the upper surface of said current passing region are formed substantially on the same plane.

3. The nitride semiconductor laser element according to claim 1, wherein said second nitride semiconductor layer has a projecting ridge portion (308, 348, 368, 388, 608) including the current passing region.

4. The nitride semiconductor laser element according to claim 3, wherein the side ends of said light absorption layer (307, 407, 607) are substantially located immediately under the side ends of said ridge portion.

5. The nitride semiconductor laser element according to claim 3, wherein the side ends of said light absorption layer (327, 347, 437, 457, 477, 497) are provided on positions separated at prescribed intervals from the side ends of said ridge portion.

6. The nitride semiconductor laser element according to claim 3, wherein said light absorption layer (367, 387) is provided on each side surface of said ridge portion.

7. The nitride semiconductor laser element according to claim 1, wherein said light absorption layer has a larger number of crystal defects than said current passing region.

8. The nitride semiconductor laser element according to claim 1, wherein said light absorption layer has a current blocking function.

9. The nitride semiconductor laser element according to claim 1, further comprising a current blocking layer (197b, 207b) formed by introducing a second impurity element into at least parts of the regions of said first nitride semiconductor layer and said second nitride semiconductor layer other than the current passing region.

10. The nitride semiconductor laser element according to claim 1, wherein said light absorption layer is formed by ion-implanting said first impurity element into the regions of said first nitride semiconductor layer and said second nitride semiconductor layer other than the current passing region.

11. The nitride semiconductor laser element according to claim 1, wherein said light absorption layer has either high resistance or a reverse conductivity type to said current passing region.

12. The nitride semiconductor laser element according to claim 1, wherein said first impurity element is an impurity element other than group 3 and group 5 elements.

13. The nitride semiconductor laser element according to claim 1, wherein said first impurity element is an impurity element having a larger mass number than carbon.

14. The nitride semiconductor laser element according to claim 1, wherein the maximum value of the impurity concentration of said first impurity element is at least 5.0×10¹⁹ cm⁻³.

15. The nitride semiconductor laser element according to claim 1, wherein the maximum value of crystal defect density of at least either said first nitride semiconductor layer or said second nitride semiconductor layer containing said first impurity element is at least 5×10¹⁸ cm⁻³.

16. The nitride semiconductor laser element according to claim 1, wherein the maximum value of the absorption coefficient of said light absorption layer is at least 1×10⁴ cm⁻¹.

17. The nitride semiconductor laser element according to claim 1, heat-treated after introduction of said first impurity element.

18. The nitride semiconductor laser element according to claim 1, wherein said light absorption layer is formed by ion implantation from a direction inclined from the [0001] direction of a nitride semiconductor.

19. The nitride semiconductor laser element according to claim 9, wherein said current blocking layer consists of a nitride semiconductor having high resistance.

20. The nitride semiconductor laser element according to claim 9, wherein said current passing region has a p type, and
said current blocking layer contains hydrogen in higher density than said current passing region.

21. The nitride semiconductor laser element according to claim 9, wherein said current blocking layer has a reverse conductivity type to said current passing region.

22. The nitride semiconductor laser element according to claim 9, wherein said second impurity element is an impurity element other group 3 and group 5 elements.

23. The nitride semiconductor laser element according to claim 9, wherein said current blocking layer is formed by ionimplanting said second impurity element.

24. The nitride semiconductor laser element according to claim 9, wherein said current blocking layer is formed by ion-implanting said second impurity element into the lower portion of a mask layer obliquely from above.

25. The nitride semiconductor laser element according to claim 9, wherein said current blocking layer is formed by diffusing said second impurity element.

26. The nitride semiconductor laser element according to claim 9, wherein said light absorption layer is formed excluding a first width while said current narrowing layer is formed excluding a second width, said first width is larger than said second width, and a region of said second width is formed in a region of said first width.

27. The nitride semiconductor laser element according to claim 9, wherein said light absorption layer is formed separately from the emission layer by a first distance in the depth direction while said current blocking layer is formed separately from said emission layer by a second distance in the depth direction, and said first distance is larger than said second distance.

28. The nitride semiconductor laser element according to claim 9, wherein the concentration of said second impurity element in said current blocking layer is lower than the concentration of said first impurity element in said light absorption layer.

29. The nitride semiconductor laser element according to claim 9, wherein the density of crystal defects in said current blocking layer is lower than the density of crystal defects in said light absorption layer.

30. The nitride semiconductor laser element according to claim 1, wherein the impurity concentration of said first impurity element in a portion of the emission layer corresponding to an upper or lower region of said light absorption layer is not more than 5.0×10¹⁸ cm⁻³.

31. The nitride semiconductor laser element according to claim 1, wherein the density of crystal defects in a portion of said emission layer located on an upper or lower region of said light absorption layer is not more than 5.0×10^{17 cm}⁻³.

32. The nitride semiconductor laser element according to claim 1, wherein said first nitride semiconductor layer and said second nitride semiconductor layer include a cladding layer, and
the concentration of said first impurity element is maximized in the cladding layer.

33. The nitride semiconductor laser element according to claim 1, wherein said light absorption layer is formed not to be formed in the emission layer.

34. The nitride semiconductor laser element according to claim 1, wherein said first nitride semiconductor layer and said second nitride semiconductor layer include a cladding layer, and
the density of crystal defects in said light absorption layer is maximized in the cladding layer.

35. The nitride semiconductor laser element according to claim 1, wherein said first nitride semiconductor layer and said second nitride semiconductor layer include a cladding layer, and
the light absorption coefficient of said light absorption layer is maximized in the cladding layer.

36. The nitride semiconductor laser element according to claim 1, wherein said emission layer is formed on said first nitride semiconductor layer after said first impurity element is introduced into said first nitride semiconductor layer.

37. The nitride semiconductor laser element according to claim 1, wherein the impurity concentration of said first impurity element is maximized in the emission layer.

38. The nitride semiconductor laser element according to claim 1, wherein the density of crystal defects in said light absorption layer is maximized in the emission layer.

39. The nitride semiconductor laser element according to claim 1, wherein the light absorption coefficient of said light absorption layer is maximized in the emission layer.

40. The nitride semiconductor laser element according to claim 1, wherein a contact layer is formed on said second nitride semiconductor layer after said light absorption layer is formed by introducing said first impurity element into said second nitride semiconductor layer on said emission layer.

41. The nitride semiconductor laser element according to claim 1, wherein said first impurity element is ion-implanted through a through film.

42. The nitride semiconductor laser element according to claim 41, wherein said through film is an insulator film.

43. The nitride semiconductor laser element according to claim 1, wherein said first impurity element is ion-implanted through a through film having a first ion permeation region having first stopping power and a second ion permeation region having second stopping power more hardly permeating ions than said first ion permeation region.

44. The nitride semiconductor laser element according to claim 1, employing a first film including a first region having first stopping power and a second region having third stopping power hardly permeating ions as a through film while employing said second region as a mask for ion-implanting said first impurity element.

45. The nitride semiconductor laser element according to claim 1, further comprising an electrode layer formed on said second nitride semiconductor layer, wherein said first impurity element is ion-implanted into said second nitride semiconductor layer through a through film with said electrode layer serving as a mask.

46. The nitride semiconductor laser element according to claim 1, wherein an insulator film is formed on said light absorption layer.

47. (canceled)

48. The nitride semiconductor laser element according to claim 1, wherein said light absorption layer is formed excluding a first width, the nitride semiconductor laser element further comprising an electrode layer coming into ohmic contact with said second nitride semiconductor laser with a width larger than said first width.

49. The nitride semiconductor laser element according to claim 1, further comprising an electric isolation region of high resistance formed by introducing a third impurity element into at least part of a region other than said current passing region over a region passing through the emission layer from the surface of said second nitride semiconductor layer.

50. The nitride semiconductor laser element according to claim 49, wherein said electric isolation region is formed by ion-implanting said third impurity element.

51. The nitride semiconductor laser element according to claim 49, introducing a fourth impurity element into the region other than said current passing region and at least part of a region other than said electric isolation region over the region passing through the emission layer from the surface of said second nitride semiconductor layer so that the region passing through said emission layer from said second nitride semiconductor layer has the same conductivity type as said first nitride semiconductor layer.

52. The nitride semiconductor laser element according to claim 1, wherein said nitride semiconductor laser element includes a nitride semiconductor laser element, assembled in a junction-down system, mounted on a base for heat radiation from the surface of a side closer to said emission layer.

53. The nitride semiconductor laser element according to claim 1, wherein said light absorption layer (407, 437, 457, 477, 497) is divided into a plurality of parts between said current passing region and side ends of the element.

54. The nitride semiconductor laser element according to claim 53, wherein a portion of said light absorption layer (437a, 497a) closer to said current passing region has a smaller depth than a portion of said light absorption layer closer to the side ends of said element.

55. The nitride semiconductor laser element according to claim 54, wherein the portion of the light absorption layer (437a, 497a) closer to said current passing region has a depth not reaching said emission layer.

56. The nitride semiconductor laser element according to claim 1, wherein a first width (W21, W31) between side ends of said light absorption layer in the vicinity of a cavity end surface of the element is smaller than a second width (W22, W33) between side ends of a portion of said light absorption layer in the vicinity of the central portion of the element.

57. The nitride semiconductor laser element according to claim 56, wherein a boundary region between a region of said light absorption layer (607, 627) having said first width and a region having said second width has a width gradually enlarging to approach from said first width to said second width.

58. The nitride semiconductor laser element according to claim 57, wherein the boundary region between the region of said light absorption layer (607, 627) having said first width and the region having said second width is formed in a tapered shape in plan view.

59. A nitride semiconductor laser element comprising:
a first nitride semiconductor layer (2, 3, 172, 173, 302, 303, 602, 603);
an emission layer (4, 174, 304, 604) formed on said first nitride semiconductor layer;
a second nitride semiconductor layer (5, 6, 175, 176, 305, 306, 345, 365, 385, 605, 606, 625, 626) formed on said emission layer; and
a light absorption layer (7, 17, 27, 37, 47, 57, 67, 77b, 87b, 97b, 107b, 117a, 127, 137, 147, 157a, 157b, 177a, 187, 197a, 207a, 307, 327, 347, 367, 387, 407, 437, 457, 477, 497, 607, 627) formed by introducing a first impurity element into at least parts of regions of said first nitride semiconductor layer and said second nitride semiconductor layer other than a current passing region (8, 128, 138, 148, 158a, 158b, 178, 188, 198, 208, 628), wherein said second nitride semiconductor layer has a projecting ridge portion (308, 348, 368, 388, 608) including a current passing region.

60. A nitride semiconductor laser element comprising:
a first nitride semiconductor layer (2, 3, 172, 173, 302, 303, 602, 603);
an emission layer (4, 174, 304, 604) formed on said first nitride semiconductor layer;
a second nitride semiconductor layer (5, 6, 175, 176, 305, 306, 345, 365, 385, 605, 606, 625, 626) formed on said emission layer; and
a light absorption layer (7, 17, 27, 37, 47, 57, 67, 77b, 87b, 97b, 107b, 117a, 127, 137, 147, 157a, 157b, 177a, 187, 197a, 207a, 307, 327, 347, 367, 387, 407, 437, 457, 477, 497, 607, 627) formed by introducing a first impurity element into at least parts of regions of said first nitride semiconductor layer and said second nitride semiconductor layer other than a current passing region (8, 128, 138, 148, 158a, 158b, 178, 188, 198, 208, 628), wherein an insulator film is provided on said light absorption layer.
